(19) United States
(12) Patent Application Publication
(10) Pub. No.: US 2024/0210830 A1
(43) Pub. Date: Jun. 27, 2024

(54) RESIST COMPOSITION AND PATTERN FORMING PROCESS

(71) Applicant: Shin-Etsu Chemical Co., Ltd., Tokyo (JP)

(72) Inventors: Masaki Ohashi, Joetsu-shi (JP); Kazuhiro Katayama, Joetsu-shi (JP); Tatsuya Yamahira, Joetsu-shi (JP); Yutaro Otomo, Joetsu-shi (JP); Kousuke Ohyama, Joetsu-shi (JP)

(73) Assignee: Shin-Etsu Chemical Co., Ltd., Tokyo (JP)

(21) Appl. No.: 18/388,665

(22) Filed: Nov. 10, 2023

(30) Foreign Application Priority Data
Nov. 29, 2022 (JP) 2022-189708

(51) Int. Cl. G03F 7/039; G03F 7/004; G03F 7/029; G03F 7/20

(52) U.S. Cl. CPC G03F 7/0397; G03F 7/0045; G03F 7/0048; G03F 7/029; G03F 7/2004

(57) ABSTRACT

A resist composition is provided comprising (A) a polymer comprising repeat units having an acid labile group, (B) an organic solvent, and (C) an onium salt having formula: Zq⁺Xq⁻ wherein Zq⁺ is a sulfonium, iodonium or ammonium cation, and Xq⁻ is an anion. When processed by high-energy radiation lithography, the resist composition exhibits satisfactory sensitivity. LWR and maximum resolution and is resistant to pattern collapse.

### CROSS-REFERENCE TO RELATED APPLICATIONS

This non-provisional application claims priority under 35 U.S.C. § 119(a) on Patent Application No. 2022-189708 filed in Japan on Nov. 29, 2022, the entire contents of which are hereby incorporated by reference.

### TECHNICAL FIELD

This invention relates to a resist composition and a patterning process using the composition.

### BACKGROUND ART

To meet the demand for higher integration density and operating speed of LSIs, the effort to reduce the pattern rule is in rapid progress. As the use of 5G high-speed communications and artificial intelligence (AI) is widely spreading, high-performance devices are needed for their processing. As the advanced miniaturization technology, manufacturing of microelectronic devices at the 5-nm node by the lithography using EUV of wavelength 13.5 nm has been implemented in a mass scale. Studies are made on the application of EUV lithography to 3-nm node devices of the next generation and 2-nm node devices of the next-but-one generation.

As the feature size reduces, image blurs due to acid diffusion become a problem. To insure resolution for fine patterns with a size of 45 nm et seq., not only an improvement in dissolution contrast is important as previously reported, but the control of acid diffusion is also important as reported in Non-Patent Document 1. Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

A triangular tradeoff relationship among sensitivity, resolution, and edge roughness (LER, LWR) has been pointed out. Specifically, a resolution improvement requires to suppress acid diffusion whereas a short acid diffusion distance leads to a decline of sensitivity.

The addition of an acid generator capable of generating a bulky acid is an effective means for suppressing acid diffusion. It was then proposed to incorporate repeat units derived from an onium salt having a polymerizable unsaturated bond in a polymer. Since this polymer also functions as an acid generator, it is referred to as polymer-bound acid generator. Patent Document 1 discloses a polymer-bound acid generator capable of generating a specific fluorosulfonic acid.

Studies have also been made on quenchers or acid diffusion inhibitors. Amines are typically used as the quencher. Many problems associated with line width roughness (LWR) as an index of pattern roughness and pattern profile are left unsolved. Also, the use of weak acid onium salts as the quencher is under study. For example, Patent Document 2 describes improvements in sensitivity, resolution and exposure margin by the addition of ammonium salts of sulfonic acids or carboxylic acids. Patent Document 3 describes that a resist composition for KrF or EB lithography comprising a PAG capable of generating a fluorinated carboxylic acid is improved in resolution and process latitude such as exposure margin and depth of focus. Patent Document 4 describes a positive photosensitive composition for ArF excimer laser lithography comprising a carboxylic acid onium salt. Patent Document 5 describes an onium salt of fluoroalkanesulfonamide which converts to a weak acid onium salt. On use of this onium salt, the LWR as an index of pattern roughness and resolution are yet insufficient for the upcoming generation of ultrafine processing using ArF lithography or ArF immersion lithography. There is still a need for a weak acid onium salt having better quencher function. Also Patent Documents 6 to 8 describe an onium salt of α,α-difluorocarboxylic acid and an onium salt having an oxalic acid structure as the carboxylic acid onium salt.

These series of weak acid onium salts are based on the mechanism that a salt exchange occurs between a weak acid onium salt and a strong acid (sulfonic acid) which is generated by another PAG upon exposure, to form a weak acid and a strong acid onium salt. That is, the strong acid (α,α-difluorosulfonic acid) having high acidity is replaced by a weak acid (alkanesulfonic acid or carboxylic acid), thereby suppressing acid-aided elimination reaction of acid labile group and reducing or controlling the distance of acid diffusion. The onium salt apparently functions as a quencher. However, the resist compositions using such weak acid onium salts become unsatisfactory with respect to resolution, roughness (LWR), depth of focus (DOF) and the like, when the EUV lithography is applied to form smaller size patterns. Particularly in the region where the line-and-space pattern has a half pitch of 18 nm or smaller, the pattern collapse as a result of resist film swelling becomes serious. It is desired to have a quencher which prevents a resist pattern from collapsing as a result of the resist film swelling in alkaline developer.

### CITATION LIST

Patent Document 1: JP-A 2008-133448
Patent Document 2: JP-A H11-327143
Patent Document 3: JP-A 2001-281849
Patent Document 4: JP 4226803
Patent Document 5: JP-A 2012-108447
Patent Document 6: JP-A 2015-054833 (U.S. Pat. No. 9,221,742)
Patent Document 7: WO 2021/199789
Patent Document 8: JP 6304246
Non-Patent Document 1: SPIE Vol. 6520 65203L-1 (2007)

### SUMMARY OF THE INVENTION

An object of the invention is to provide a resist composition which when processed by lithography using high-energy radiation, especially EUV and EB, forms a resist pattern with satisfactory sensitivity, maximum resolution, LWR, and collapse resistance, and a pattern forming process using the resist composition.

The inventors have found that a resist composition comprising as the quencher an onium salt of a weak acid having a boiling point of lower than 165° C. and a molecular weight of up to 150 is effective for preventing a resist film from swelling during development, exhibits improved maximum resolution, and is quite useful in precise micropatterning.

In one aspect, the invention provides a resist composition comprising (A) a base polymer containing a polymer comprising repeat units having an acid labile group, (B) an organic solvent, and (C) an onium salt having the formula (1):

Zq⁺Xq⁻ (1)

wherein Zq⁺ is a sulfonium, iodonium or ammonium cation, and Xq⁻ is an anion, with the proviso that an acid having Xq⁻ as conjugate base, i.e., XqH has a boiling point of lower than 165° C. and a molecular weight of up to 150.

In a preferred embodiment, the repeat unit having an acid labile group is represented by the formula (a1) or (a2).

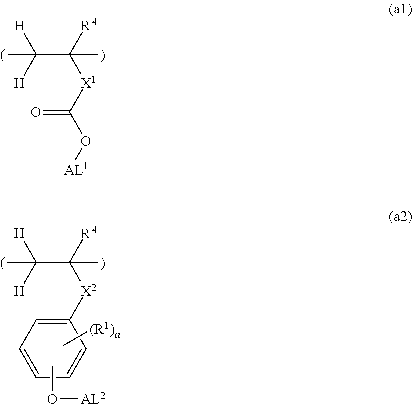

Herein R^{A} is each independently hydrogen, fluorine, methyl or trifluoromethyl,
X is a single bond, phenylene group, naphthylene group or *—C(═O)—O—X¹¹—, X¹¹ is a C₁-C₁₀ saturated hydrocarbylene group which may contain a hydroxy moiety, ether bond, ester bond or lactone ring, a phenylene group or naphthylene group,
X² is a single bond or *—C(═O)—O—,
* designates a point of attachment to the carbon atom in the backbone, and
AL¹ and AL² are each independently an acid labile group.
R¹ is halogen or a C₁-C₂₀ hydrocarbyl group which may contain a heteroatom, and
a is an integer of 0 to 4.

In a preferred embodiment, the polymer further comprises repeat units having the formula (b1) or (b2).

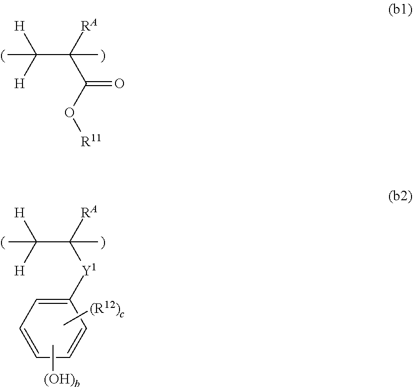

Herein R^{A} is each independently hydrogen, fluorine, methyl or trifluoromethyl,
Y¹ is a single bond or *—C(═O)—O—, * designates a point of attachment to the carbon atom in the backbone,
R¹¹ is hydrogen, or a C₁-C₂₀ group containing at least one moiety selected from hydroxy moiety, cyano moiety, carbonyl moiety, carboxy moiety, ether bond, ester bond, sulfonic ester bond, carbonate bond, lactone ring, sultone ring, and carboxylic anhydride (—C(═O)—O—C(═O)—),
R¹¹ is halogen or a C₁-C₂₀ hydrocarbyl group which may contain a heteroatom,
b is 1 or 2, c is an integer of 0 to 4, and b+c is from 1 to 5.

In a preferred embodiment, the polymer further comprises repeat units having a photoacid generating group. The repeat unit having a photoacid generating group is preferably represented by any one of the formulae (c1) to (c4).

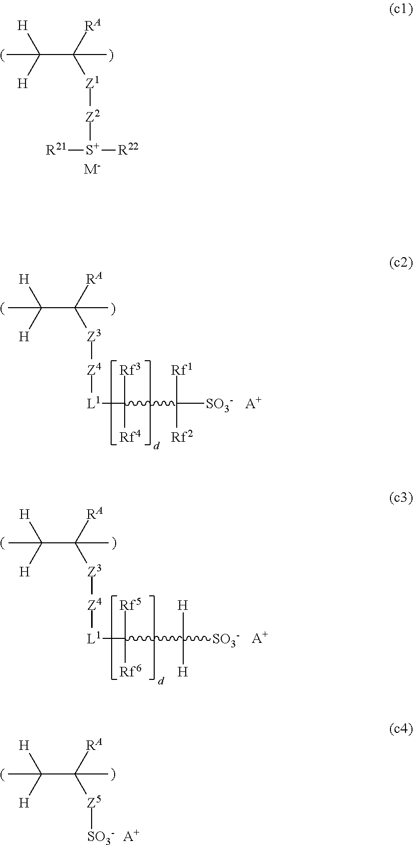

Herein R^{A} is each independently hydrogen, fluorine, methyl or trifluoromethyl,
Z¹ is a single bond or phenylene group,
Z² is *—C(═O)—O—Z²¹—, *—C(═O)—NH—Z²¹—, or *—O—Z²¹—, wherein Z¹ is a C₁-C₆ aliphatic hydrocarbylene group, phenylene, or divalent group obtained by combining the foregoing, which may contain a carbonyl moiety, ester bond, ether bond or hydroxy moiety,
Z³ is a single bond, phenylene group, naphthylene group or *—C(═O)—O—Z³¹—, wherein Z³¹ is a C₁-C₁₀ aliphatic hydrocarbylene group which may contain a hydroxy moiety, ether bond, ester bond or lactone ring, or a phenylene group or naphthylene group,
Z⁴ is a single bond or **—Z⁴¹—C(═O)—O—, wherein Z⁴¹ is a C₁-C₂₀ hydrocarbylene group which may contain a heteroatom,
Z⁵ is a single bond, methylene, ethylene, phenylene, fluorinated phenylene, trifluoromethyl-substituted phenylene, *—C(═O)—O—Z⁵¹—, *—C(═O)—N(H)—Z⁵¹— or *—O—Z⁵¹− wherein Z⁵¹ is a C₁-C₆ aliphatic hydrocarbylene group, phenylene, fluorinated phenylene or trifluoromethyl-substituted phenylene group, which may contain a carbonyl moiety, ester bond, ether bond or hydroxy moiety,
* designates a point of attachment to the carbon atom in the backbone, ** designates a point of attachment to Z³,
R¹ and R²² are each independently a C₁-C₂₀ hydrocarbyl group which may contain a heteroatom, R²¹ and R²² may bond together to form a ring with the sulfur atom to which they are attached,

L¹ is a single bond, ether bond, ester bond, carbonyl group, sulfonic ester bond, carbonate bond or carbamate bond,

Rf¹ and Rf² are each independently fluorine or a C₁-C₆ fluorinated saturated hydrocarbyl group.

Rf³ and Rf⁴ are each independently hydrogen, fluorine or a C₁-C₆ fluorinated saturated hydrocarbyl group,

Rf⁵ and Rf⁶ are each independently hydrogen, fluorine or a C₁-C₆ fluorinated saturated hydrocarbyl group, excluding that all Rf⁵ and Rf⁶ are hydrogen at the same time,

M⁻ is a non-nucleophilic counter anion,

A⁺ is an onium cation, and

d is an integer of 0 to 3.

The resist composition may further comprise (D) a photoacid generator. Preferably, the photoacid generator (D) has the formula (2) or (3).

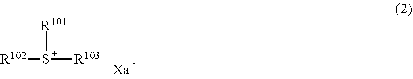

Herein R¹⁰¹, R¹⁰² and R¹⁰³ are each independently a C₁-C₂₀ hydrocarbyl group which may contain a heteroatom, R¹⁰¹ and R¹⁰² may bond together to form a ring with the sulfur atom to which they are attached, and Xa⁻ is a non-nucleophilic counter anion.

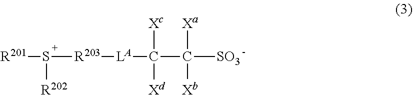

Herein R²⁰¹ and R²⁰² are each independently a C₁-C₃₀ hydrocarbyl group which may contain a heteroatom, R²⁰³ is a C₁-C₃₀ hydrocarbylene group which may contain a heteroatom, any two of R²⁰¹, R²⁰² and R²⁰³ may bond together to form a ring with the sulfur atom to which they are attached,

L^{A} is a single bond, ether bond or a C₁-C₂₀ hydrocarbylene group which may contain a heteroatom,

X^{a}, X^{b}, X^{c} and X^{d} are each independently hydrogen, fluorine or trifluoromethyl, with the proviso that at least one of X^{a}, X^{b}, X^{c} and X^{d} is fluorine or trifluoromethyl.

The resist composition may further comprise (E) a nitrogen-containing compound and/or (F) a surfactant.

In another aspect, the invention provides a process for forming a pattern comprising the steps of applying the resist composition defined herein to a substrate to form a resist film thereon, exposing the resist film to KrF excimer laser, ArF excimer laser, EB or EUV and developing the exposed resist film in a developer.

### Advantageous Effects of Invention

The resist composition is characterized by low acid diffusion and low swell. A pattern profile with reduced LWR and high resolution can be constructed therefrom.

### BRIEF DESCRIPTION OF THE DRAWINGS

FIG. 1 is a diagram showing the ¹H-NMR spectrum of Onium salt SQ-1 in Synthesis Example 2-1.

FIG. 2 is a diagram showing the ¹⁹F-NMR spectrum of Onium salt SQ-1 in Synthesis Example 2-1.

### DETAILED DESCRIPTION OF THE INVENTION

As used herein, the singular forms “a,” “an” and “the” include plural referents unless the context clearly dictates otherwise. “Optional” or “optionally” means that the subsequently described event or circumstances may or may not occur, and that description includes instances where the event or circumstance occurs and instances where it does not. The notation (Cn-Cm) means a group containing from n to m carbon atoms per group. In chemical formulae, the broken line ( - - - ) and asterisk (*) each designate a point of attachment, namely valence bond. Me stands for methyl and Ac for acetyl. As used herein, the term “fluorinated” refers to a fluorine-substituted or fluorine-containing compound or group. The terms “group” and “moiety” are interchangeable.

The abbreviations and acronyms have the following meaning.
EB: electron beam
EUV: extreme ultraviolet
Mw: weight average molecular weight
Mn: number average molecular weight
Mw/Mn: molecular weight distribution or dispersity
GPC: gel permeation chromatography
PEB: post-exposure bake
PAG: photoacid generator
LWR: line width roughness
CDU: critical dimension uniformity
EL: exposure latitude
DOF: depth of focus

### (A) Polymer

One embodiment of the invention is a resist composition comprising (A) a base polymer containing a polymer comprising repeat units having an acid labile group. The repeat unit having an acid labile group is preferably a repeat unit having the formula (a1) or a repeat unit having the formula (a2). These repeat units are also referred to as repeat units (a1) and (a2).

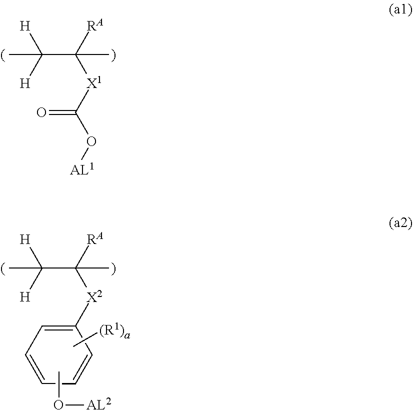

In formulae (a1) and (a2), R^{A} is each independently hydrogen, fluorine, methyl or trifluoromethyl. X¹ is a single bond, phenylene group, naphthylene group or *—C(═O)—O—X¹¹—. X¹¹ is a C₁-C₁₀ saturated hydrocarbylene group which may contain a hydroxy moiety, ether bond, ester bond or lactone ring, a phenylene group or naphthylene group. X² is a single bond or *—C(═O)—O—. The asterisk (*) designates a point of attachment to the carbon atom in the backbone. AL¹ and AL² are each independently an acid labile group.

In formula (a2), R¹ is halogen or a C₁-C₂₀ hydrocarbyl group which may contain a heteroatom. The hydrocarbyl group may be saturated or unsaturated and straight, branched or cyclic.

In formula (a2), “a” is an integer of 0 to 4, preferably 0 or 1.

Examples of the structure of formula (a1) wherein X¹ is a variant are illustrated below, but not limited thereto. Herein R^{A} and AL¹ are as defined above.

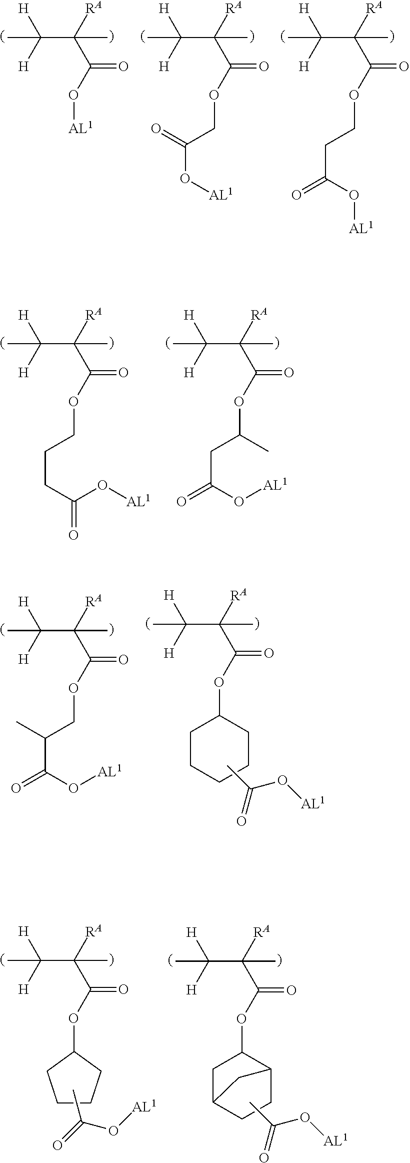

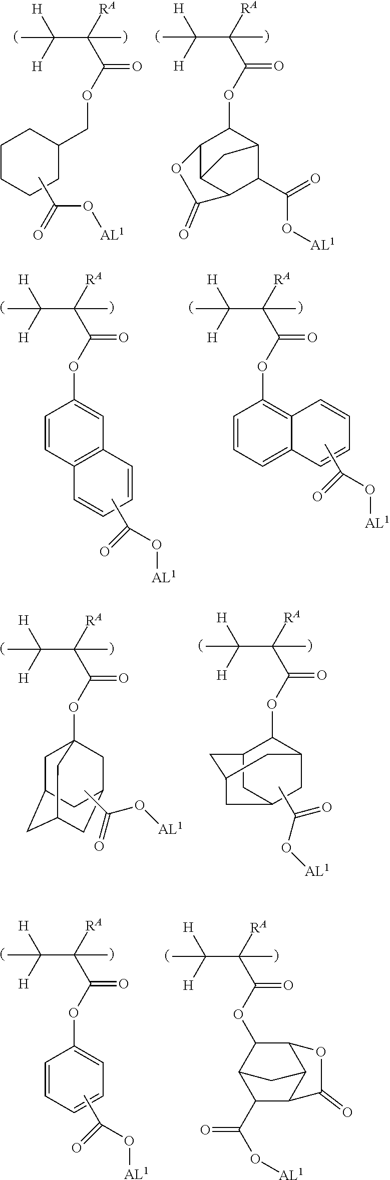

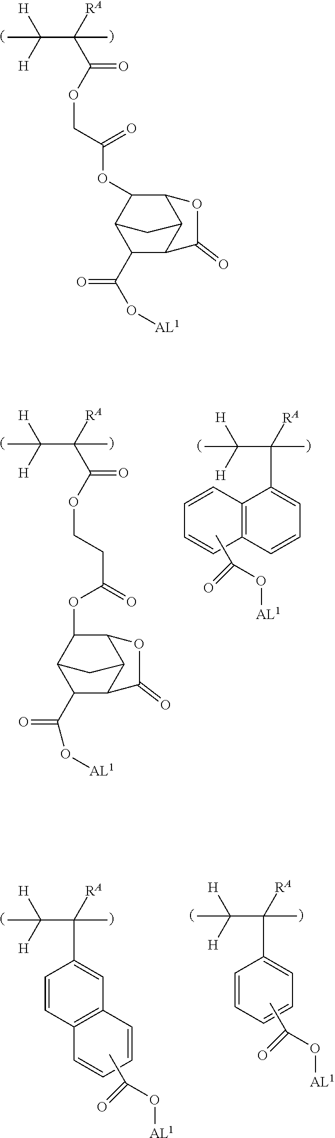

A polymer comprising repeat units (a1) turns alkali soluble through the mechanism that it is decomposed to generate a carboxy group under the action of acid.

The acid labile groups represented by AL¹ and AL² may be selected from a variety of such groups. Preferred examples of the acid labile group are groups of the following formulae (L1) to (L4), C₄-C₂₀, preferably C₄-C₁₅ tertiary hydrocarbyl groups, trihydrocarbylsilyl groups in which each hydrocarbyl moiety has 1 to 6 carbon atoms, and C₄-C₂₀ hydrocarbyl groups containing a carbonyl moiety, ether bond or ester bond.

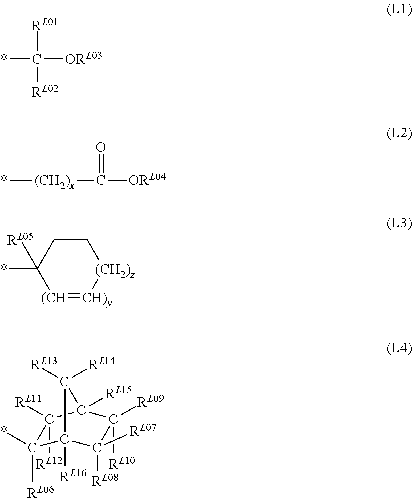

In formula (L1), R^{L01} and R^{L02} are each independently hydrogen or a C₁-Cia saturated hydrocarbyl group. The saturated hydrocarbyl group may be straight, branched or cyclic and examples thereof include alkyl groups such as methyl, ethyl, n-propyl, isopropyl, n-butyl, sec-butyl, tert-butyl, n-octyl, and 2-ethylhexyl, and cyclic saturated hydrocarbyl groups such as cyclopentyl, cyclohexyl, norbornyl, tricyclodecanyl, tetracyclododecanyl, and adamantyl. Of the saturated hydrocarbyl groups, those of 1 to 10 carbon atoms are preferred.

R^{L03} is a C₁-C₁₈, preferably C₁-C₁₀ hydrocarbyl group which may contain a moiety containing a heteroatom. The hydrocarbyl group may be saturated or unsaturated and straight, branched or cyclic. Saturated hydrocarbyl groups are preferred. In the saturated hydrocarbyl group, some or all of the hydrogen atoms may be substituted by hydroxy, saturated hydrocarbyloxy, oxo, amino, saturated hydrocarbylamino or the like, or some constituent —CH₂— may be replaced by a moiety containing a heteroatom, typically oxygen. Suitable saturated hydrocarbyl groups are as exemplified above for the saturated hydrocarbyl groups R^{L01} and R^{L02}. Examples of the substituted saturated hydrocarbyl group are shown below.

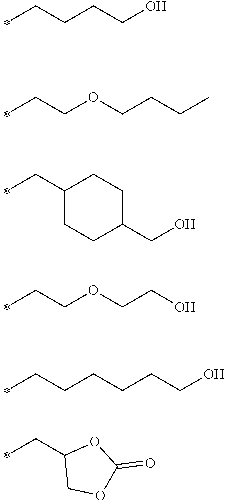

Any two of R^{L01}, R^{L02}, and R^{L03} may bond together to form a ring with the carbon atom or the carbon and oxygen atoms to which they are attached. When any two of R^{L01}, R^{L02} and R^{L03} form a ring, each is independently a C₁-C₁₈, preferably C₁-C₁₀ alkanediyl group.

In formula (L2), R^{L04} is a C₄-C₂₀, preferably C₄-C₁₅ tertiary hydrocarbyl group, a trialkylsilyl group in which each alkyl moiety has 1 to 6 carbon atoms, a C₄-C₂₀ saturated hydrocarbyl group containing a carbonyl moiety, ether bond or ester bond, or a group of formula (L1). The subscript x is an integer of 0 to 6.

Of the groups R^{L04}, the tertiary hydrocarbyl group may be branched or cyclic, and examples thereof include tert-butyl, tert-pentyl, 1,1-diethylpropyl, 2-cyclopentylpropan-2-yl, 2-cyclohexylpropan-2-yl, 2-(bicyclo[2.2.1]heptan-2-yl)propan-2-yl, 2-(adamantan-1-yl)propan-2-yl, 1-ethylcyclopentyl, 1-butylcyclopentyl, 1-ethylcyclohexyl, 1-butylcyclohexyl, 1-ethyl-2-cyclopentenyl, 1-ethyl-2-cyclohexenyl, 2-methyl-2-adamantyl, and 2-ethyl-2-adamantyl. Exemplary trialkylsilyl groups include trimethylsilyl, triethylsilyl, and dimethyl-tert-butylsilyl. Exemplary saturated hydrocarbyl groups containing a carbonyl, ether bond or ester bond include 3-oxocyclohexyl, 4-methyl-2-oxooxan-4-yl, and 5-methyl-2-oxooxolan-5-yl.

In formula (L3), RIAS is an optionally substituted C₁-C₈ saturated hydrocarbyl group or an optionally substituted C₆-C₂₀ aryl group. The optionally substituted saturated hydrocarbyl group may be straight, branched or cyclic and examples thereof include alkyl groups such as methyl, ethyl, n-propyl, isopropyl, n-butyl, sec-butyl, tert-butyl, n-pentyl, tert-pentyl, and n-hexyl, cyclic saturated hydrocarbyl groups such as cyclopentyl and cyclohexyl, and substituted forms of the foregoing in which some or all of the hydrogen atoms are substituted by hydroxy, C₁-C₈ saturated hydrocarbyloxy, carboxy, C₁-C₈ saturated hydrocarbylcarbonyl, oxo, amino, C₁-C₆ saturated hydrocarbylamino, cyano, mercapto, C₁-C₈ saturated hydrocarbylthio, sulfo or the like. Examples of the optionally substituted aryl group include phenyl, methylphenyl, naphthyl, anthryl, phenanthryl, and pyrenyl, and substituted forms of the foregoing in which some or all of the hydrogen atoms are substituted by hydroxy, C₁-C₈ saturated hydrocarbyloxy, carboxy, C₁-C₈ saturated hydrocarbylcarbonyl, oxo, amino, C₁-C₈ saturated hydrocarbylamino, cyano, mercapto, C₁-C₈ saturated hydrocarbylthio, sulfo or the like.

In formula (L3), y is equal to 0 or 1, z is an integer of 0 to 3, and 2y+z is equal to 2 or 3.

In formula (L4), R^{L06} is an optionally substituted C₁-C₈ saturated hydrocarbyl group or an optionally substituted C₆-C₂₀ aryl group. Examples of the optionally substituted saturated hydrocarbyl and optionally substituted aryl groups are the same as exemplified above for R^{L05}.

R^{L07} to R^{L06} are each independently hydrogen or an optionally substituted C₁-C₁₅ hydrocarbyl group. The hydrocarbyl group may be saturated or unsaturated and straight, branched or cyclic, with saturated hydrocarbyl groups being preferred. Examples of the hydrocarbyl group include alkyl groups such as methyl, ethyl, n-propyl, isopropyl, n-butyl, sec-butyl, tert-butyl, n-pentyl, tert-pentyl, n-hexyl, n-octyl, n-nonyl, and n-decyl; cyclic saturated hydrocarbyl groups such as cyclopentyl, cyclohexyl, cyclopentylmethyl, cyclopentylethyl, cyclopentylbutyl, cyclohexyhuethyl, cyclohexylethyl and cyclohexylbutyl; and substituted forms of the foregoing in which some or all of the hydrogen atoms are substituted by hydroxy, C₁-C₈ saturated hydrocarbyloxy, carboxy, C₁-C₈ saturated hydrocarbyloxycarbonyl, oxo, amino, C₁-C₈ saturated hydrocarbylamino, cyano, mercapto, C₁-C₈ saturated hydrocarbylthio, sulfo or the like. Alternatively, two of R^{L07} to R^{L06} may bond together to form a ring with the carbon atom to which they are attached (for example, a pair of R^{L07} and R^{L08}, R^{L07} and R^{L09}, R^{L07} and R^{L10}, R^{L08} and R^{L10}, R^{L09} and R^{L10}, R^{L11} and R^{L12}, R^{L13} and R^{L14}, or a similar pair form a ring). Each of ring-forming R^{L07} to R^{L16} represents a C₁-C₁₅ hydrocarbylene group, examples of which are the ones exemplified above for the hydrocarbyl groups, with one hydrogen atom being eliminated. Two of R^{L07} to R^{L16} which are attached to vicinal carbon atoms may bond together directly to form a double bond (for example, a pair of R^{L07} and R^{L09}, R^{L09} and R^{L15}, R^{L13} and R^{L15}, R^{L14} and R^{L15}, or a similar pair).

Of the acid labile groups having formula (L1), the straight and branched ones are exemplified by the following groups, but not limited thereto.

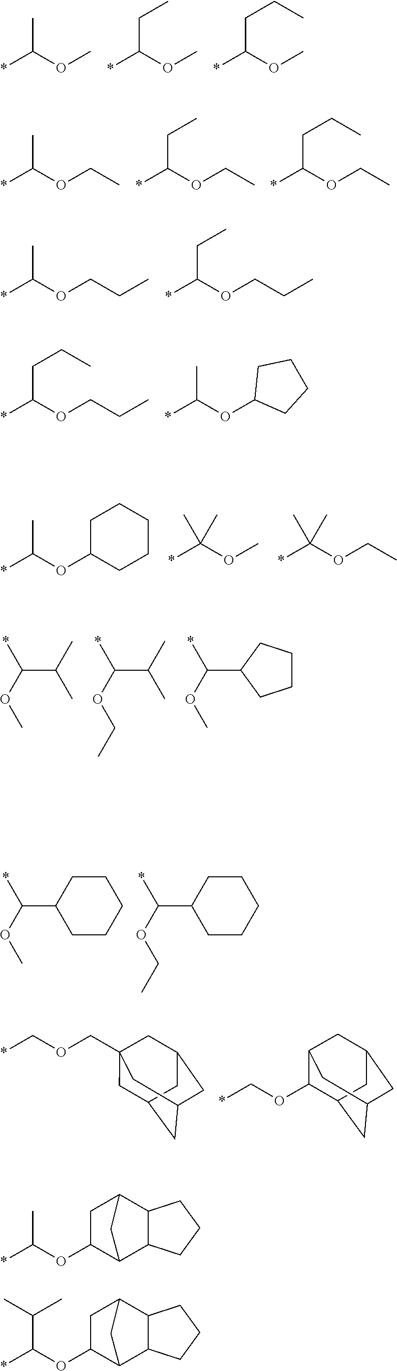

Of the acid labile groups having formula (L1), the cyclic ones are, for example, tetrahydrofuran-2-yl, 2-methyltetrahydrofuran-2-yl, tetrahydropyran-2-yl, and 2-methyltetrahydropyran-2-yl.

Examples of the acid labile group having formula (L2) include tert-butoxycarbonyl, tert-butoxycarbonylmethyl, tert-pentyloxycarbonyl, tert-pentyloxycarbonylmethyl, 1,1-diethylpropyloxycarbonyl, 1,1-diethylpropyloxycarbonylmethyl, 1-ethylcyclopentyloxycarbonyl, 1-ethylcyclopentyloxycarbonylmethyl, 1-ethyl-2-cyclopentenyloxycarbonyl, 1-ethyl-2-cyclopentenyloxycarbonyhuethyl, 1-ethoxyethoxycarbonylmethyl, 2-tetrahydropyranyloxycarbonylmethyl, and 2-tetrahydrofuranyloxycarbonylmethyl groups.

Examples of the acid labile group having formula (L3) include 1-methylcyclopentyl, 1-ethylcyclopentyl, 1-n-propylcyclopentyl, 1-isopropylcyclopentyl, 1-n-butylcyclopentyl, 1-sec-butylcyclopentyl, 1-cyclohexylcyclopentyl, 1-(4-methoxy-n-butyl)cyclopentyl, 1-methylcyclohexyl, 1-ethylcyclohexyl, 3-methyl-1-cyclopenten-3-yl, 3-ethyl-1-cyclopenten-3-yl, 3-methyl-1-cyclohexen-3-yl, and 3-ethyl-1-cyclohexen-3-yl groups.

Of the acid labile groups having formula (L4), groups having the following formulae (L4-1) to (L4-4) are preferred.

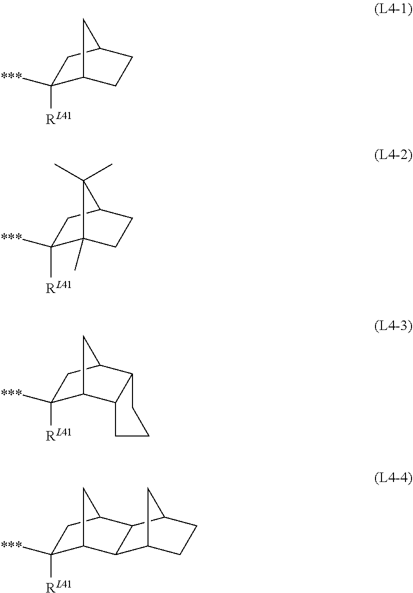

In formulae (L4-1) to (L4-4), the triple asterisks (***) denotes a bonding site and direction. R^{L41} is each independently a C₁-C₁₀ hydrocarbyl group. The hydrocarbyl group may be saturated or unsaturated and straight, branched or cyclic, with saturated hydrocarbyl groups being preferred. Suitable hydrocarbyl groups include alkyl groups such as methyl, ethyl, n-propyl, isopropyl, n-butyl, sec-butyl, tert-butyl, n-pentyl, tert-pentyl, and n-hexyl, and cyclic saturated hydrocarbyl groups such as cyclopentyl and cyclohexyl.

For formulae (L4-1) to (L4-4), there can exist stereoisomers (enantiomers or diastereomers). Each of formulae (L4-1) to (L4-4) collectively represents all such stereoisomers. When the acid labile group is of formula (L4), there may be contained a plurality of stereoisomers.

For example, the formula (L4-3) represents one or a mixture of two selected from groups having the following formulae (L4-3-1) and (L4-3-2).

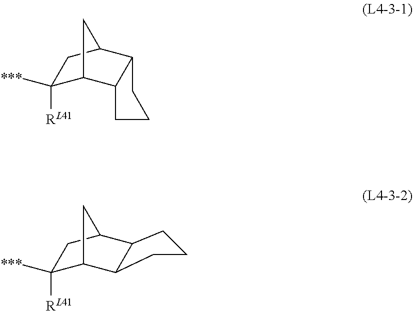

Herein R^{L41} and *** are as defined above.

Similarly, the formula (L4-4) represents one or a mixture of two or more selected from groups having the following formulae (L4-4-1) to (L4-4-4).

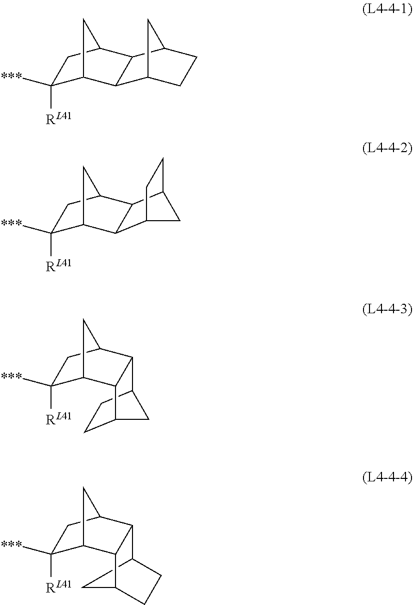

Herein R^{L41} and *** are as defined above.

Each of formulae (L4-1) to (L4-4), (L4-3-1), (L4-3-2), and (L4-4-1) to (L4-4-4) collectively represents an enantiomer thereof and a mixture of enantiomers.

It is noted that in the above formulae (L4-1) to (L4-4), (L4-3-1), (L4-3-2), and (L4-4-1) to (L4-4-4), the bond direction is on the exo side relative to the bicyclo[2.2.1]heptane ring, which ensures high reactivity for acid catalyzed elimination reaction (see JP-A 2000-336121). In preparing these monomers having a tertiary exo-saturated hydrocarbyl group of bicyclo[2.2.1]heptane skeleton as a substituent group, there may be contained monomers substituted with an endo-alkyl group as represented by the following formulae (L4-1-endo) to (L4-4-endo). For good reactivity, an exo proportion of at least 50 mol % is preferred, with an exo proportion of at least 80 mol % being more preferred.

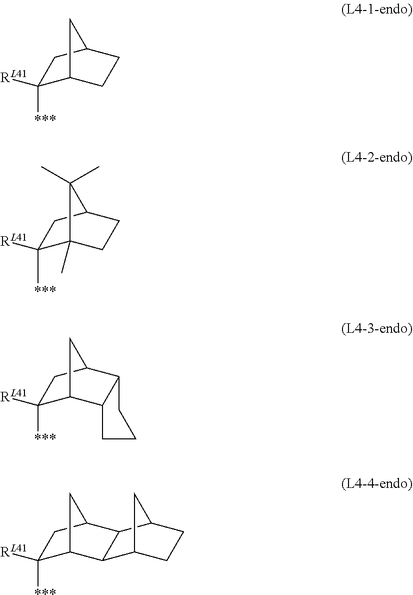

Herein R^{L41} and *** are as defined above.

Illustrative examples of the acid labile group having formula (L4) are given below, but not limited thereto.

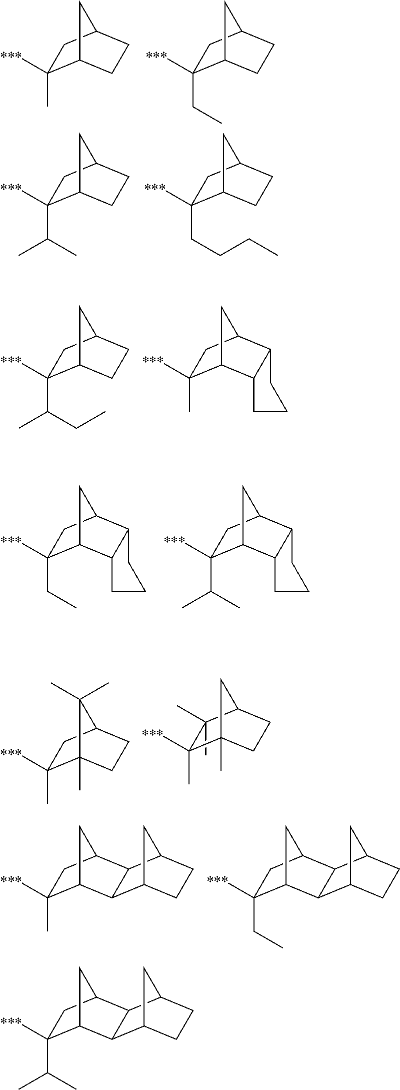

Herein *** is as defined above.

Of the acid labile groups represented by AL¹ and AL², examples of the C₄-C₂₀ tertiary hydrocarbyl groups, trihydrocarbylsilyl groups in which each hydrocarbyl moiety has 1 to 6 carbon atoms, and C₄-C₂₀ saturated hydrocarbyl groups containing carbonyl, ether bond or ester bond are as exemplified above for R^{L04}.

Illustrative examples of the repeat unit (a1) are given below, but not limited thereto. Herein R^{A} is as defined above.

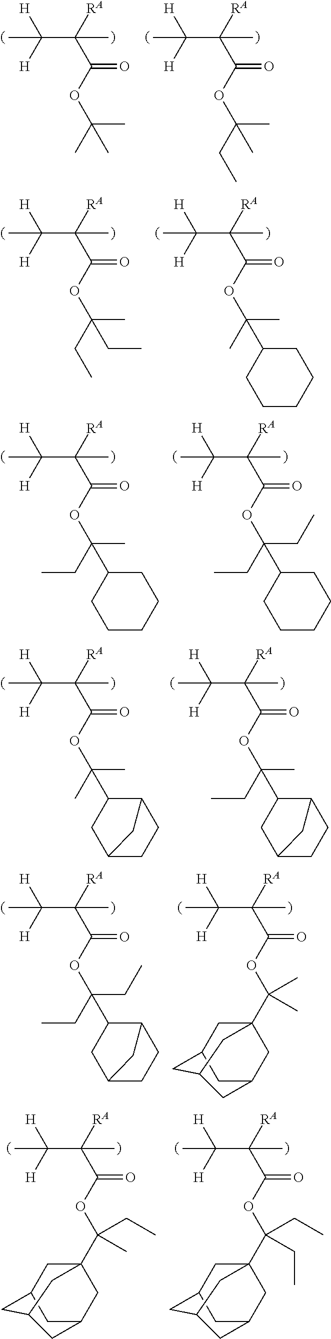

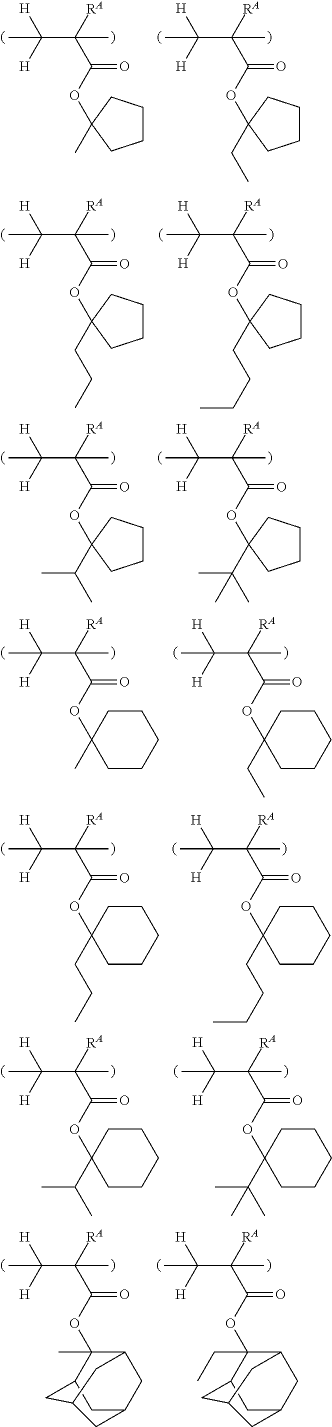

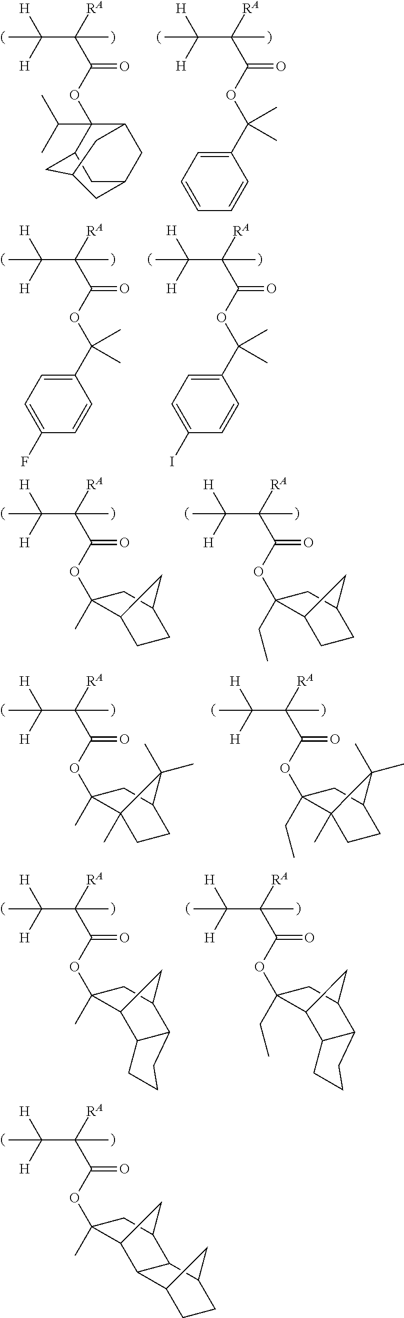

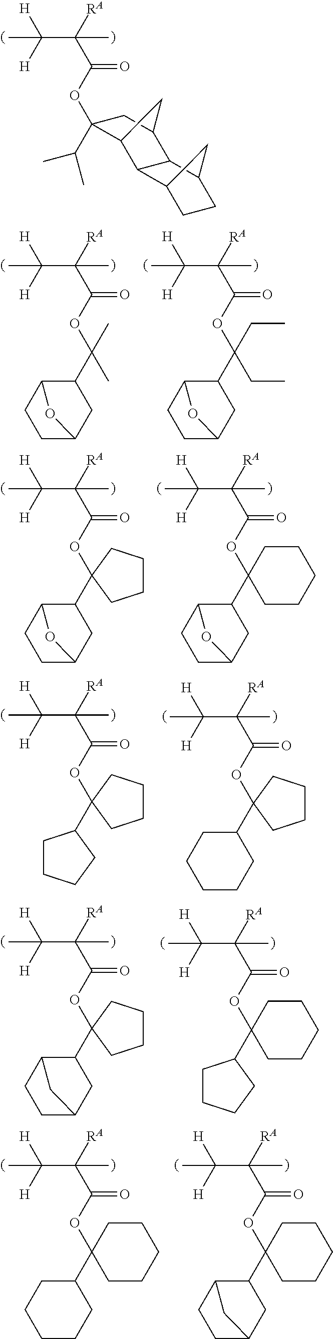

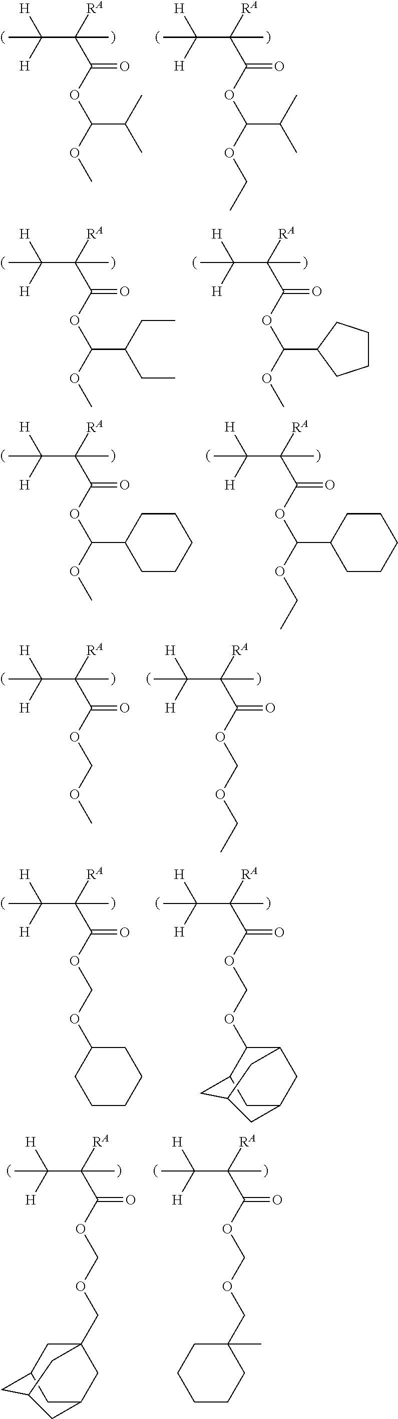

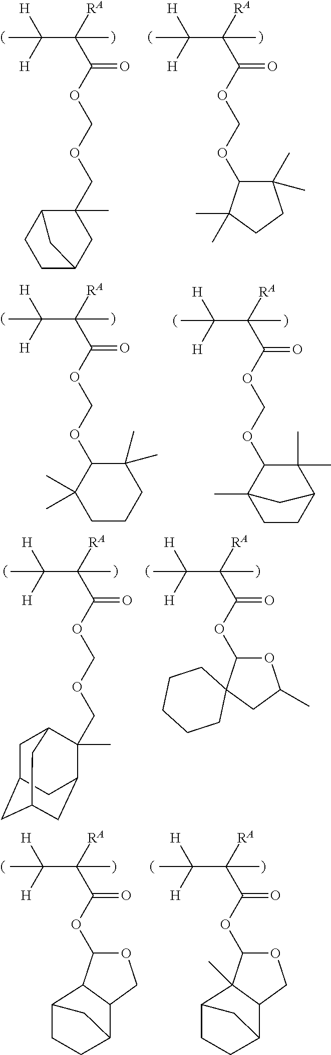

While the foregoing examples correspond to those units wherein X¹ is a single bond, X¹ which is other than a single bond may be combined with similar acid labile groups. Examples of units wherein X¹ is other than a single bond are substantially the same as illustrated above.

Like the repeat units (a1), a polymer comprising repeat units (a2) turns alkali soluble through the mechanism that it is decomposed to generate a hydroxy group under the action of acid. Illustrative examples of the repeat units (a2) are given below, but not limited thereto. Herein R^{A} is as defined above.

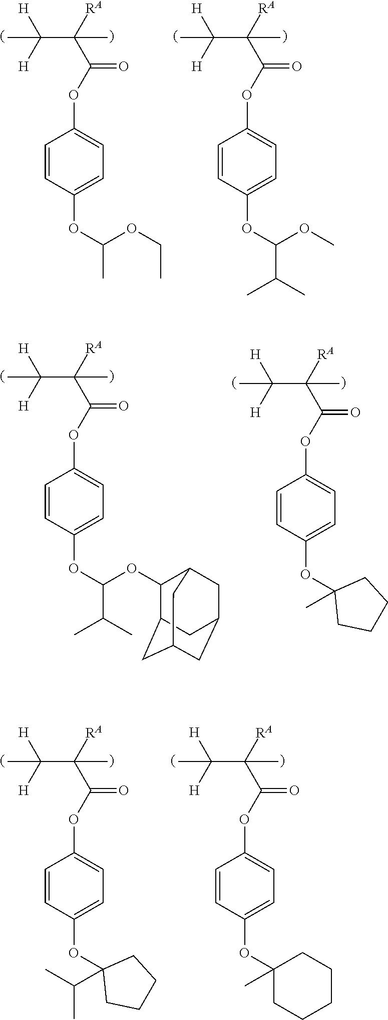

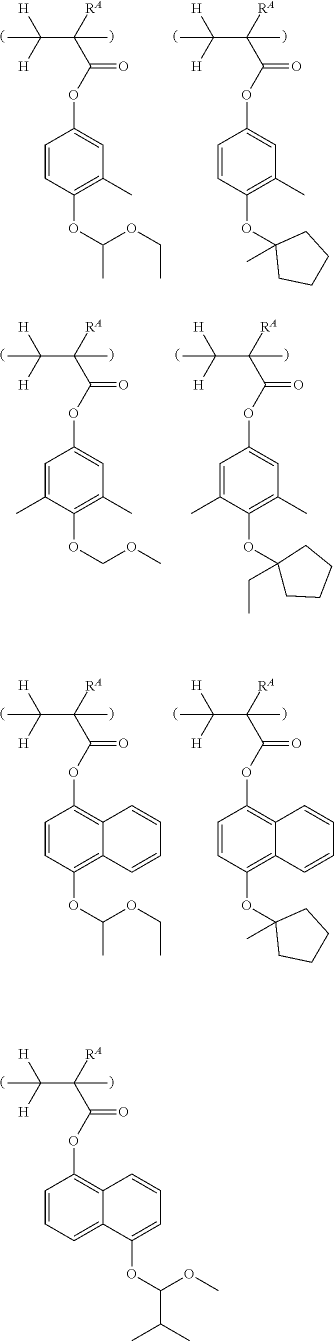

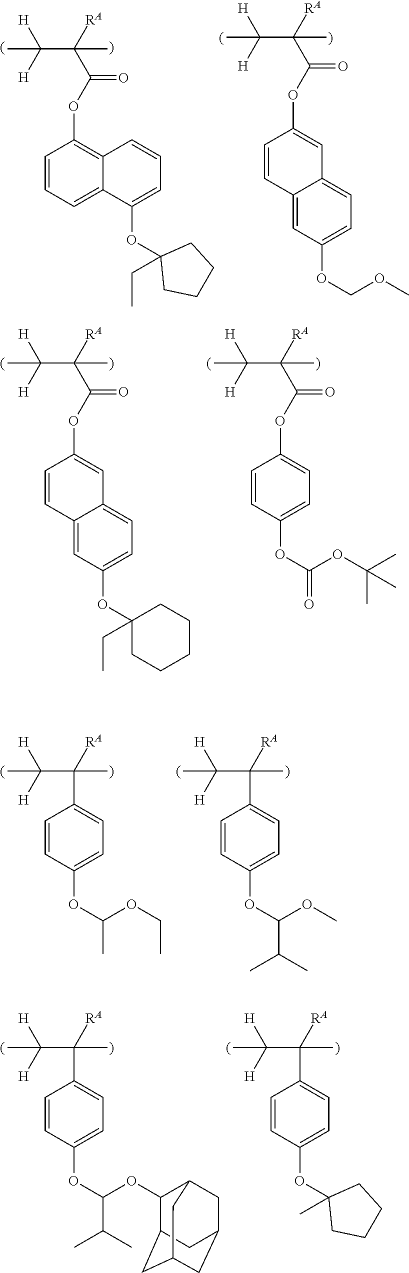

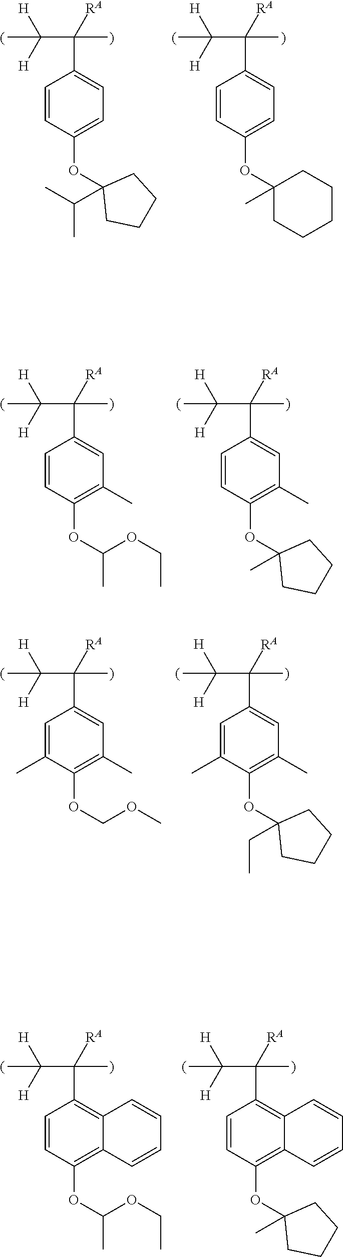

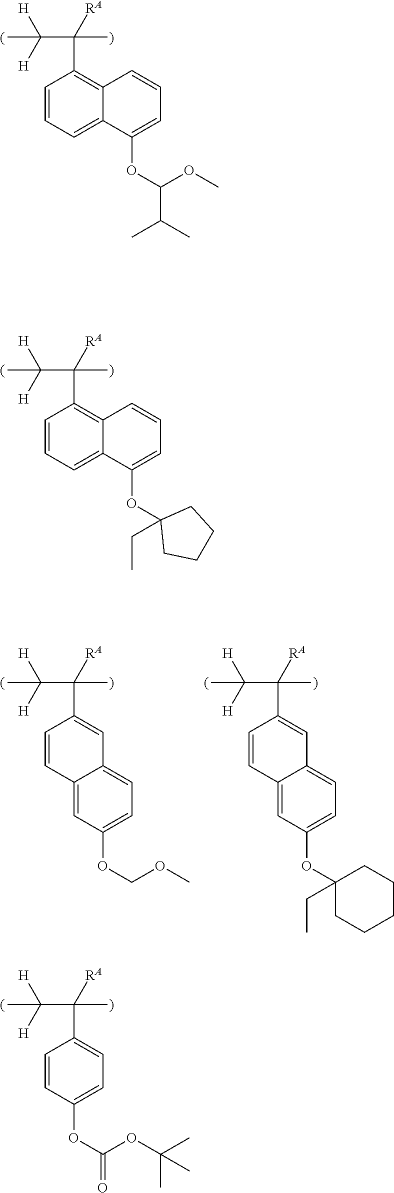

In a preferred embodiment, the base polymer further comprises repeat units having the formula (b1) or repeat units having the formula (b2), which are simply referred to as repeat units (b1) or (b2).

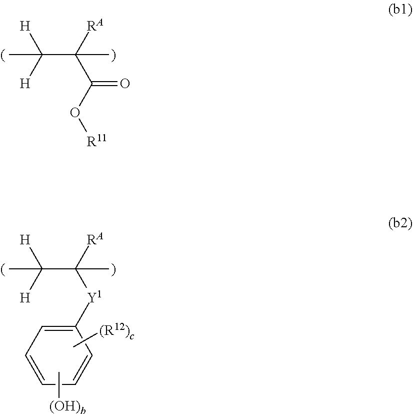

In formulae (b1) and (b2), R^{A} is each independently hydrogen, fluorine, methyl or trifluoromethyl. Y¹ is a single bond or *—C(═O)—O—. The asterisk (*) designates a point of attachment to the carbon atom in the backbone. R¹¹ is hydrogen or a C₁-C₂₀ group containing at least one structure selected from among hydroxy, cyano, carbonyl, carboxy, ether bond, ester bond, sulfonic ester bond, carbonate bond, lactone ring, sultone ring, and carboxylic anhydride (—C(═O)—O—C(═O)—). R¹² is halogen or a C₁-C₂₀ hydrocarbyl group which may contain a heteroatom. The subscript b is 1 or 2, c is an integer of 0 to 4, and b+c is from 1 to 5.

Examples of the repeat unit (b1) are shown below, but not limited thereto. Herein, R^{A} is as defined above.

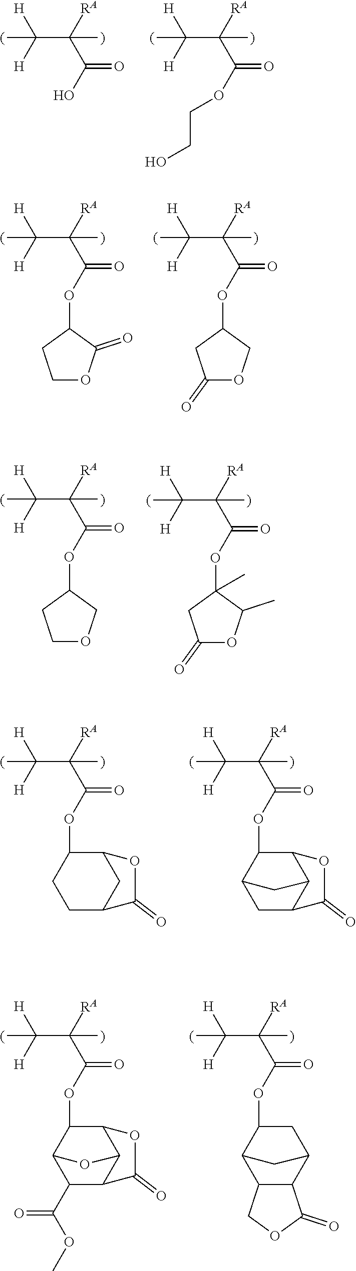

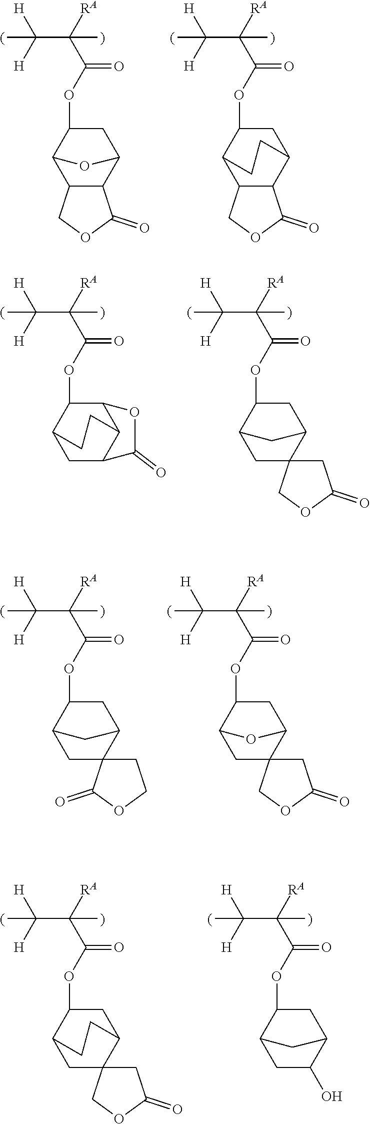

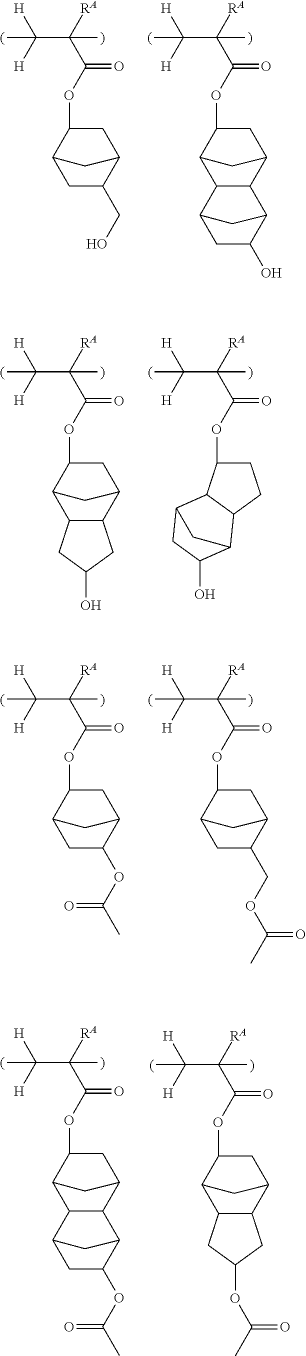

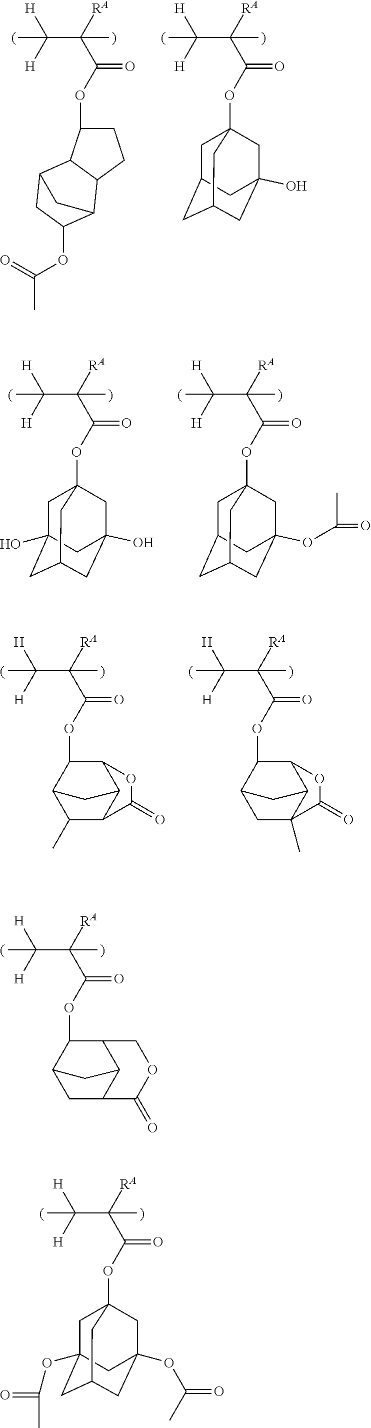

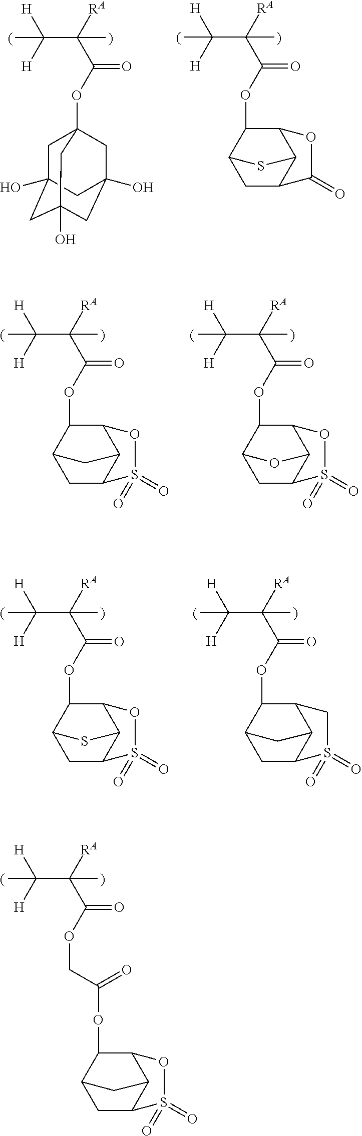

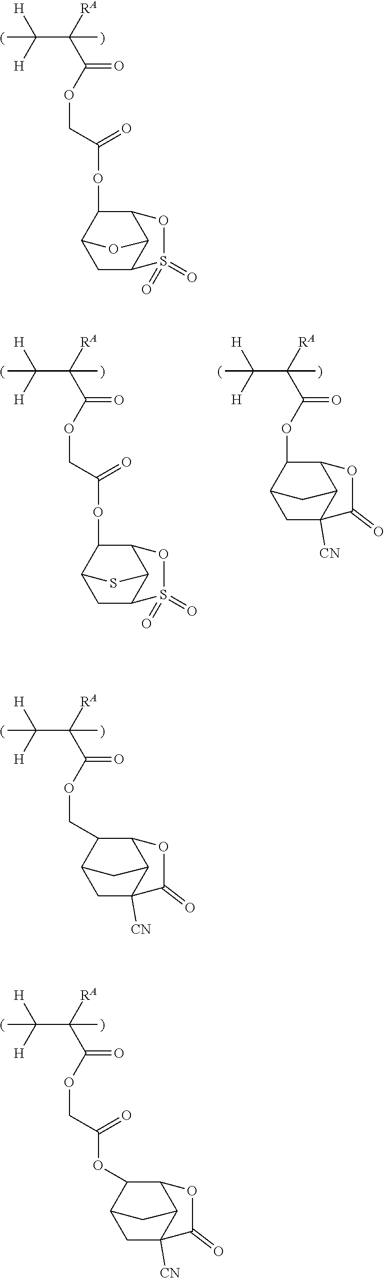

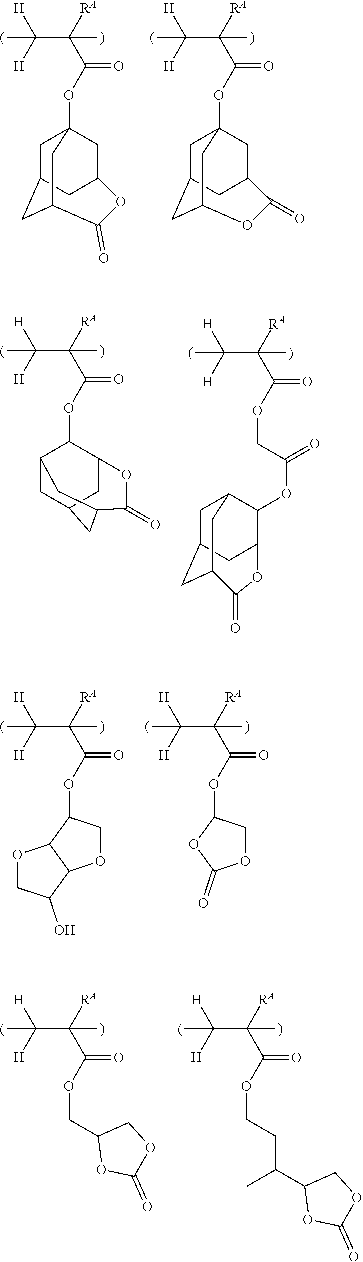

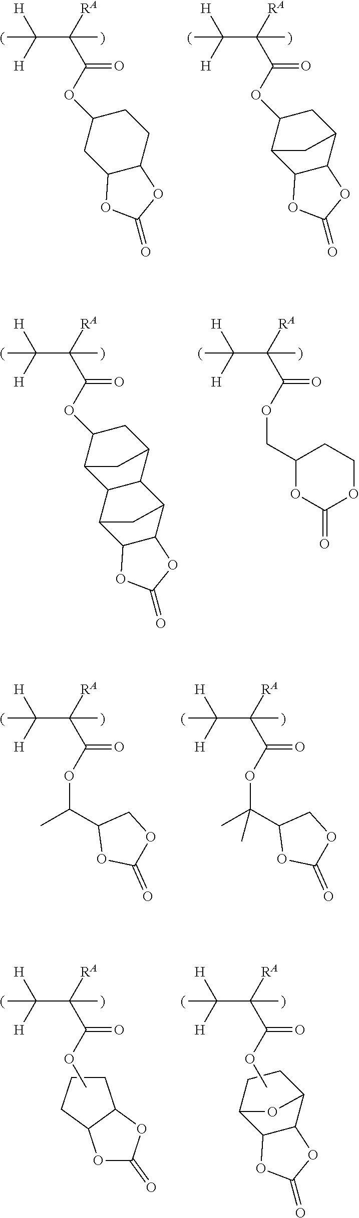

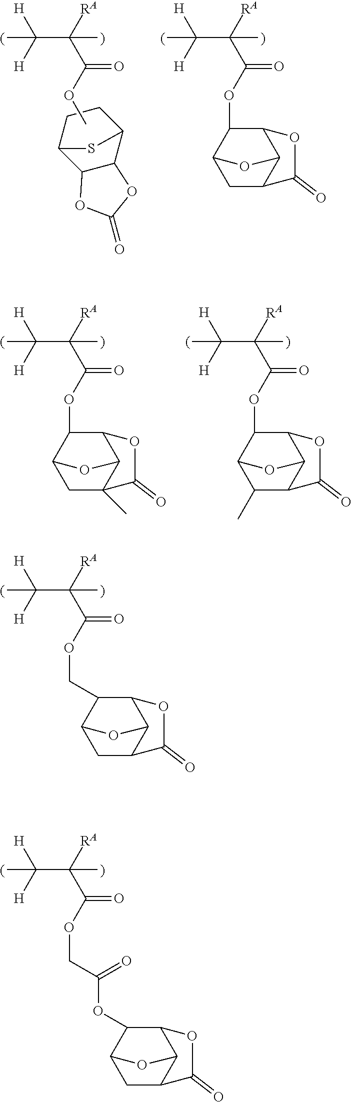

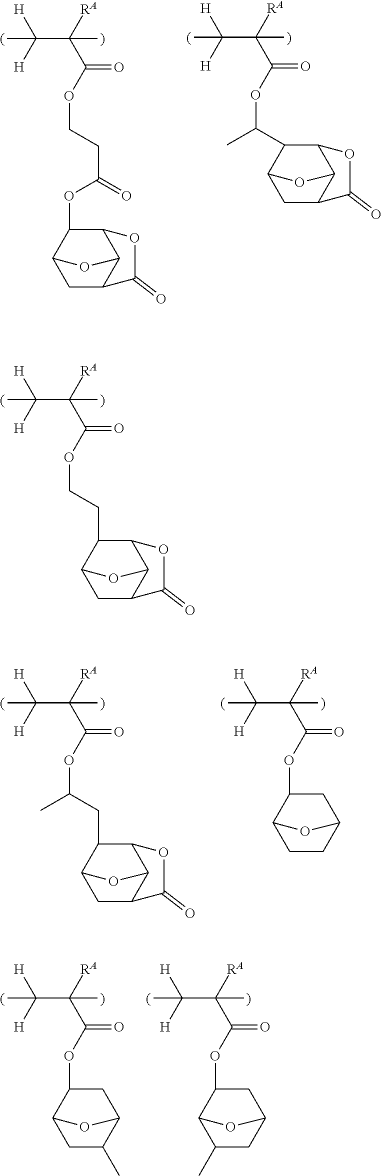

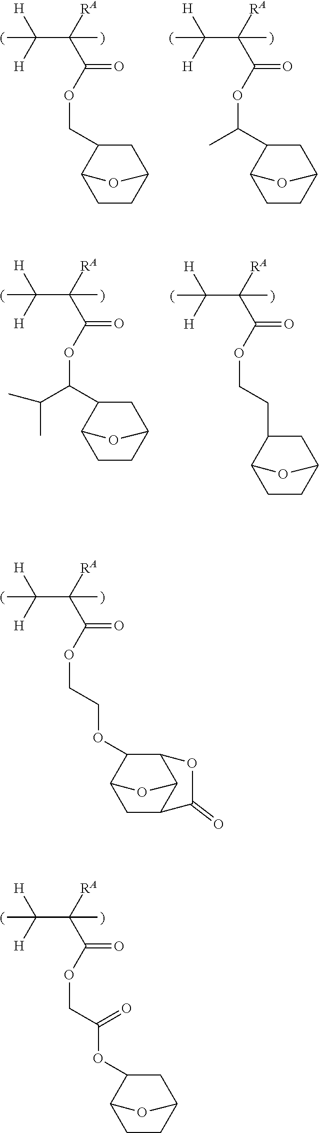

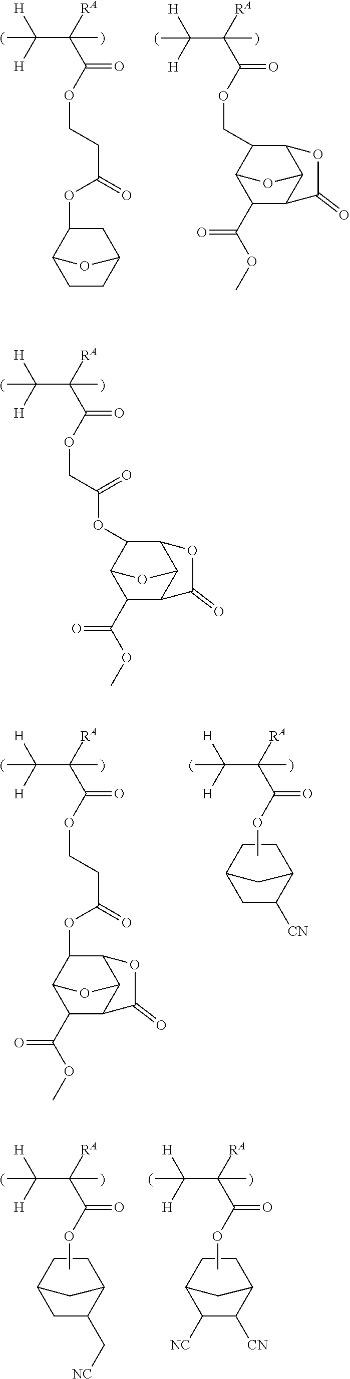

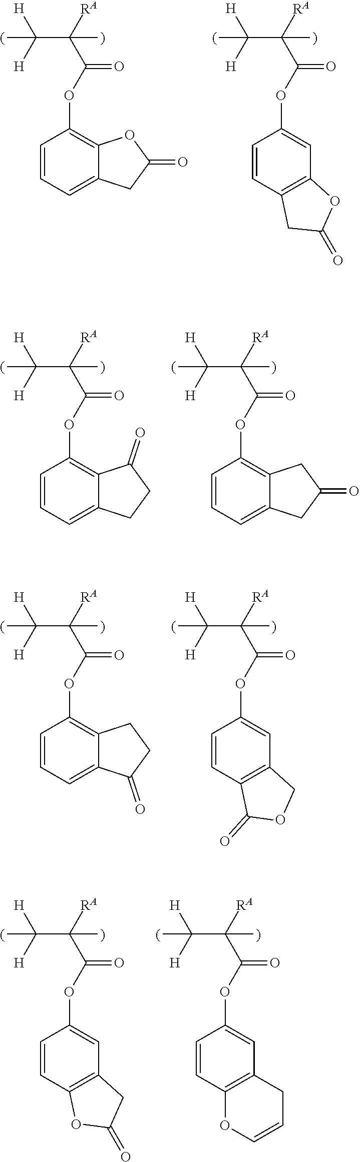

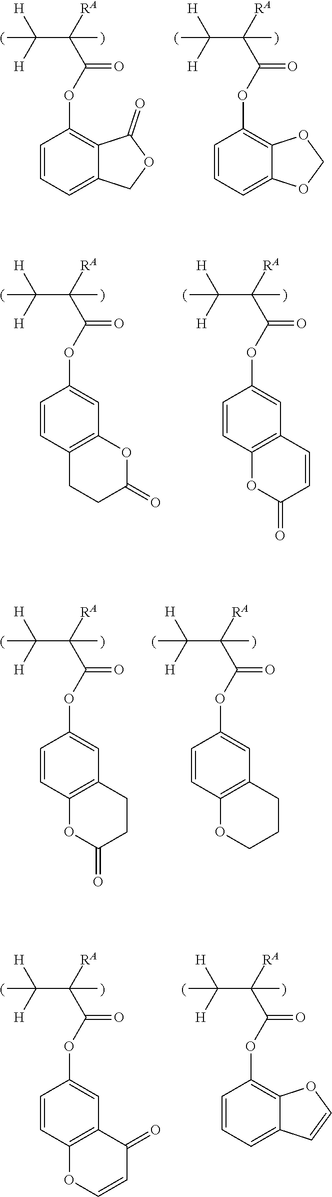

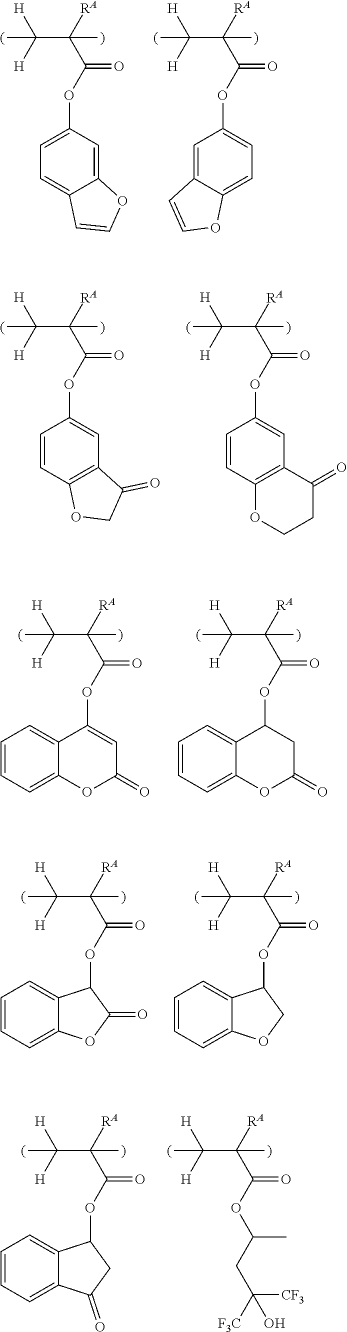

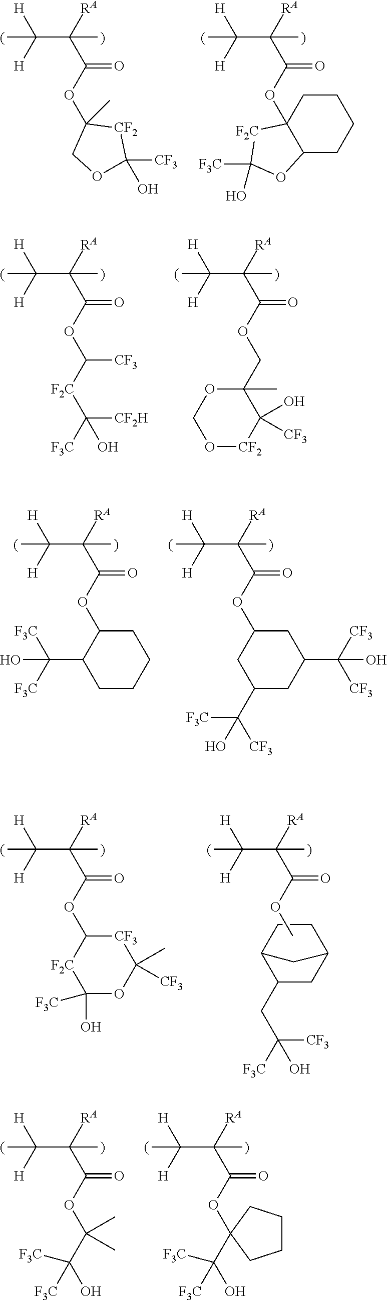

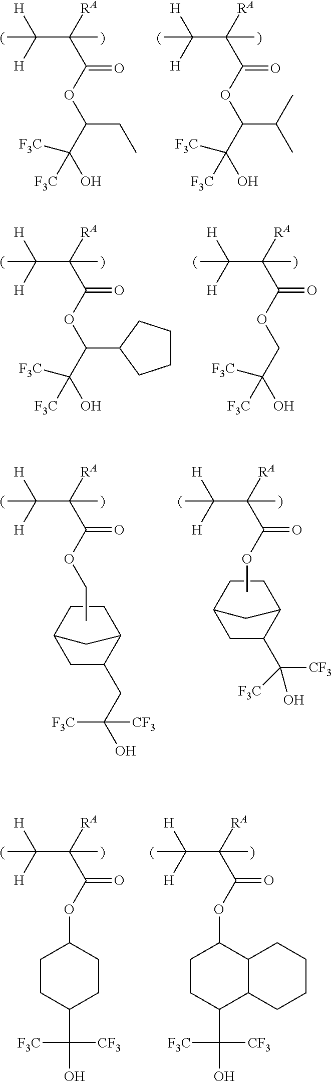

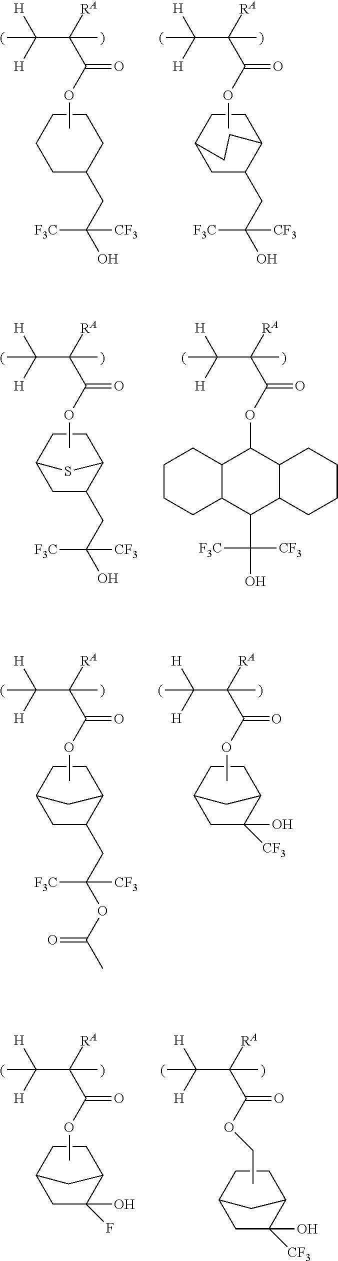

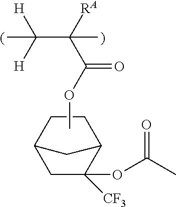

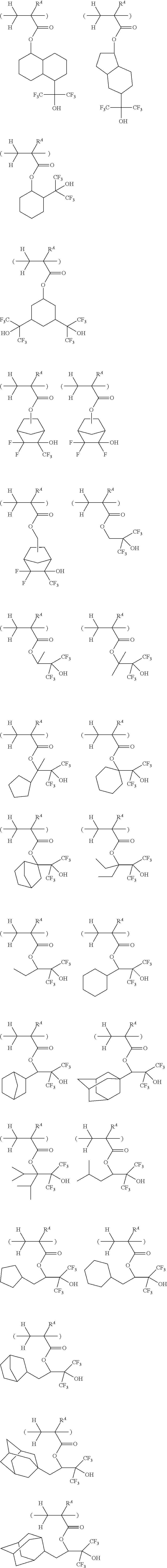

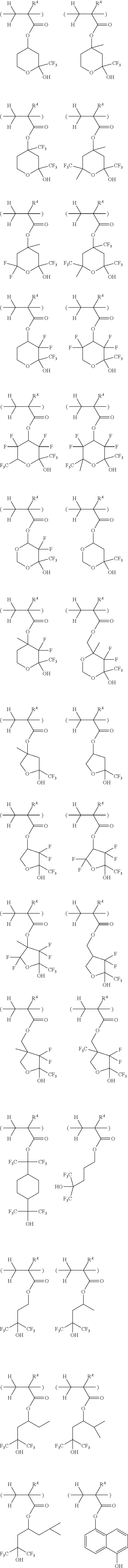

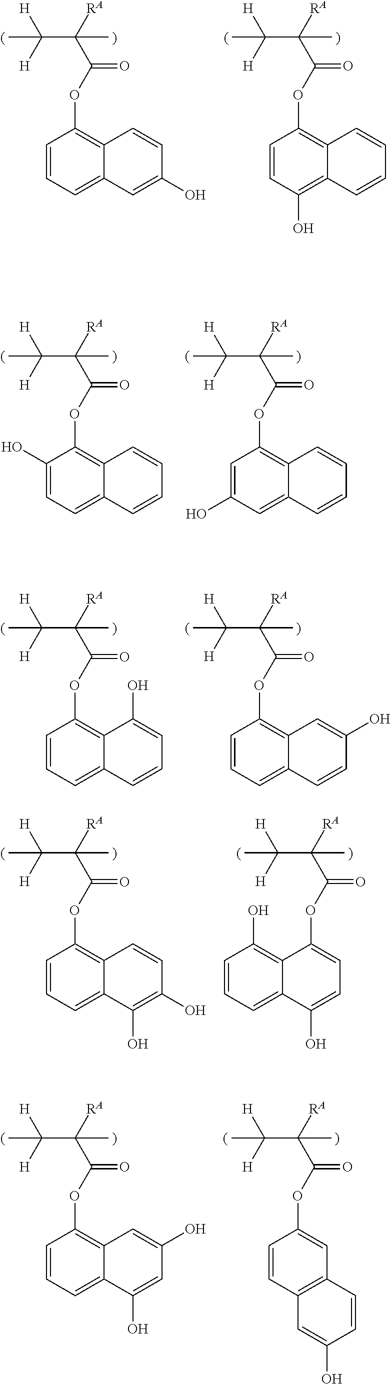

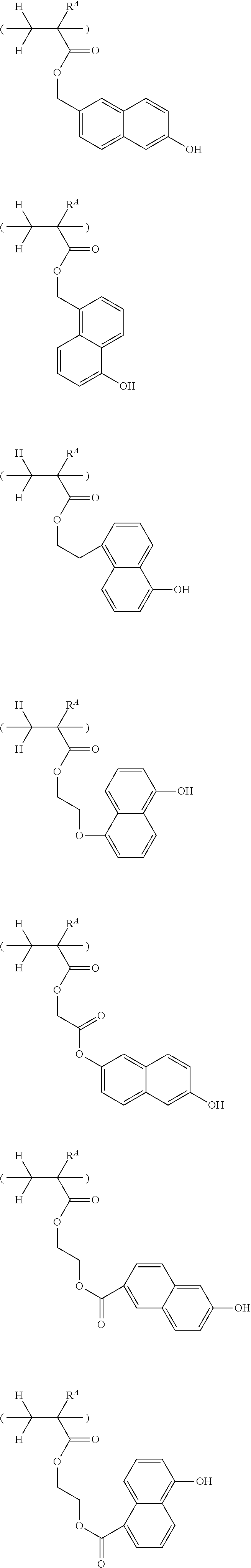

Examples of the repeat unit (b2) are shown below, but not limited thereto. Herein, R^{A} is as defined above.

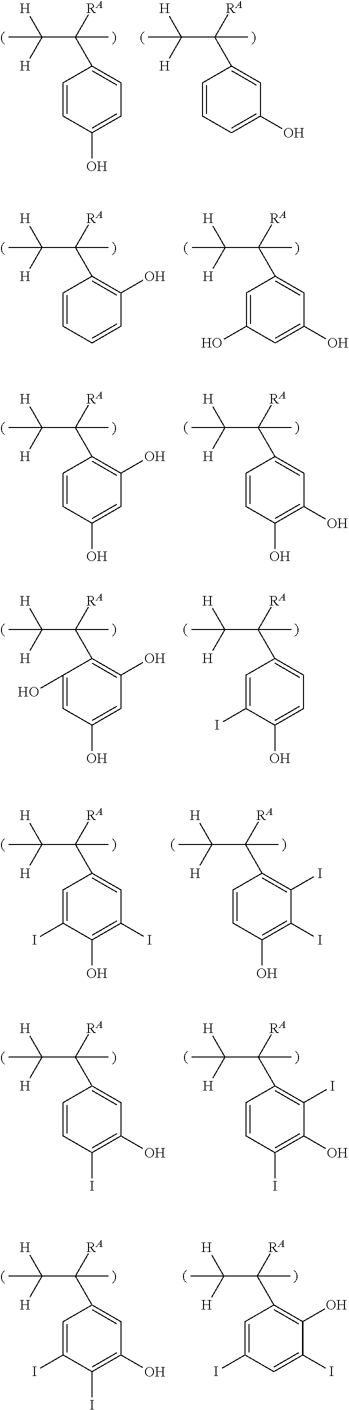

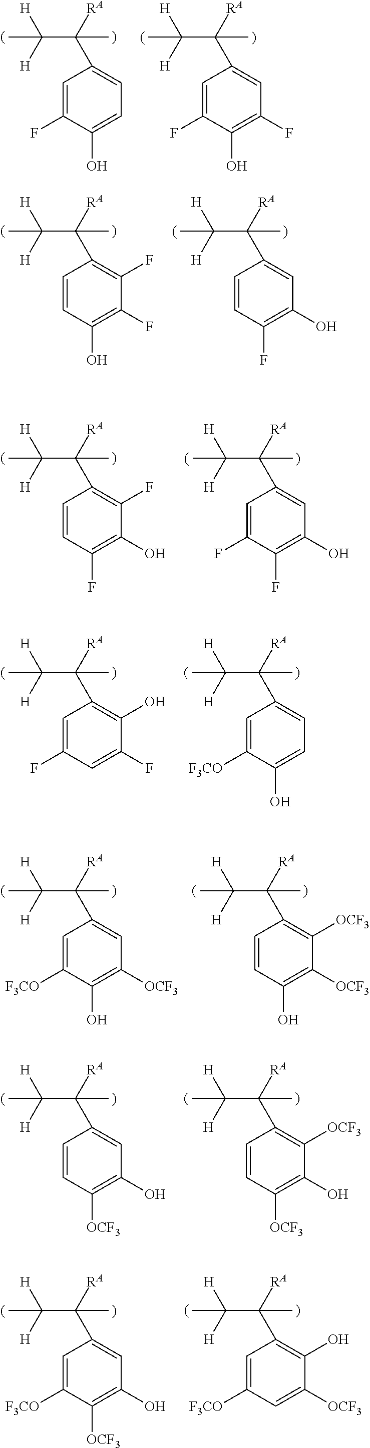

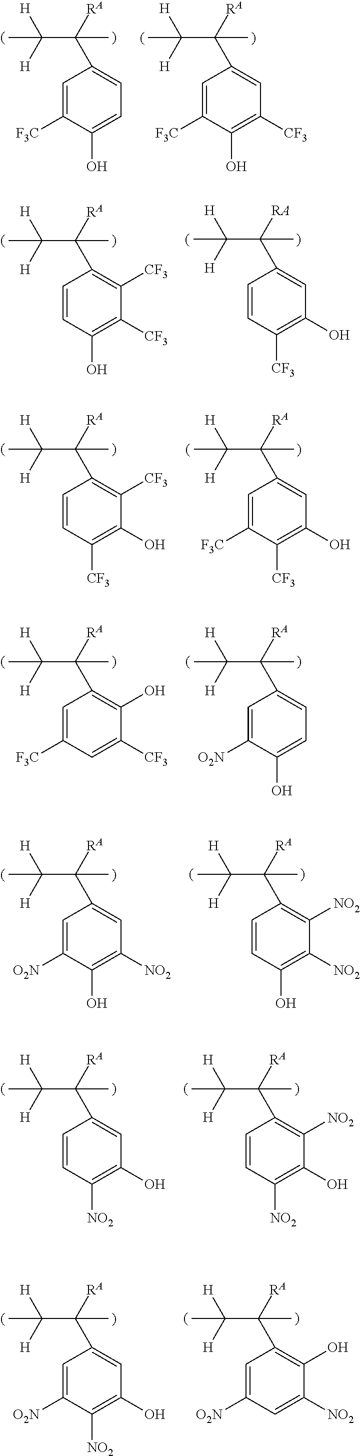

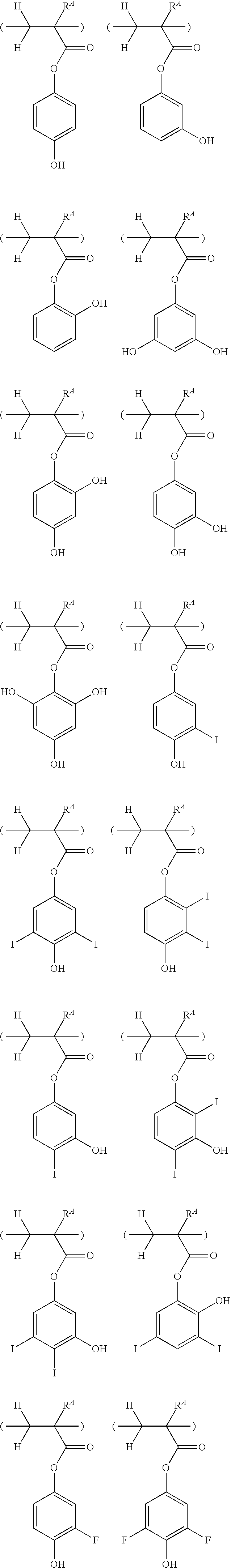

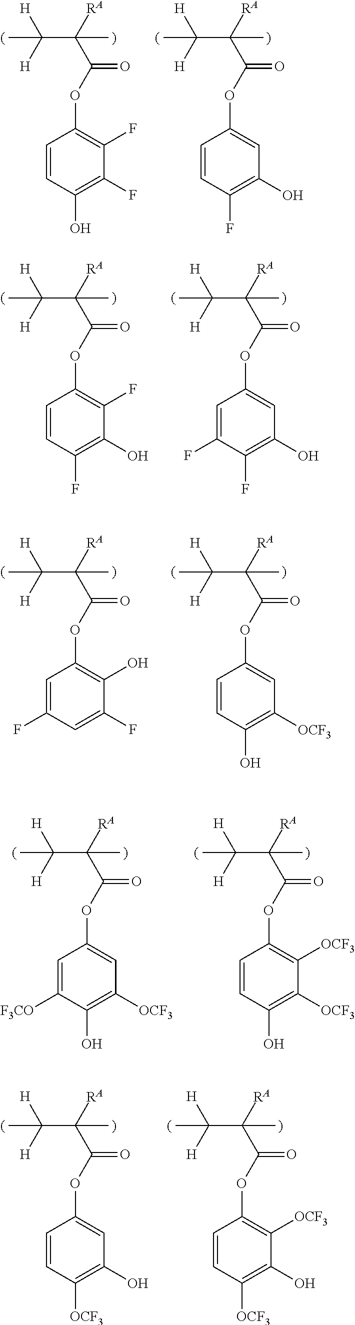

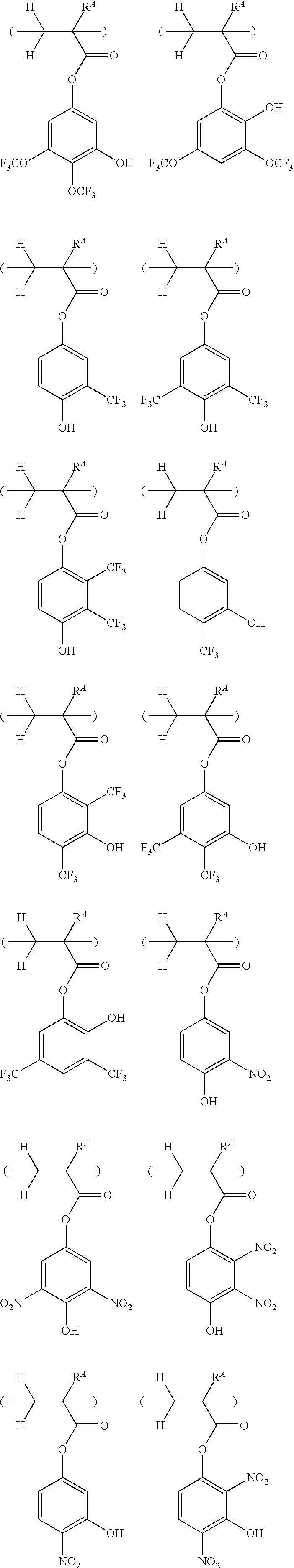

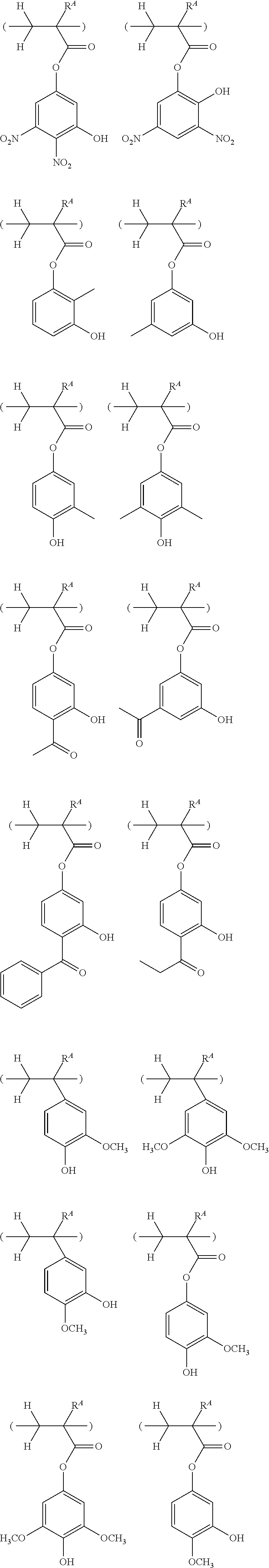

Of the repeat units (b1) and (b2), those units having a lactone ring as the polar group are preferred in the ArF lithography and those units having a phenolic site are preferred in the KrF, EB and EUV lithography.

In a preferred embodiment, the base polymer further comprises repeat units having a photoacid generating group. This enables to positively control the diffusion of the generated acid, leading to improvements in LWR and CDU. Suitable repeat units having a photoacid generating group are repeat units having the formulae (c1) to (c4), which are simply referred to as repeat units (c) to (c4).

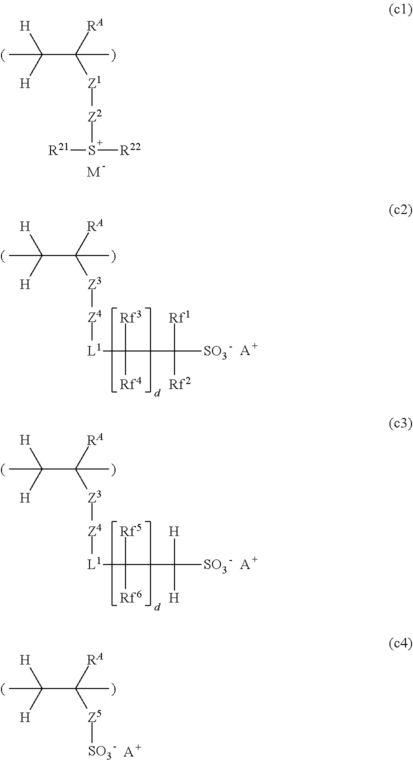

In formulae (c1) to (c4), R^{A} is each independently hydrogen, fluorine, methyl or trifluoromethyl. Z¹ is a single bond or phenylene group. Z² is *—C(═)—O—Z²¹—, *—C(═O)—NH—Z²¹— or *—O—Z²¹—. Z²¹ is a C₁-C₆ aliphatic hydrocarbylene group, a phenylene group or a divalent group obtained by combining the foregoing, which may contain a carbonyl moiety, ester bond, ether bond or hydroxy moiety. Z³ is a single bond, phenylene group, naphthylene group or *—C(═O)—O—Z³¹—. Z³¹ is a C₁-C₁₀ aliphatic hydrocarbylene group which may contain a hydroxy moiety, ether bond, ester bond or lactone ring, or phenylene or naphthylene group. Z⁴ is a single bond or **—Z⁴¹—C(═O)—O—. Z⁴¹ is a C₁-C₂₀ hydrocarbylene group which may contain a heteroatom. Z⁵ is a single bond, methylene, ethylene, phenylene, fluorinated phenylene, trifluoromethyl-substituted phenylene group, *—C(═O)—O—Z⁵¹—, *—C(═O)—N(H)—Z⁵¹—, or *—O—Z⁵¹—. Z⁵¹ is a C₁-C₆ aliphatic hydrocarbylene group, phenylene group, fluorinated phenylene group or trifluoromethyl-substituted phenylene group, which may contain a carbonyl moiety, ester bond, ether bond or hydroxy moiety. The asterisk (*) designates a point of attachment to the carbon atom in the backbone, and the double asterisks (**) designates a point of attachment to Z³.

In formulae (c1) to (c4), the aliphatic hydrocarbylene group represented by Z²¹, Z³¹ and Z⁵¹ may be straight, branched or cyclic. Examples thereof include alkanediyl groups such as methanediyl, ethane-1,1-diyl, ethane-1,2-diyl, propane-1,1-diyl, propane-1,2-diyl, propane-1,3-diyl, propane-2,2-diyl, butane-1,1-diyl, butane-1,2-diyl, butane-1,3-diyl, butane-2,3-diyl, butane-1,4-diyl, 1,1-dimethylethane-1,2-diyl, pentane-1,5-diyl, 2-methylbutane-1,2-diyl, and hexane-1,6-diyl; cycloalkanediyl groups such as cyclopropanediyl, cyclobutanediyl, cyclopentanediyl, and cyclohexanediyl; and combinations thereof.

The hydrocarbylene group represented by Z⁴¹ may be saturated or unsaturated and straight, branched or cyclic. Examples thereof are shown below, but not limited thereto.

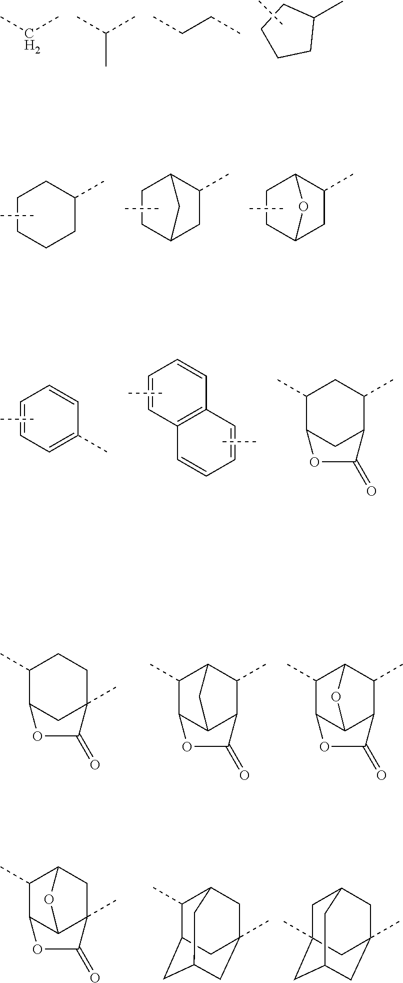

In formula (c1), R²¹ and R²² are each independently a C₁-C₂₀ hydrocarbyl group which may contain a heteroatom. The hydrocarbyl group may be saturated or unsaturated and straight, branched or cyclic. Examples thereof include C₁-C₂₀ alkyl groups such as methyl, ethyl, n-propyl, isopropyl, n-butyl, tert-butyl; C₃-C₂₀ cyclic saturated hydrocarbyl groups such as cyclopropyl, cyclopentyl, cyclohexyl, cyclopropylmethyl, 4-methylcyclohexyl, cyclohexylmethyl, norbornyl, and adamantyl; C₂-C₂₀ alkenyl groups such as vinyl, allyl, propenyl, butenyl, hexenyl; C₃-C₂₀ cyclic unsaturated hydrocarbyl groups such as cyclohexenyl; C₆-C₂₀ aryl groups such as phenyl, naphthyl and thienyl; C₇-C₂₀ aralkyl groups such as benzyl, 1-phenylethyl and 2-phenylethyl, and combinations thereof. Inter alia, aryl groups are preferred. In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, fluorine, chlorine, bromine, iodine, cyano moiety, carbonyl moiety, ether bond, ester bond, sulfonic ester bond, carbonate bond, lactone ring, sultone ring, carboxylic anhydride (—C(═O)—O—C(═O)—) or haloalkyl moiety.

R²¹ and R² may bond together to form a ring with the sulfur atom to which they are attached. Examples of the ring are as will be exemplified later for the ring that R⁴¹ and R⁴² in formula (cation-1), taken together, form with the sulfur atom to which they are attached.

Examples of the cation in repeat unit (c1) are shown below, but not limited thereto. Herein R^{A} is as defined above.

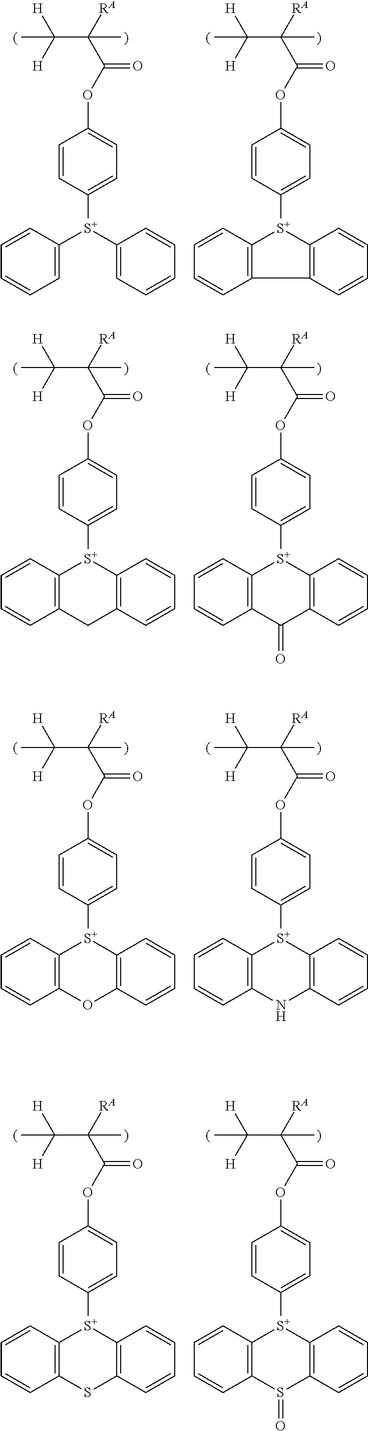

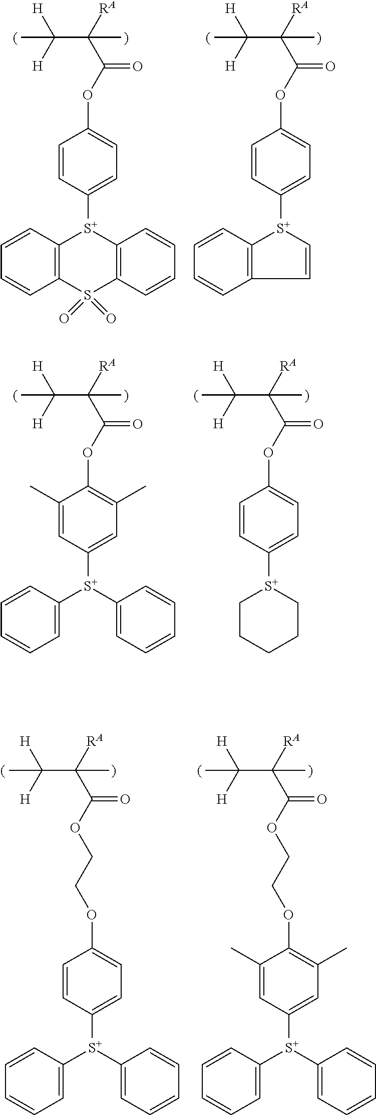

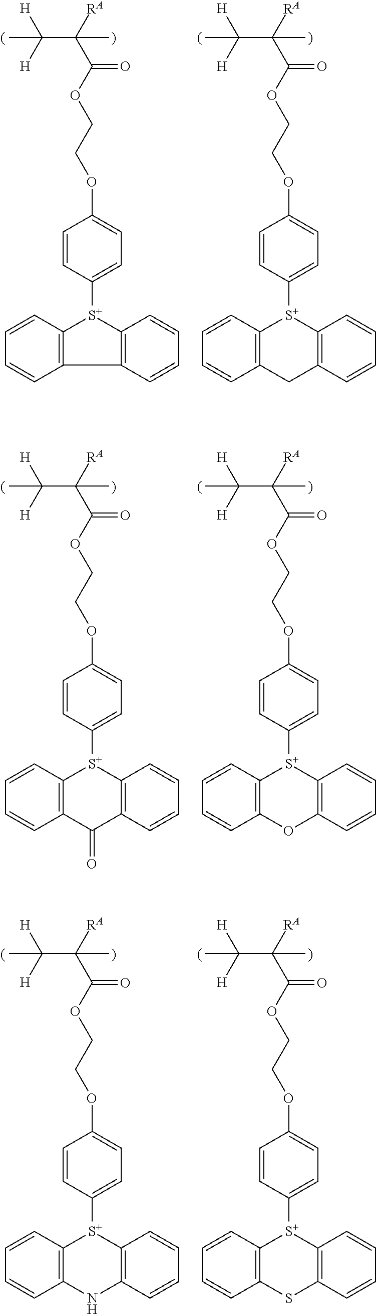

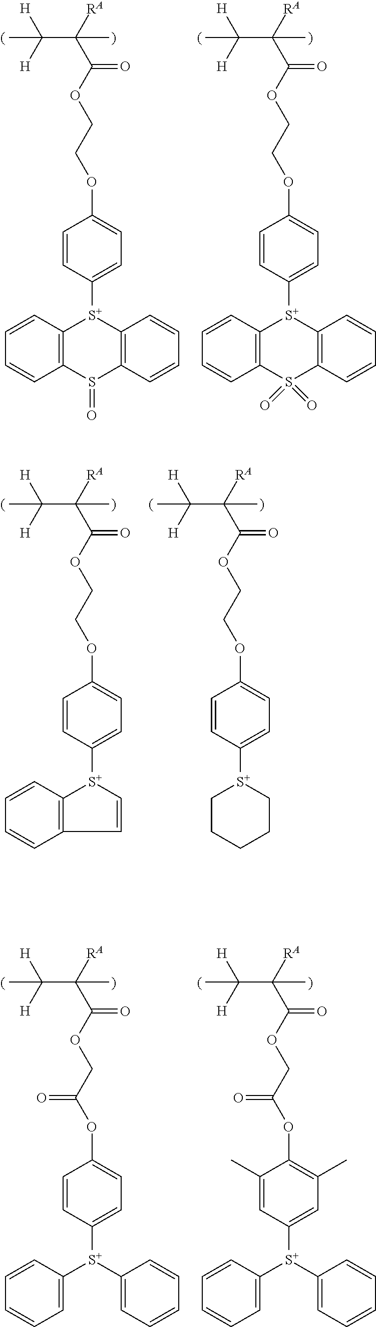

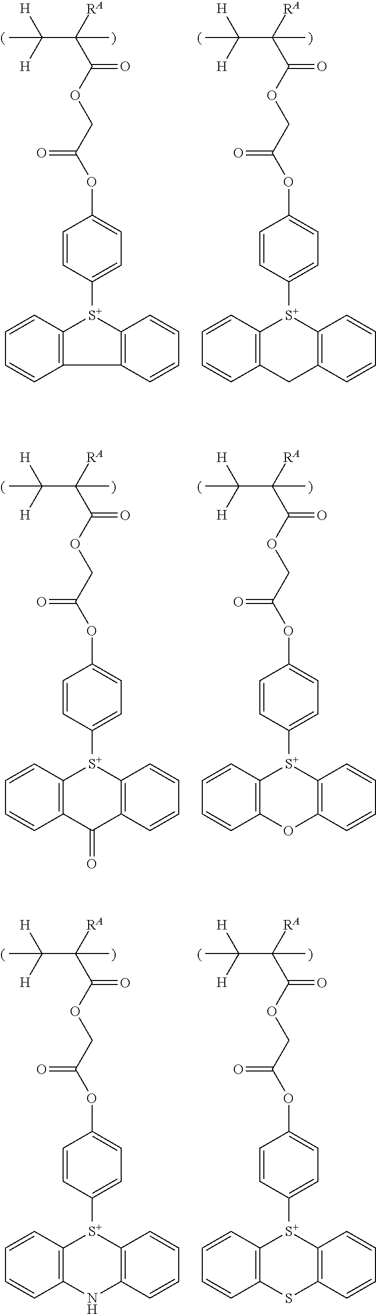

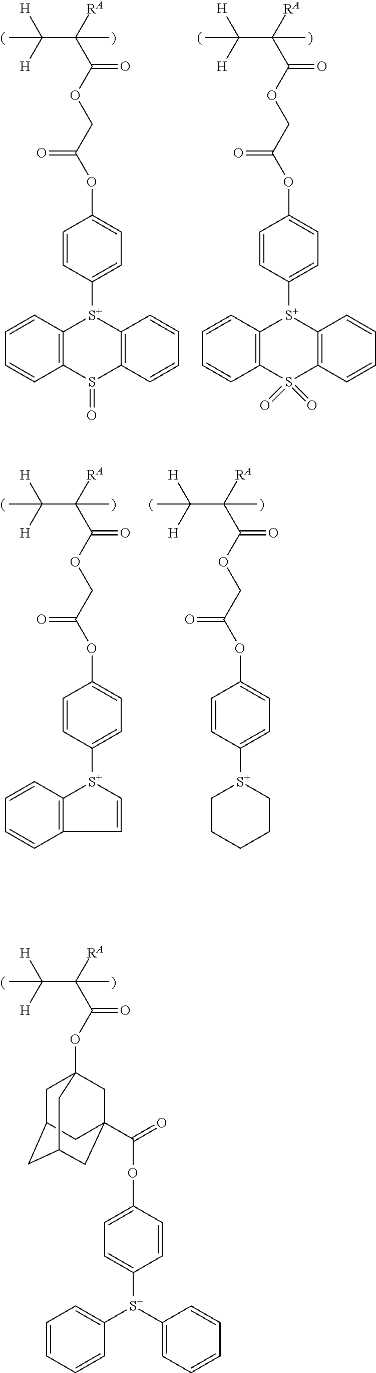

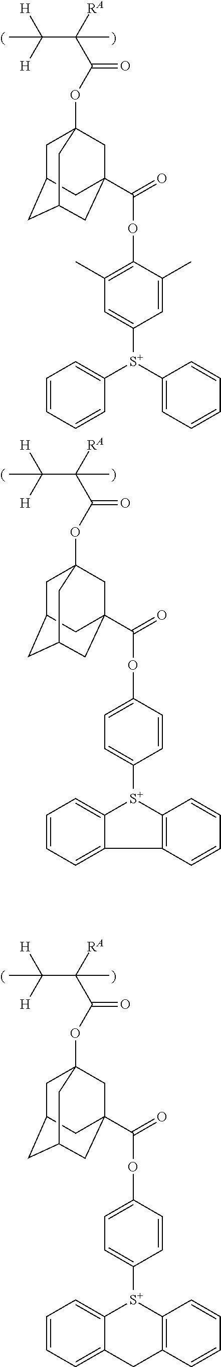

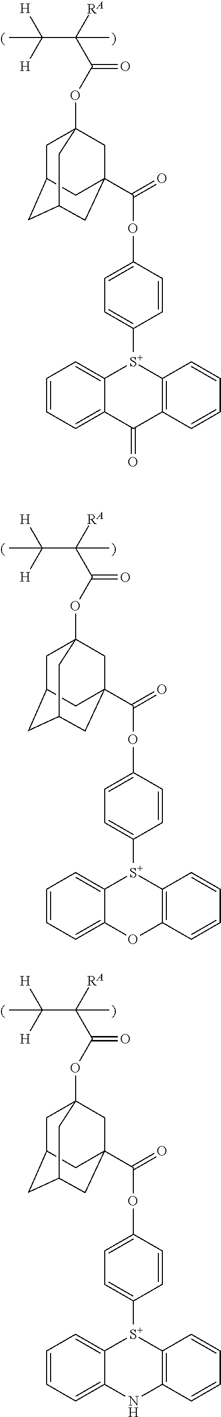

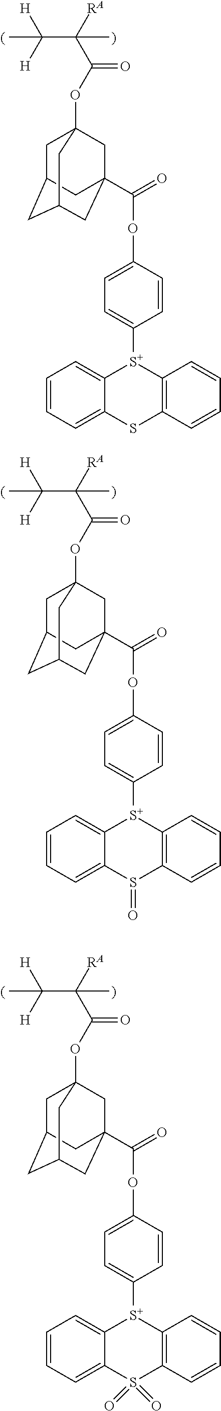

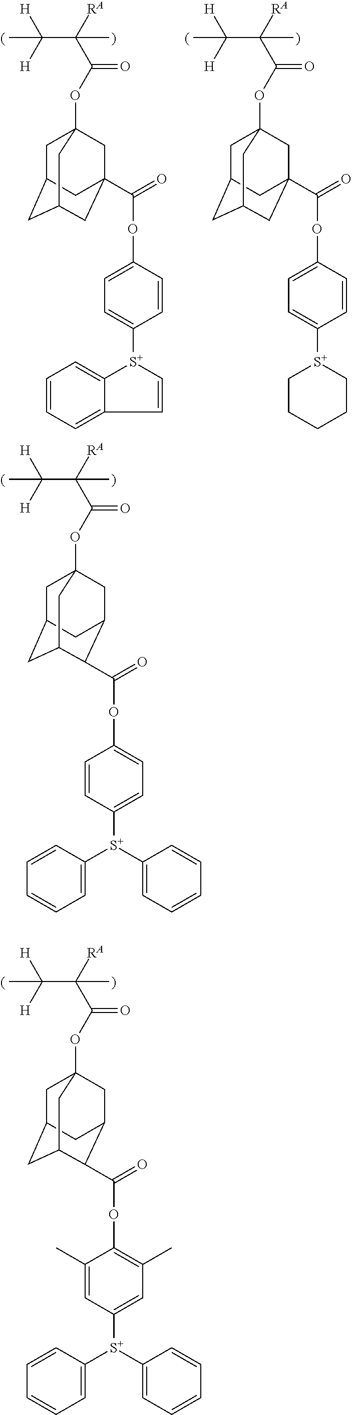

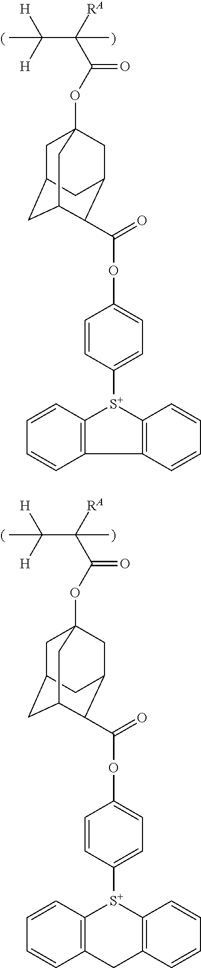

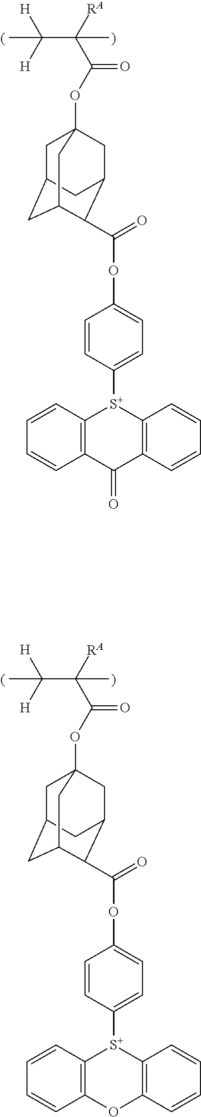

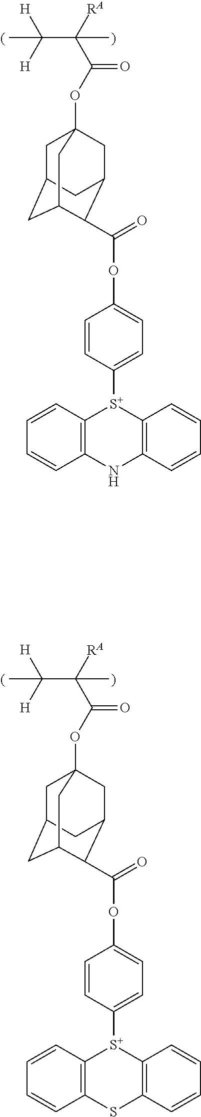

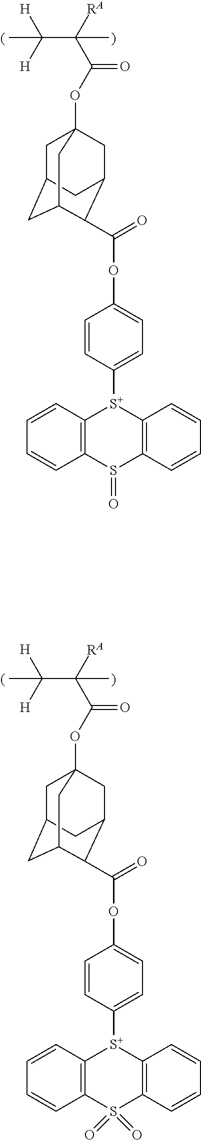

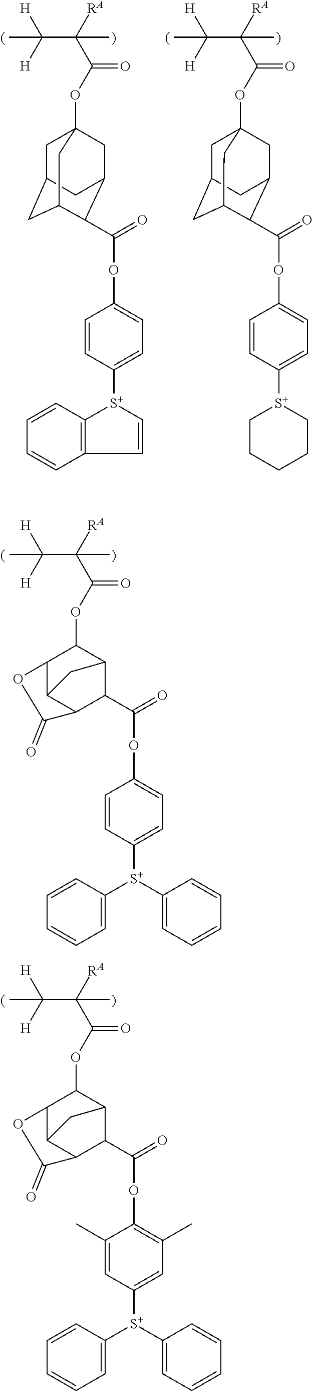

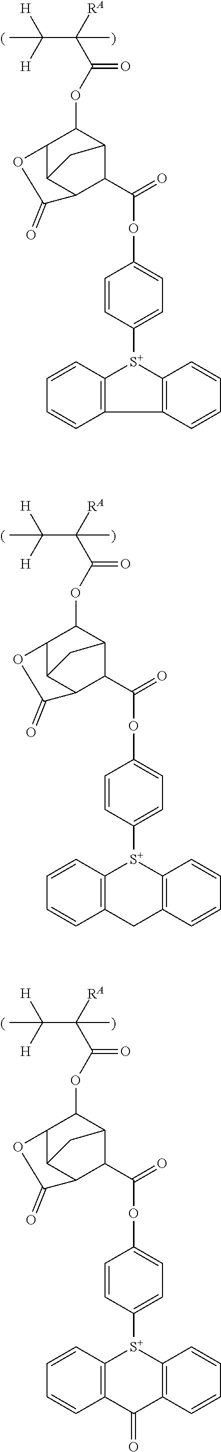

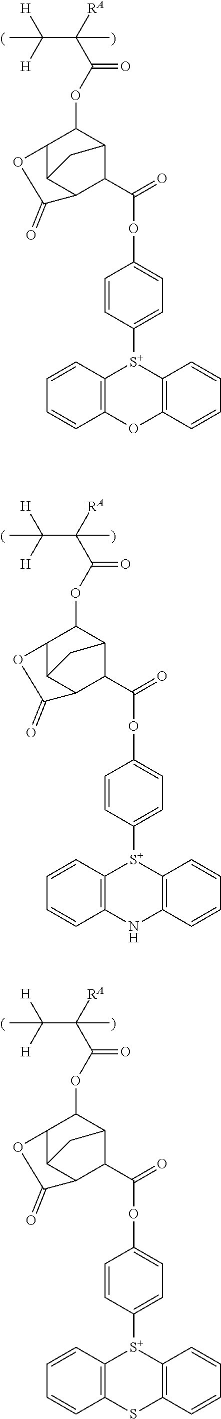

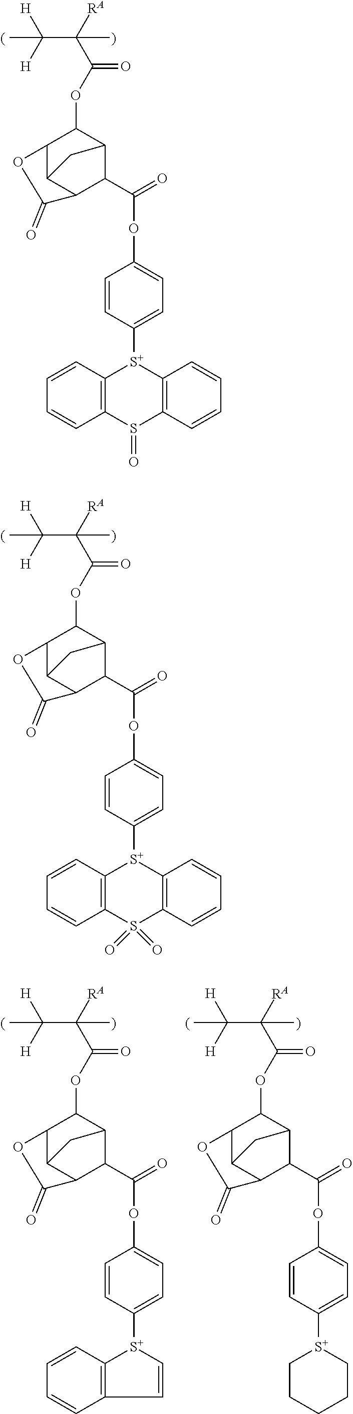

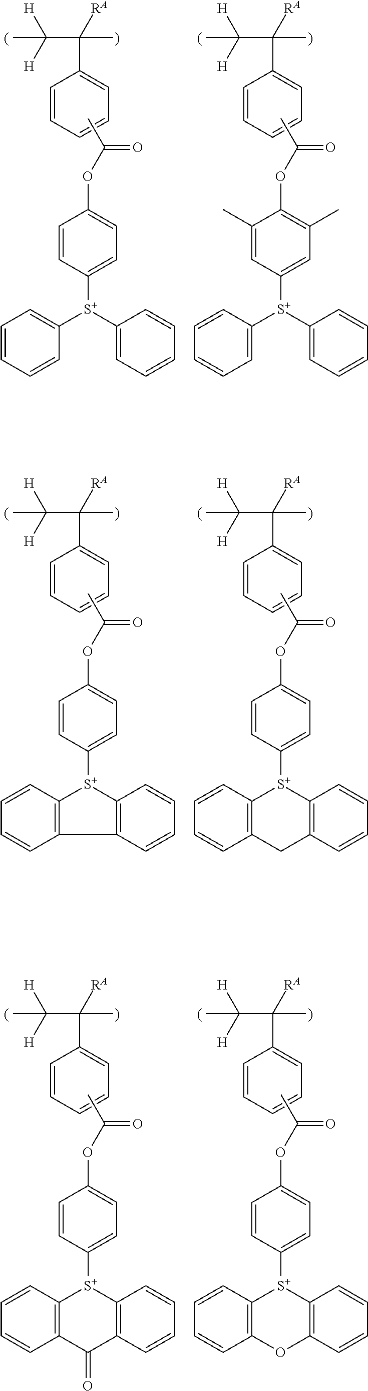

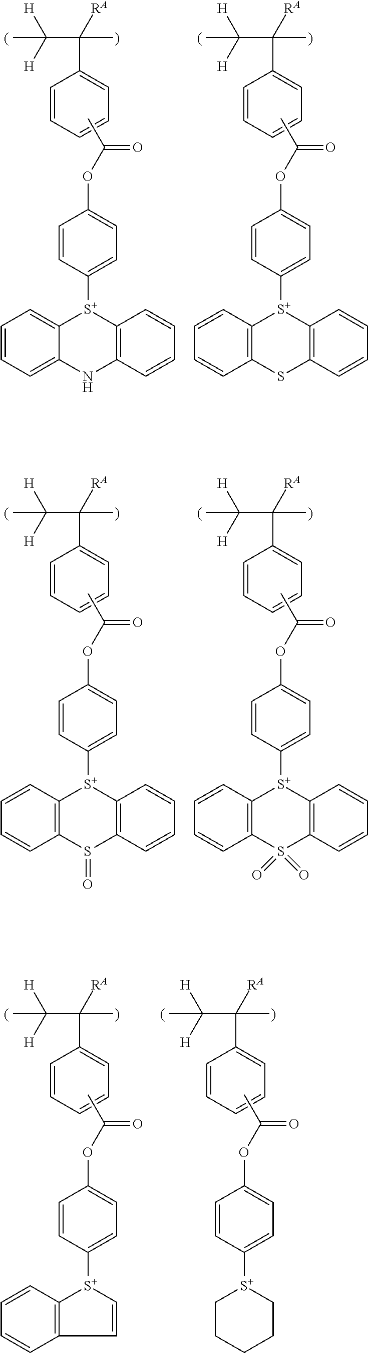

In formula (c1), M⁻ is a non-nucleophilic counter anion. Examples of the non-nucleophilic counter anion include halide ions such as chloride and bromide ions; fluoroalkylsulfonate ions such as triflate, 1,1,1-trifluoroethanesulfonate, and nonafluorobutanesulfonate; arylsulfonate ions such as tosylate, benzenesulfonate, 4-fluorobenzenesulfonate, and 1,2,3,4,5-pentafluorobenzenesulfonate; alkylsulfonate ions such as mesylate and butanesulfonate; imide ions such as bis(trifluoromethylsulfonyl)imide, bis(perfluoroethylsulfonyl)imide and bis(perfluorobutylsulfonyl)imide; and methide ions such as tris(trifluoromethylsulfonyl)methide and tris(perfluoroethylsulfonyl)methide.

Also included are a sulfonate anion which is fluorinated at α-position as represented by the formula (c1-1) and a sulfonate anion which is substituted with fluorine at α-position and trifluoromethyl at β-position as represented by the formula (c1-2).

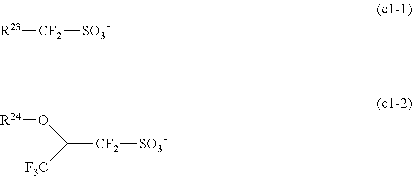

In formula (c1-1), R²³ is hydrogen, a C₁-C₃₀ hydrocarbyl group, C₂-C₃₀ hydrocarbylcarbonyloxy group, or C₂-C₃ hydrocarbyloxycarbonyl group. The hydrocarbyl group may contain halogen, an ether bond, ester bond, carbonyl moiety or lactone ring. The hydrocarbyl group and hydrocarbyl moiety in the hydrocarbylcarbonyloxy group and hydrocarbyloxycarbonyl group may be saturated or unsaturated and straight, branched or cyclic, and examples thereof are as will be exemplified later for the hydrocarbyl group R^{fa1} in formula (2A′).

In formula (c1-2), R²⁴ is hydrogen, a C₁-C₃₀ hydrocarbyl group, or C₂-C₃₀ hydrocarbylcarbonyl group. The hydrocarbyl group and hydrocarbylcarbonyl group may contain halogen, an ether bond, ester bond, carbonyl moiety or lactone ring. The hydrocarbyl group and hydrocarbyl moiety in the hydrocarbylcarbonyl group may be saturated or unsaturated and straight, branched or cyclic, and examples thereof are as will be exemplified later for the hydrocarbyl group R^{fa1} in formula (2A′).

Examples of the sulfonate anion having formula (c1-1) or (c1-2) are shown below, but not limited thereto. Herein R²⁵ is hydrogen, fluorine or C₁-C₆ fluorinated saturated hydrocarbyl group, preferably trifluoromethyl.

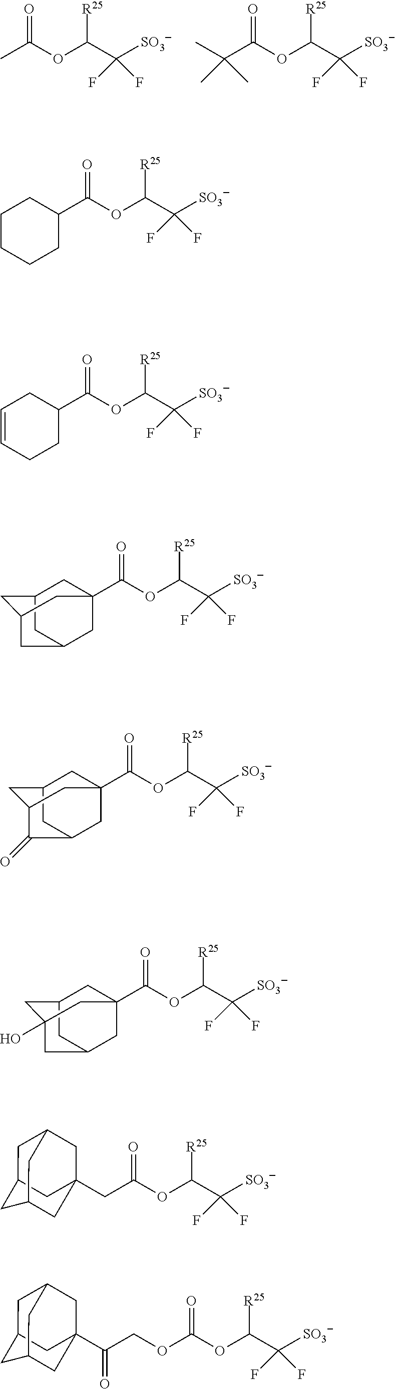

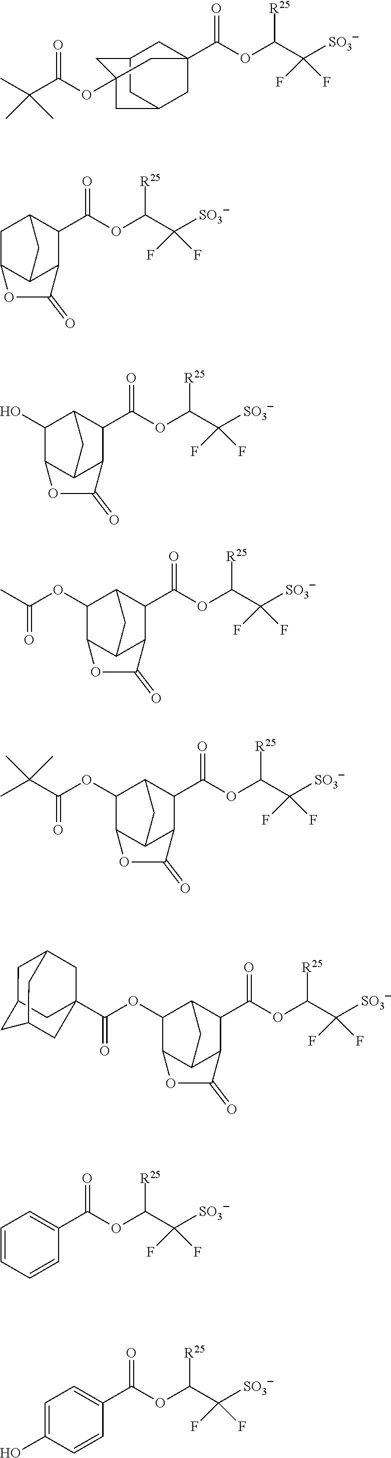

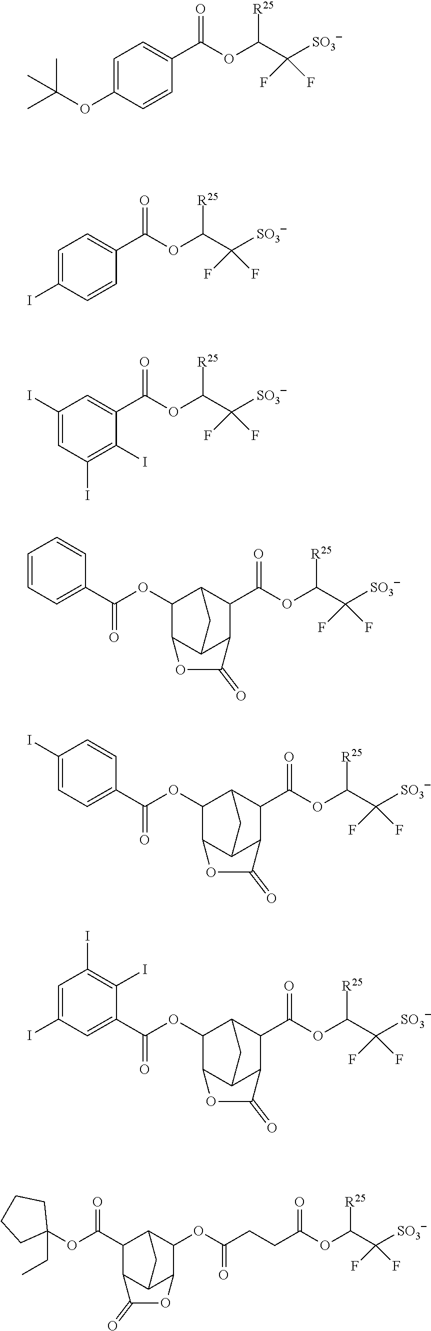

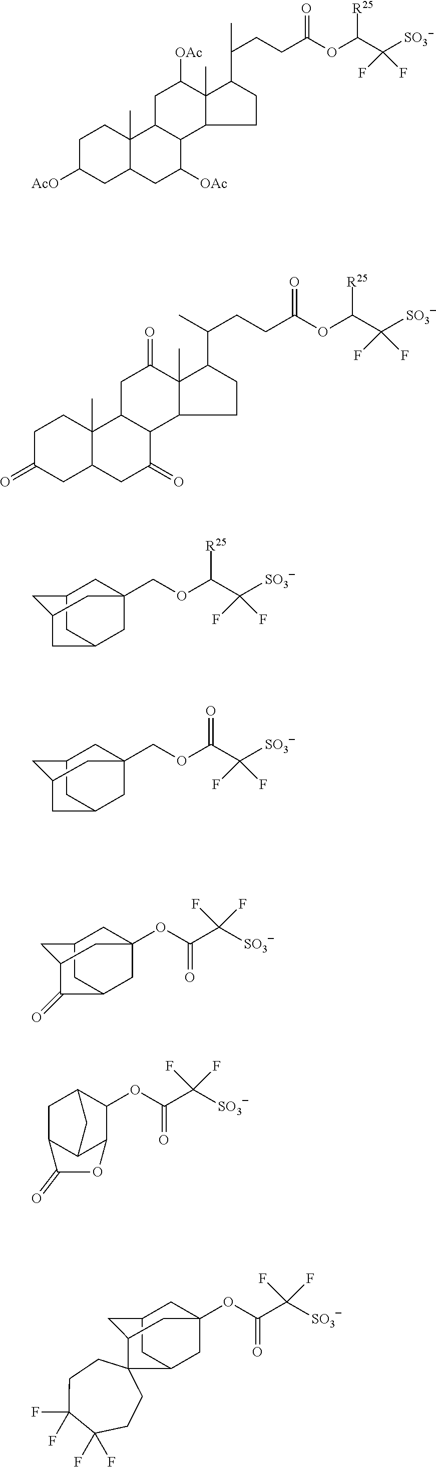

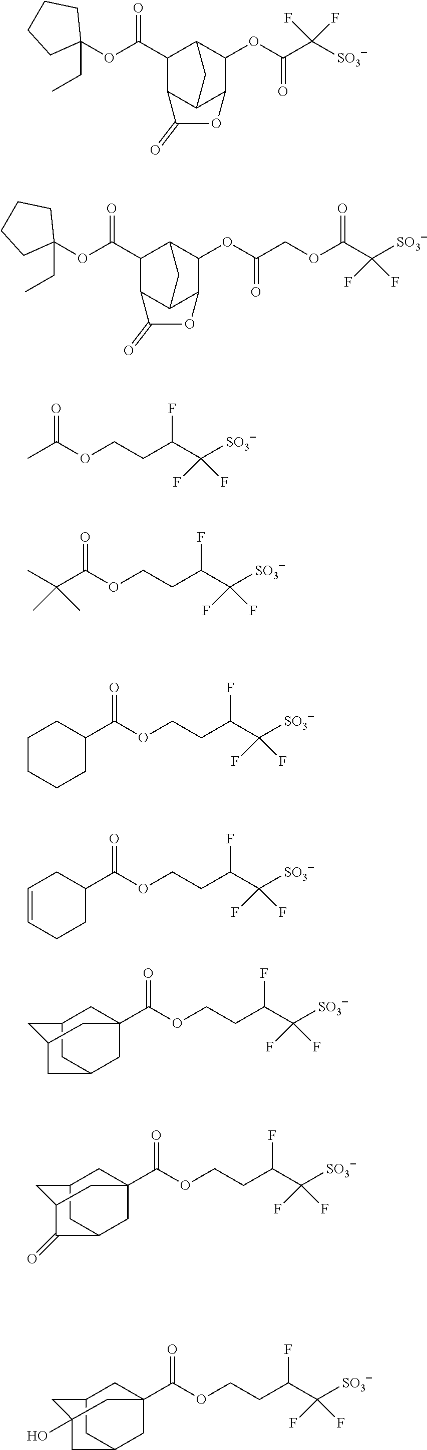

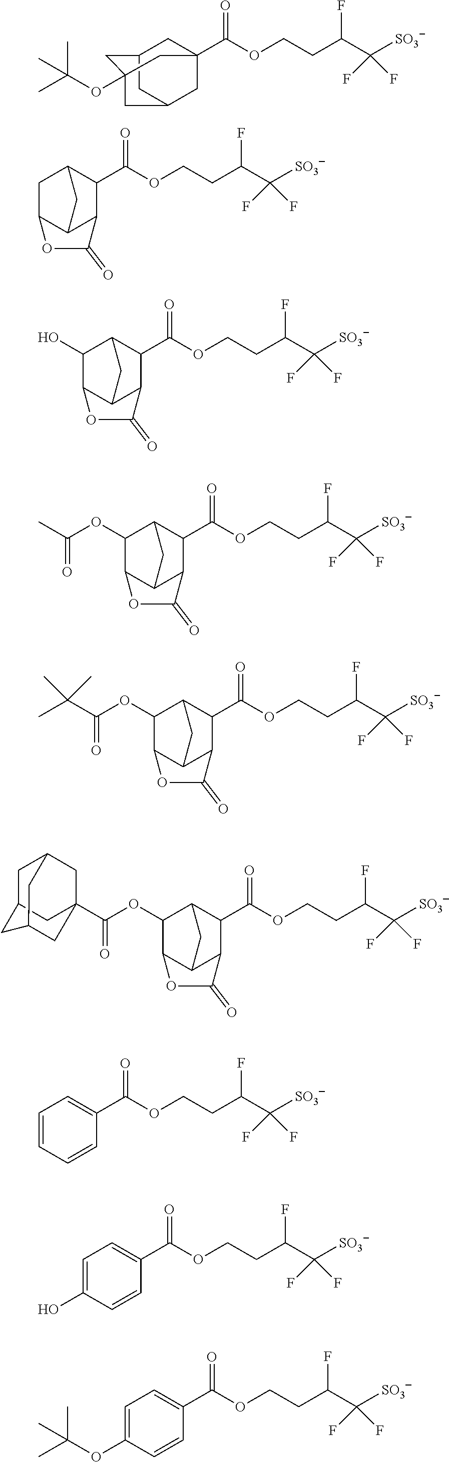

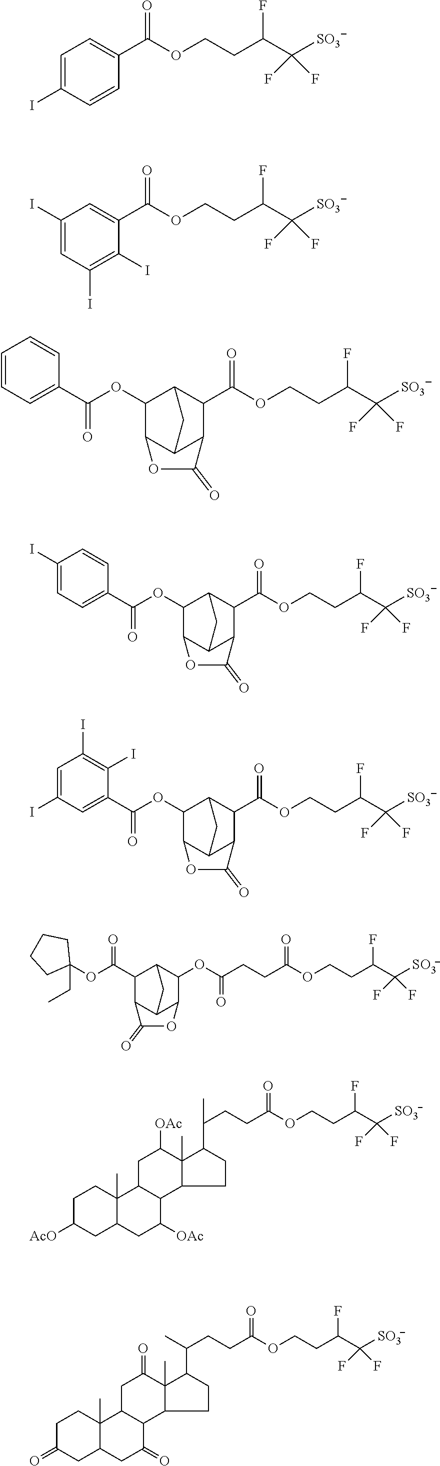

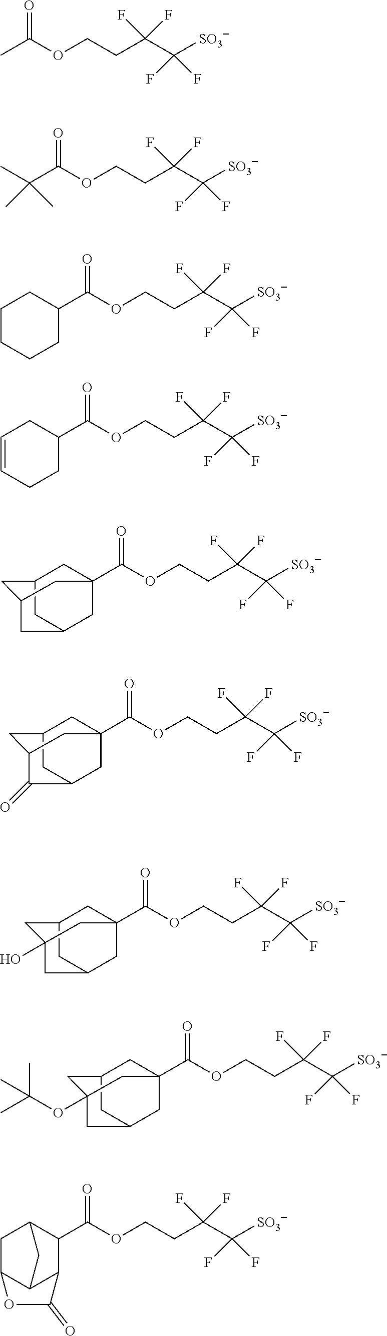

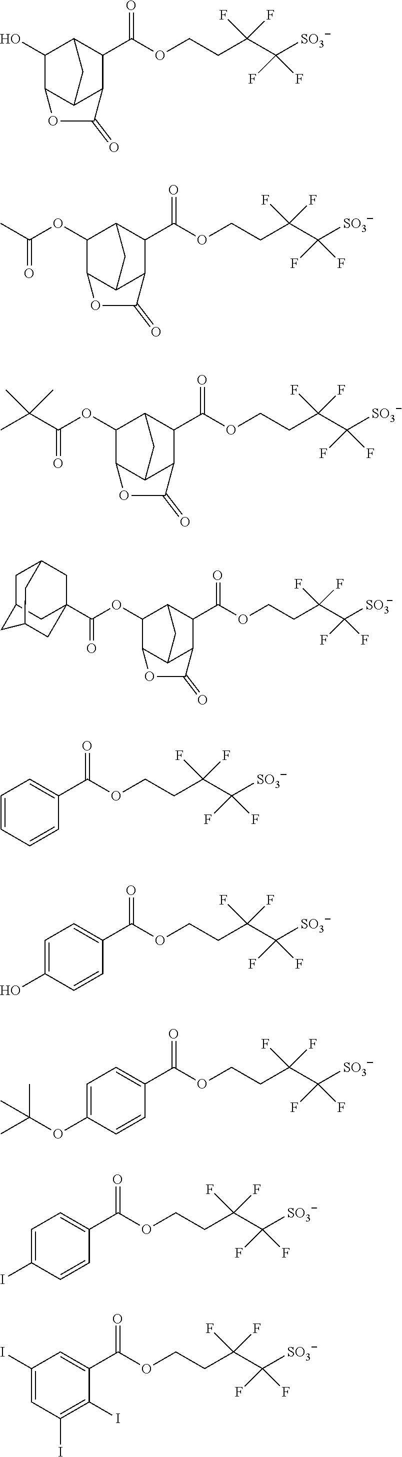

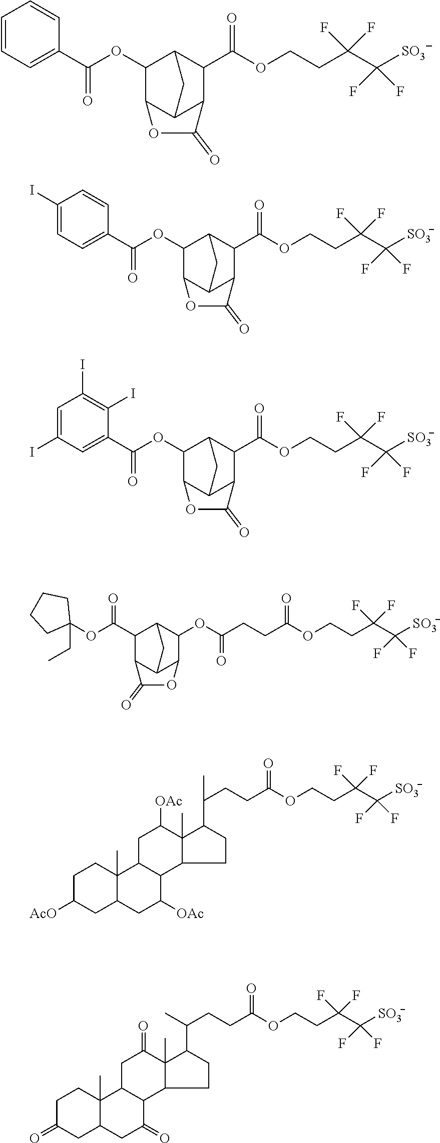

In formulae (c2) and (c3), L¹ is a single bond, ether bond, ester bond, carbonyl group, sulfonic ester bond, carbonate bond or carbamate bond. From the aspect of synthesis, an ether bond, ester bond, and carbonyl group are preferred, with an ester bond and carbonyl group being more preferred.

In formula (c2), Rf¹ and Rf² are each independently fluorine or a C₁-C₆ fluorinated saturated hydrocarbyl group. It is preferred for enhancing the acid strength of the generated acid that both Rf¹ and Rf² be fluorine. Rf³ and Rf⁴ are each independently hydrogen, fluorine or a C₁-C₆ fluorinated saturated hydrocarbyl group. It is preferred for enhancing solvent solubility that at least one of Rf³ and R⁴ be trifluoromethyl.

In formula (c3), Rf⁵ and Rf⁶ are each independently hydrogen, fluorine or a C₁-C₆ fluorinated saturated hydrocarbyl group. It is excluded that all Rf⁵ and Rf⁶ are hydrogen at the same time. It is preferred for enhancing solvent solubility that at least one of Rf⁵ and Rf⁶ be trifluoromethyl.

In formulae (c2) and (c3), d is an integer of 0 to 3, preferably 1.

Examples of the anion in repeat unit (c2) are shown below, but not limited thereto. Herein R^{A} is as defined above.

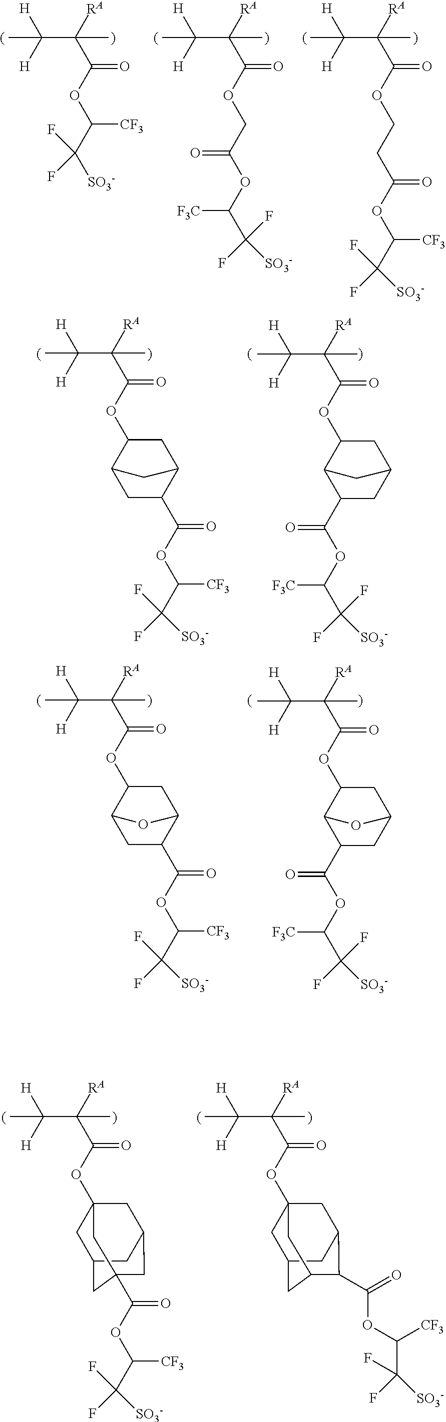

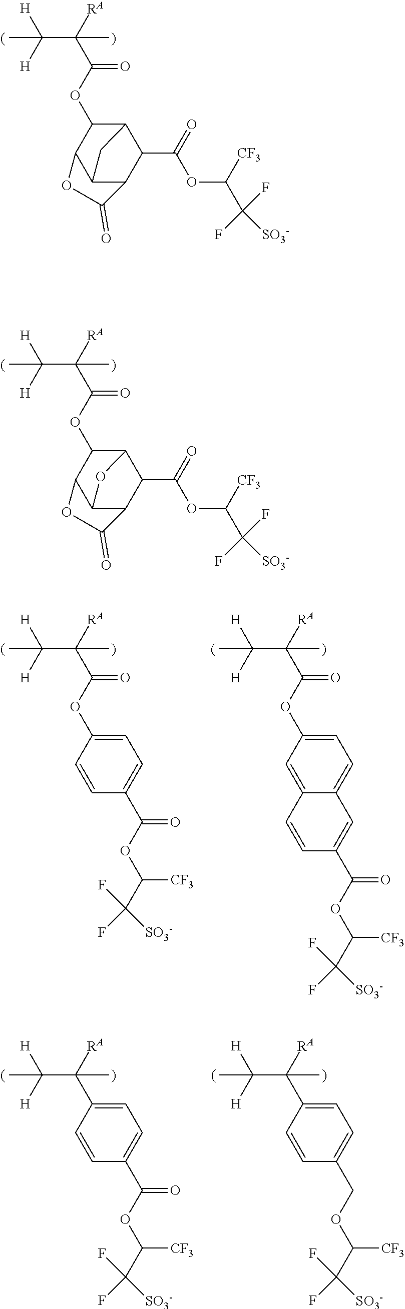

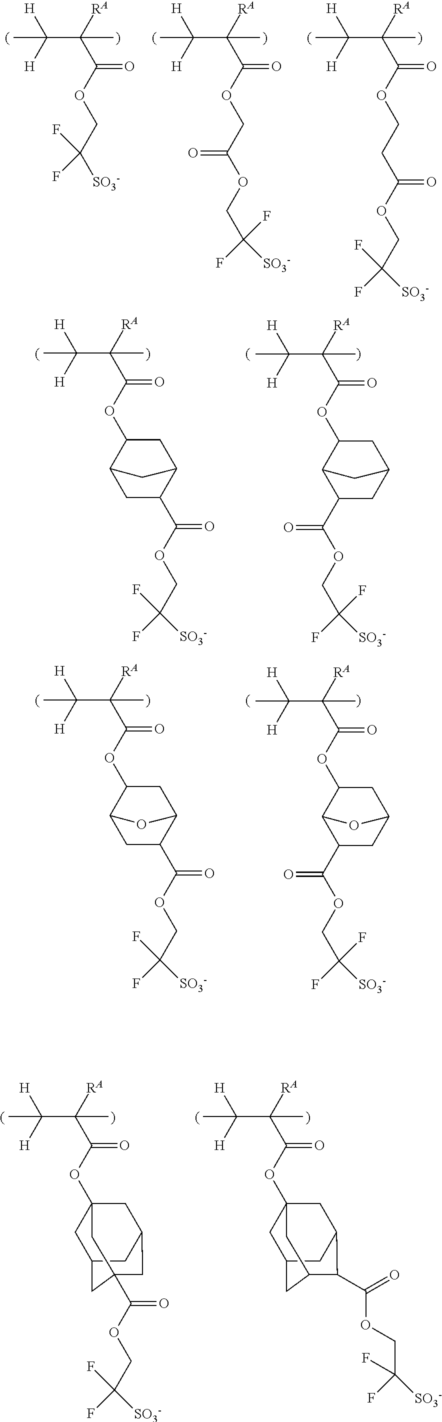

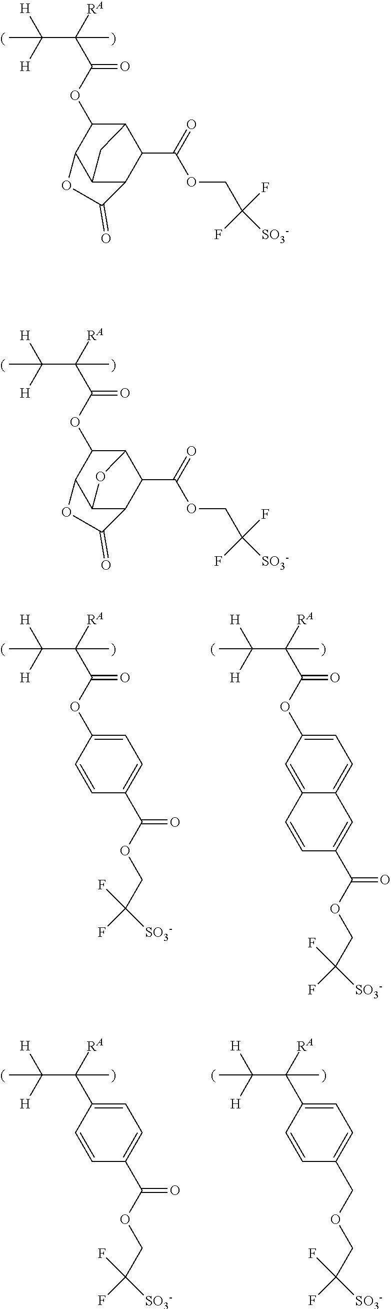

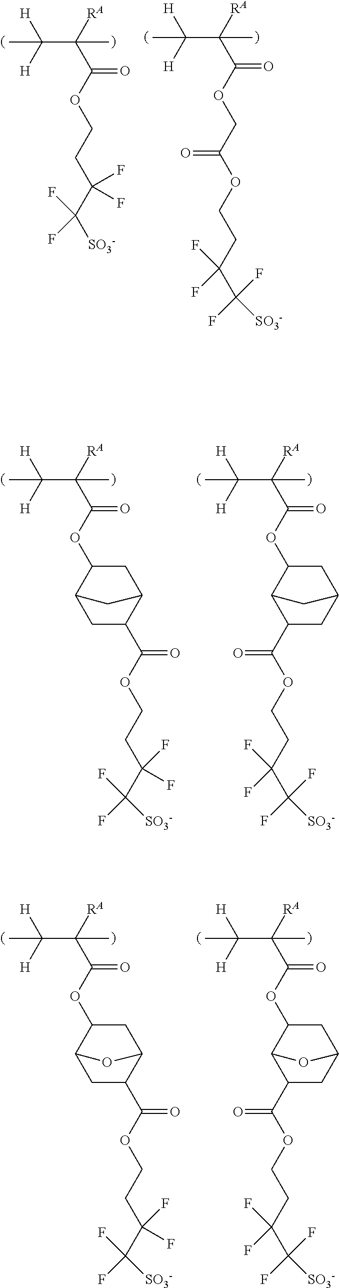

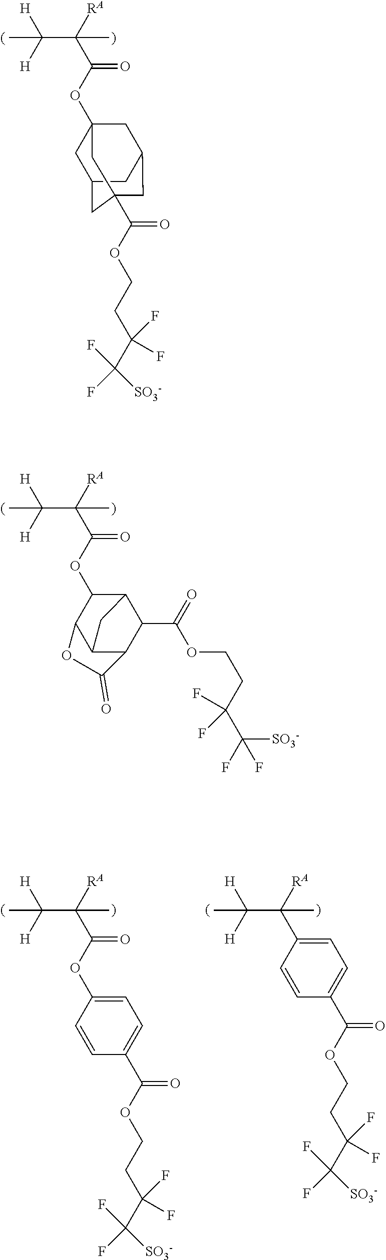

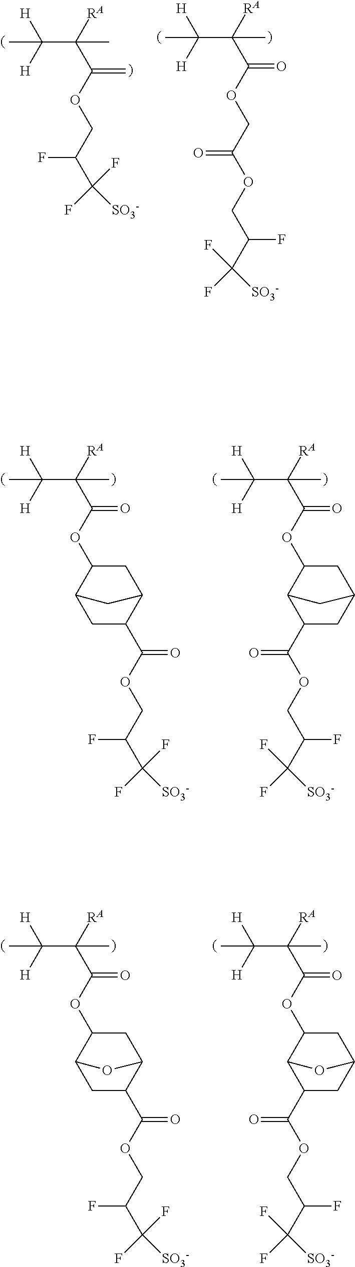

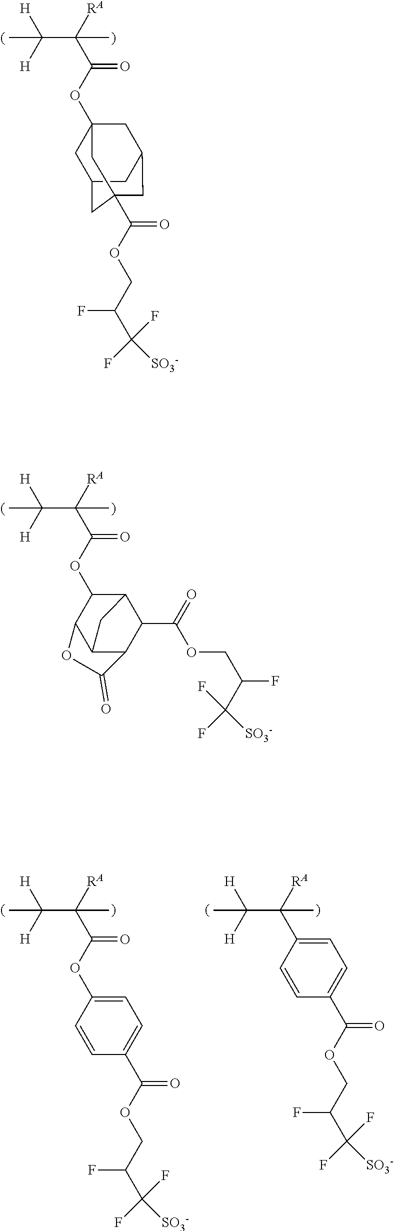

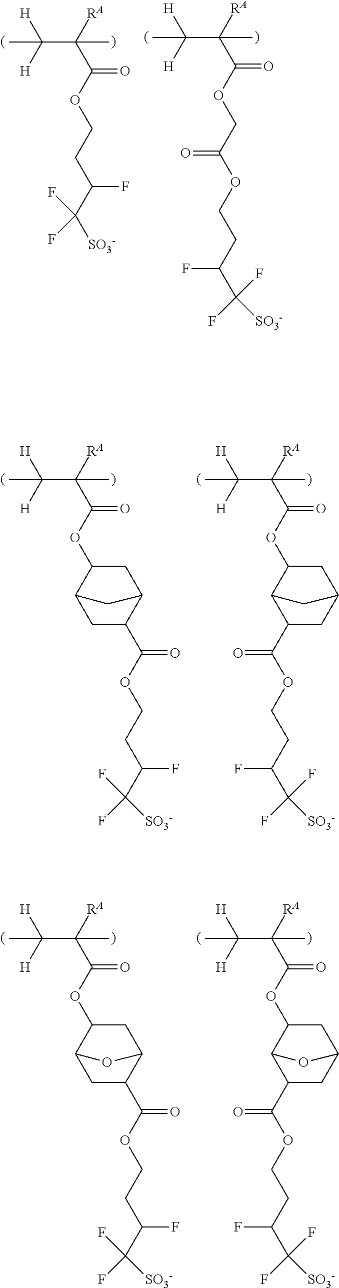

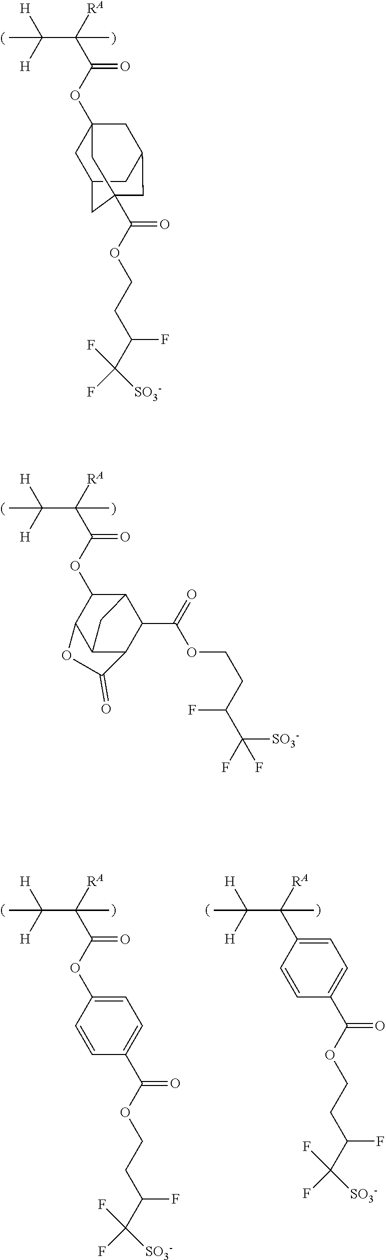

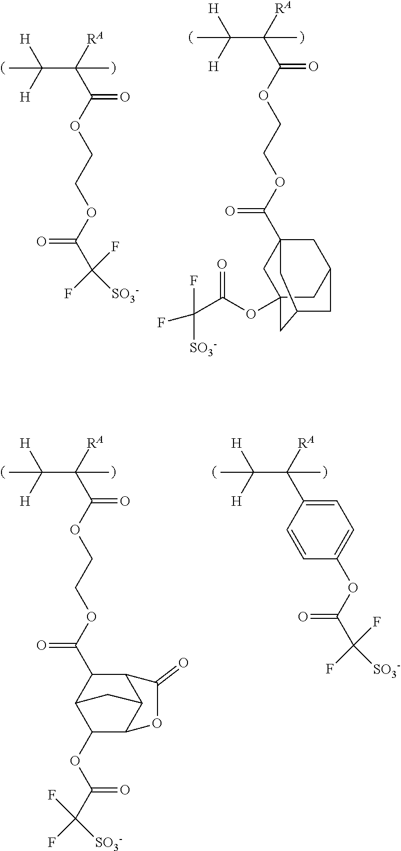

Examples of the anion in repeat unit (c3) are shown below, but not limited thereto. Herein R^{A} is as defined above.

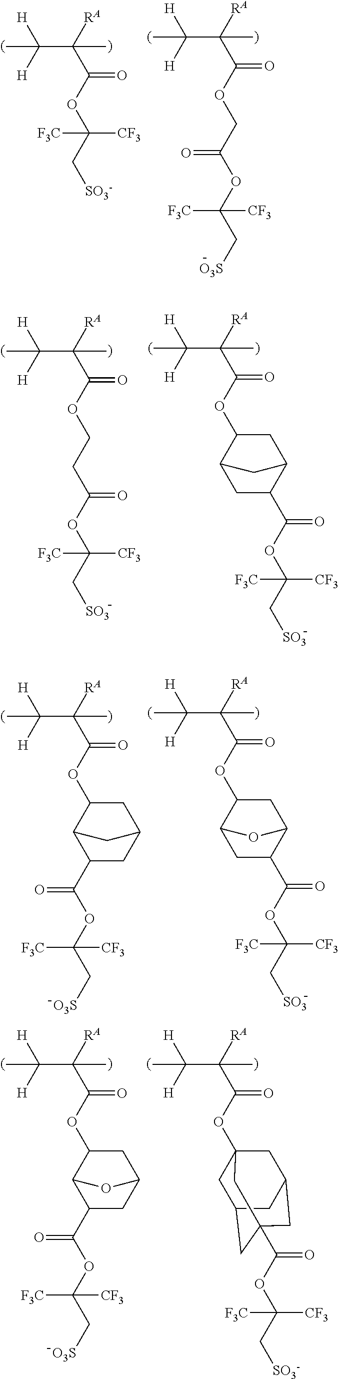

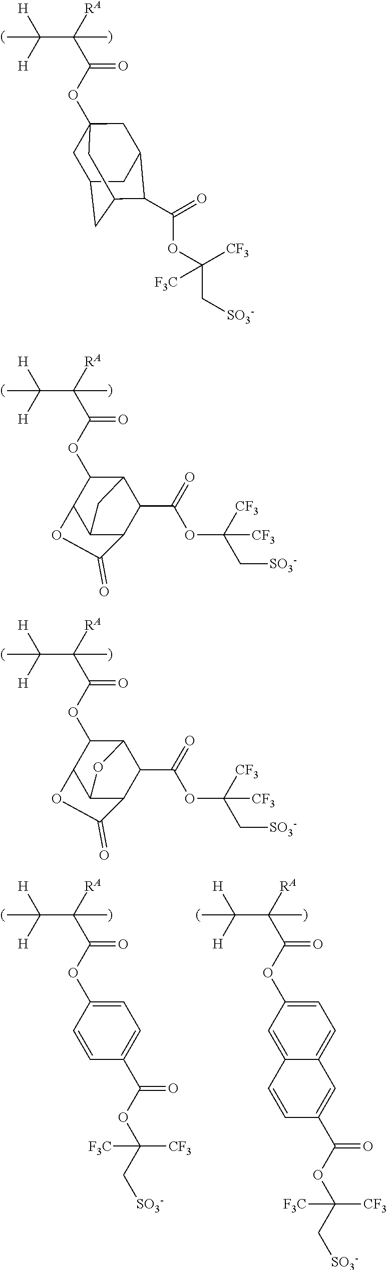

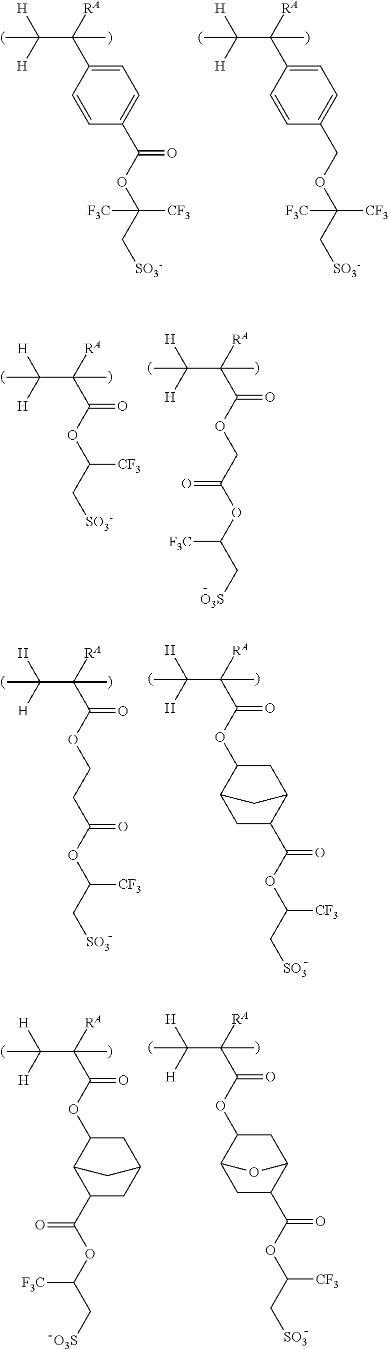

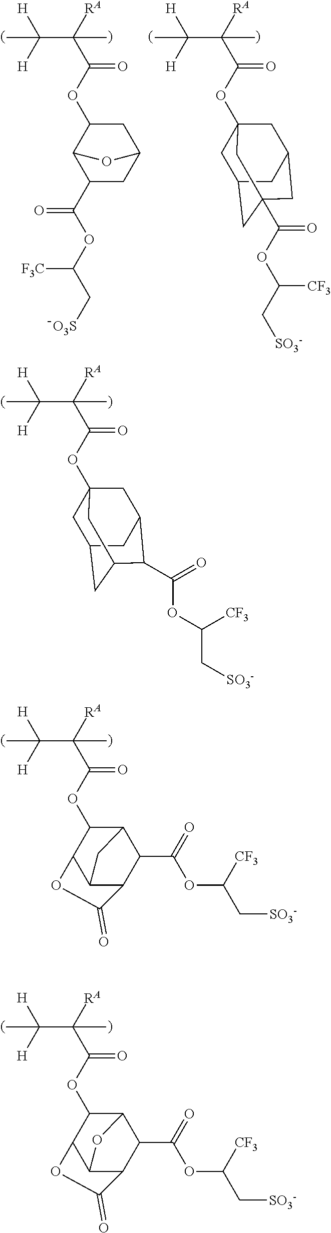

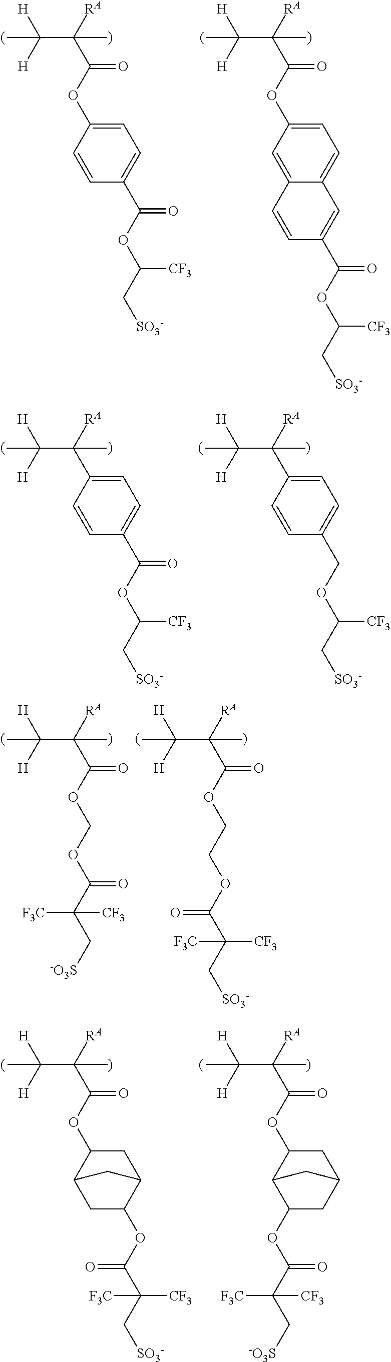

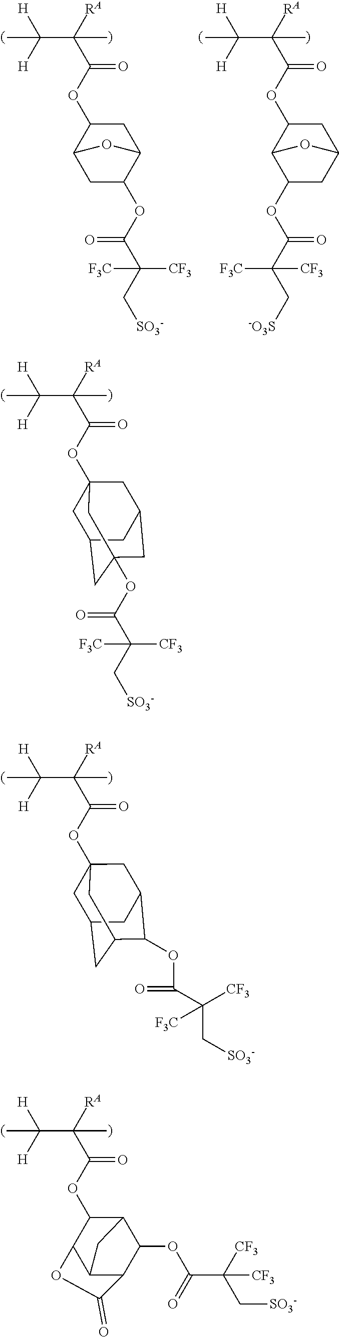

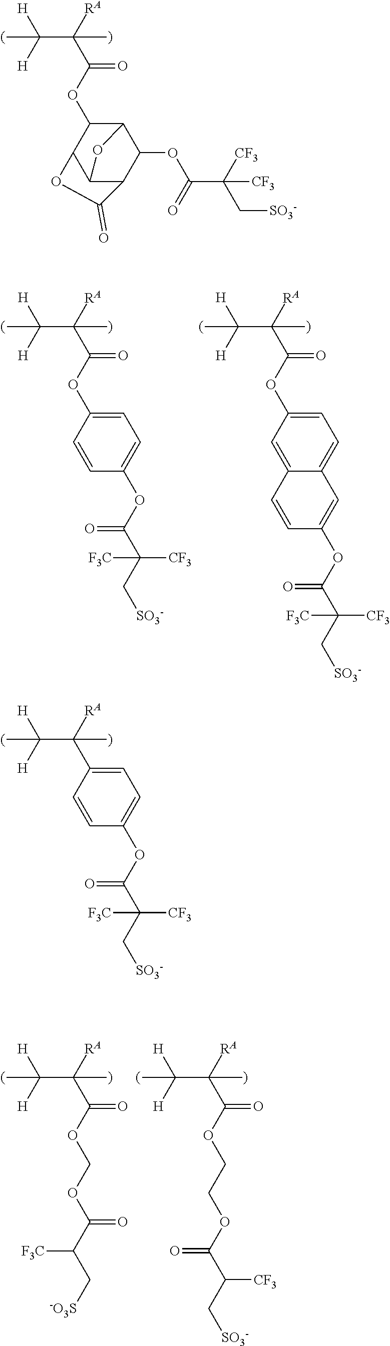

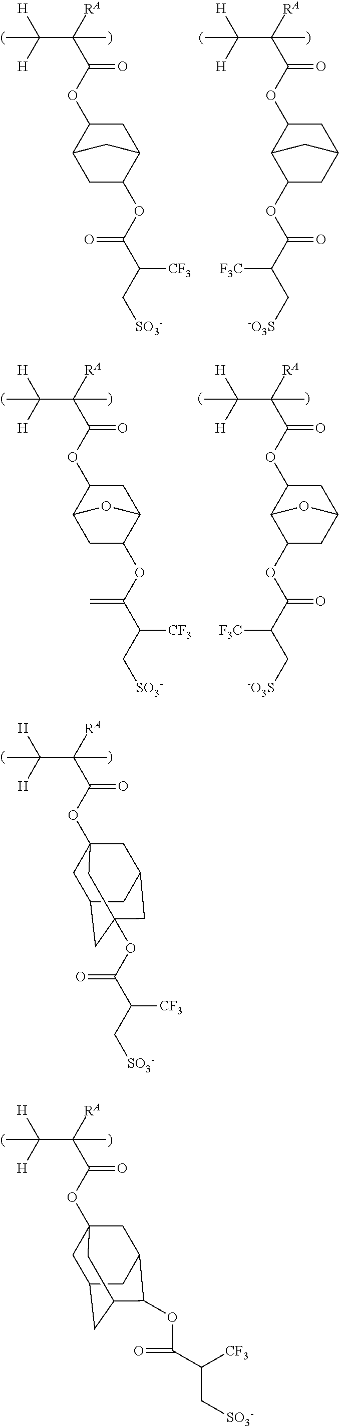

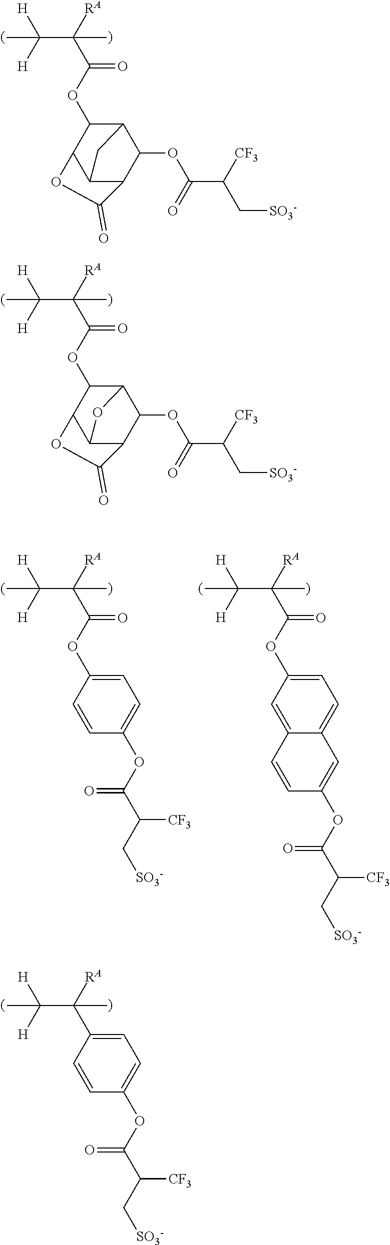

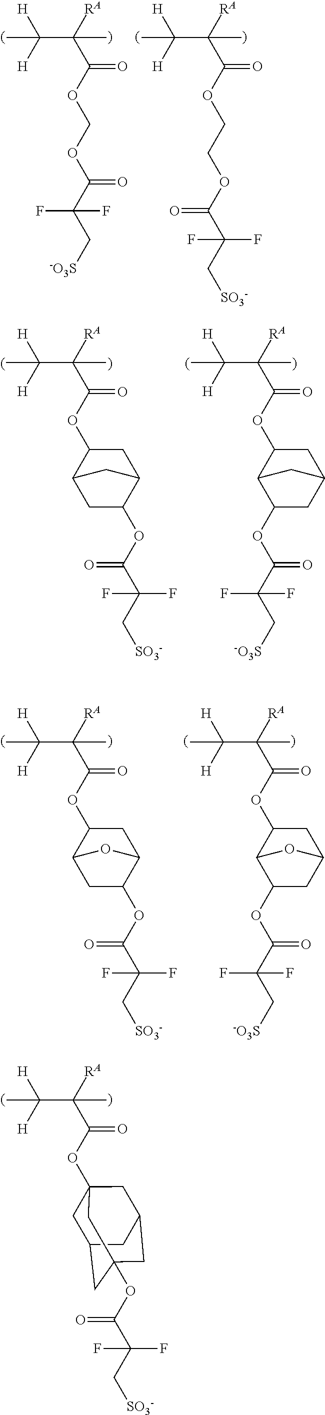

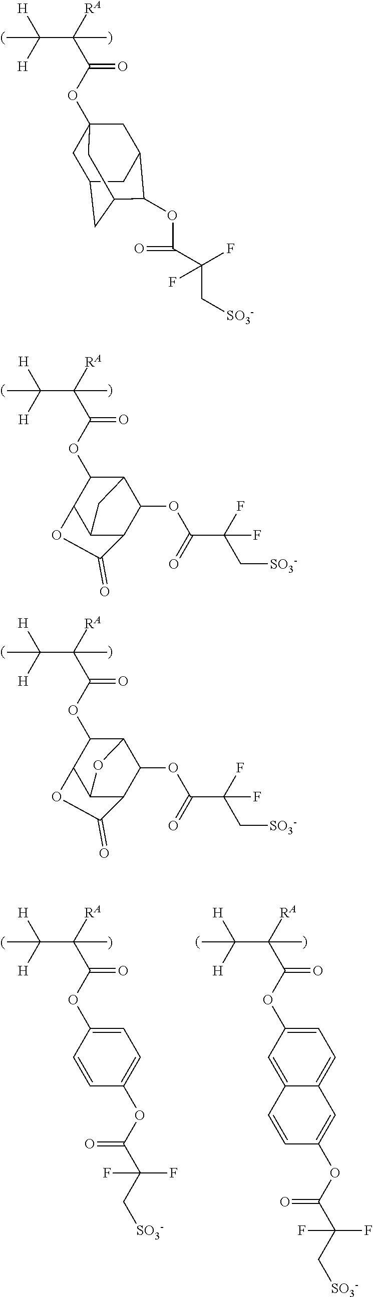

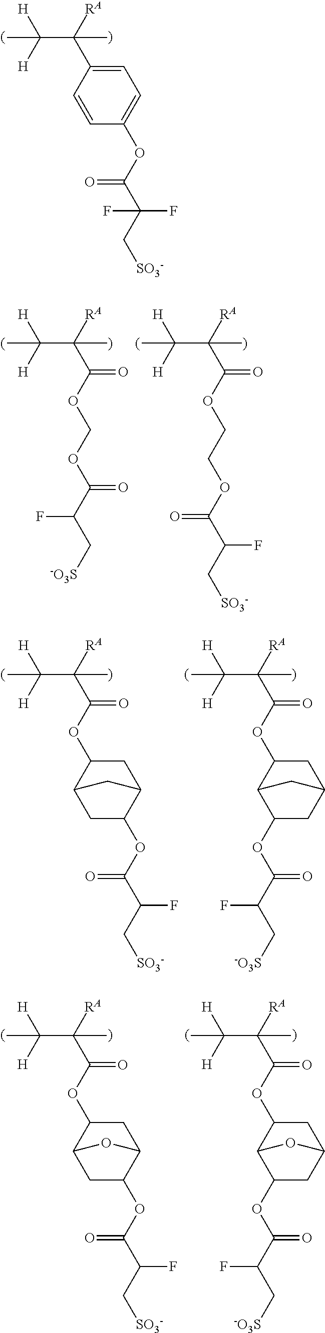

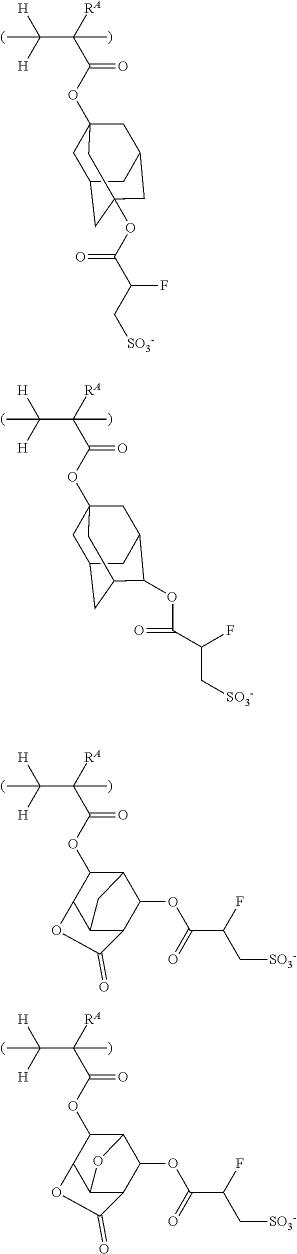

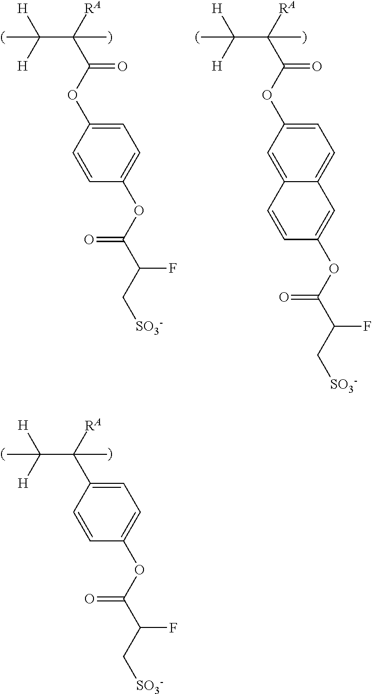

Examples of the anion in repeat unit (c4) are shown below, but not limited thereto. Herein R^{A} is as defined above.

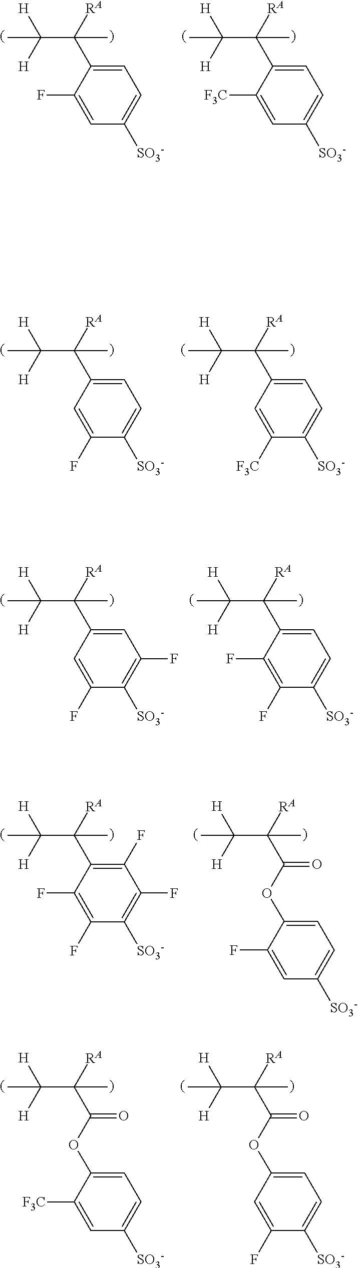

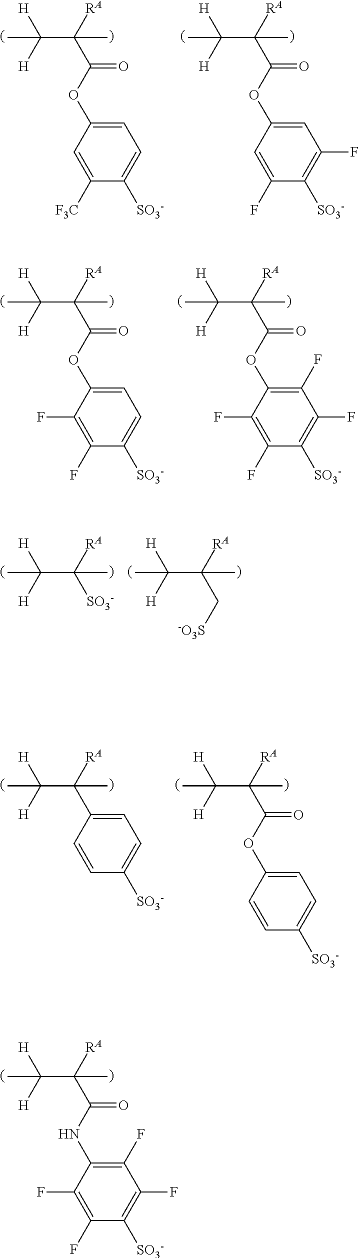

In formulae (c2) to (c4), A⁺ is an onium cation. Suitable onium cations include sulfonium, iodonium and ammonium cations, with the sulfonium and iodonium cations being preferred. Exemplary are cations having the formula (cation-1) or (cation-2) which is described later.

Repeat units (c1) to (c4) function as a photoacid generator. Where a base polymer comprising any of repeat units (c1) to (c4), that is, polymer-bound acid generator is used, the resist composition may or may not contain (D) a photoacid generator.

The base polymer may further comprise repeat units (d) of a structure having a hydroxy group protected with an acid labile group. The repeat unit (d) is not particularly limited as long as the unit includes one or more structures having a hydroxy group protected with a protective group such that the protective group is decomposed to generate the hydroxy group under the action of acid. Repeat units having the formula (d1) are preferred.

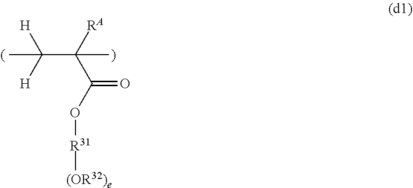

In formula (d1), R^{A} is as defined above, and e is an integer of 1 to 4. R³¹ is a C₁-C₃₀ (e+1)-valent hydrocarbon group which may contain a heteroatom. R³² is an acid labile group.

In formula (d1), the acid labile group R³² is deprotected under the action of acid so that a hydroxy group is generated. Although the structure of R³² is not particularly limited, an acetal structure, ketal structure, alkoxycarbonyl group and alkoxymethyl group having the following formula (d2) are preferred, with the alkoxymethyl group having formula (d2) being more preferred.

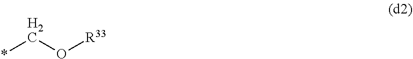

Herein R³³ is a C₁-C₁₅ hydrocarbyl group.

Illustrative examples of the acid labile group R³², the alkoxymethyl group having formula (d2), and the repeat units (d) are as exemplified for the repeat units (d) in JP-A 2020-111564 (US 20200223796).

In addition to the foregoing units, the base polymer may further comprise repeat units (e) derived from indene, benzofuran, benzothiophene, acenaphthylene, chromone, coumarin, and norbornadiene, or derivatives thereof. Examples of the monomer from which repeat units (e) are derived are shown below, but not limited thereto.

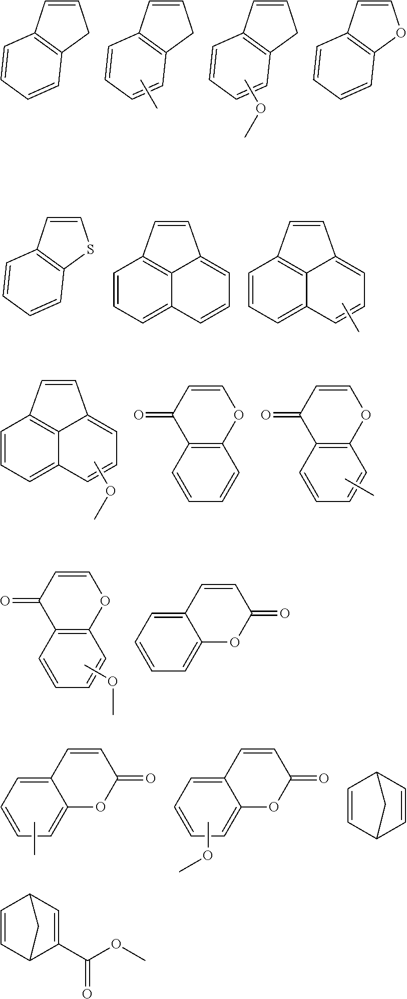

Furthermore, the base polymer may comprise repeat units (f) derived from indane, vinylpyridine, vinylcarbazole, or derivatives thereof.

In the polymer, a fraction of units (a1), (a2), (b1), (b2), (c1) to (c4), (d), (e), and (f) is: preferably 0<a1≤0.8, 0≤a2≤0.8, 0≤b1≤0.6, 0≤b2≤0.6, 0≤c1≤0.4, 0≤c2≤0.4, 0≤c3≤0.4, 0≤c4≤0.4, 0≤d≤0.5, 0≤e≤0.3, and 0≤f≤0.3; more preferably 0<a1≤0.7, 0≤a2≤0.7, 0≤b1≤0.5, 0≤b2≤0.5, 0≤c1≤0.3, 0≤c2≤0.3, 0≤c3≤0.3, 0≤c4≤0.3, 0≤d≤0.3, 0≤e≤0.3, and 0≤f≤0.3.

The polymer should preferably have a weight average molecular weight (Mw) in the range of 1,000 to 500,000, and more preferably 3.000 to 100,000. A Mw in the range ensures satisfactory etch resistance and eliminates the risk of resolution being lowered due to a failure to acquire a difference in dissolution rate before and after exposure. It is noted that Mw is as measured by GPC versus polystyrene standards using tetrahydrofuran (THF) or N,N-dimethylformamide (DMF) solvent.

Since the influence of dispersity (Mw/Mn) becomes stronger as the pattern rule becomes finer, the polymer should preferably have a narrow dispersity (Mw/Mn) of 1.0 to 2.0 in order to provide a resist composition suitable for micropatterning to a small feature size. A Mw/Mn in the range indicates smaller amounts of lower and higher molecular weight fractions and eliminates the risk of leaving foreign particles on the pattern or degrading the pattern profile after exposure and development.

The polymer may be synthesized by any desired methods, for example, by dissolving one or more monomers selected from the monomers corresponding to the foregoing repeat units in an organic solvent, adding a radical polymerization initiator thereto, and heating for polymerization. Examples of the organic solvent which can be used for polymerization include toluene, benzene, tetrahydrofuran (THF), diethyl ether, dioxane, cyclohexane, cyclopentane, methyl ethyl ketone (MEK), PGMEA, and GBL. Examples of the polymerization initiator used herein include 2,2′-azobisisobutyronitrile (AIBN), 2,2′-azobis(2,4-dimethylvaleronitrile), dimethyl 2,2-azobis(2-methylpropionate), 1,1′-azobis(1-acetoxy-1-phenylethane), benzoyl peroxide, and lauroyl peroxide. The amount of the initiator added is preferably 0.01 to 25 mol % based on the total of monomers. The reaction temperature is preferably 50 to 150° C., more preferably 60 to 100° C. The reaction time is preferably 2 to 24 hours, a time of 2 to 12 hours being more preferred in view of production efficiency.

The polymerization initiator may be added to the monomer solution, which is fed to the reactor. Alternatively, a solution of the polymerization initiator is prepared separately from the monomer solution, and the monomer and initiator solutions be independently fed to the reactor. Since there is a possibility that the initiator generates a radical in the standby time, by which polymerization reaction takes place to form a ultrahigh molecular weight compound, it is preferred from the standpoint of quality control that the monomer solution and the initiator solution be independently prepared and added dropwise. The acid labile group that has been incorporated in the monomer may be kept as such, or the polymerization may be followed by protection or partial protection. Any of well-known chain transfer agents such as dodecylmercaptan and 2-mercaptoethanol may be used for the purpose of adjusting molecular weight. An appropriate amount of the chain transfer agent is 0.01 to 20 mol % based on the total of monomers to be polymerized.

Where a monomer having a hydroxy group is copolymerized, the hydroxy group may be replaced by an acetal group susceptible to deprotection with acid, typically ethoxyethoxy, prior to polymerization, and the polymerization be followed by deprotection with weak acid and water. Alternatively, the hydroxy group may be replaced by an acetyl, formyl, pivaloyl or similar group prior to polymerization, and the polymerization be followed by alkaline hydrolysis.

Hydroxystyrene or hydroxyvinyinaphthalene may be copolymerized by combining it with another monomer in an organic solvent, adding a radical initiator, and heating the mixture for polymerization. Alternatively, acetoxystyrene or acetoxyvinylnaphthalene is used instead of hydroxystyrene or hydroxyvinylnaphthalene, and after polymerization, the acetoxy group is deprotected by alkaline hydrolysis, for thereby converting the polymer product to hydroxystyrene or hydroxyvinylnaplithalene. For alkaline hydrolysis, a base such as aqueous ammonia or triethylamine may be used. Preferably the reaction temperature is −20° C. to 100° C., more preferably 0° C. to 60° C., and the reaction time is 0.2 to 100 hours, more preferably 0.5 to 20 hours.

The amounts of monomers in the monomer solution may be determined appropriate so as to provide the preferred fractions of repeat units as mentioned above.

It is described how to use the polymer obtained by the above preparation method. The reaction solution resulting from polymerization reaction may be used as the final product. Alternatively, the polymer may be recovered in powder form through a purifying step such as re-precipitation step of adding the reaction solution to a poor solvent and letting the polymer precipitate as powder, after which the polymer powder is used as the final product. It is preferred from the standpoints of operation efficiency and consistent quality to handle a polymer solution which is obtained by dissolving the powder polymer resulting from the purifying step in a solvent, as the final product.

The solvents which can be used herein are described in JP-A 2008-111103, paragraphs [0144]-[0145] (U.S. Pat. No. 7,537,880). Exemplary solvents include ketones such as cyclohexanone and methyl-2-n-pentyl ketone; alcohols such as 3-methoxybutanol, 3-methyl-3-methoxybutanol, 1-methoxy-2-propanol, 1-ethoxy-2-propanol; ethers such as PGME, ethylene glycol monomethyl ether, propylene glycol monoethyl ether, ethylene glycol monoethyl ether, propylene glycol dimethyl ether, and diethylene glycol dimethyl ether; esters such as PGMEA, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones such as GBL; alcohols such as DAA; and high-boiling alcohols such as diethylene glycol, propylene glycol, glycerol, 1,4-butanediol, and 1,3-butanediol, which may be used alone or in admixture.

The polymer solution preferably has a polymer concentration of 0.01 to 30% by weight, more preferably 0.1 to 20% by weight.

Prior to use, the reaction solution or polymer solution is preferably filtered through a filter. Filtration is effective for consistent quality because foreign particles and gel which can cause defects are removed.

Suitable materials of which the filter is made include fluorocarbon, cellulose, nylon, polyester, and hydrocarbon base materials. Preferred for the filtration of a resist composition are filters made of fluorocarbons commonly known as Teflon®, hydrocarbons such as polyethylene and polypropylene, and nylon. While the pore size of the filter may be selected appropriate to comply with the desired cleanness, the filter preferably has a pore size of up to 100 nm, more preferably up to 20 mu. A single filter may be used or a plurality of filters may be used in combination. Although the filtering method may be single pass of the solution, preferably the filtering step is repeated by flowing the solution in a circulating manner. In the polymer preparation process, the filtering step may be carried out any times, in any order and in any stage. The reaction solution as polymerized or the polymer solution may be filtered, preferably both are filtered.

The base polymer (A) may be used alone or as a mixture of two or more polymers which are different in compositional ratio, Mw and/or Mw/Mn. In addition to the polymer defined above, the base polymer (A) may contain a hydrogenated product of ring-opening metathesis polymerization (ROMP) polymer, which is described in JP-A 2003-066612.

The base polymer (A) preferably comprises photoacid generating units particularly when narrow pitch patterns are formed by applying the EUV lithography. It is more preferred that an acid generating anion structure be bound to the polymer because acid diffusion is minimized. Further preferably, the polymer additionally contains an aromatic moiety in the acid labile unit and comprises hydroxystyrene units having formula (b2). Incorporation of aromatic-bearing groups ensures improvements in etch resistance and the efficiency of generating secondary electrons upon exposure to EUV radiation.

### (B) Organic Solvent

The resist composition comprises (B) an organic solvent. The organic solvent used herein is not particularly limited as long as the foregoing and other components are soluble therein. Suitable solvents include ketones such as cyclopentanone, cyclohexanone, and methyl 2-n-pentyl ketone; alcohols such as 3-methoxybutanol, 3-methyl-3-methoxybutanol, 1-methoxy-2-propanol, 1-ethoxy-2-propanol, and diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone (GBL), and mixtures thereof.

The organic solvent (B) is preferably added in an amount of 100 to 10,000 parts by weight, and more preferably 200 to 8,000 parts by weight per 80 parts by weight of the base polymer (A). The organic solvent may be used alone or in admixture.

### (C) Onium Salt

The resist composition comprises (C) an onium salt having the formula (1). The onium salt undergoes an ion exchange with a strong acid (sulfonic acid) generated from another PAG upon light exposure for thereby controlling acid-elimination reaction of the acid labile group for reducing or controlling the distance of acid diffusion. The onium salt apparently functions as a quencher.

Zq⁺Xq⁻ (1)

In formula (1), Zq⁺ is a sulfonium, iodonium or ammonium cation. Preferably, the sulfonium cation has the formula (cation-1), the iodonium cation has the formula (cation-2), and the ammonium cation has the formula (cation-3).

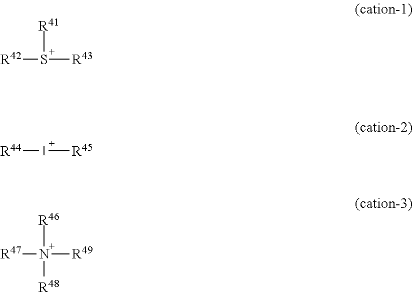

In formulae (cation-1) to (cation-3), R¹ to R⁴⁹ are each independently a C₁-C₃₀ hydrocarbyl group which may contain a heteroatom. The hydrocarbyl group may be saturated or unsaturated and straight, branched or cyclic. Examples thereof include C₁-C₃₀ alkyl groups such as methyl, ethyl, n-propyl, isopropyl, n-butyl, and tert-butyl; C₃-C₃₀ cyclic saturated hydrocarbyl groups such as cyclopropyl, cyclopentyl, cyclohexyl, cyclopropylmethyl, 4-methylcyclohexyl, cyclohexylmethyl, norbornyl, and adamantyl; C₂-C₃₀ alkenyl groups such as vinyl, allyl, propenyl, butenyl, and hexenyl; C₃-C₃₀ cyclic unsaturated hydrocarbyl groups such as cyclohexenyl; C₆-C₃₀ aryl groups such as phenyl, naphthyl and thienyl; C₇-C₃₀ aralkyl groups such as benzyl, 1-phenylethyl and 2-phenylethyl, and combinations thereof. Inter alia, aryl groups are preferred. In the hydrocarbyl group, some or all of the hydrogen atoms may be substituted by a moiety containing a heteroatom such as oxygen, sulfur, nitrogen or halogen and some constituent —CH₂— may be replaced by a moiety containing a heteroatom such as oxygen, sulfur or nitrogen, so that the group may contain a hydroxy, cyano, carbonyl, ether bond, ester bond, sulfonic ester bond, carbonate bond, lactone ring, sultone ring, carboxylic anhydride (—C(═O)—O—C(═O)—), or haloalkyl moiety.

Also, R⁴¹ and R⁴² may bond together to form a ring with the sulfur atom to which they are attached. Examples of the sulfonium cation having formula (cation-1) wherein R⁴¹ and R⁴² form a ring are shown below.

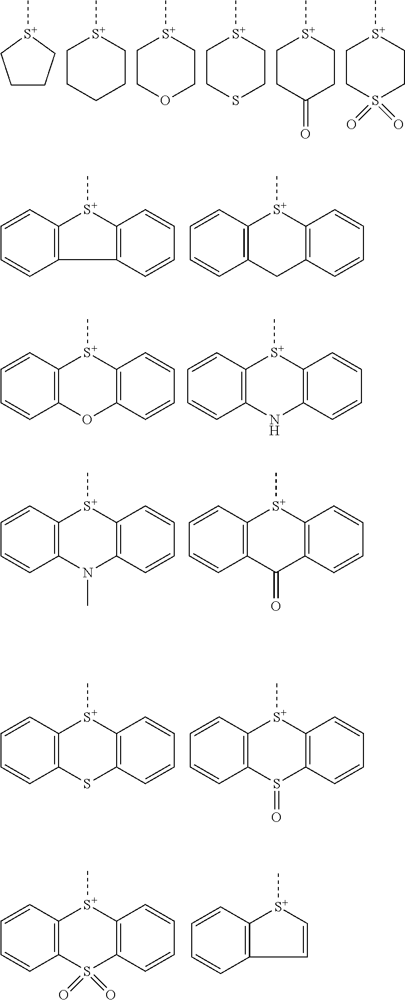

Herein the broken line designates a point of attachment to R⁴³.

Examples of the sulfonium cation having formula (cation-1) are shown below, but not limited thereto.

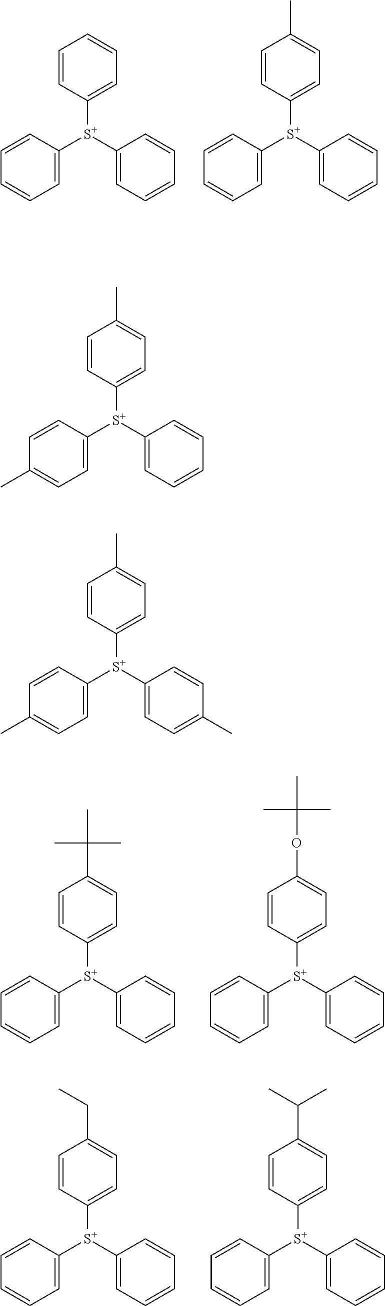

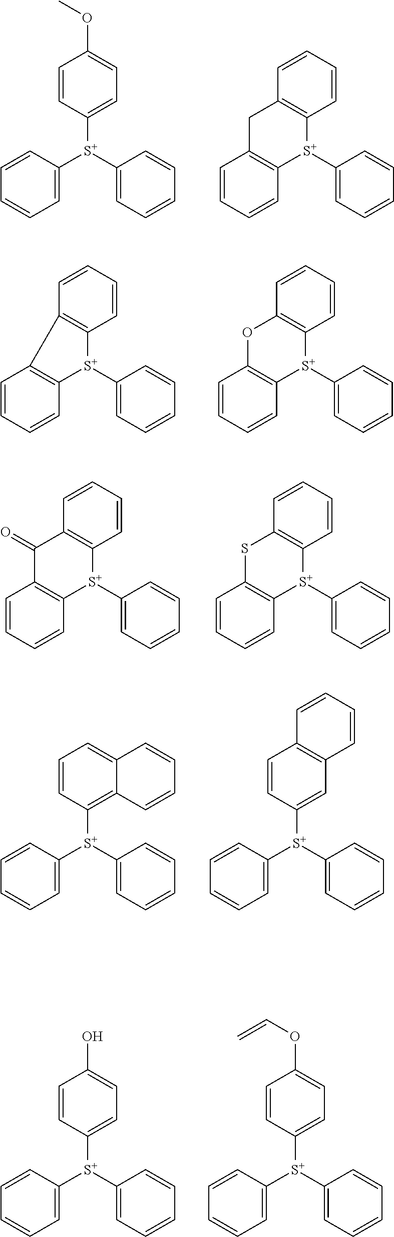

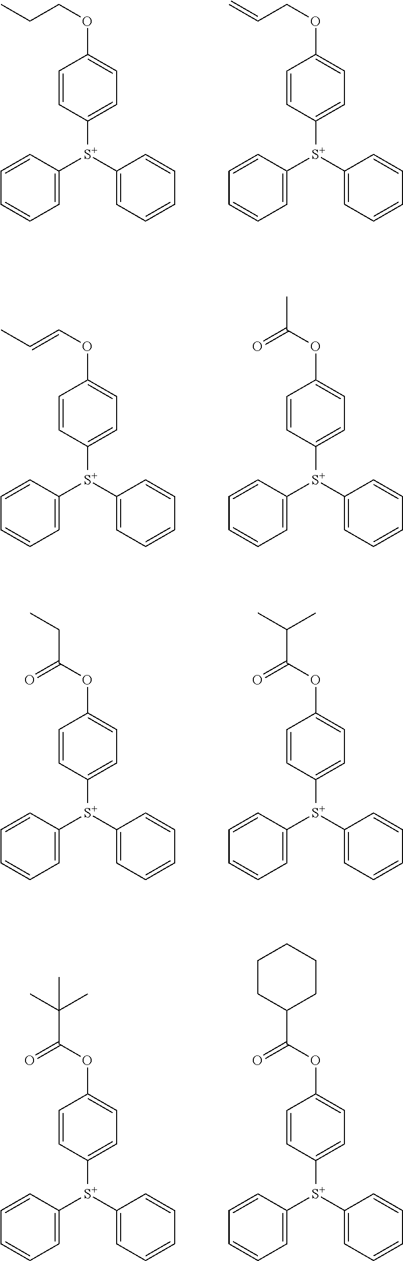

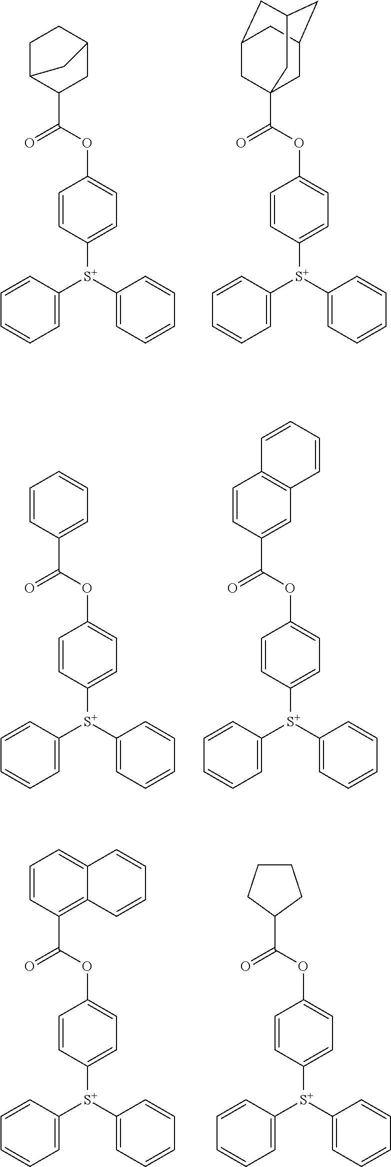 [SMILES: O=C(Oc1ccc([S+](c2ccccc2)c2ccccc2)cc1)C1CC2CCC1C2 ; O=C(Oc1ccc([S+](c2ccccc2)c2ccccc2)cc1)C12CC3CC(CC(C3)C1)C2 ; O=C(Oc1ccc([S+](c2ccccc2)c2ccccc2)cc1)c1ccccc1 ; O=C(Oc1ccc([S+](c2ccccc2)c2ccccc2)cc1)c1ccc2ccccc2c1 ; O=C(Oc1ccc([S+](c2ccccc2)c2ccccc2)cc1)c1cccc2ccccc12 ; O=C(Oc1ccc([S+](c2ccccc2)c2ccccc2)cc1)C1CCCC1]

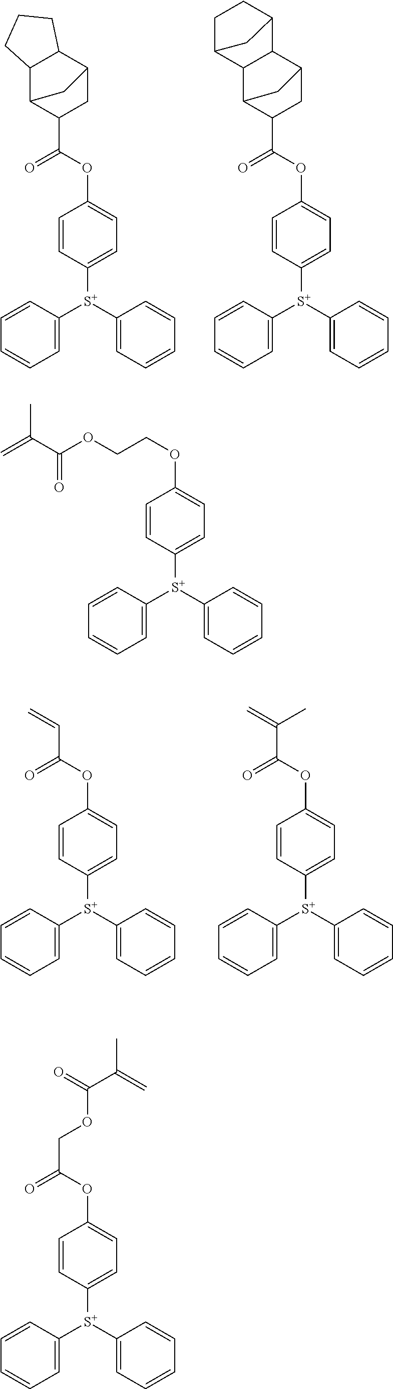 [SMILES: O=C(Oc1ccc([S+](c2ccccc2)c2ccccc2)cc1)C1CC2CC1C1CCCC21 ; O=C(Oc1ccc([S+](c2ccccc2)c2ccccc2)cc1)C1CC2CC1C1C3CCC(C3)C21 ; C=C(C)C(=O)OCCOc1ccc([S+](c2ccccc2)c2ccccc2)cc1 ; C=CC(=O)Oc1ccc([S+](c2ccccc2)c2ccccc2)cc1 ; C=C(C)C(=O)Oc1ccc([S+](c2ccccc2)c2ccccc2)cc1 ; C=C(C)C(=O)OCC(=O)Oc1ccc([S+](c2ccccc2)c2ccccc2)cc1]

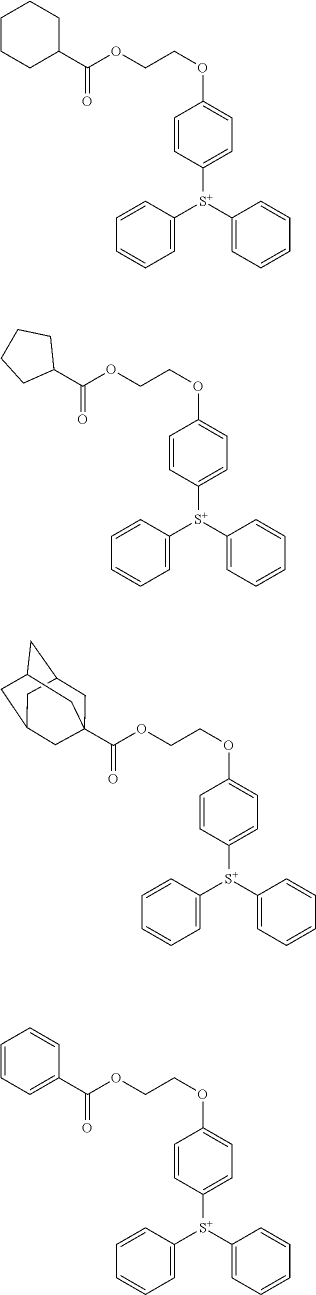 [SMILES: O=C(OCCOc1ccc([S+](c2ccccc2)c2ccccc2)cc1)C1CCCCC1 ; O=C(OCCOc1ccc([S+](c2ccccc2)c2ccccc2)cc1)C1CCCC1 ; O=C(OCCOc1ccc([S+](c2ccccc2)c2ccccc2)cc1)C12CC3CC(CC(C3)C1)C2 ; O=C(OCCOc1ccc([S+](c2ccccc2)c2ccccc2)cc1)c1ccccc1]

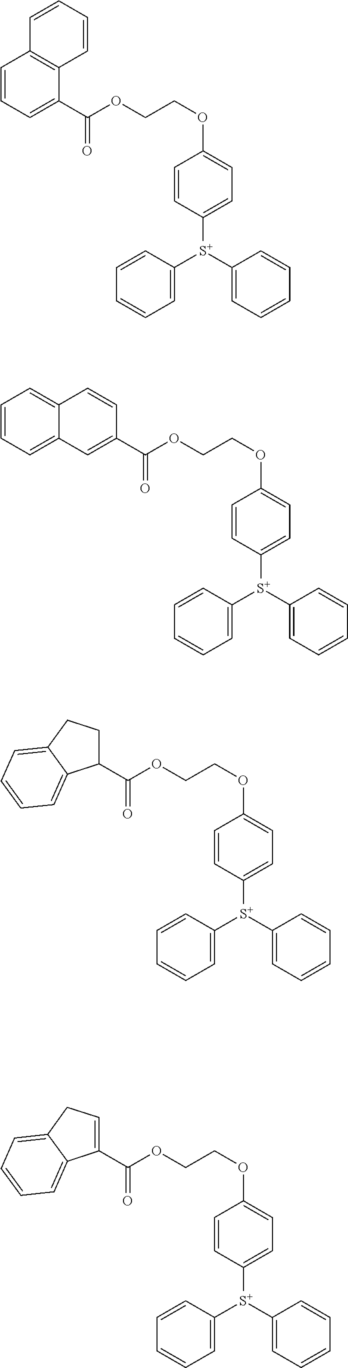 [SMILES: O=C(OCCOc1ccc([S+](c2ccccc2)c2ccccc2)cc1)c1cccc2ccccc12 ; O=C(OCCOc1ccc([S+](c2ccccc2)c2ccccc2)cc1)c1ccc2ccccc2c1 ; O=C(OCCOc1ccc([S+](c2ccccc2)c2ccccc2)cc1)C1CCc2ccccc21 ; O=C(OCCOc1ccc([S+](c2ccccc2)c2ccccc2)cc1)C1=CCc2ccccc21]

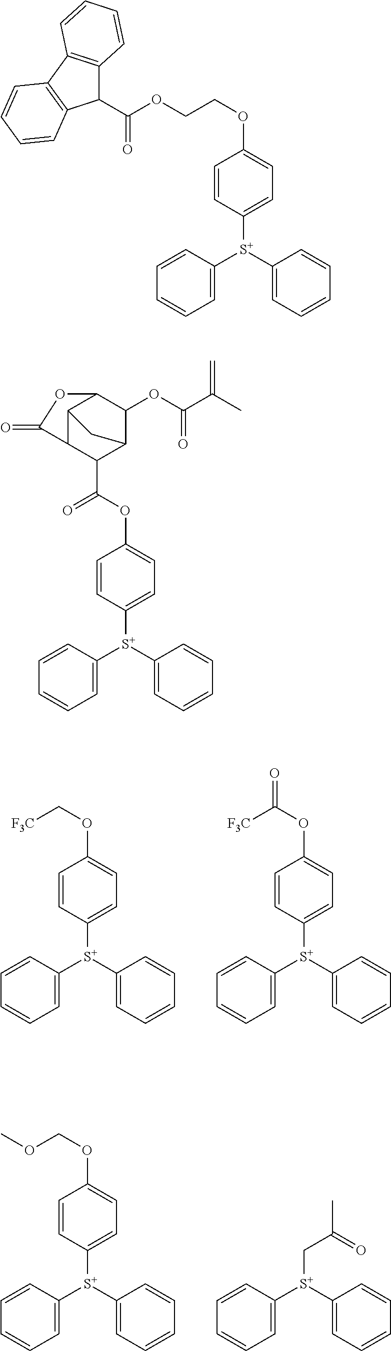 [SMILES: O=C(OCCOc1ccc([S+](c2ccccc2)c2ccccc2)cc1)C1c2ccccc2-c2ccccc21 ; C=C(C)C(=O)OC1C2CC3C1OC(=O)C3C2C(=O)Oc1ccc([S+](c2ccccc2)c2ccccc2)cc1 ; FC(F)(F)COc1ccc([S+](c2ccccc2)c2ccccc2)cc1 ; O=C(Oc1ccc([S+](c2ccccc2)c2ccccc2)cc1)C(F)(F)F ; COCOc1ccc([S+](c2ccccc2)c2ccccc2)cc1 ; CC(=O)C[S+](c1ccccc1)c1ccccc1]

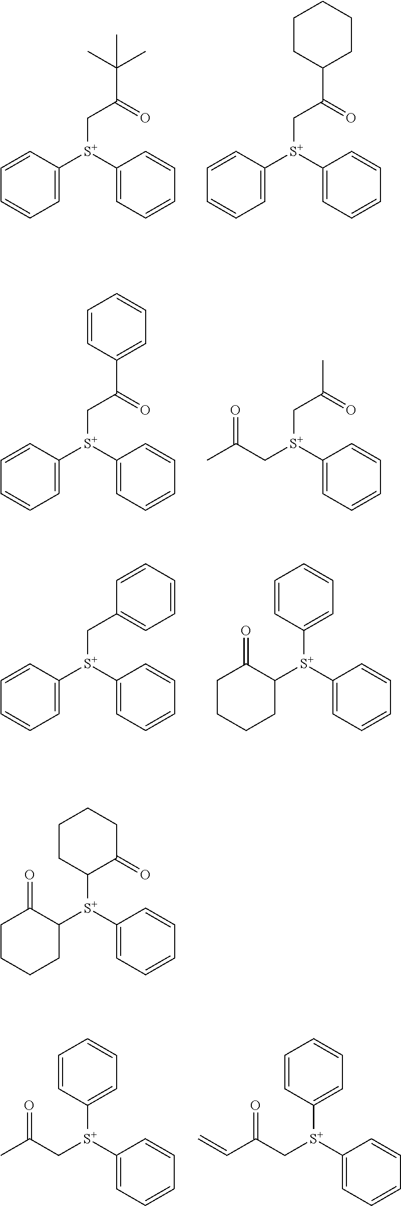

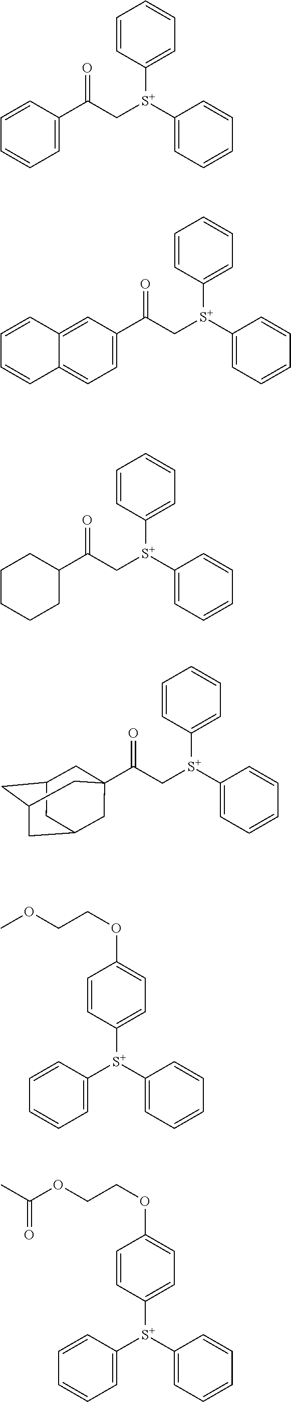 [SMILES: O=C(C[S+](c1ccccc1)c1ccccc1)c1ccccc1 ; O=C(C[S+](c1ccccc1)c1ccccc1)c1ccc2ccccc2c1 ; O=C(C[S+](c1ccccc1)c1ccccc1)C1CCCCC1 ; O=C(C[S+](c1ccccc1)c1ccccc1)C12CC3CC(CC(C3)C1)C2 ; COCCOc1ccc([S+](c2ccccc2)c2ccccc2)cc1 ; CC(=O)OCCOc1ccc([S+](c2ccccc2)c2ccccc2)cc1]

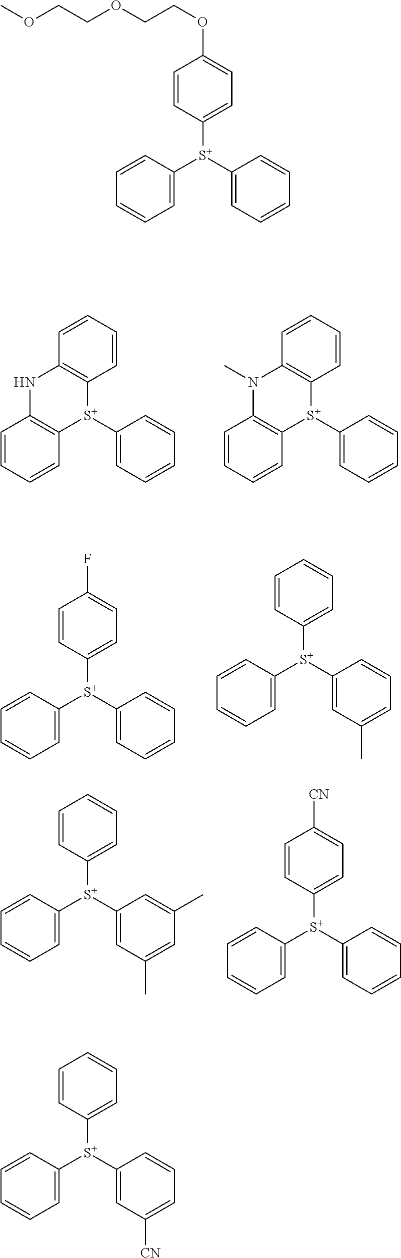

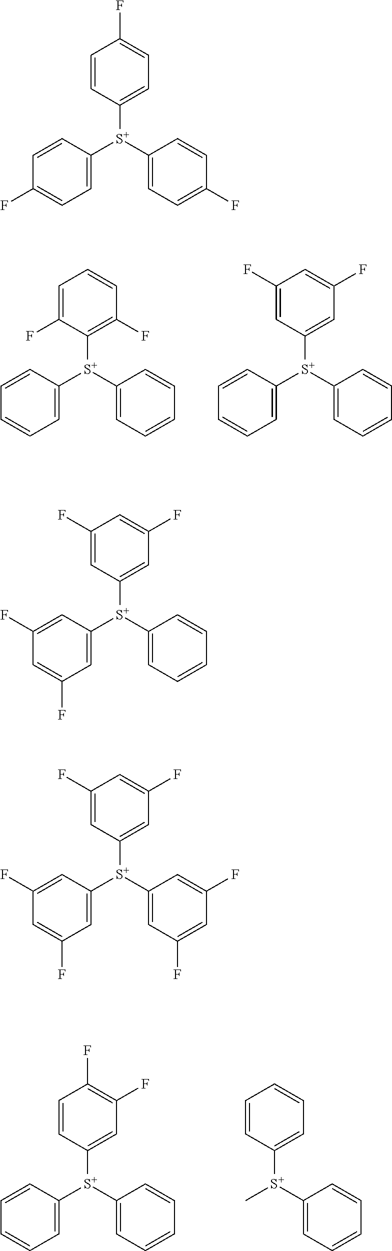

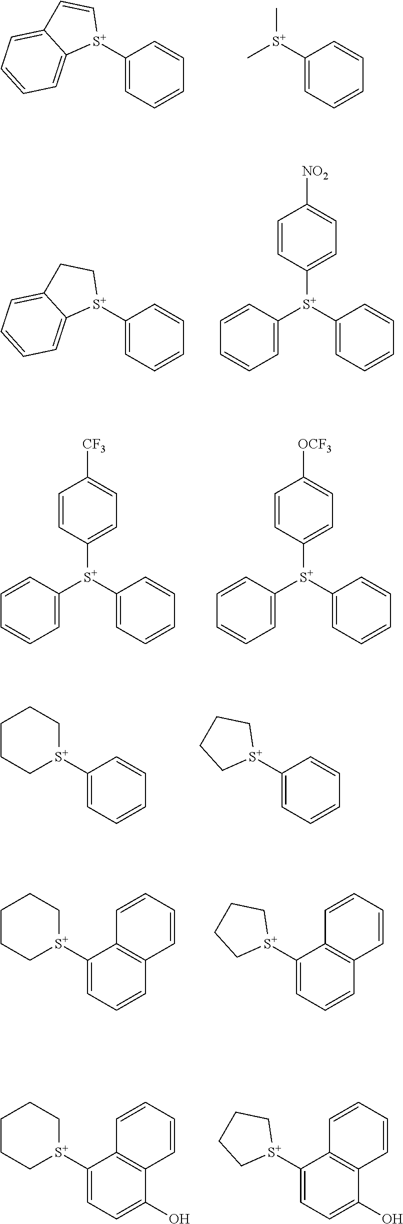

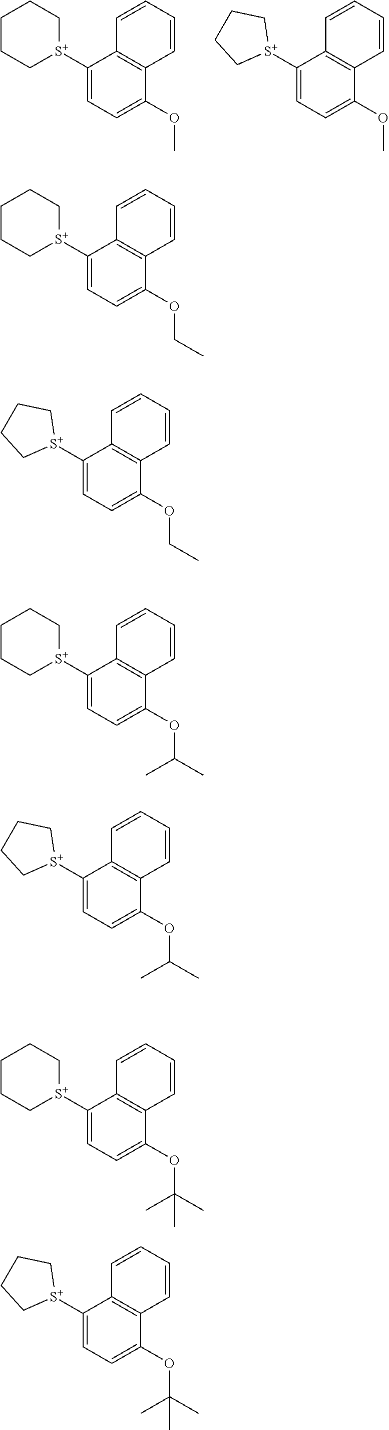

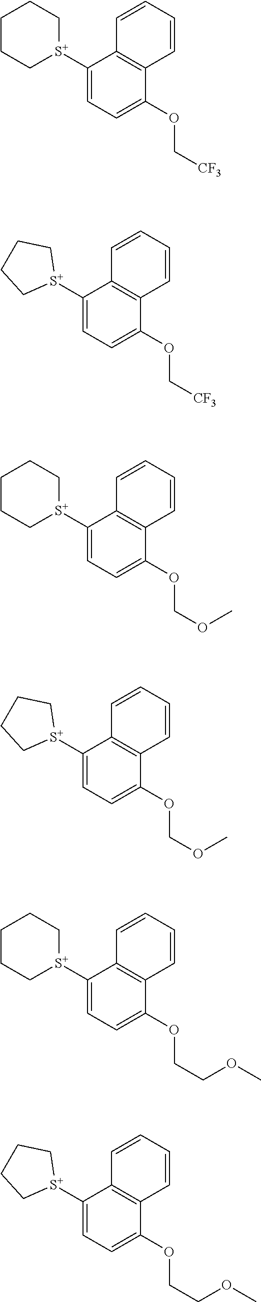 [SMILES: FC(F)(F)COc1ccc([S+]2CCCCC2)c2ccccc12 ; FC(F)(F)COc1ccc([S+]2CCCC2)c2ccccc12 ; COCOc1ccc([S+]2CCCCC2)c2ccccc12 ; COCOc1ccc([S+]2CCCC2)c2ccccc12 ; COCCOc1ccc([S+]2CCCCC2)c2ccccc12 ; COCCOc1ccc([S+]2CCCC2)c2ccccc12]

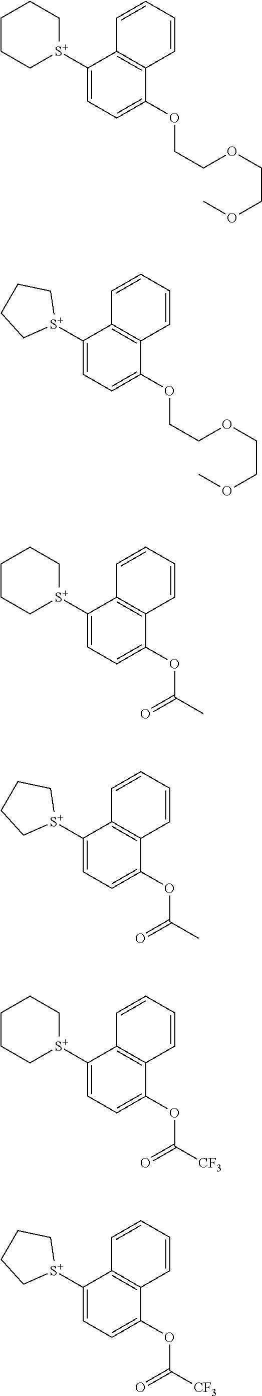 [SMILES: COCCOCCOc1ccc([S+]2CCCCC2)c2ccccc12 ; COCCOCCOc1ccc([S+]2CCCC2)c2ccccc12 ; CC(=O)Oc1ccc([S+]2CCCCC2)c2ccccc12 ; CC(=O)Oc1ccc([S+]2CCCC2)c2ccccc12 ; O=C(Oc1ccc([S+]2CCCCC2)c2ccccc12)C(F)(F)F ; O=C(Oc1ccc([S+]2CCCC2)c2ccccc12)C(F)(F)F]

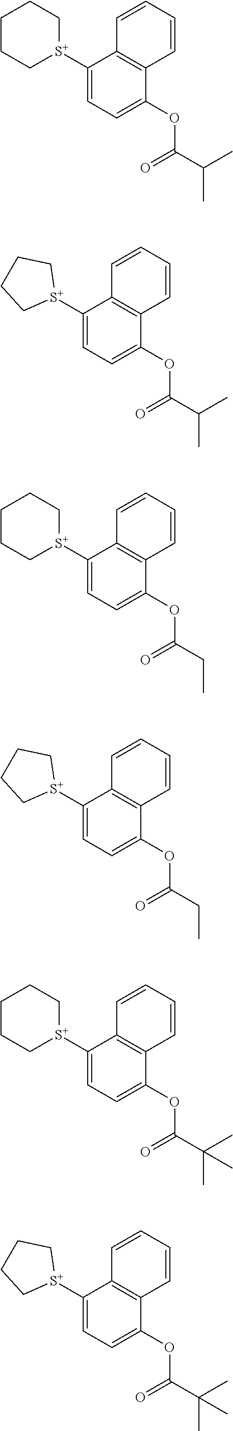 [SMILES: CC(C)C(=O)Oc1ccc([S+]2CCCCC2)c2ccccc12 ; CC(C)C(=O)Oc1ccc([S+]2CCCC2)c2ccccc12 ; CCC(=O)Oc1ccc([S+]2CCCCC2)c2ccccc12 ; CCC(=O)Oc1ccc([S+]2CCCC2)c2ccccc12 ; CC(C)(C)C(=O)Oc1ccc([S+]2CCCCC2)c2ccccc12 ; CC(C)(C)C(=O)Oc1ccc([S+]2CCCC2)c2ccccc12]

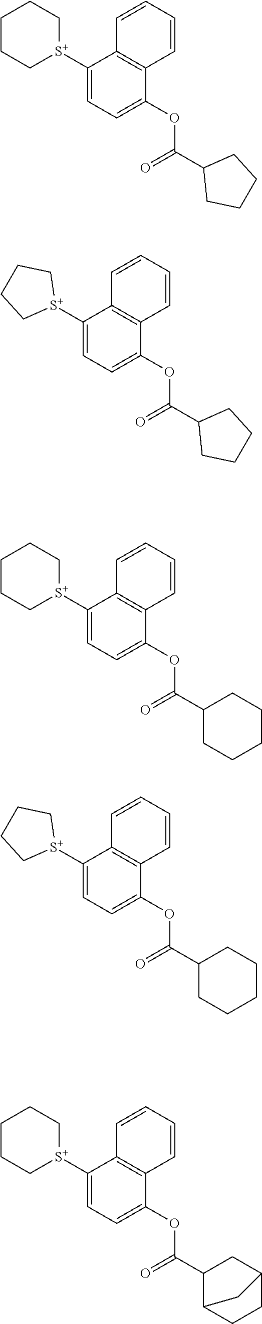 [SMILES: O=C(Oc1ccc([S+]2CCCCC2)c2ccccc12)C1CCCC1 ; O=C(Oc1ccc([S+]2CCCC2)c2ccccc12)C1CCCC1 ; O=C(Oc1ccc([S+]2CCCCC2)c2ccccc12)C1CCCCC1 ; O=C(Oc1ccc([S+]2CCCC2)c2ccccc12)C1CCCCC1 ; O=C(Oc1ccc([S+]2CCCCC2)c2ccccc12)C1CC2CCC1C2]

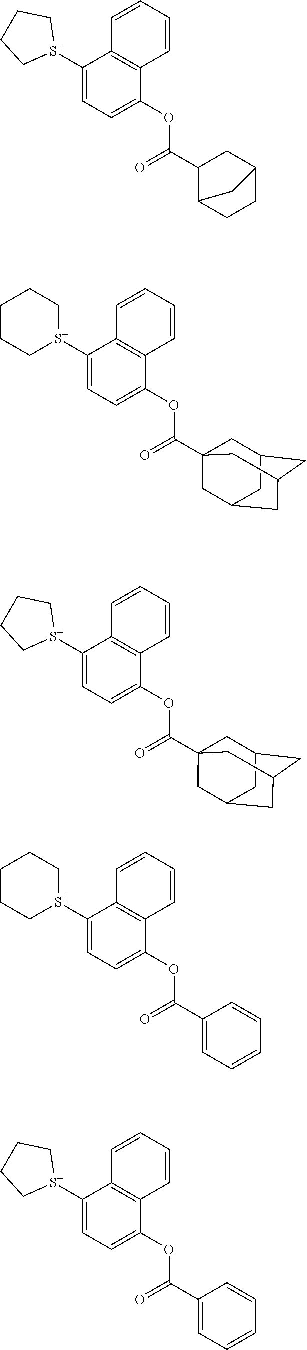 [SMILES: O=C(Oc1ccc([S+]2CCCC2)c2ccccc12)C1CC2CCC1C2 ; O=C(Oc1ccc([S+]2CCCCC2)c2ccccc12)C12CC3CC(CC(C3)C1)C2 ; O=C(Oc1ccc([S+]2CCCC2)c2ccccc12)C12CC3CC(CC(C3)C1)C2 ; O=C(Oc1ccc([S+]2CCCCC2)c2ccccc12)c1ccccc1 ; O=C(Oc1ccc([S+]2CCCC2)c2ccccc12)c1ccccc1]

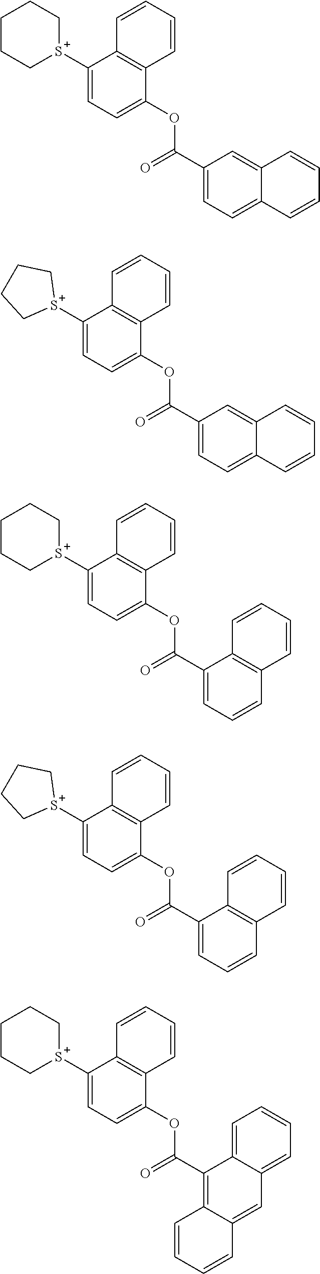 [SMILES: O=C(Oc1ccc([S+]2CCCCC2)c2ccccc12)c1ccc2ccccc2c1 ; O=C(Oc1ccc([S+]2CCCC2)c2ccccc12)c1ccc2ccccc2c1 ; O=C(Oc1ccc([S+]2CCCCC2)c2ccccc12)c1cccc2ccccc12 ; O=C(Oc1ccc([S+]2CCCC2)c2ccccc12)c1cccc2ccccc12 ; O=C(Oc1ccc([S+]2CCCCC2)c2ccccc12)c1c2ccccc2cc2ccccc12]

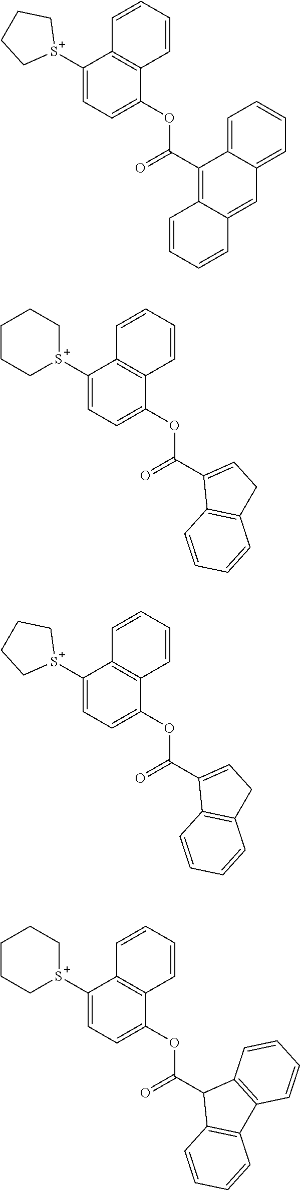 [SMILES: O=C(Oc1ccc([S+]2CCCC2)c2ccccc12)c1c2ccccc2cc2ccccc12 ; O=C(Oc1ccc([S+]2CCCCC2)c2ccccc12)C1=CCc2ccccc21 ; O=C(Oc1ccc([S+]2CCCC2)c2ccccc12)C1=CCc2ccccc21 ; O=C(Oc1ccc([S+]2CCCCC2)c2ccccc12)C1c2ccccc2-c2ccccc21]

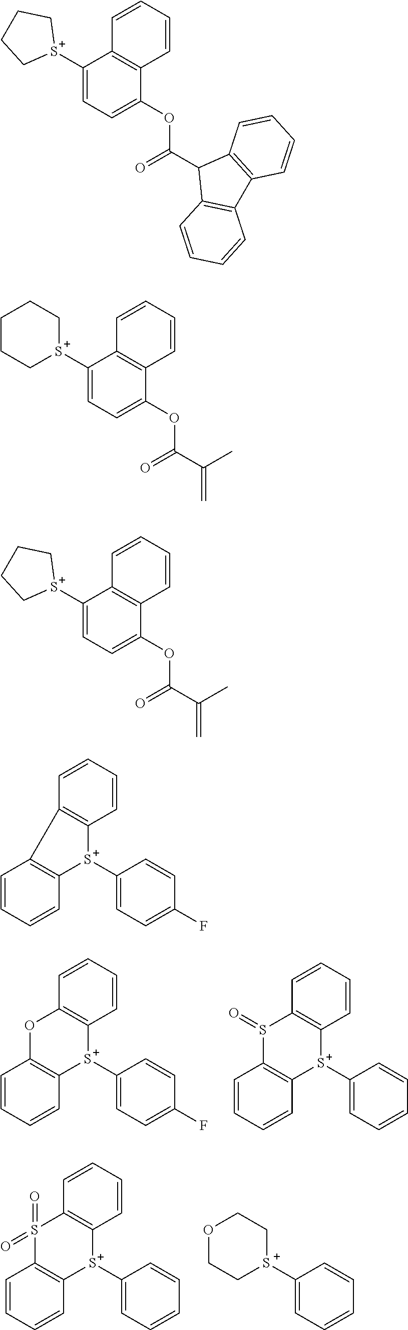

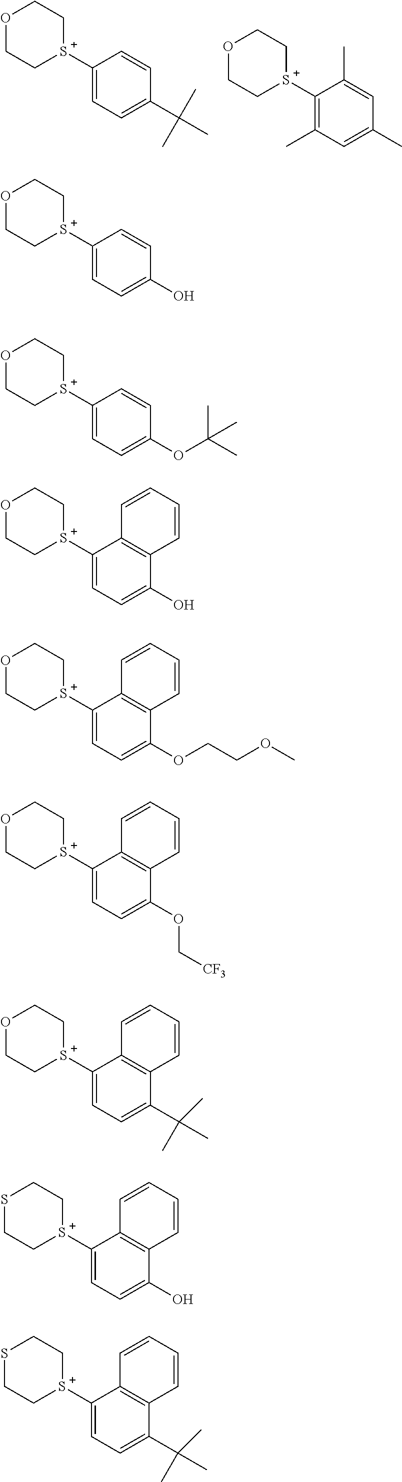

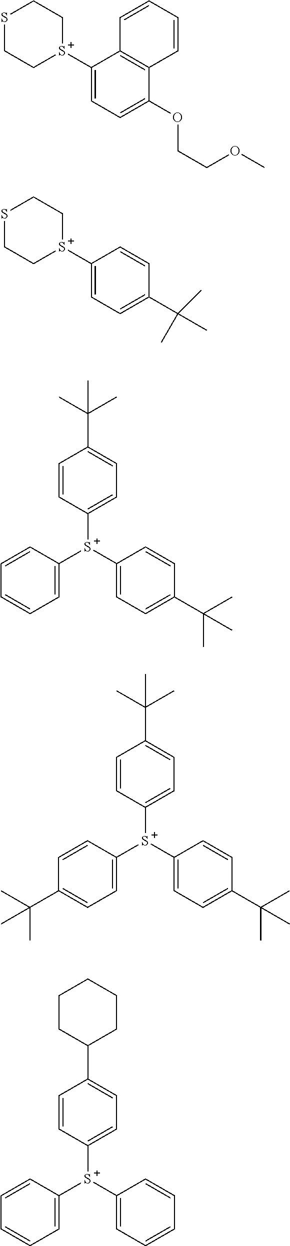

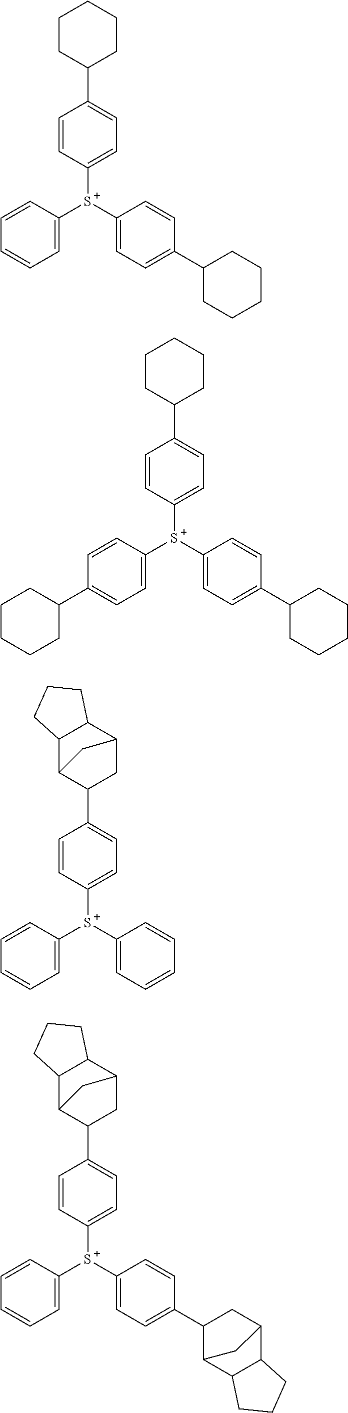 [SMILES: c1ccc([S+](c2ccc(C3CCCCC3)cc2)c2ccc(C3CCCCC3)cc2)cc1 ; c1cc([S+](c2ccc(C3CCCCC3)cc2)c2ccc(C3CCCCC3)cc2)ccc1C1CCCCC1 ; c1ccc([S+](c2ccccc2)c2ccc(C3CC4CC3C3CCCC43)cc2)cc1 ; c1ccc([S+](c2ccc(C3CC4CC3C3CCCC43)cc2)c2ccc(C3CC4CC3C3CCCC43)cc2)cc1]

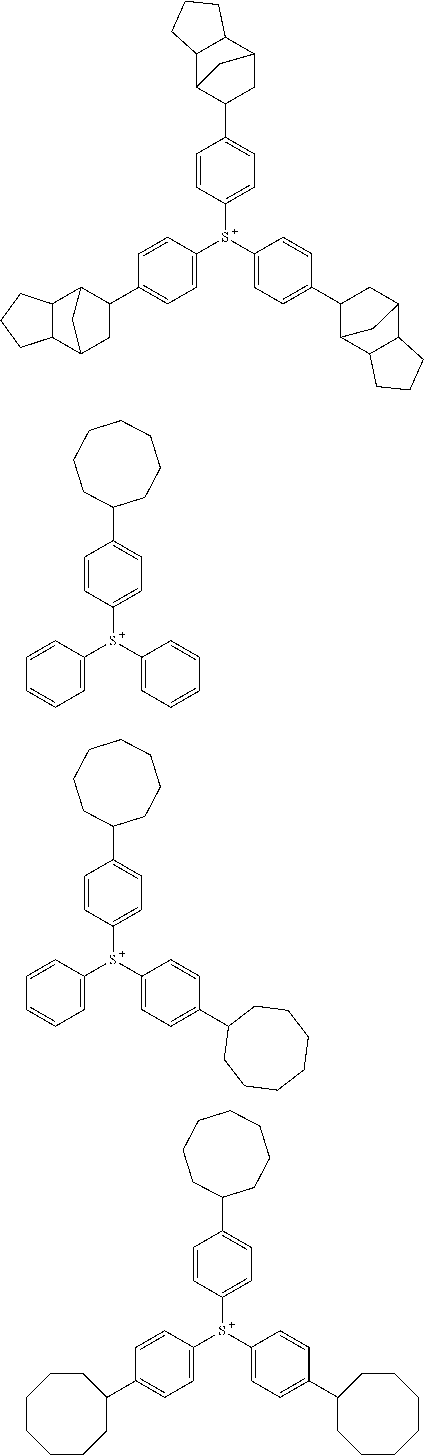 [SMILES: c1cc([S+](c2ccc(C3CC4CC3C3CCCC43)cc2)c2ccc(C3CC4CC3C3CCCC43)cc2)ccc1C1CC2CC1C1CCCC21 ; c1ccc([S+](c2ccccc2)c2ccc(C3CCCCCCC3)cc2)cc1 ; c1ccc([S+](c2ccc(C3CCCCCCC3)cc2)c2ccc(C3CCCCCCC3)cc2)cc1 ; c1cc([S+](c2ccc(C3CCCCCCC3)cc2)c2ccc(C3CCCCCCC3)cc2)ccc1C1CCCCCCC1]

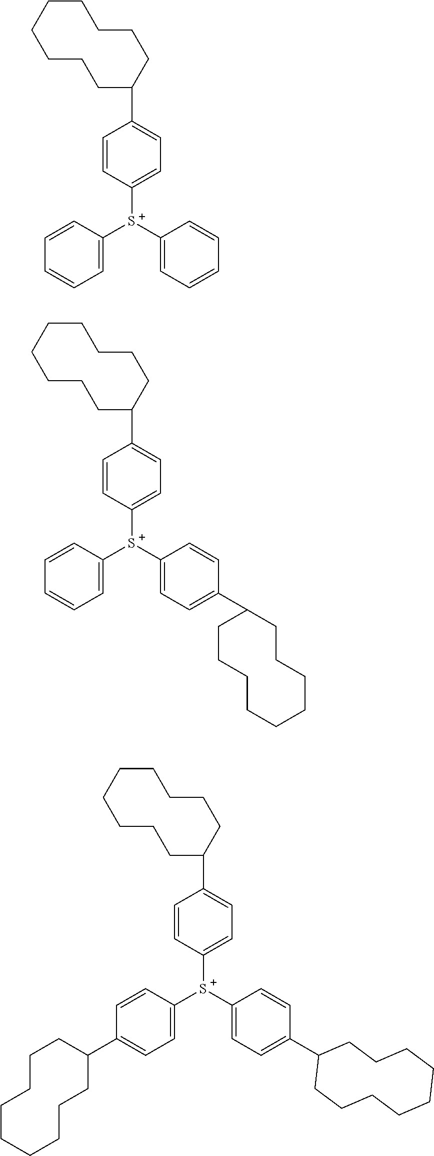 [SMILES: c1ccc([S+](c2ccccc2)c2ccc(C3CCCCCCCCC3)cc2)cc1 ; c1ccc([S+](c2ccc(C3CCCCCCCCC3)cc2)c2ccc(C3CCCCCCCCC3)cc2)cc1 ; c1cc([S+](c2ccc(C3CCCCCCCCC3)cc2)c2ccc(C3CCCCCCCCC3)cc2)ccc1C1CCCCCCCCC1]

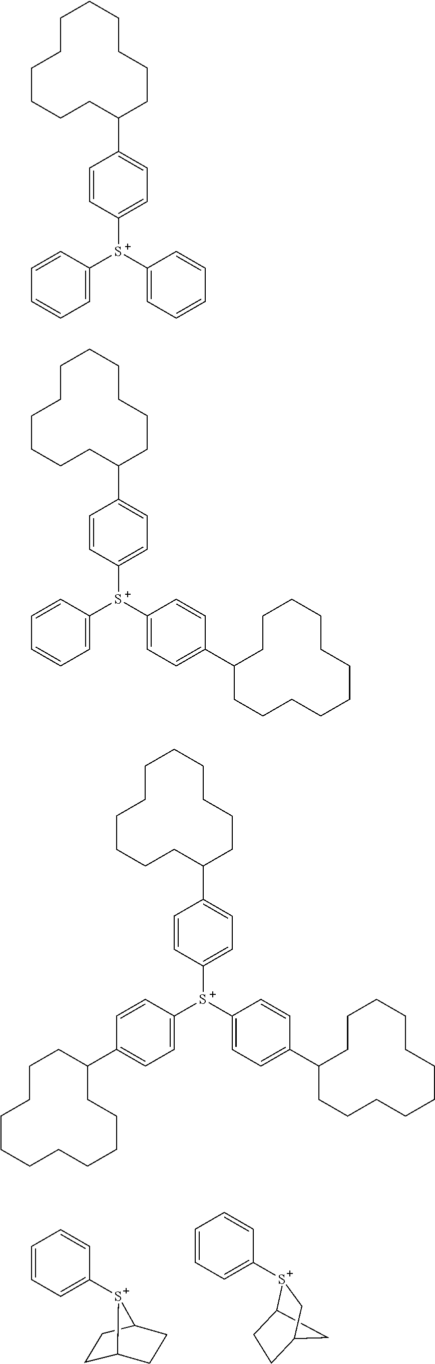 [SMILES: c1ccc([S+](c2ccccc2)c2ccc(C3CCCCCCCCCCC3)cc2)cc1 ; c1ccc([S+](c2ccc(C3CCCCCCCCCCC3)cc2)c2ccc(C3CCCCCCCCCCC3)cc2)cc1 ; c1cc([S+](c2ccc(C3CCCCCCCCCCC3)cc2)c2ccc(C3CCCCCCCCCCC3)cc2)ccc1C1CCCCCCCCCCC1 ; c1ccc([S+]2C3CCC2CC3)cc1 ; c1ccc([S+]2CC3CCC2C3)cc1]

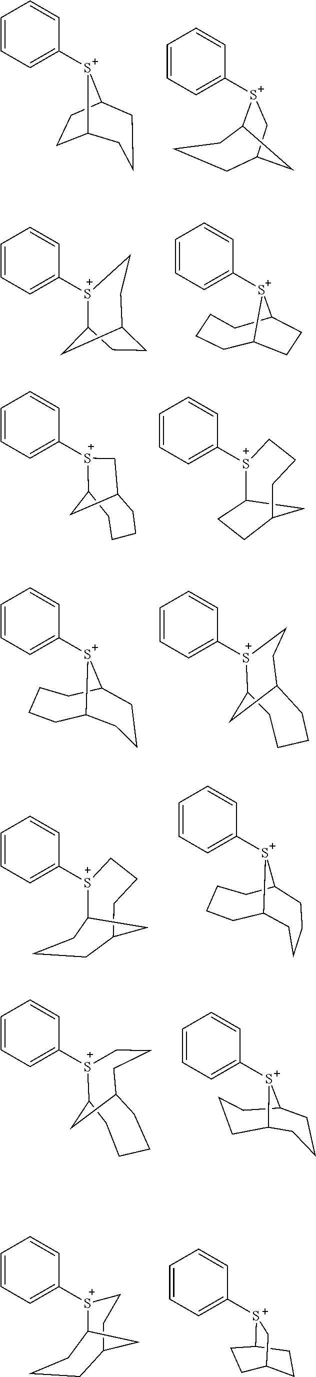

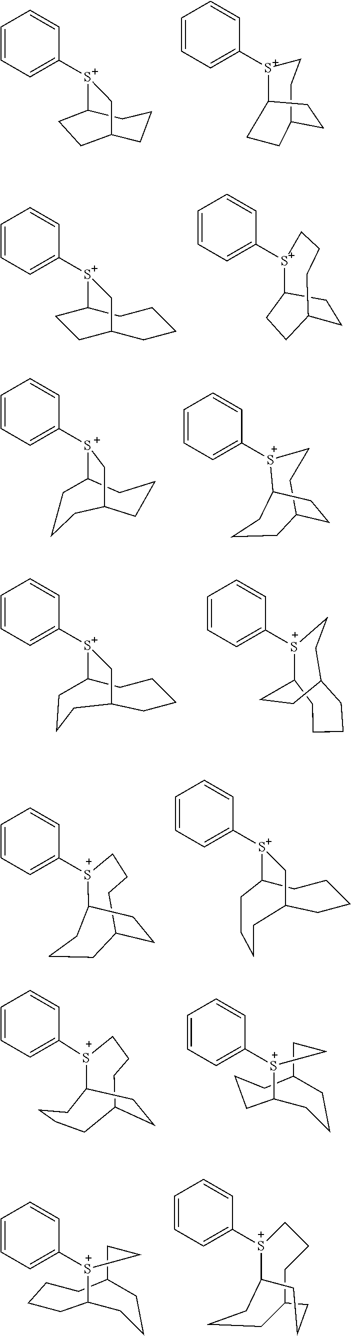

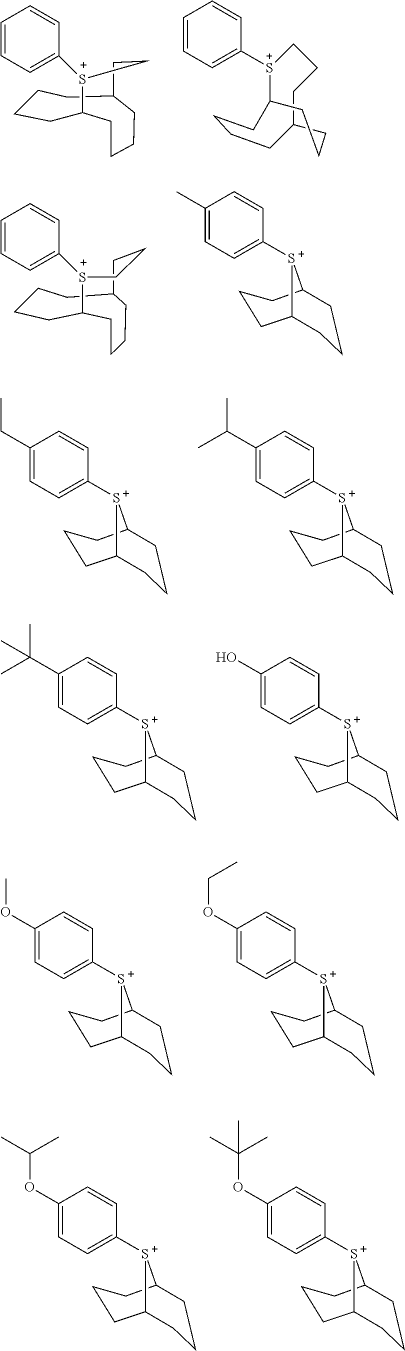

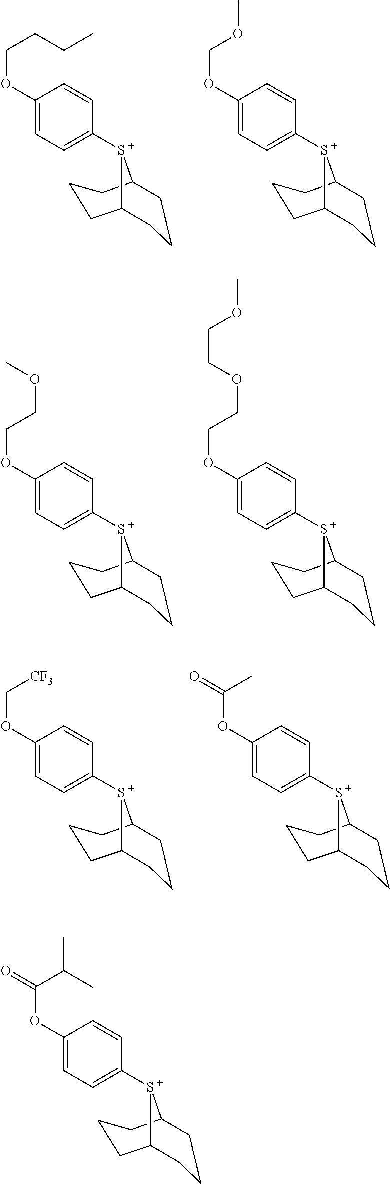

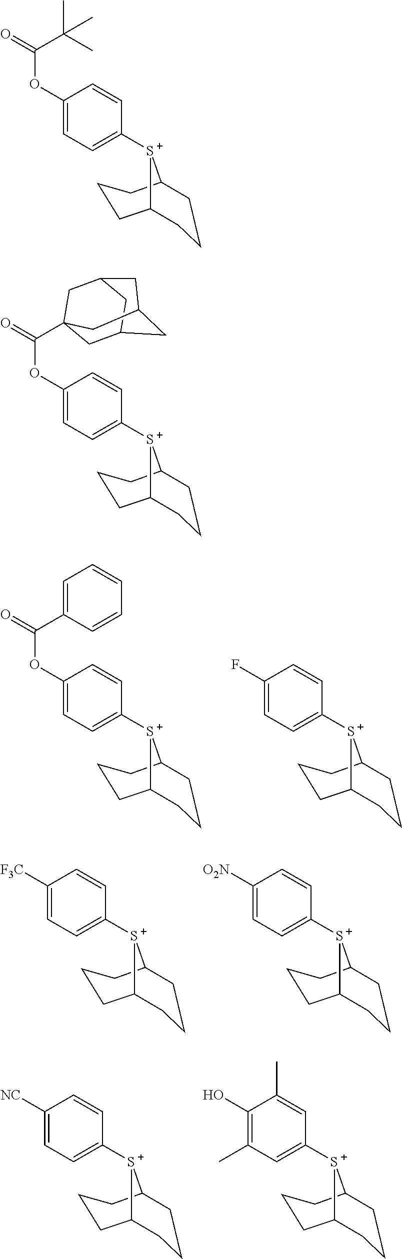

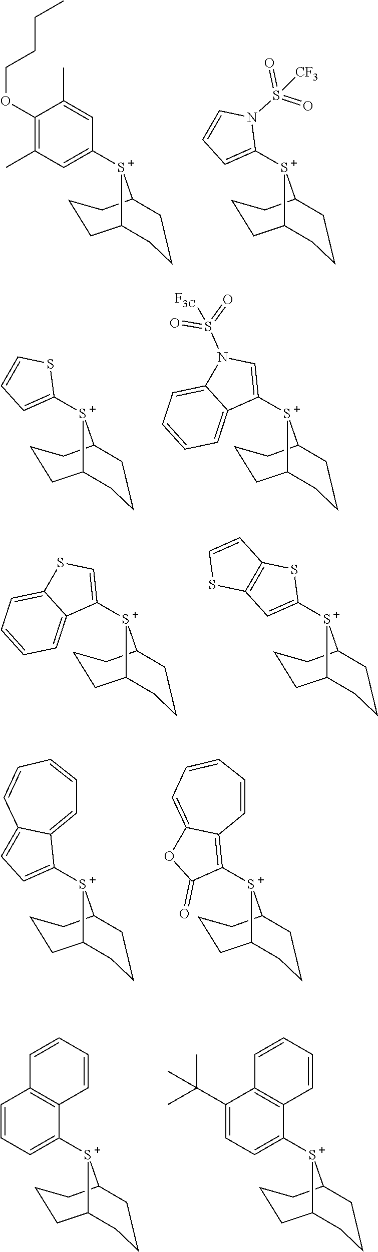

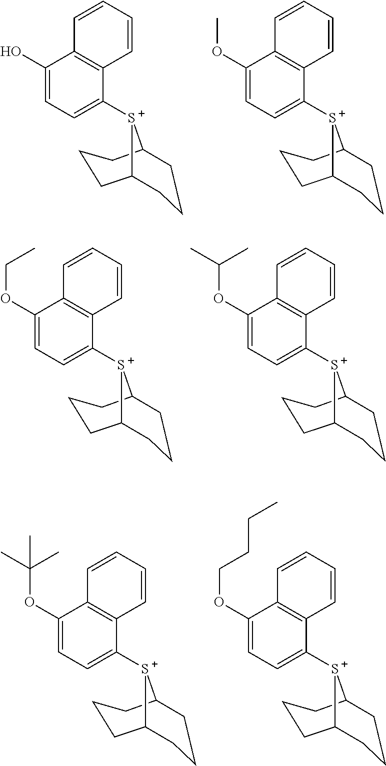 [SMILES: Oc1ccc([S+]2C3CCCC2CCC3)c2ccccc12 ; COc1ccc([S+]2C3CCCC2CCC3)c2ccccc12 ; CCOc1ccc([S+]2C3CCCC2CCC3)c2ccccc12 ; CC(C)Oc1ccc([S+]2C3CCCC2CCC3)c2ccccc12 ; CC(C)(C)Oc1ccc([S+]2C3CCCC2CCC3)c2ccccc12 ; CCCCOc1ccc([S+]2C3CCCC2CCC3)c2ccccc12]

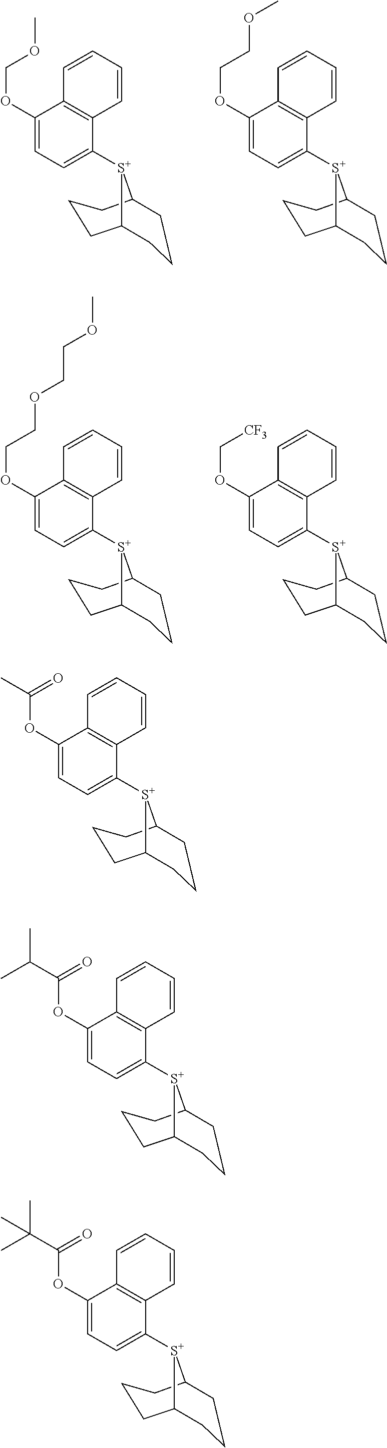

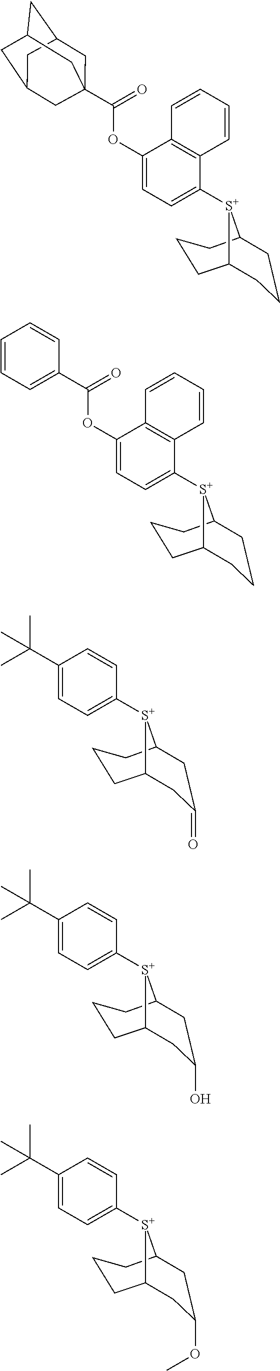 [SMILES: O=C(Oc1ccc([S+]2C3CCCC2CCC3)c2ccccc12)C12CC3CC(CC(C3)C1)C2 ; O=C(Oc1ccc([S+]2C3CCCC2CCC3)c2ccccc12)c1ccccc1 ; CC(C)(C)c1ccc([S+]2C3CCCC2CC(=O)C3)cc1 ; CC(C)(C)c1ccc([S+]2C3CCCC2CC(O)C3)cc1 ; COC1CC2CCCC(C1)[S+]2c1ccc(C(C)(C)C)cc1]

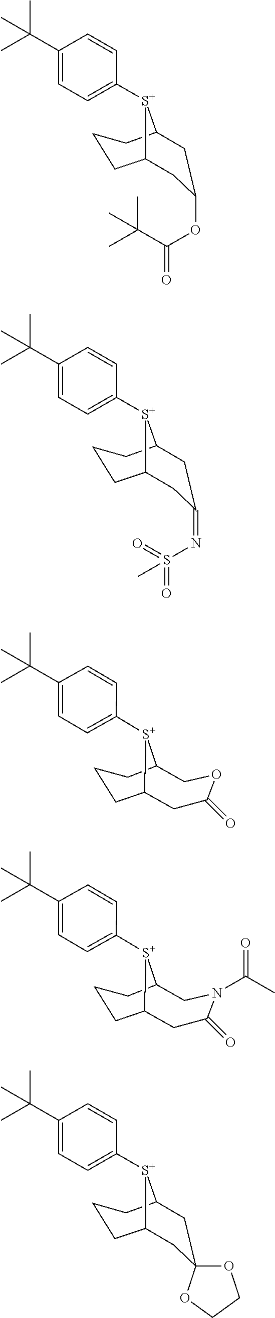

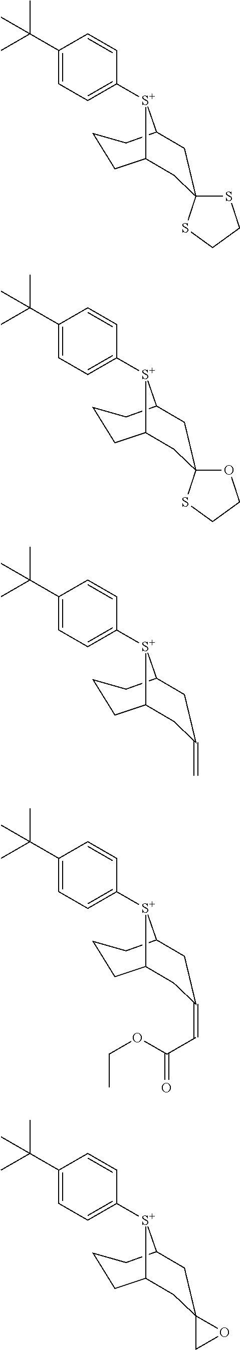

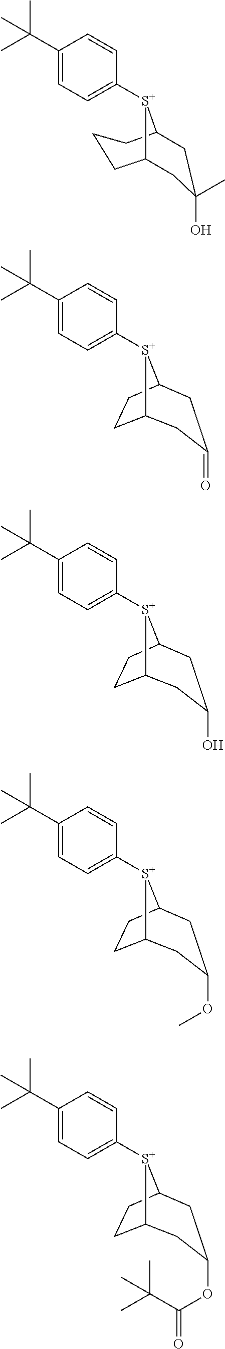

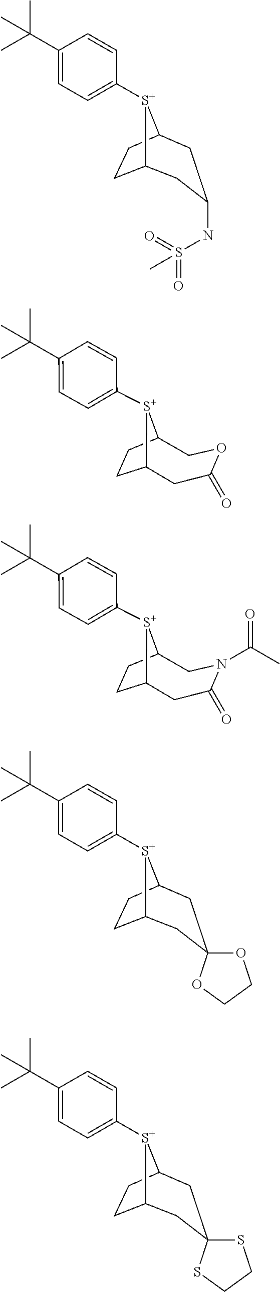

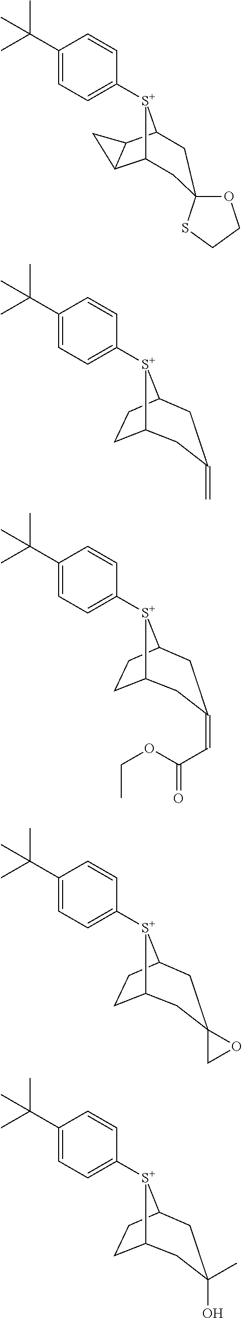

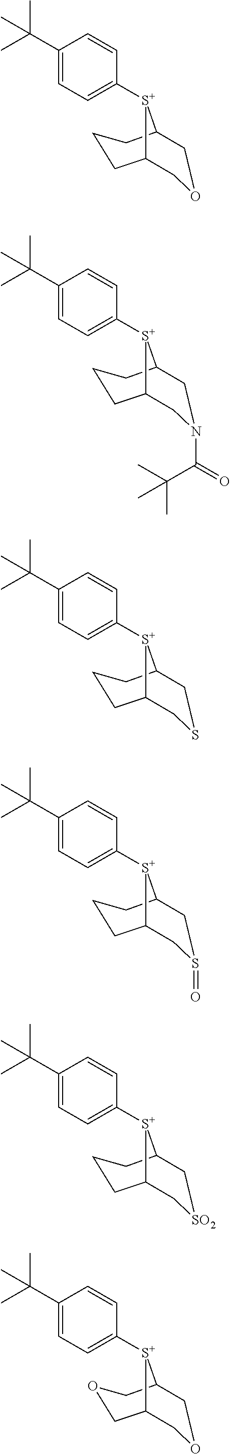 [SMILES: CC(C)(C)c1ccc([S+]2C3CCCC2COC3)cc1 ; CC(C)(C)C(=O)N1CC2CCCC(C1)[S+]2c1ccc(C(C)(C)C)cc1 ; CC(C)(C)c1ccc([S+]2C3CCCC2CSC3)cc1 ; CC(C)(C)c1ccc([S+]2C3CCCC2CS(=O)C3)cc1 ; CC(C)(C)c1ccc([S+]2C3CCCC2CS(=O)(=O)C3)cc1 ; CC(C)(C)c1ccc([S+]2C3COCC2COC3)cc1]

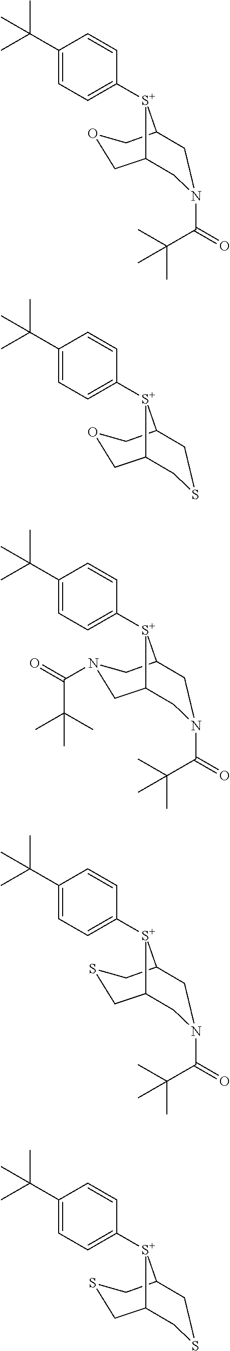 [SMILES: CC(C)(C)C(=O)N1CC2COCC(C1)[S+]2c1ccc(C(C)(C)C)cc1 ; CC(C)(C)c1ccc([S+]2C3COCC2CSC3)cc1 ; CC(C)(C)C(=O)N1CC2CN(C(=O)C(C)(C)C)CC(C1)[S+]2c1ccc(C(C)(C)C)cc1 ; CC(C)(C)C(=O)N1CC2CSCC(C1)[S+]2c1ccc(C(C)(C)C)cc1 ; CC(C)(C)c1ccc([S+]2C3CSCC2CSC3)cc1]

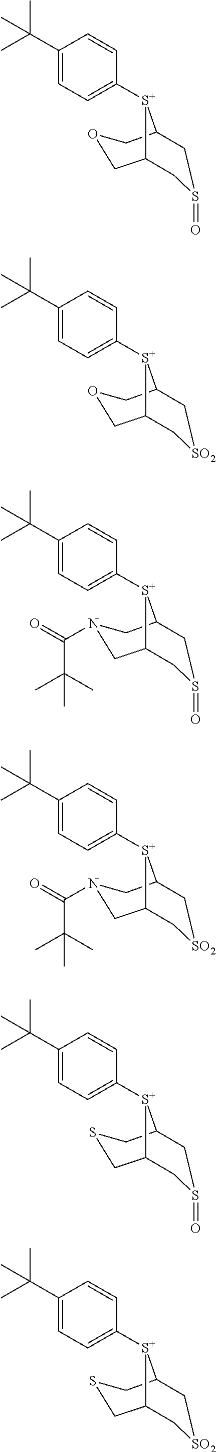 [SMILES: CC(C)(C)c1ccc([S+]2C3COCC2CS(=O)C3)cc1 ; CC(C)(C)c1ccc([S+]2C3COCC2CS(=O)(=O)C3)cc1 ; CC(C)(C)C(=O)N1CC2CS(=O)CC(C1)[S+]2c1ccc(C(C)(C)C)cc1 ; CC(C)(C)C(=O)N1CC2CS(=O)(=O)CC(C1)[S+]2c1ccc(C(C)(C)C)cc1 ; CC(C)(C)c1ccc([S+]2C3CSCC2CS(=O)C3)cc1 ; CC(C)(C)c1ccc([S+]2C3CSCC2CS(=O)(=O)C3)cc1]

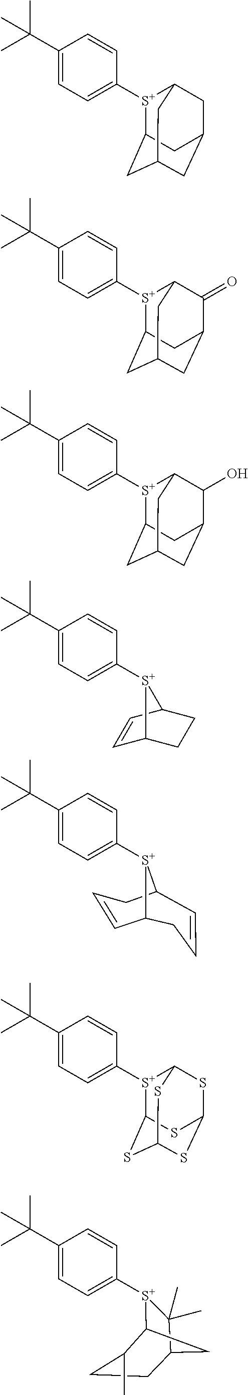

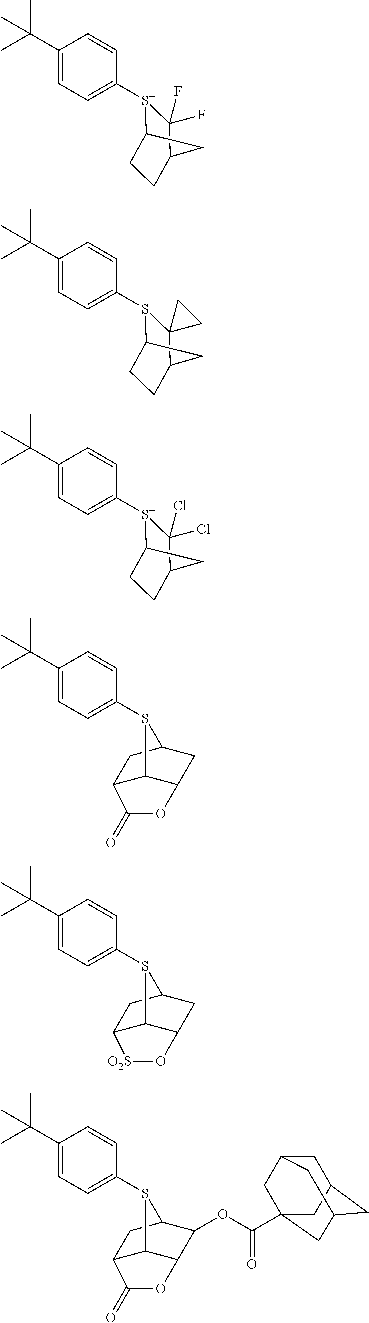 [SMILES: CC(C)(C)c1ccc([S+]2C3CCC(C3)C2(F)F)cc1 ; CC(C)(C)c1ccc([S+]2C3CCC(C3)C23CC3)cc1 ; CC(C)(C)c1ccc([S+]2C3CCC(C3)C2(Cl)Cl)cc1 ; CC(C)(C)c1ccc([S+]2C3CC4OC(=O)C(C3)C42)cc1 ; CC(C)(C)c1ccc([S+]2C3CC4OS(=O)(=O)C(C3)C42)cc1 ; CC(C)(C)c1ccc([S+]2C3CC4C(=O)OC(C3OC(=O)C35CC6CC(CC(C6)C3)C5)C42)cc1]

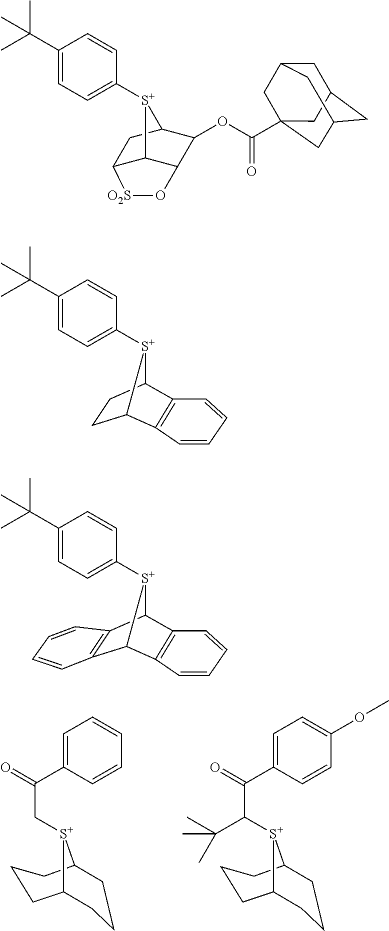 [SMILES: CC(C)(C)c1ccc([S+]2C3CC4C2C(OS4(=O)=O)C3OC(=O)C23CC4CC(CC(C4)C2)C3)cc1 ; CC(C)(C)c1ccc([S+]2C3CCC2c2ccccc23)cc1 ; CC(C)(C)c1ccc([S+]2C3c4ccccc4C2c2ccccc23)cc1 ; O=C(C[S+]1C2CCCC1CCC2)c1ccccc1 ; COc1ccc(C(=O)C([S+]2C3CCCC2CCC3)C(C)(C)C)cc1]

Examples of the iodonium cation having formula (cation-2) are shown below, but not limited thereto.

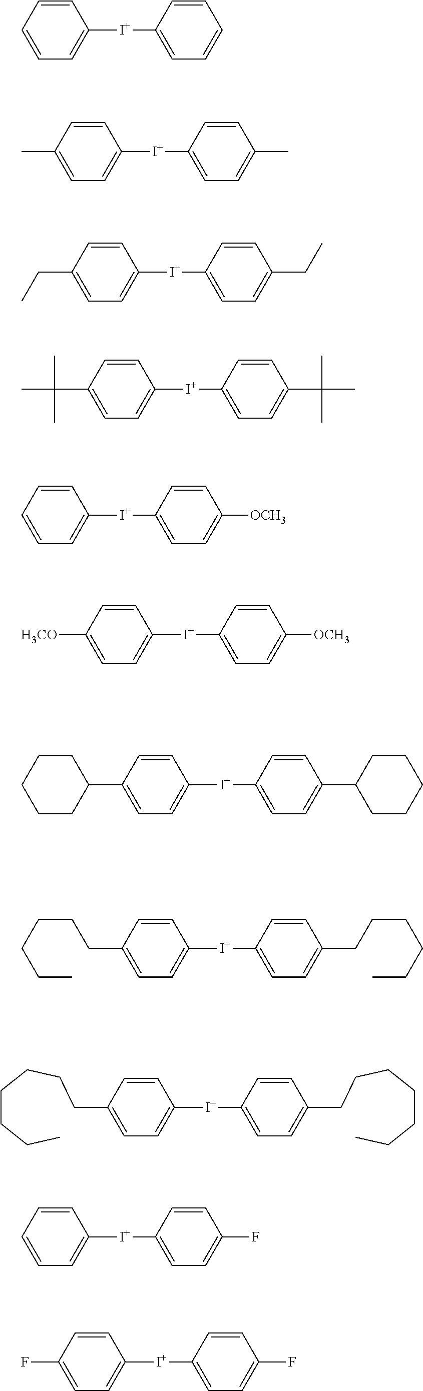

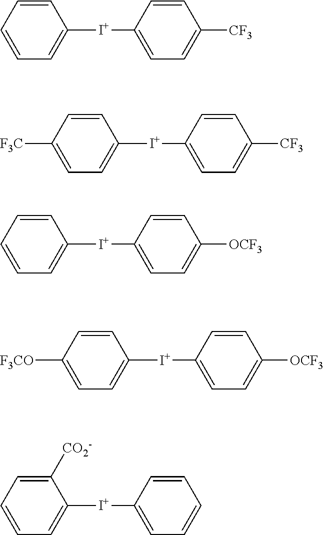

Examples of the ammonium cation having formula (cation-3) are shown below, but not limited thereto.

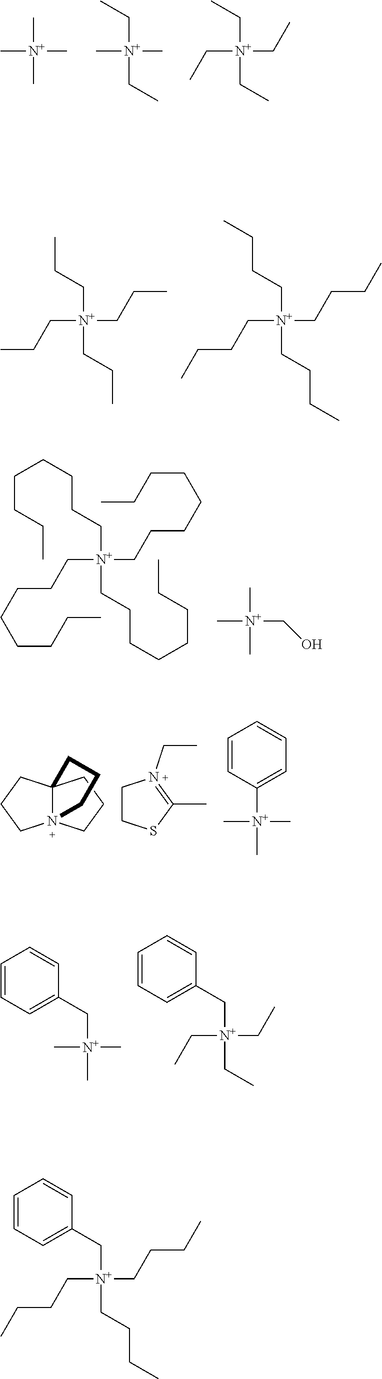

In formula (1), Xq⁻ is an anion. It is provided that an acid having Xq⁻ as conjugate base, i.e., XqH has a boiling point of lower than 165° C. and a molecular weight of up to 150. Examples of XqH include formic acid, acetic acid, propionic acid, butyric acid, trifluoroacetic acid, 3,3,3-trifluoropropionic acid, pivalic acid, and nitric acid. The preferred XqH has a boiling point of lower than 150° C. and a molecular weight of up to 120.

Specific structures of the onium salt include arbitrary combinations of the anion with the cation, both as exemplified above.

The onium salt is synthesized by any well-known methods. For example, the onium salt is synthesized by mixing a desired cation intermediate with a desired anion intermediate, and allowing reaction to run in a two-layer system of organic solvent and water as described in JP-A 2007-145797, paragraph [0158]. The onium salt may also be synthesized by mixing a silver salt of carboxylic acid with a cation intermediate as described in JP-A 2011-039502, paragraph [0183], or by mixing an onium salt of hydrogen carbonate with a desired acid as described in JP 6465026, paragraph [0124].

As described above, the onium salt functions as an acid diffusion controlling agent through a salt exchange with a strong acid (typically α-fluorinated sulfonic acid) generated from the PAG. Although such onium salt type quenchers are known in the past, the onium salt used herein is distinguished or characterized in that the generated weak acid has a boiling point of lower than 165° C. and a molecular weight of up to 150. Using the onium salt having the conjugate base of weak acid as the anion according to the invention, the lithography performance, especially maximum resolution is substantially improved. Although the reason is not well understood, the following mechanism is presumed.

Since the weak acid generated from the onium salt has a low boiling point, it is presumed that part of the generated acid volatilizes off. The tendency becomes stronger particularly in the EUV lithography involving exposure in vacuum. The generated weak acid penetrates into the developer and induces swelling of the resist film, eventually provoking pattern collapse. Now that the weak acid resulting from the inventive onium salt volatilizes off, swelling is reduced. That is, the maximum resolution is improved.

Since the anion has a low molecular weight, it is likely to flow with the developer. This minimizes the likelihood that a small amount of residue remains at the interface between exposed and unexposed regions after development. As a result, LWR is improved.

The inventive resist composition having such properties is effective particularly in the EUV lithography for forming line-and-space patterns with a pitch of 36 nm or less below which pattern collapse takes place outstandingly. In this region, precise control of acid diffusion, swell reduction and dissolution contrast enhancement are important. The onium salt type quencher generates an acid in the form of a non-sulfonic weak acid, which features low acid diffusion and low swelling as mentioned above. In the embodiment wherein the acid generator is a polymer-bound acid generator which is obtained by incorporating photoacid generating units in a polymer, more precise control of acid diffusion becomes possible.

In the resist composition, the onium salt (C) is preferably added in an amount of 0.1 to 40 parts, and more preferably 1 to 20 parts by weight per 80 parts by weight of the base polymer (A). As long as the amount of the onium salt is in the range, it satisfactorily functions as a quencher, eliminating the risks of sensitivity lowering, formation of foreign particles due to shortage of solubility, and performance degradation. The onium salt may be used alone or in admixture.

### (D) Photoacid Generator

The resist composition may comprise (D) a photoacid generator. The PAG is not particularly limited as long as it is capable of generating an acid upon exposure to high-energy radiation. The preferred PAG is a salt having the formula (2).

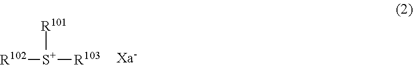

In formula (2), R¹⁰¹, R¹⁰² and R¹⁰³ are each independently a C₁-C₂₀ hydrocarbyl group which may contain a heteroatom. R¹⁰¹ and R¹⁰² may bond together to form a ring with the sulfur atom to which they are attached. Examples of the hydrocarbyl group are as exemplified above for the hydrocarbyl groups R⁴¹ to R⁴³ in formula (cation-1). Examples of the cation in the sulfonium salt having formula (2) are as exemplified above for the sulfonium cation having formula (cation-1).

In formula (2), Xa⁻ is a non-nucleophilic counter anion, which is typically selected from the formulae (2A) to (2D).

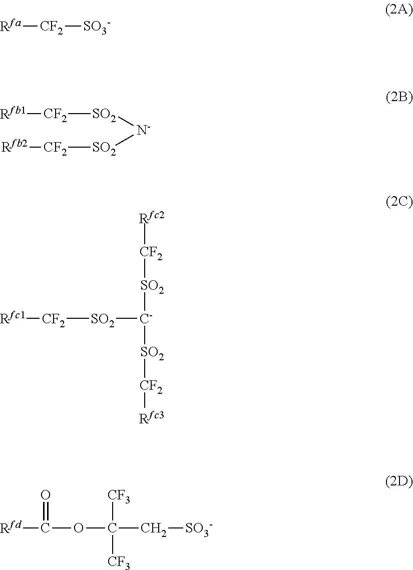

In formula (2A), R^{f} is fluorine or a C₁-C₄₀ hydrocarbyl group which may contain a heteroatom. The hydrocarbyl group may be saturated or unsaturated and straight, branched or cyclic. Examples thereof are as will be exemplified later for the hydrocarbyl group R^{fa1} in formula (2A′).

Of the anions having formula (2A), anions having the formula (2A′) are preferred.

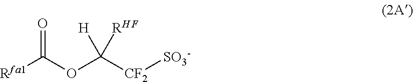

In formula (2A′), R¹ is hydrogen or trifluoromethyl, preferably trifluoromethyl.

R^{fa1} is a C₁-C₃₉ hydrocarbyl group which may contain a heteroatom. Suitable heteroatoms include oxygen, nitrogen, sulfur, and halogen atoms, with oxygen being preferred. Of the hydrocarbyl groups, those of 6 to 30 carbon atoms are preferred because a high resolution is available in fine pattern formation. The C₁-C₃₈ hydrocarbyl group may be saturated or unsaturated and straight, branched or cyclic. Examples thereof include C₁-C₃₈ alkyl groups such as methyl, ethyl, n-propyl, isopropyl, n-butyl, isobutyl, sec-butyl, tert-butyl, pentyl, neopentyl, hexyl, heptyl, octyl, 2-ethylhexyl, nonyl, decyl, undecyl, dodecyl, tridecyl, pentadecyl, heptadecyl, and icosyl; C₃-C₃₈ cyclic saturated hydrocarbyl groups such as cyclopentyl, cyclohexyl, 1-adamantyl, 2-adamantyl, 1-adamantylmethyl, norbornyl, norbornylmethyl, tricyclodecanyl, tetracyclododecanyl, tetracyclododecanylmethyl, and dicyclohexylmethyl; C₂-C₃₈ unsaturated aliphatic hydrocarbyl groups such as allyl and 3-cyclohexenyl; C₆-C₃₈ aryl groups such as phenyl, 1-naphthyl and 2-naphthyl; C₇-C₃M aralkyl groups such as benzyl and diphenylmethyl, and combinations thereof.

In the foregoing hydrocarbyl groups, some or all of the hydrogen atoms may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy, fluorine, chlorine, bromine, iodine, cyano, carbonyl, ether bond, ester bond, sulfonic ester bond, carbonate bond, lactone ring, sultone ring, carboxylic anhydride (—C(═O)—O—C(═O)—) or haloalkyl moiety. Examples of the heteroatom-containing hydrocarbyl group include tetrahydrofuryl, methoxymethyl, ethoxymethyl, methylthiomethyl, acetamidomethyl, trifluoroethyl, (2-methoxyethoxy)methyl, acetoxymethyl, 2-carboxy-1-cyclohexyl, 2-oxopropyl, 4-oxo-1-adamantyl, 5-hydroxy-1-adamantyl, 5-tert-butylcarbonyloxy-1-adamantyl, 4-oxatricyclo[4.2.1.0^{3,7}]nonan-5-on-2-yl, and 3-oxocyclohexyl.

With respect to the synthesis of the sulfonium salt having an anion of formula (2A′), reference may be made to JP-A 2007-145797, JP-A 2008-106045, JP-A 2009-007327, and JP-A 2009-258695. Also useful are the sulfonium salts described in JP-A 2010-215608, JP-A 2012-041320, JP-A 2012-106986, and JP-A 2012-153644.

Examples of the anion having formula (2A) are as exemplified above for the anions having formulae (c1-1) and (c1-2).

In formula (2B), R^{fb1} and R^{fb2} are each independently fluorine or a C₁-C₄₀ hydrocarbyl group which may contain a heteroatom. The hydrocarbyl group may be saturated or unsaturated and straight, branched or cyclic. Examples thereof are as exemplified above for R^{fa1} in formula (2A′). Preferably R^{fb1} and R^{fb2} are fluorine or C₁-C₄ straight fluorinated hydrocarbyl groups. Also, R^{fb1} and R^{fb2} may bond together to form a ring with the linkage: —CF₂—SO₂—N⁻—SO₂—CF₂— to which they are attached. It is preferred that a combination of R^{fb1} and R^{fb2} be a fluorinated ethylene or fluorinated propylene group.

In formula (2C), R^{fc1}, R^{fc2} and R^{fc3} are each independently fluorine or a C₁-C₄₀ hydrocarbyl group which may contain a heteroatom. The hydrocarbyl group may be saturated or unsaturated and straight, branched or cyclic. Examples thereof are as exemplified for the hydrocarbyl group R^{fa1} in formula (2A′). Preferably R^{fc1}, R^{fc2} and R^{fc3} are fluorine or C₁-C₄ straight fluorinated saturated hydrocarbyl groups. Also, R^{fc1} and R^{fc2} may bond together to form a ring with the linkage: —CF₂—SO₂—C⁻—SO₂—CF₂— to which they are attached. It is preferred that a combination of R^{fc1} and R^{fc2} be a fluorinated ethylene or fluorinated propylene group.

In formula (2D), R is a C₁-C₄₀ hydrocarbyl group which may contain a heteroatom. The hydrocarbyl group may be saturated or unsaturated and straight, branched or cyclic. Examples thereof are as exemplified above for the hydrocarbyl group R¹ in formula (2A′).

With respect to the synthesis of the sulfonium salt having an anion of formula (2D), reference may be made to JP-A 2010-215608 and JP-A 2014-133723.

Examples of the anion having formula (2D) are shown below, but not limited thereto.

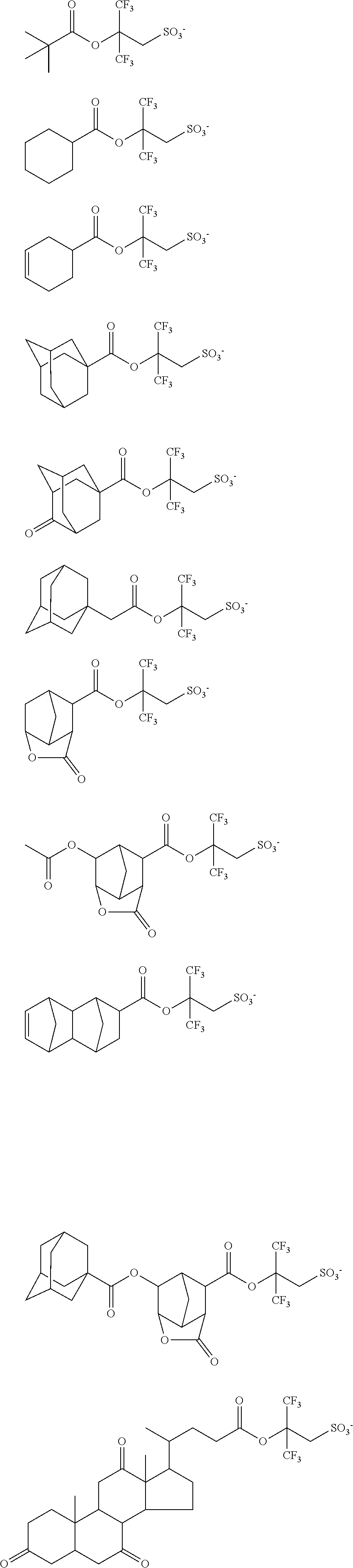

Another example of the non-nucleophilic counter anion is an anion having an iodine or bromine-substituted aromatic ring. The preferred anion has the formula (2E).

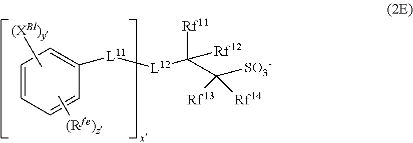

In formula (2E), x′ is an integer of 1 to 3, y′ is an integer of 1 to 5, z′ is an integer of 0 to 3, and y′+z′ is from 1 to 5. Preferably, y′ is an integer of 1 to 3, more preferably 2 or 3, and z′ is an integer of 0 to 2.

In formula (2E), X^{BI} is iodine or bromine. When x′ and/or y′ is 2 or more, a plurality of X^{BI} may be the same or different.

In formula (2E), L¹¹ is a single bond, ether bond, ester bond, or a C₁-C₆ saturated hydrocarbylene group which may contain an ether bond or ester bond. The saturated hydrocarbylene group may be straight, branched or cyclic.

In formula (2E), L¹² is a single bond or a C₁-C₂₀ divalent linking group when x′=1, and a C₁-C₂₀ (x′+1)-valent linking group which may contain oxygen, sulfur or nitrogen when x′=2 or 3.

In formula (2E), R^{fe} is hydroxy, carboxy, fluorine, chlorine, bromine, amino, or a C₁-C₂₀ hydrocarbyl group, C₁-C₂₀ hydrocarbyloxy group, C₂-C₂₀ hydrocarbylcarbonyl group, C₂-C₂₀ hydrocarbyloxycarbonyl group, C₂-C₂₀ hydrocarbylcarbonyloxy group, or C₁-C₂₀ hydrocarbylsulfonyloxy group, which may contain fluorine, chlorine, bromine, hydroxy, amino or ether bond, or —N(R^{feA})(R^{feB}), —N(R^{feC})—C(═O)—R^{feD} or —N(R^{feC})—C(═O)—O—R^{feD}. R^{feA} and R^{feB} are each independently hydrogen or a C₁-C₆ saturated hydrocarbyl group. R^{feC} is hydrogen or a C₁-C₆ saturated hydrocarbyl group which may contain halogen, hydroxy, C₁-C₆ saturated hydrocarbyloxy. C₂-C₆ saturated hydrocarbylcarbonyl or C₂-C₆ saturated hydrocarbylcarbonyloxy moiety. R^{feD} is a C₁-C₁₆ aliphatic hydrocarbyl group, C₆-C₁₂ aryl group or C₇-C₁₅ aralkyl group, which may contain halogen, hydroxy. C₁-C₆ saturated hydrocarbyloxy, C₂-C₆ saturated hydrocarbylcarbonyl or C₂-C₆ saturated hydrocarbylcarbonyloxy moiety. The aliphatic hydrocarbyl group may be saturated or unsaturated and straight, branched or cyclic. The hydrocarbyl, hydrocarbyloxy, hydrocarbylcarbonyl, hydrocarbyloxycarbonyl, hydrocarbylcarbonyloxy and hydrocarbylsulfonyloxy groups may be straight, branched or cyclic. A plurality of groups R^{fe} may be the same or different when x′ and/or z′ is 2 or more. Of these, R^{fe} is preferably hydroxy, —N(R^{feC})—C(═O)—R^{feD}, —N(R^{feC})—C(═O)—O—R_{feD}, fluorine, chlorine, bromine, methyl or methoxy.

In formula (2E), R^{f11} to R^{f14} are each independently hydrogen, fluorine or trifluoromethyl, at least one of R^{f11} to R^{f14} is fluorine or trifluoromethyl. R^{f11} and R^{f12}, taken together, may form a carbonyl group. Preferably, both R^{f13} and R^{f14} are fluorine.

Examples of the onium salt anion having formula (2E) are shown below, but not limited thereto. Herein X^{BI} is as defined above.

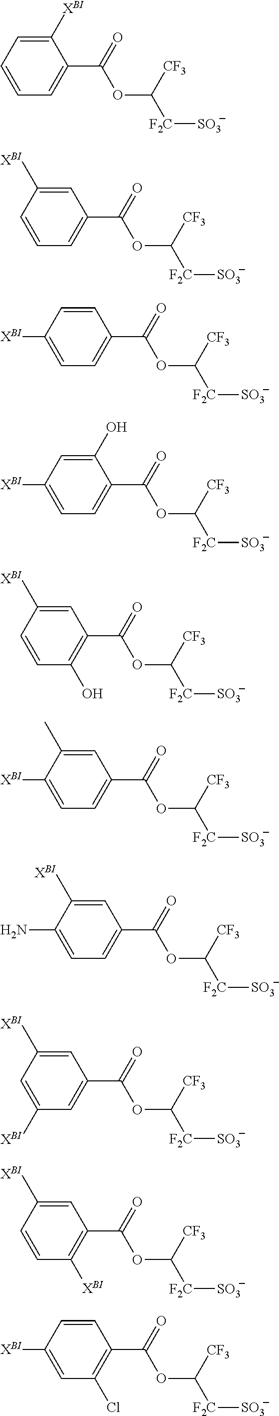

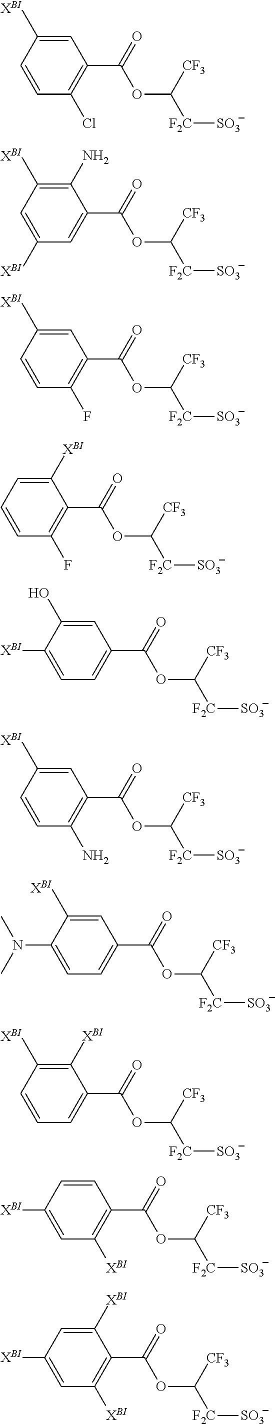

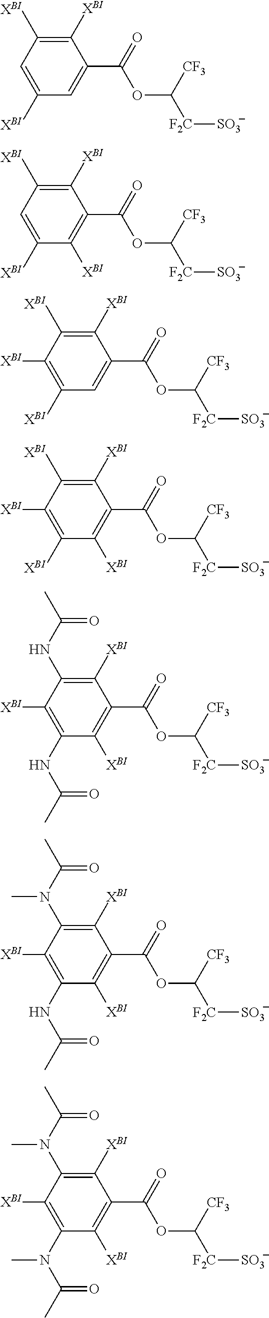

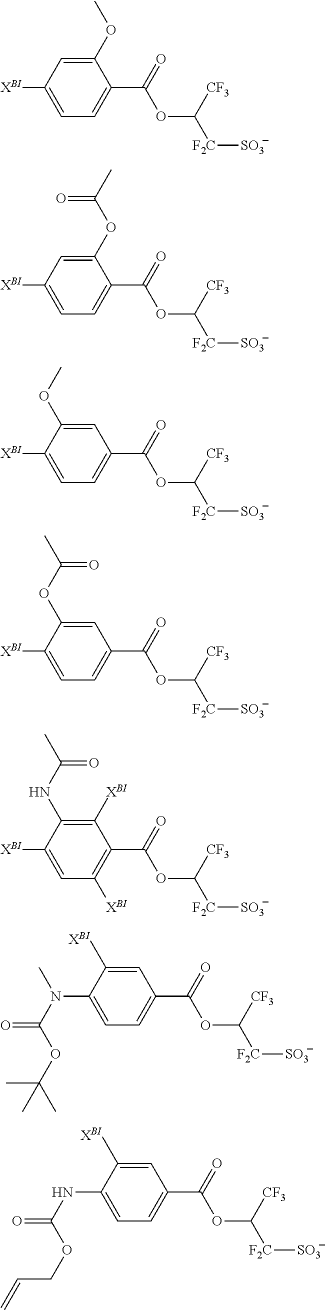

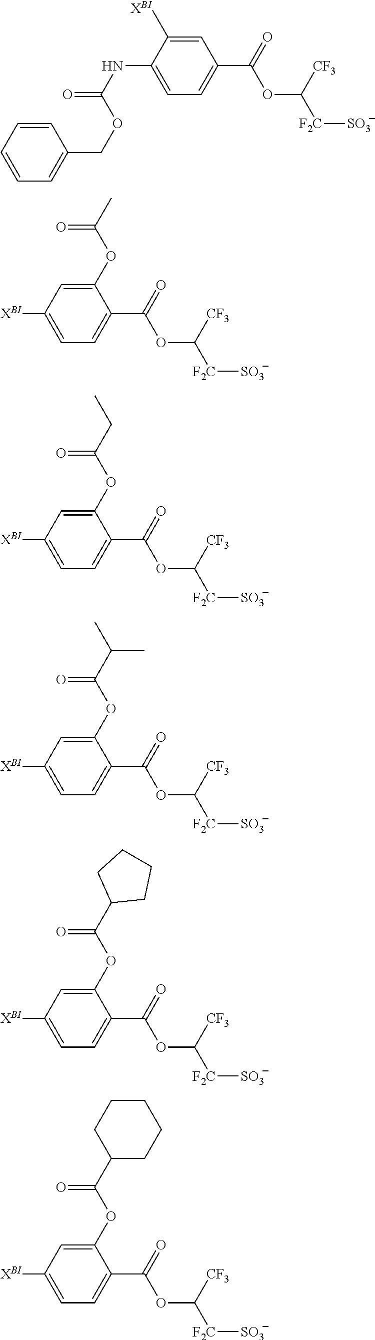

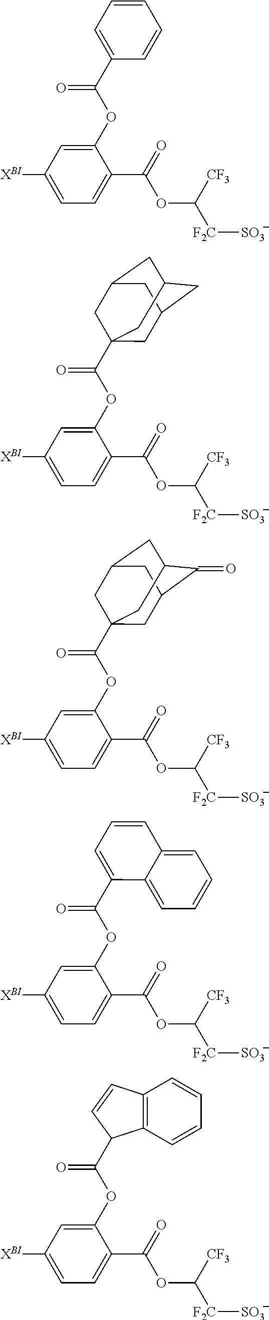

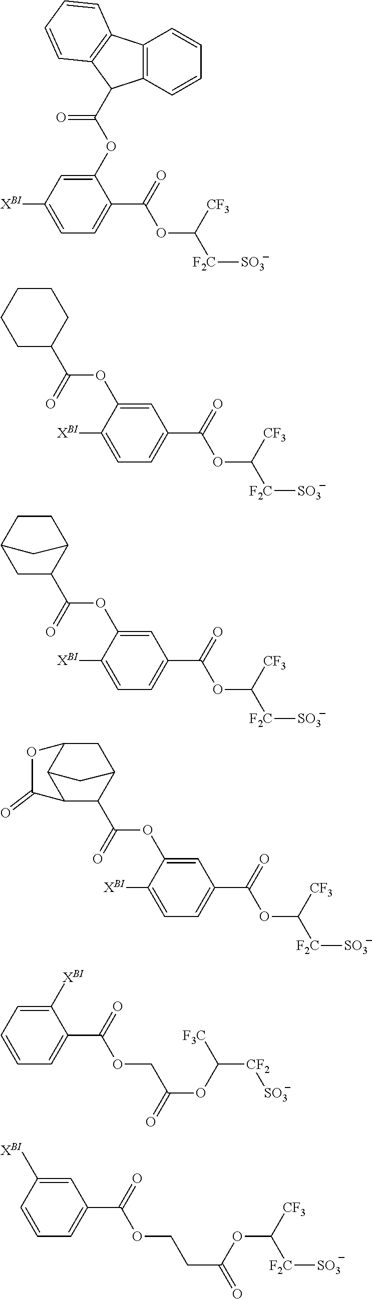

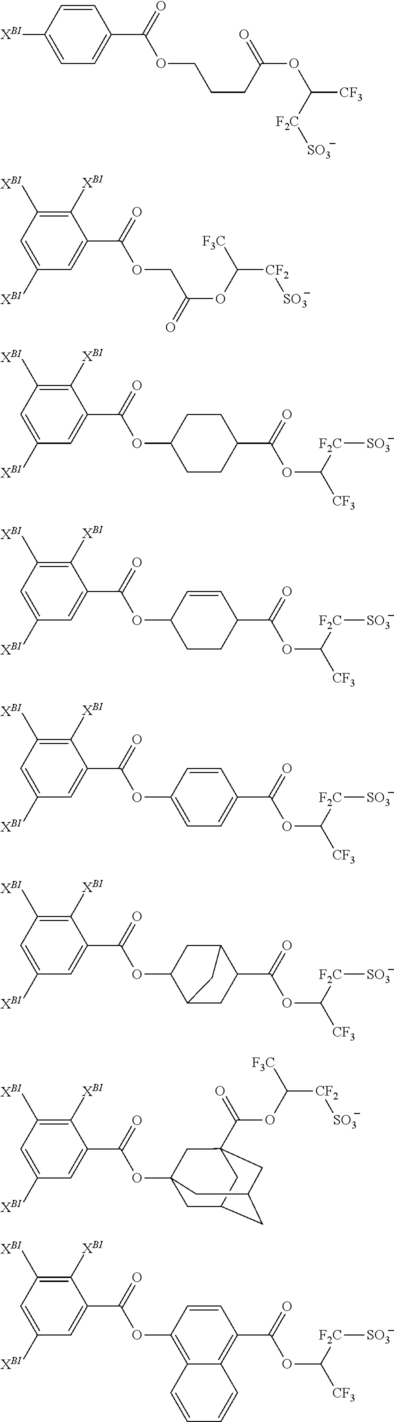

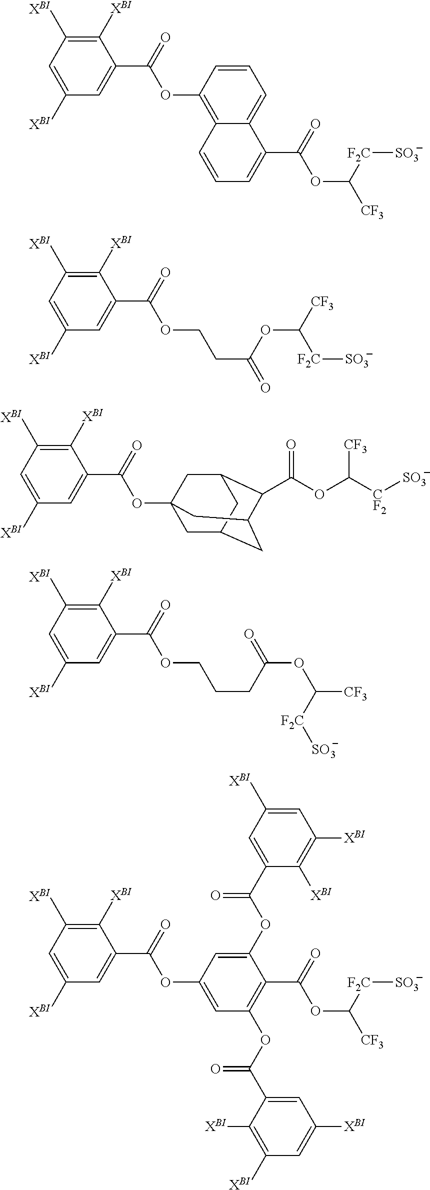

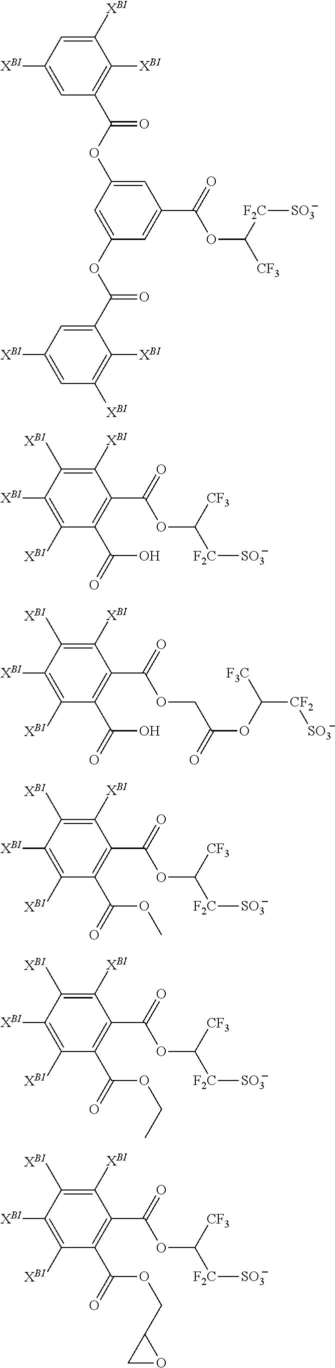

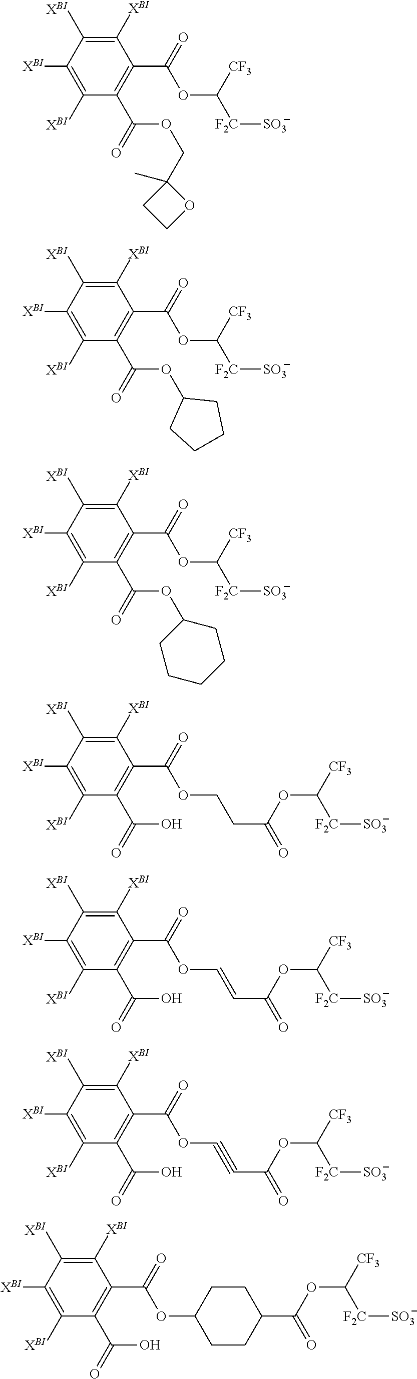

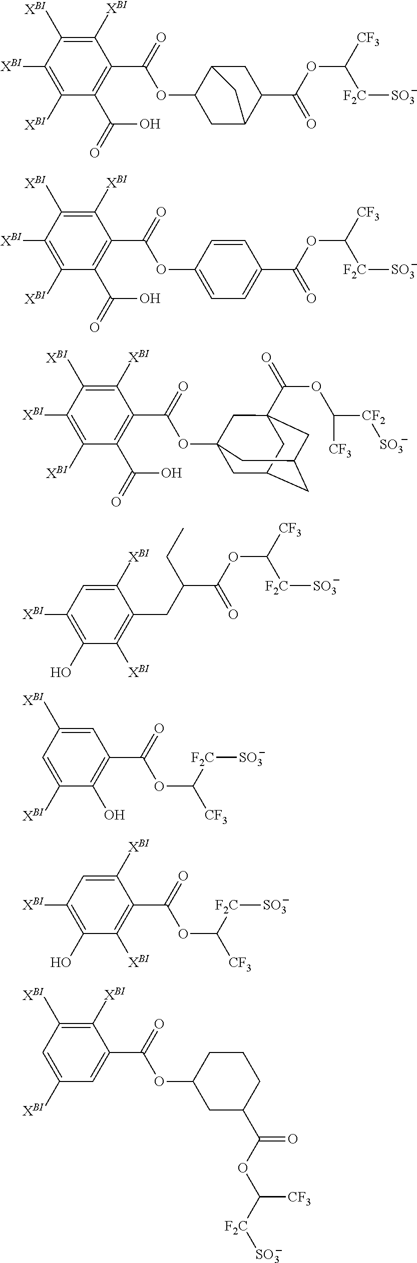

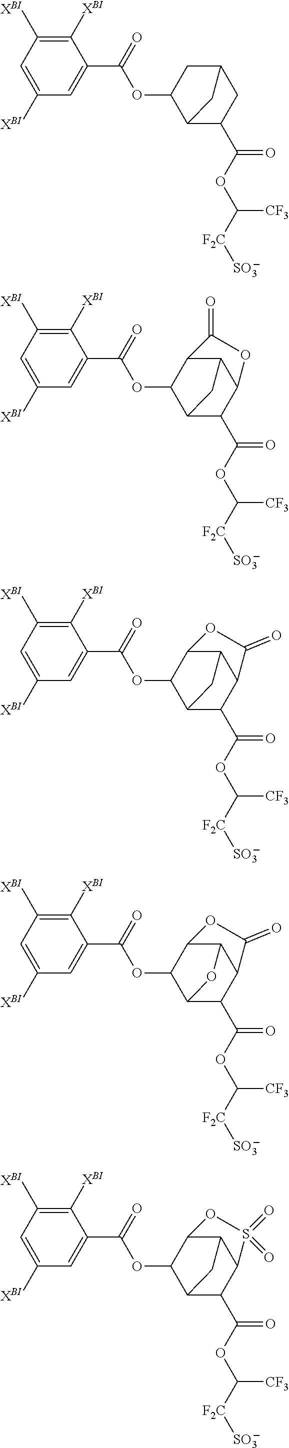

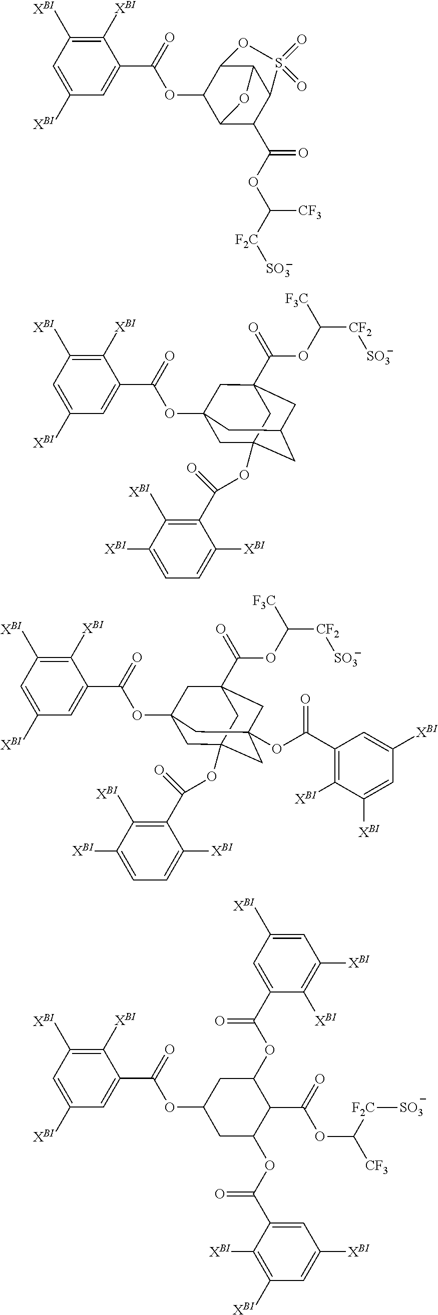

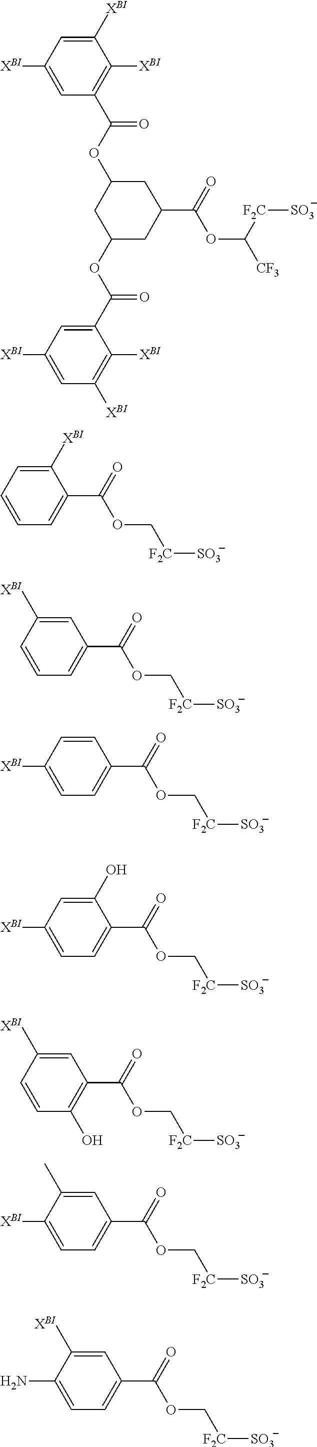

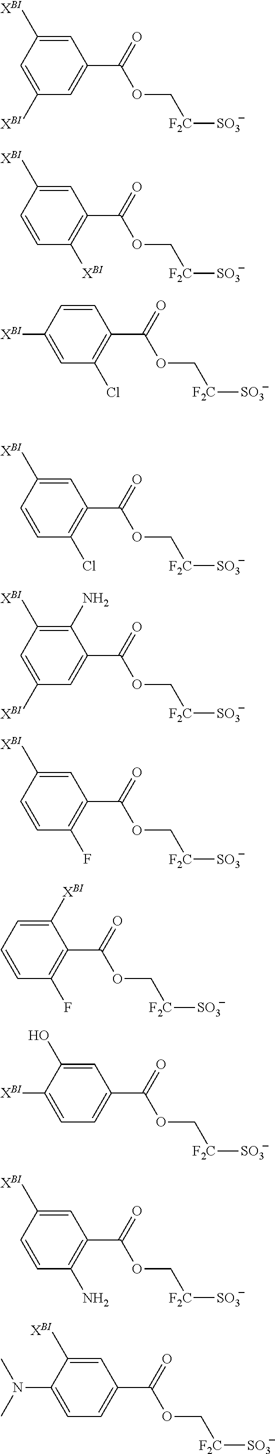

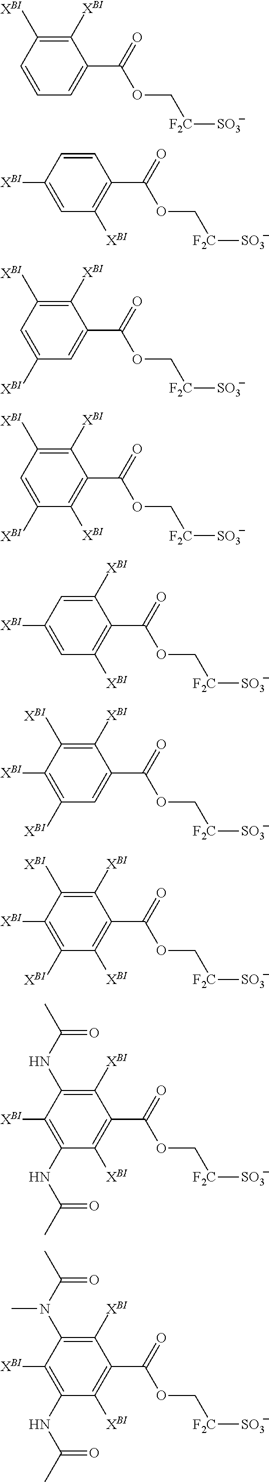

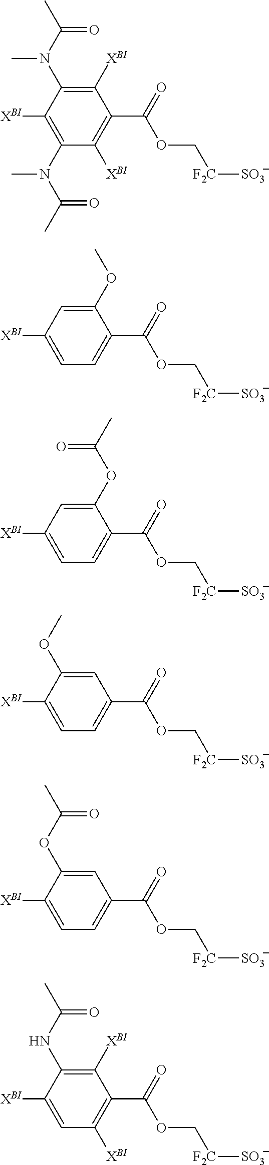

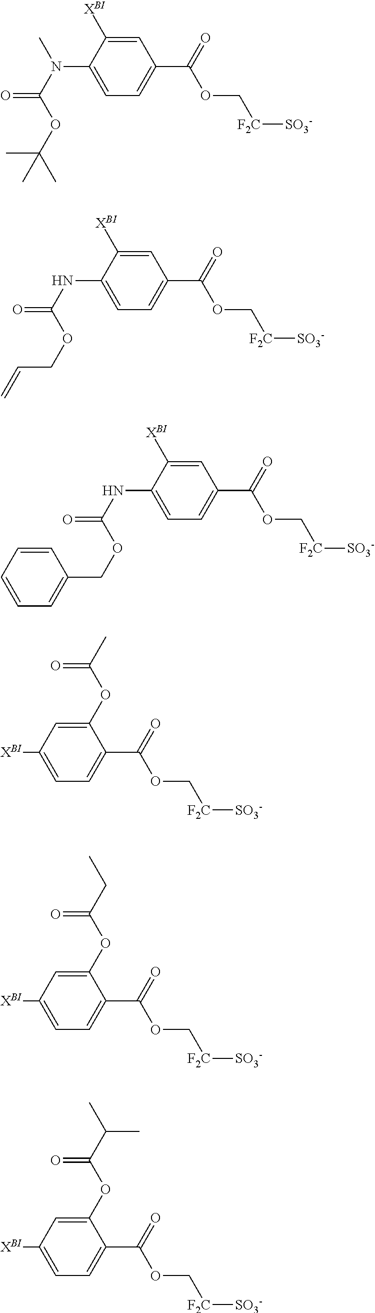

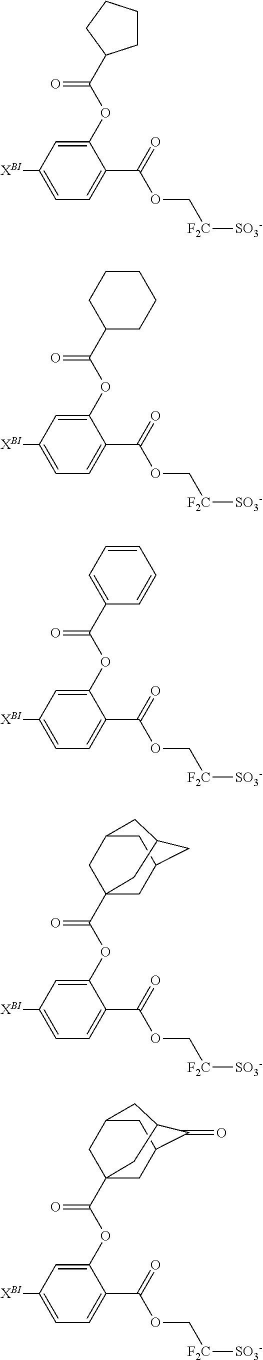

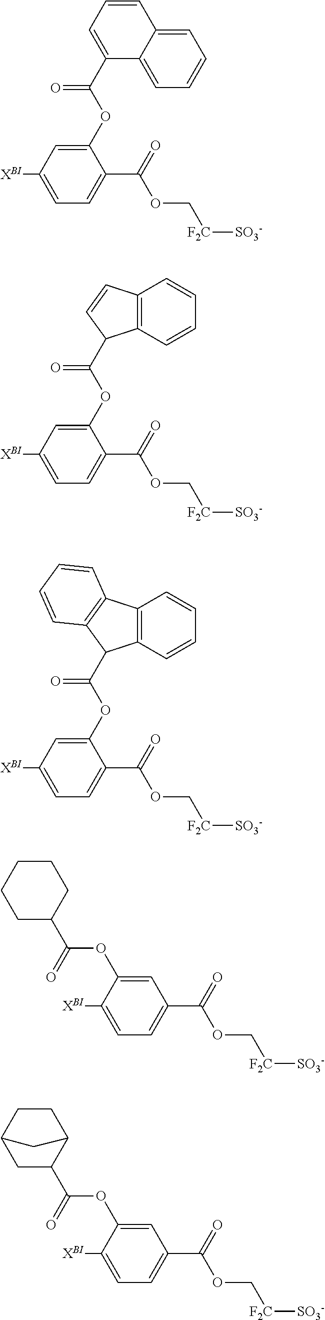

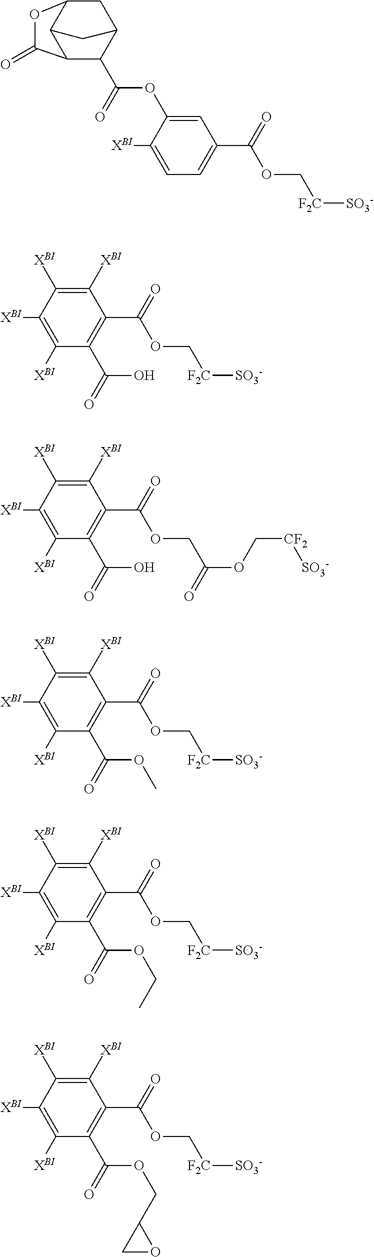

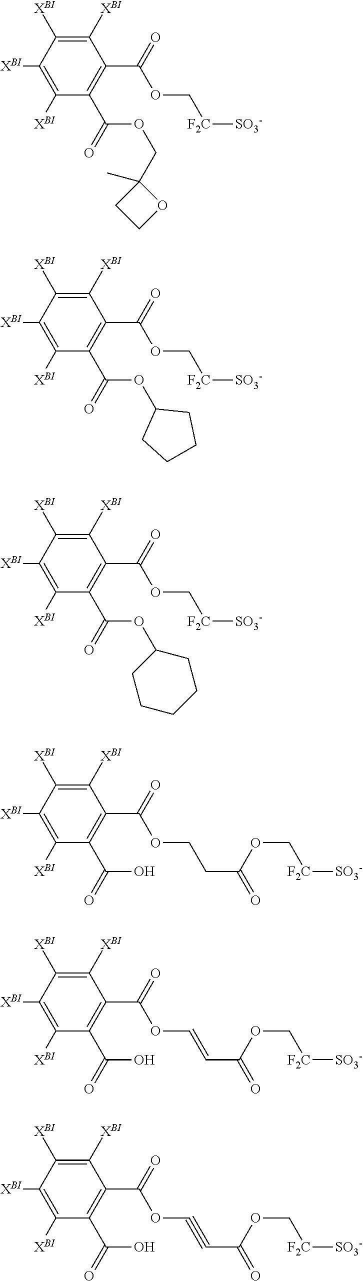

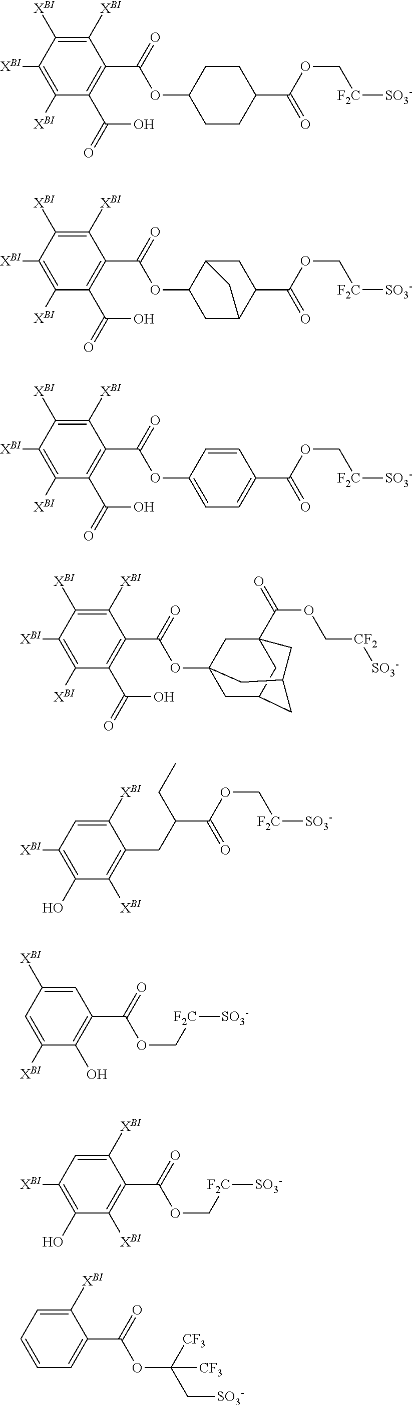

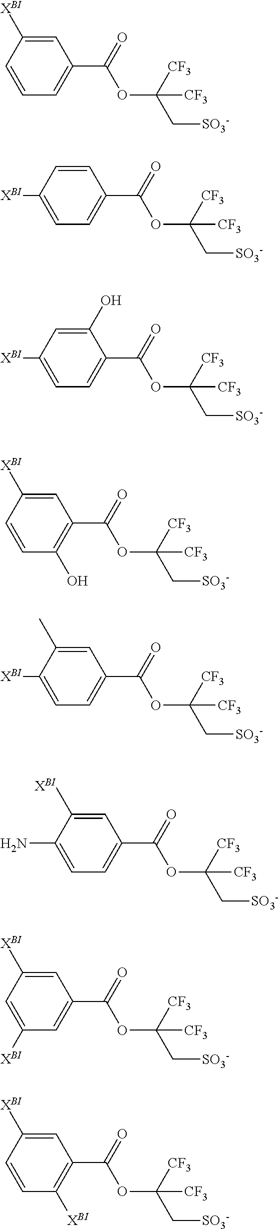

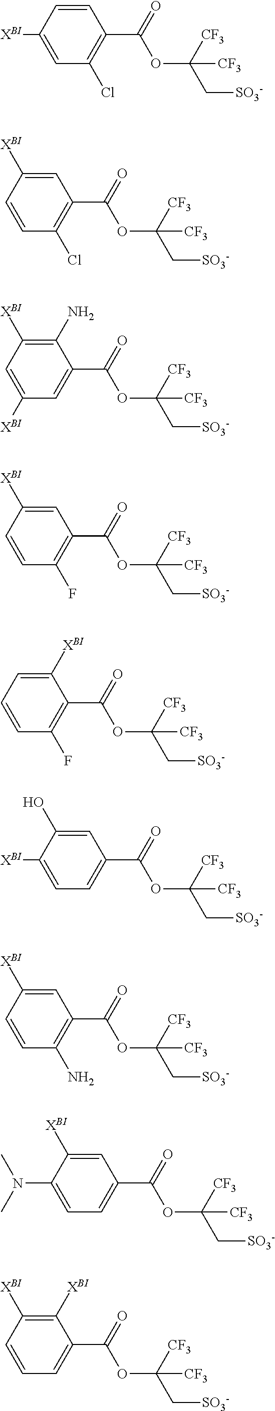

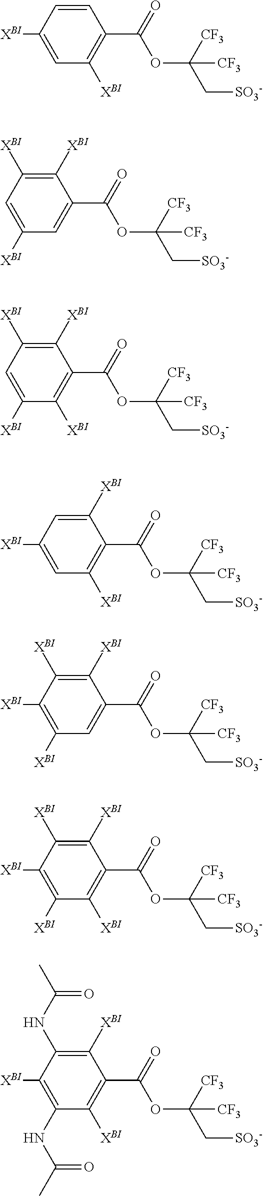

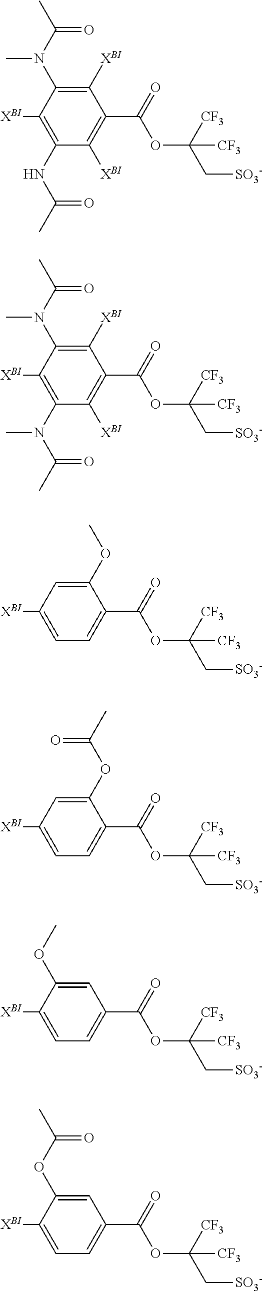

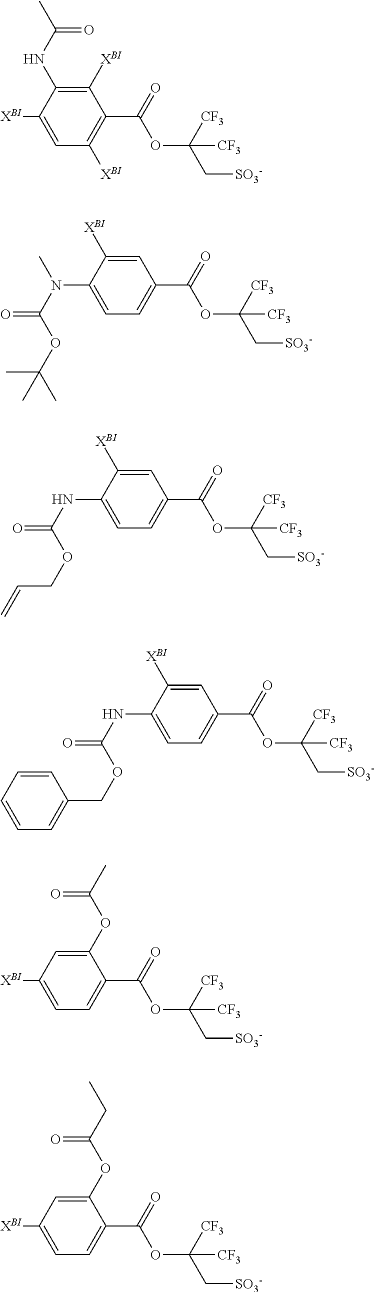

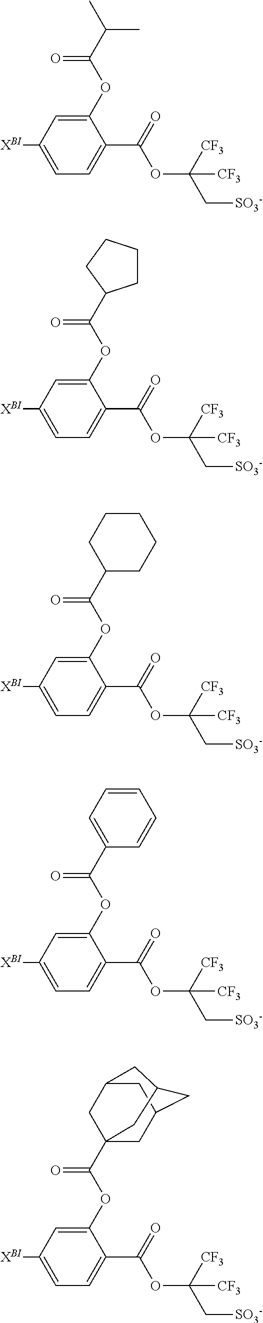

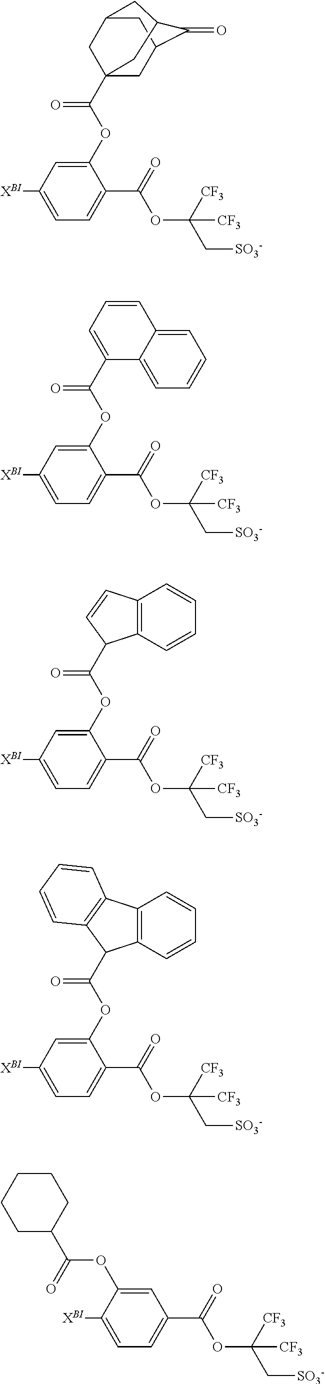

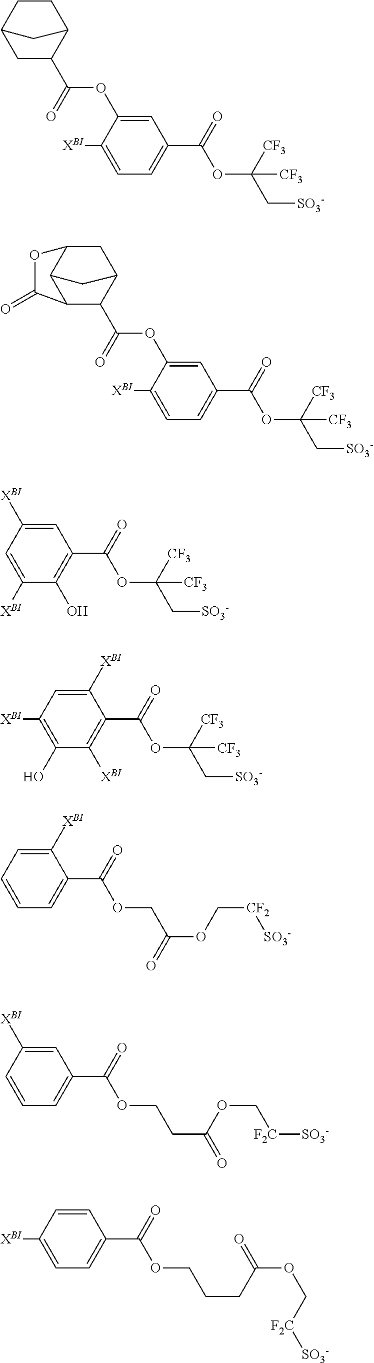

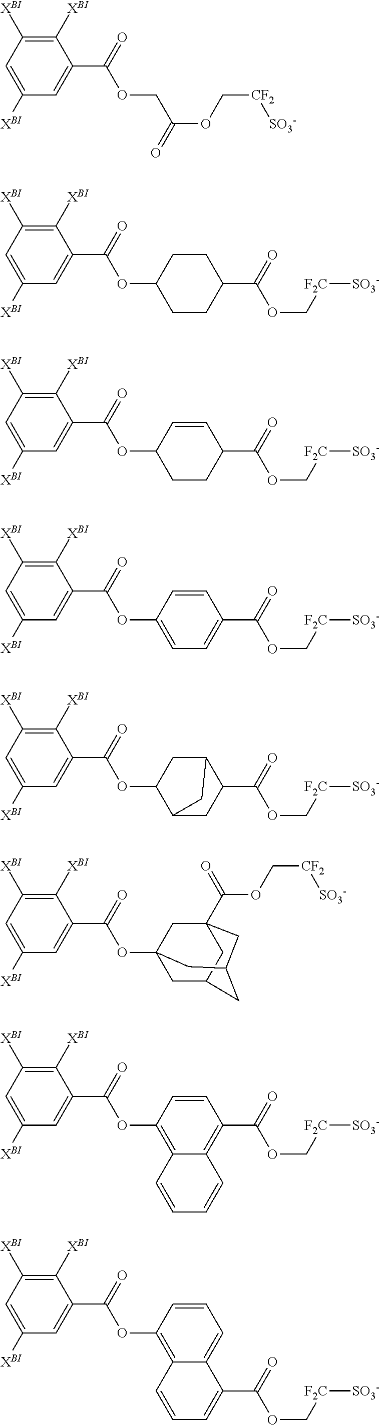

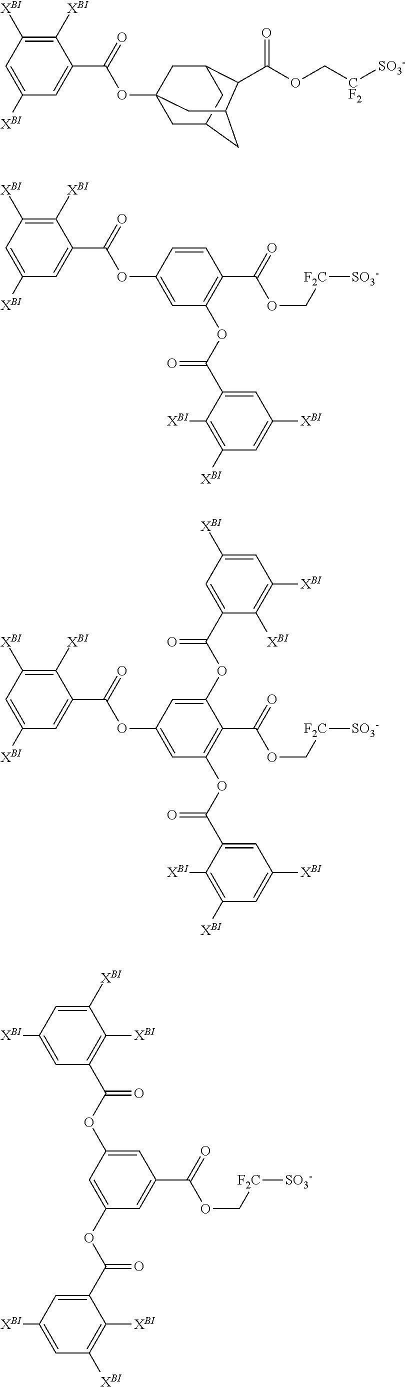

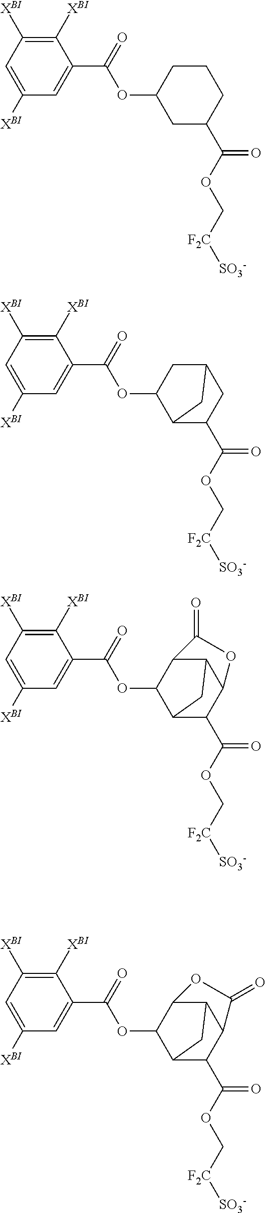

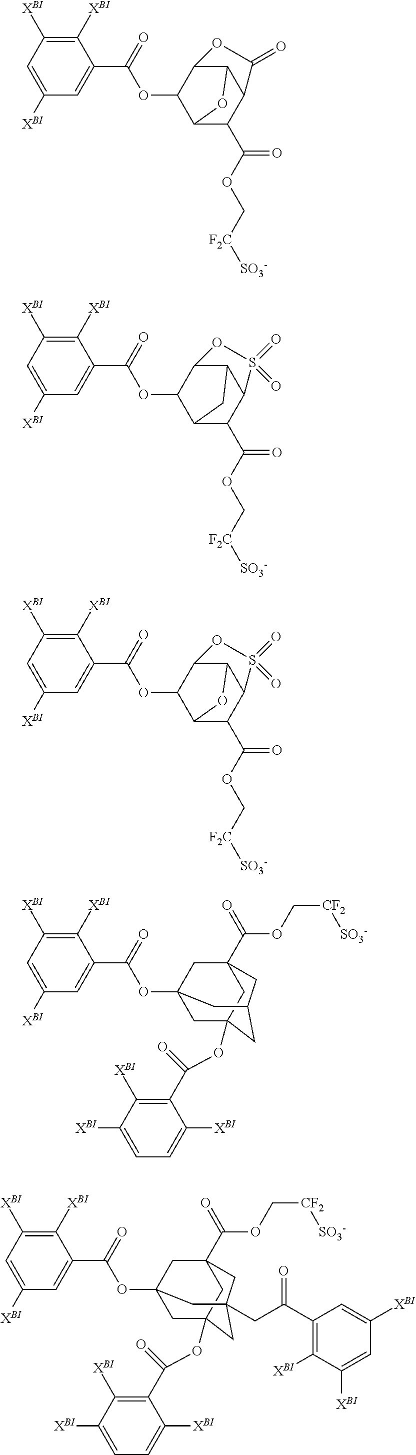

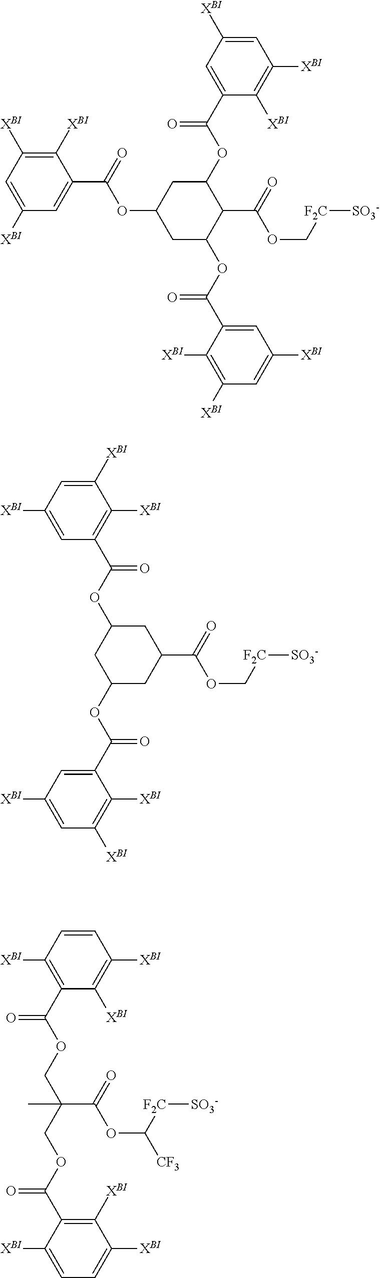

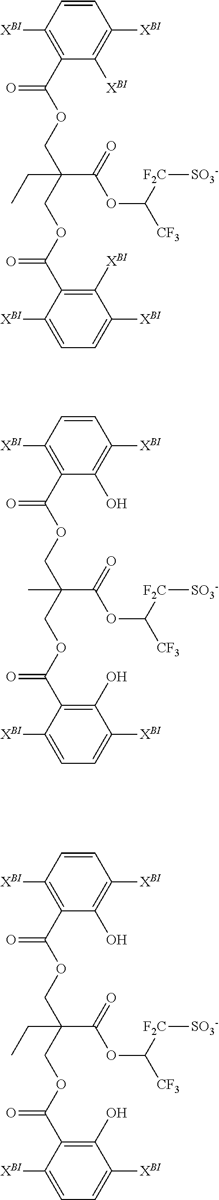

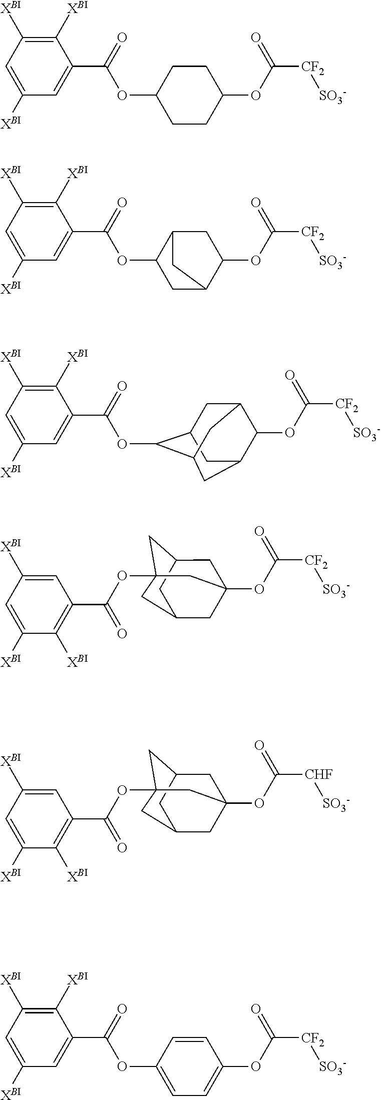

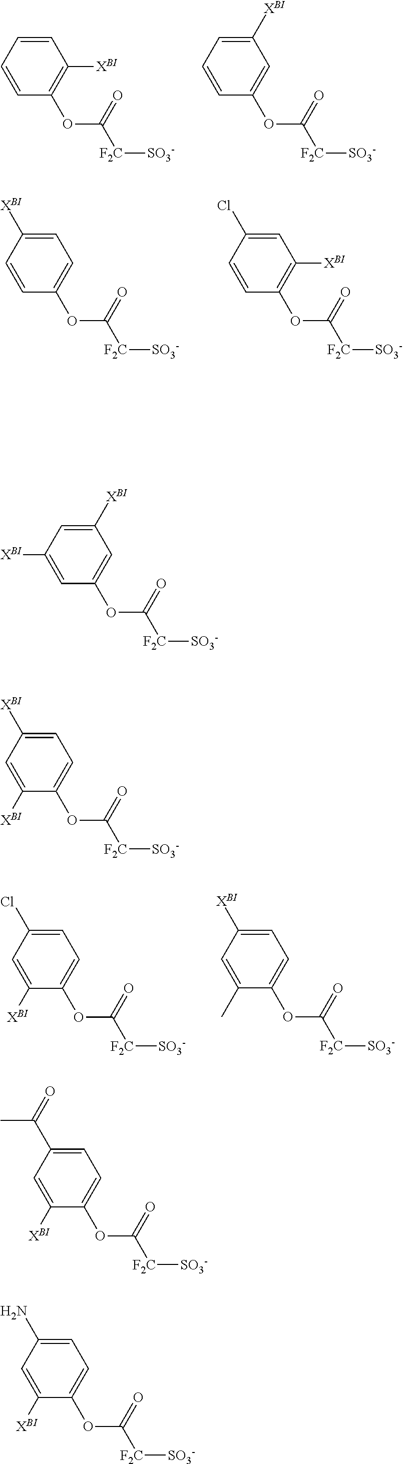

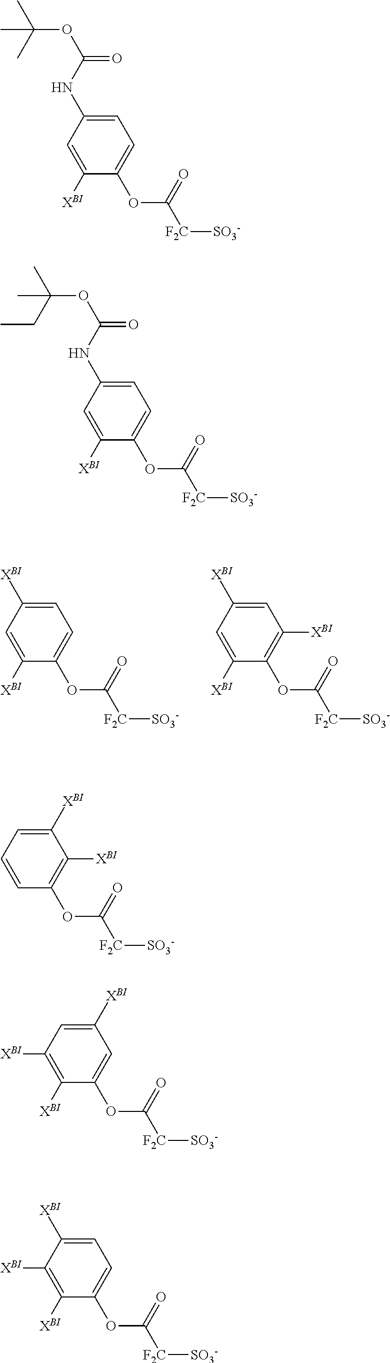

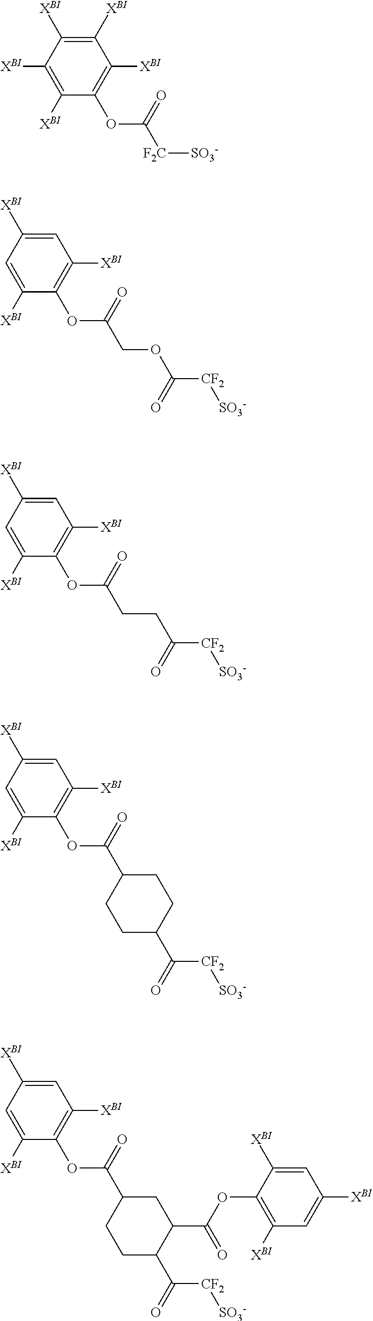

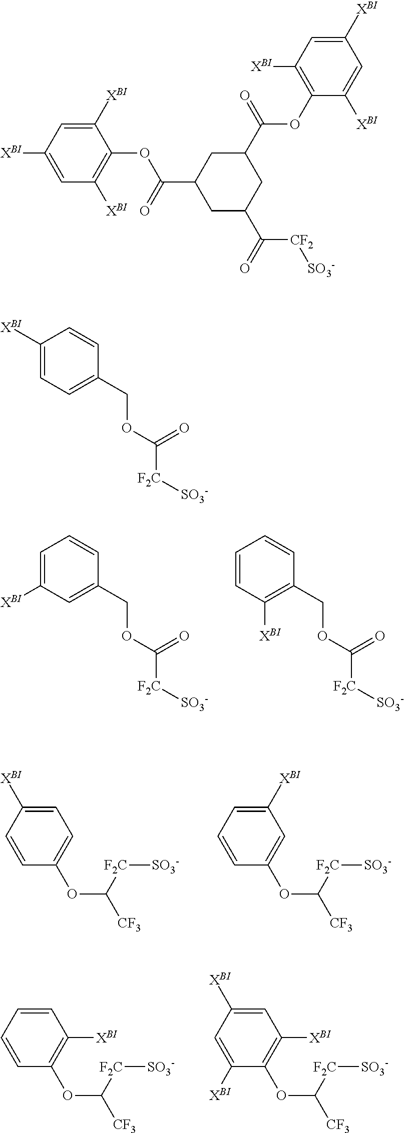

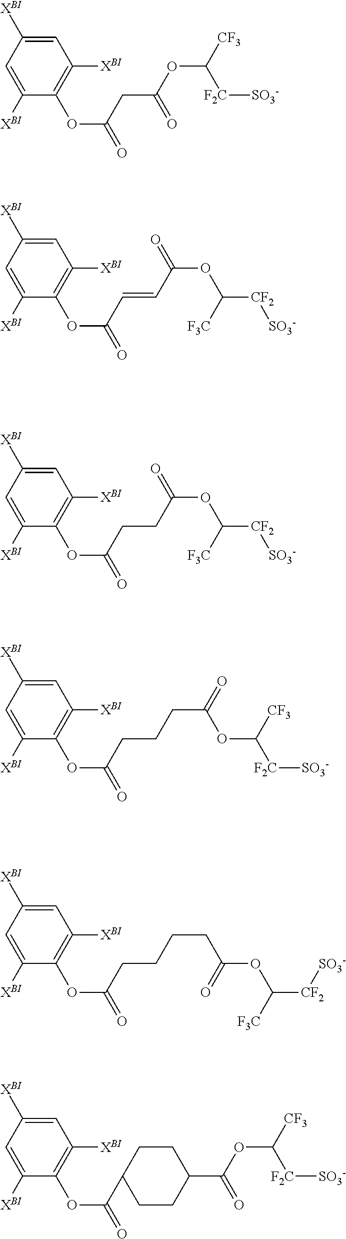

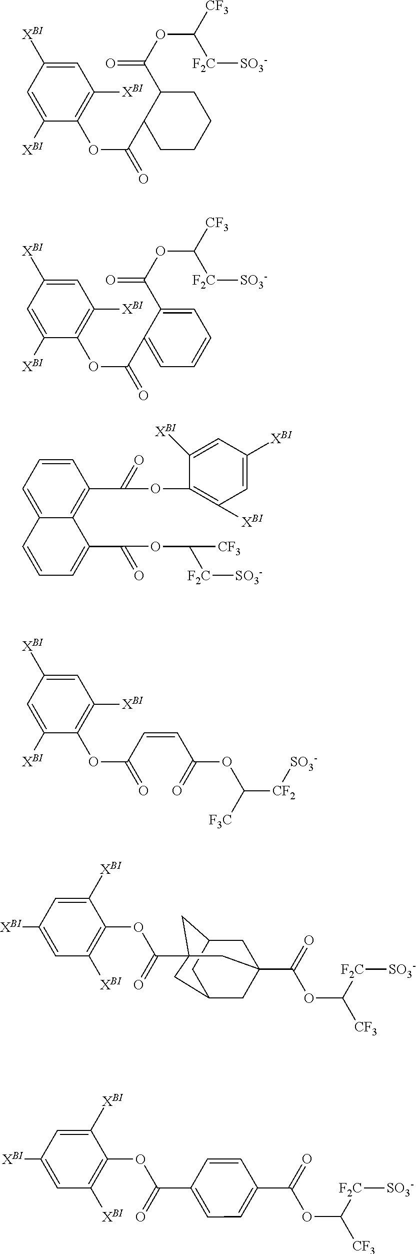

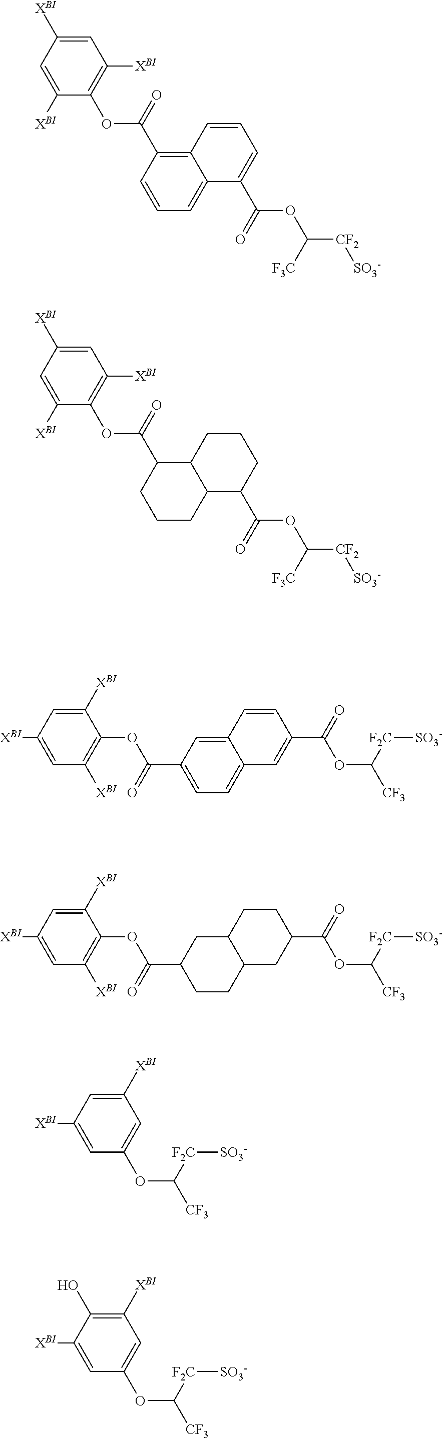

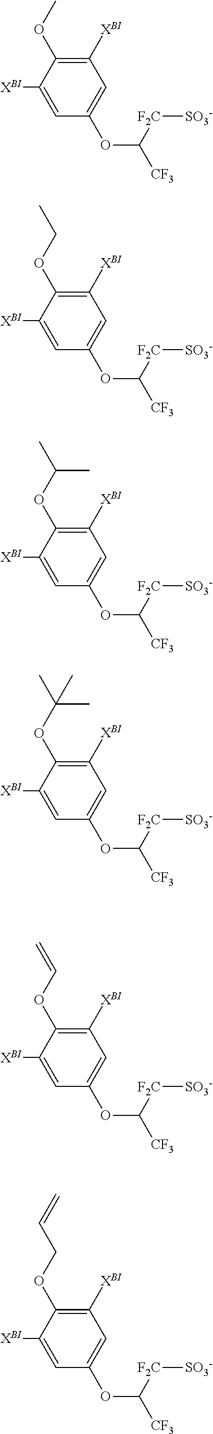

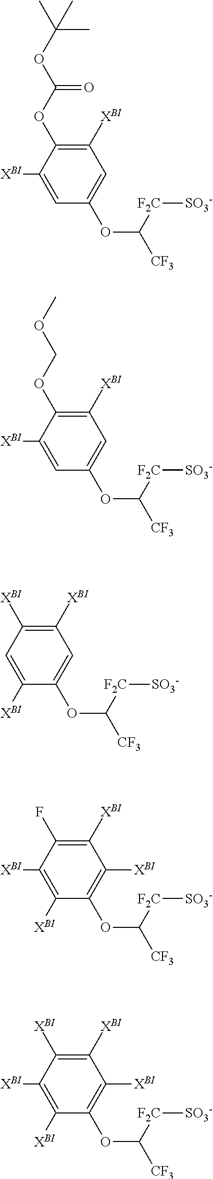

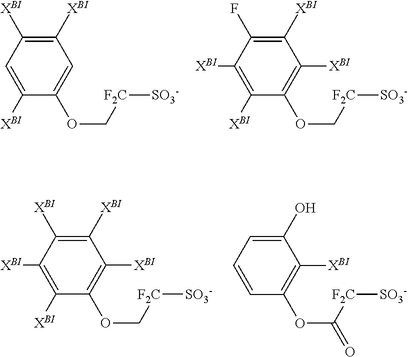

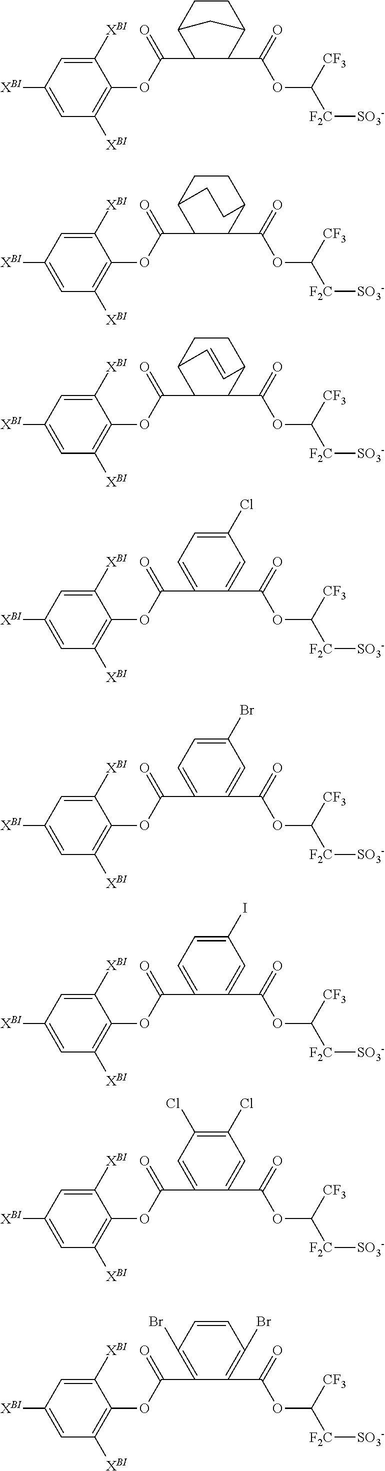

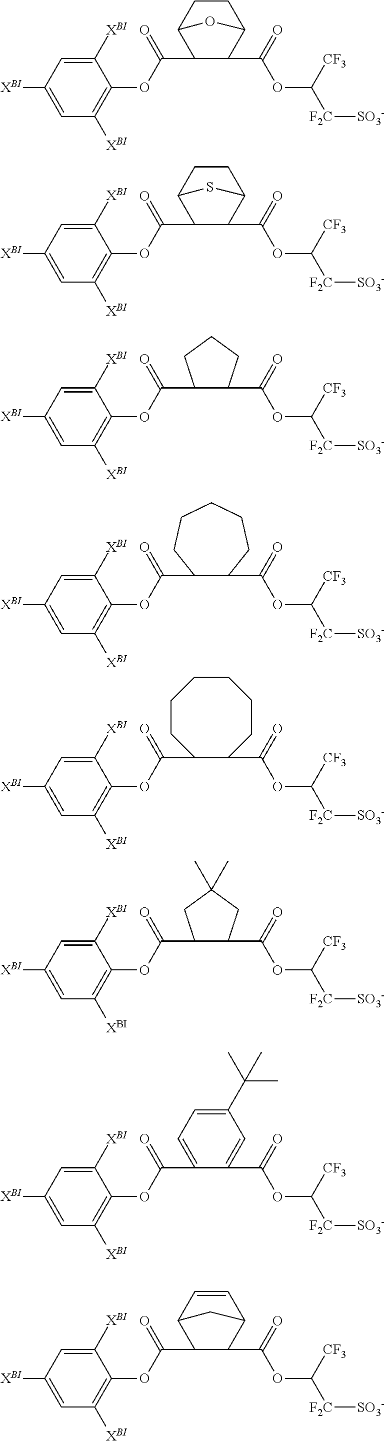

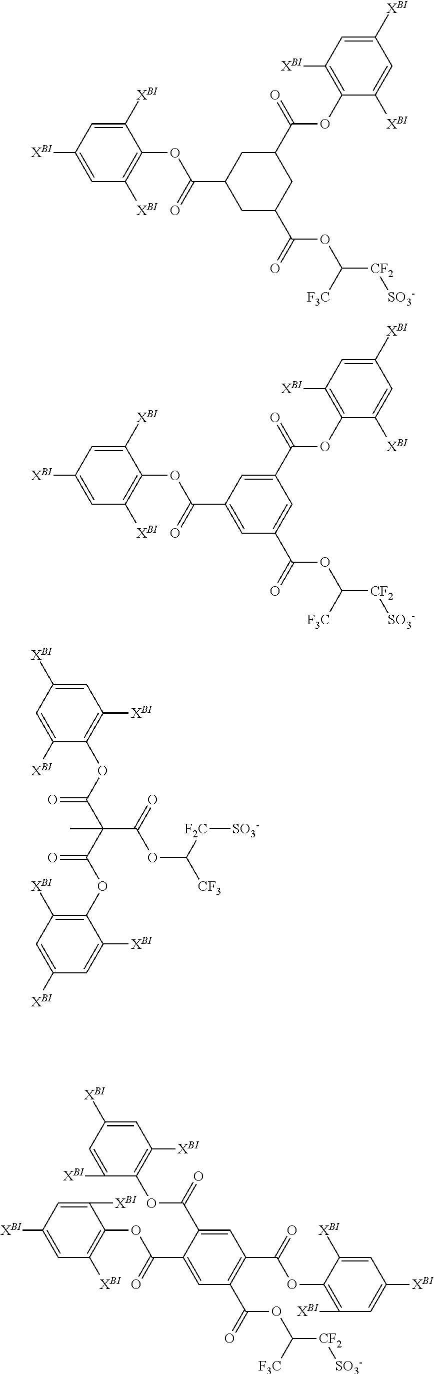

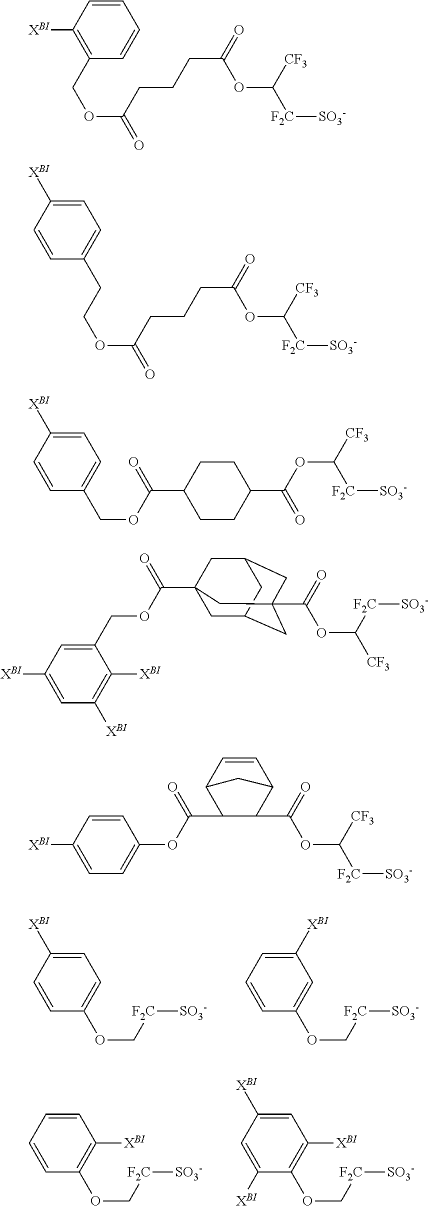

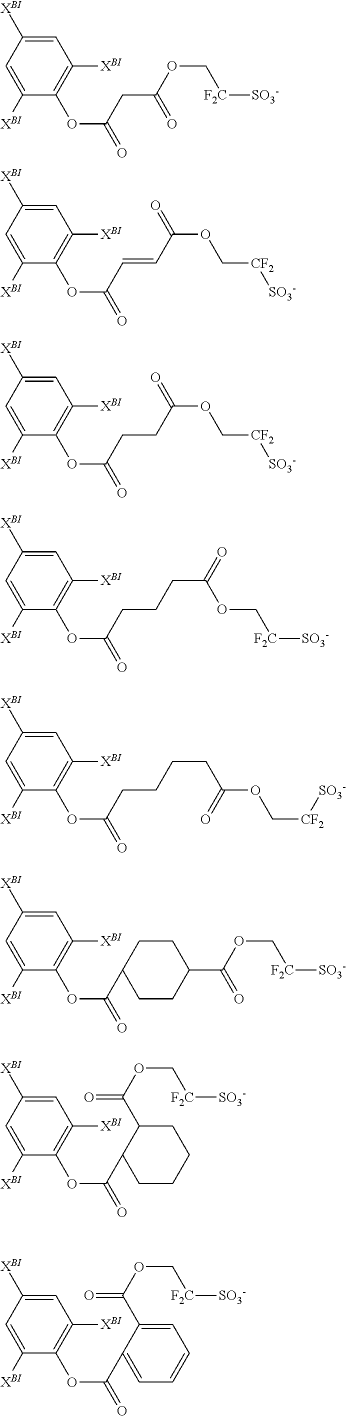

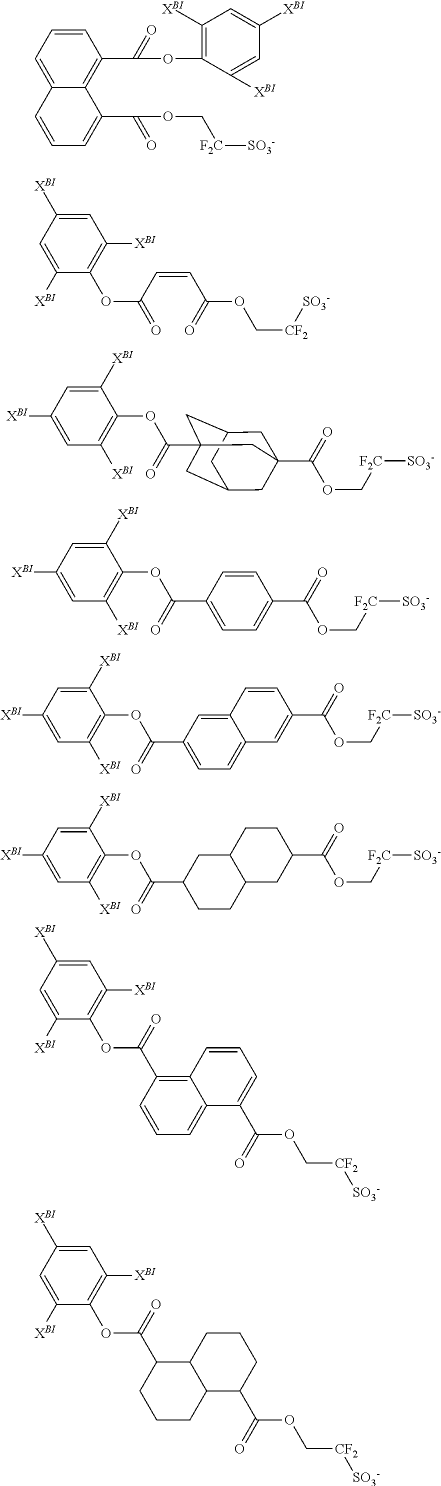

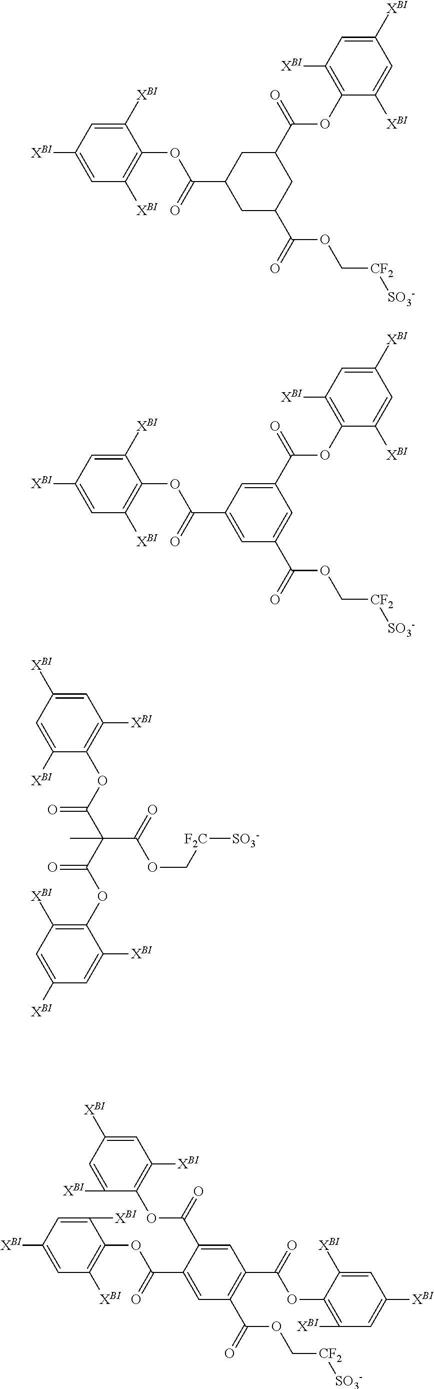

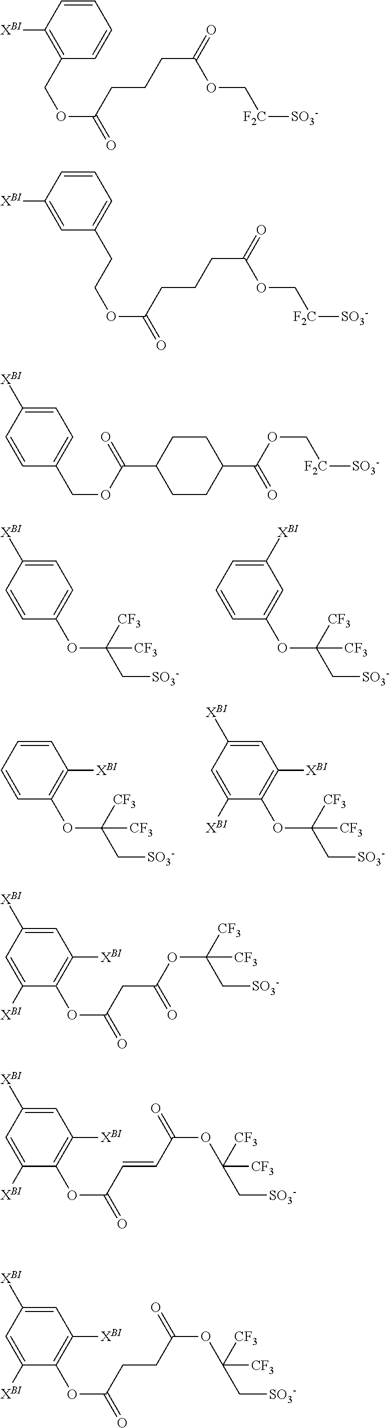

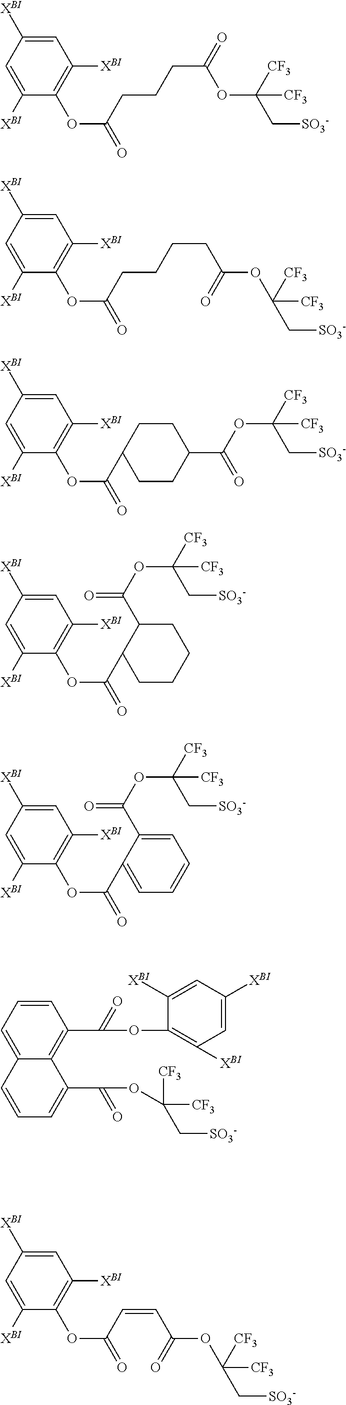

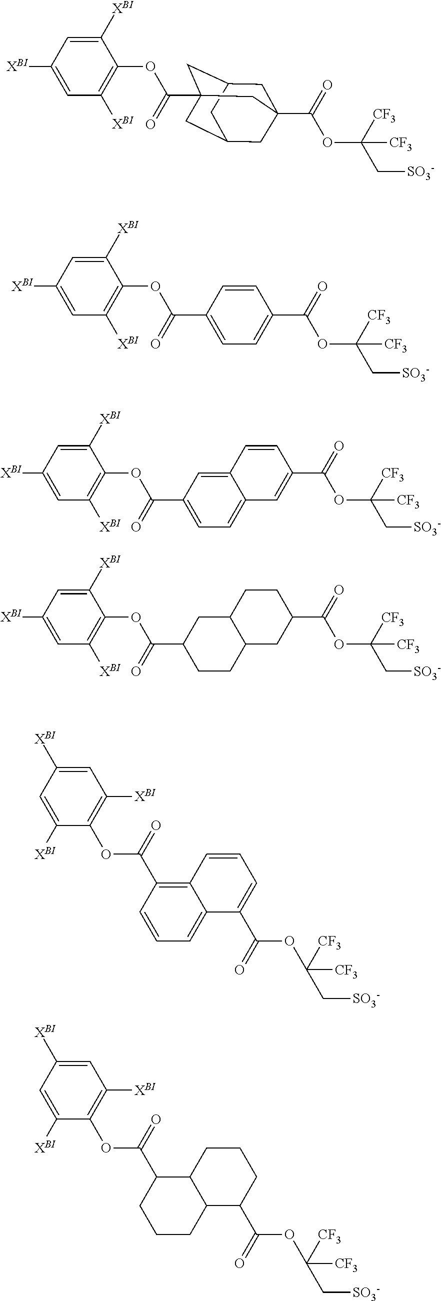

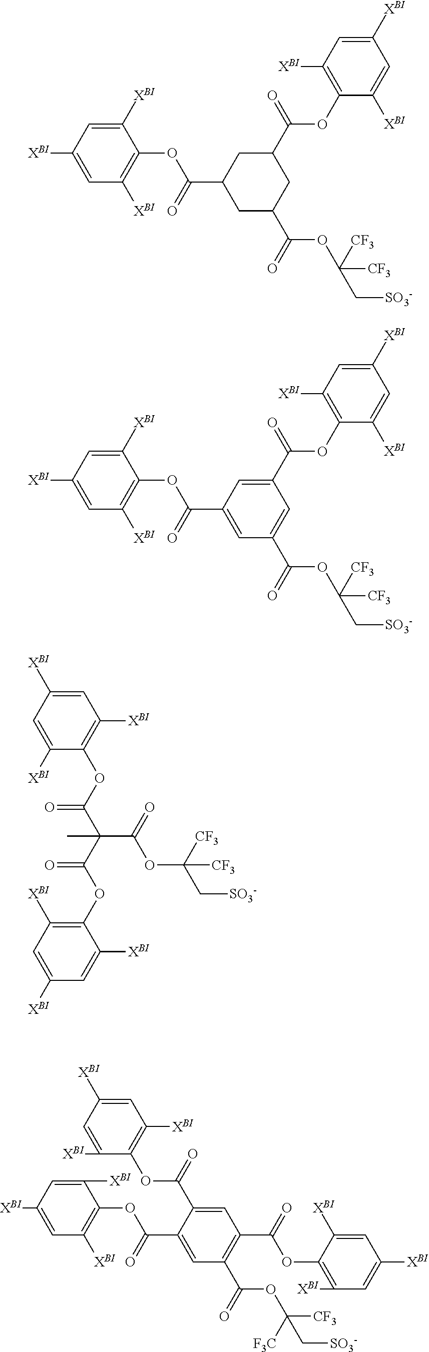

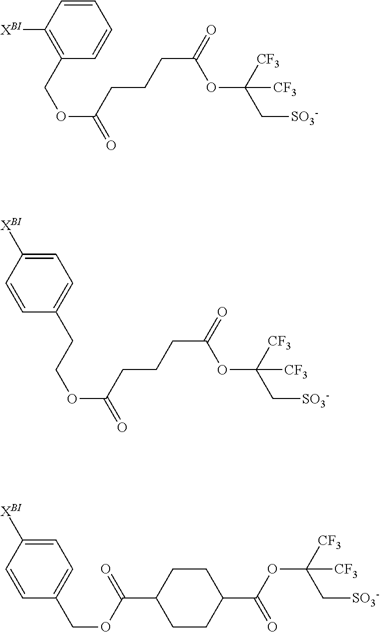

Other useful examples of the non-nucleophilic counter anion include fluorobenzenesulfonic acid anions having an iodized aromatic ring bonded thereto as described in JP 6648726, anions having an acid-catalyzed decomposition mechanism as described in WO 2021/200056 and JP-A 2021-070692, anions having a cyclic ether group as described in JP-A 2018-180525 and JP-A 2021-035935, and anions as described in JP-A 2018-092159.

Further useful examples of the non-nucleophilic counter anion include fluorine-free bulky benzenesulfonic acid anions as described in JP-A 2006-276759, JP-A 2015-117200, JP-A 2016-065016, and JP-A 2019-202974; fluorine-free benzenesulfonic acid or alkylsulfonic acid anions having an iodized aromatic group bonded thereto as described in JP 6645464.

Also useful are bissulfonic acid anions as described in JP-A 2015-206932, sulfonamide or sulfonimide anions having sulfonic acid side and different side as described in WO 2020/158366, and anions having a sulfonic acid side and a carboxylic acid side as described in JP-A 2015-024989.

Also compounds having the formula (3) are preferred as the PAG.

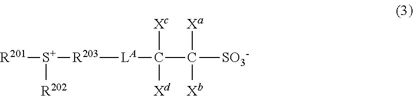

In formula (3), R²⁰¹ and R²⁰² are each independently a C₁-C₃₀ hydrocarbyl group which may contain a heteroatom. R²⁰³ is a C₁-C₃₀ hydrocarbylene group which may contain a heteroatom. Any two of R²⁰¹, R²⁰² and R²⁰³ may bond together to form a ring with the sulfur atom to which they are attached.

The C₁-C₃₀ hydrocarbyl groups R²⁰¹ and R²⁰² may be saturated or unsaturated and straight, branched or cyclic. Examples thereof include C₁-C₃₀ alkyl groups such as methyl, ethyl, n-propyl, isopropyl, n-butyl, sec-butyl, tert-butyl, n-pentyl, tert-pentyl, n-hexyl, n-octyl, 2-ethylhexyl, n-nonyl, and n-decyl; C₃-C₃₀ cyclic saturated hydrocarbyl groups such as cyclopentyl, cyclohexyl, cyclopentyhmethyl, cyclopentylethyl, cyclopentylbutyl, cyclohexylmethyl, cyclohexylethyl, cyclohexylbutyl, norbornyl, tricyclo[5.2.1.0^{2,6}]decanyl, and adamantyl; C₆-C₃₀ aryl groups such as phenyl, methylphenyl, ethylphenyl, n-propylphenyl, isopropylphenyl, n-butylphenyl, isobutylphenyl, sec-butylphenyl, tert-butylphenyl, naphthyl, methylnaphthyl, ethylnaphthyl, n-propylnaphthyl, isopropylnaphthyl, n-butylnaphthyl, isobutylnaphthyl, sec-butylnaphthyl, tert-butylnaphthyl, and anthracenyl; and combinations thereof. In these hydrocarbyl groups, some or all of the hydrogen atoms may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy, cyano, fluorine, chlorine, bromine, iodine, carbonyl, ether bond, ester bond, sulfonic ester bond, carbonate bond, lactone ring, sultone ring, carboxylic anhydride (—C(═O)—O—C(═O)—) or haloalkyl moiety.

The C₁-C₃₀ hydrocarbylene group R²⁰³ may be saturated or unsaturated and straight, branched or cyclic. Examples thereof include C₁-C₃₀ alkanediyl groups such as methanediyl, ethane-1,1-diyl, ethane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, dodecane-1,12-diyl, tridecane-1,13-diyl, tetradecane-1,14-diyl, pentadecane-1,15-diyl, hexadecane-1,16-diyl, and heptadecane-1,17-diyl; C₃-C₃₀ cyclic saturated hydrocarbylene groups such as cyclopentanediyl, cyclohexanediyl, norbornanediyl and adamantanediyl; C₆-C₃₀ arylene groups such as phenylene, methylphenylene, ethylphenylene, n-propylphenylene, isopropylphenylene, n-butylphenylene, isobutylphenylene, sec-butylphenylene, tert-butylphenylene, naphthylene, methylnaphthylene, ethylnaphthylene, n-propylnaphthylene, isopropylnaphthylene, n-butylnaphthylene, isobutylnaphthylene, sec-butylnaphthylene, and tert-butylnaphthylene; and combinations thereof. In these hydrocarbylene groups, some or all of the hydrogen atoms may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy, cyano, fluorine, chlorine, bromine, iodine, carbonyl, ether bond, ester bond, sulfonic ester bond, carbonate bond, lactone ring, sultone ring, carboxylic anhydride (—C(═O)—O—C(═O)—) or haloalkyl moiety. Of the heteroatoms, oxygen is preferred.

In formula (3), L^{A} is a single bond, ether bond or a C₁-C₂₀ hydrocarbylene group which may contain a heteroatom. The hydrocarbylene group may be saturated or unsaturated and straight, branched or cyclic. Examples thereof are as exemplified above for R²⁰³.

In formula (3), X^{a}, X^{b}, X^{c} and X^{d} are each independently hydrogen, fluorine or trifluoromethyl, with the proviso that at least one of X^{a}, X^{b}, X^{c} and X^{d} is fluorine or trifluoromethyl.

Of the PAGs having formula (3), those having the formula (3′) are preferred.

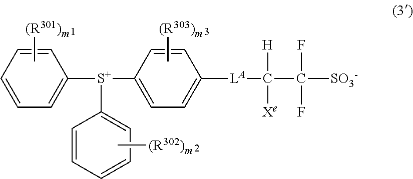

In formula (3′), L^{A} is as defined above. X^{e} is hydrogen or trifluoromethyl, preferably trifluoromethyl. R³⁰¹, R³⁰² and R³⁰³ are each independently hydrogen or a C₁-C₂₀ hydrocarbyl group which may contain a heteroatom. The hydrocarbyl group may be saturated or unsaturated and straight, branched or cyclic. Examples thereof are as exemplified above for the hydrocarbyl group R^{fa1} in formula (2A′). The subscripts m¹ and m² are each independently an integer of 0 to 5, and m³ is an integer of 0 to 4.

Examples of the PAG having formula (3) are as exemplified for the PAG having formula (2) in JP-A 2017-026980.

Of the foregoing PAGs, those having an anion of formula (2A′) or (2D) are especially preferred because of reduced acid diffusion and high solubility in the resist solvent. Also those having formula (3′) are especially preferred because of extremely reduced acid diffusion.

When the resist composition contains the PAG (D), it is preferably used in an amount of 0.1 to 40 parts, and more preferably 0.5 to 20 parts by weight per 80 parts by weight of the base polymer (A). An amount of the PAG (D) in the range ensures good resolution and eliminates the risk of leaving foreign particles after development or during separation of resist film. The PAG (D) may be used alone or in admixture of two or more. When the base polymer contains repeat units (c1) to (c4) and/or the resist composition contains the PAG (D), the resist composition functions as a chemically amplified resist composition.

### (E) Nitrogen-Containing Compound

While the resist composition essentially contains the onium salt type quencher (C), it may further contain a nitrogen-containing compound as another quencher. Suitable nitrogen-containing compounds include primary, secondary and tertiary amine compounds, specifically amine compounds having a hydroxy group, ether bond, ester bond, lactone ring, cyano group or sulfonic ester bond, as described in JP-A 2008-111103, paragraphs [0146]-[0164], and primary and secondary amine compounds protected with a carbamate group, as described in JP 3790649.

Also a sulfonium salt of sulfonic acid having a nitrogen-containing substituent may be used as the nitrogen-containing compound (E). This compound functions as a quencher in the unexposed region, but as a so-called photo-degradable base in the exposed region because it loses the quencher function in the exposed region due to neutralization thereof with the acid generated by itself. Using a photo-degradable base, the contrast between exposed and unexposed regions can be further enhanced. With respect to the photo-degradable base, reference may be made to JP-A 2009-109595 and 2012-046501, for example.

When the resist composition contains the nitrogen-containing compound (E), it is preferably used in an amount of 0.001 to 12 parts by weight, more preferably 0.01 to 8 parts by weight per 80 parts by weight of the base polymer (A). The nitrogen-containing compound may be used alone or in admixture.

### (F) Surfactant

The resist composition may further comprise (F) a surfactant. It is typically a surfactant which is insoluble or substantially insoluble in water and alkaline developer, or a surfactant which is insoluble or substantially insoluble in water and soluble in alkaline developer. For the surfactant, reference should be made to those compounds described in JP-A 2010-215608 and JP-A 2011-016746.

While many examples of the surfactant which is insoluble or substantially insoluble in water and alkaline developer are described in the patent documents cited herein, preferred examples are fluorochemical surfactants FC-4430 (3M). Olfine® E1004 (Nissin Chemical Co., Ltd.), Surflonit S-381, KH-20 and KH-30 (AGC Seimi Chemical Co., Ltd.). Partially fluorinated oxetane ring-opened polymers having the formula (surf-1) are also useful.

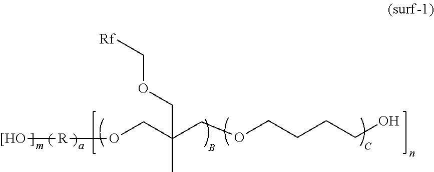

It is provided herein that R, Rf, A, B, C, m, and n are applied to only formula (surf-1), independent of their descriptions other than for the surfactant. R is a di- to tetra-valent C₂-C₅ aliphatic group. Exemplary divalent aliphatic groups include ethylene, 1,4-butylene, 1,2-propylene, 2,2-dimethyl-1,3-propylene and 1,5-pentylene. Exemplary tri- and tetra-valent groups are shown below.

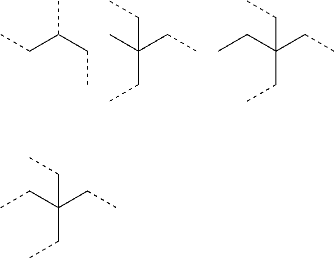

Herein the broken line denotes a valence bond. These formulae are partial structures derived from glycerol, trimethylol ethane, trimethylol propane, and pentaerythritol, respectively. Of these, 1,4-butylene and 2,2-dimethyl-1,3-propylene are preferred.

Rf is trifluoromethyl or pentafluoroethyl, and preferably trifluoromethyl. The subscript m is an integer of 0 to 3, n is an integer of 1 to 4, and the sum of m and n, which represents the valence of R, is an integer of 2 to 4. “A” is equal to 1, B is an integer of 2 to 25, and C is an integer of 0 to 10. Preferably, B is an integer of 4 to 20, and C is 0 or 1. Note that the formula (surf-1) does not prescribe the arrangement of respective constituent units while they may be arranged either blockwise or randomly. For the preparation of surfactants in the form of partially fluorinated oxetane ring-opened polymers, reference should be made to U.S. Pat. No. 5,650,483, for example.

The surfactant which is insoluble or substantially insoluble in water and soluble in alkaline developer is useful when ArF immersion lithography is applied to the resist composition in the absence of a resist protective film. In this embodiment, the surfactant has a propensity to segregate on the surface of a resist film for achieving a function of minimizing water penetration or leaching. The surfactant is also effective for preventing water-soluble components from being leached out of the resist film for minimizing any damage to the exposure tool. The surfactant becomes solubilized during alkaline development following exposure and PEB, and thus forms few or no foreign particles which become defects. The preferred surfactant is a polymeric surfactant which is insoluble or substantially insoluble in water, but soluble in alkaline developer, also referred to as “hydrophobic resin” in this sense, and especially which is water repellent and enhances water sliding.

Suitable polymeric surfactants include those containing repeat units of at least one type selected from the formulae (4A) to (4E).

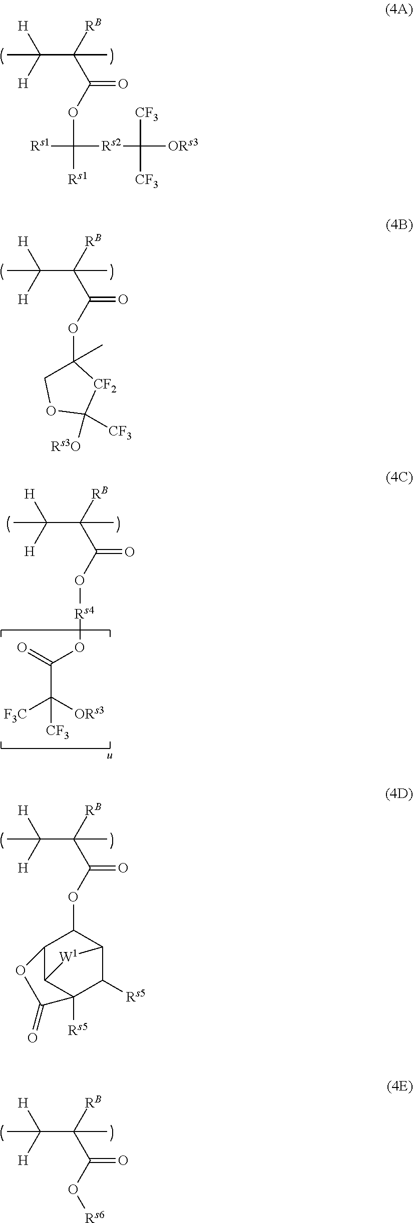

In formulae (4A) to (4E), R^{B} is hydrogen, fluorine, methyl or trifluoromethyl. W¹ is —CH₂—, —CH₂CH₂— or —O—, or two separate —H. R^{s1} is each independently hydrogen or a C₁-C₁₀ hydrocarbyl group. R^{s2} is a single bond or a C₁-C₅ straight or branched hydrocarbylene group. R^{s3} is each independently hydrogen, a C₁-C₁₅ hydrocarbyl or fluorinated hydrocarbyl group, or an acid labile group. When R³ is a hydrocarbyl or fluorinated hydrocarbyl group, an ether bond or carbonyl moiety may intervene in a carbon-carbon bond. R^{s4} is a C₁-C₂₀ (u+1)-valent hydrocarbon or fluorinated hydrocarbon group, and u is an integer of 1 to 3. R^{s5} is each independently hydrogen or a group: —C(═O)—O—R^{sa} wherein R^{sa} is a C₁-C₂₀ fluorinated hydrocarbyl group. R^{s6} is a C₁-C₁₅ hydrocarbyl or fluorinated hydrocarbyl group in which an ether bond or carbonyl moiety may intervene in a carbon-carbon bond.

The hydrocarbyl group R^{s1} is preferably saturated while it may be straight, branched or cyclic. Examples thereof include alkyl groups such as methyl, ethyl, n-propyl, isopropyl, n-butyl, isobutyl, sec-butyl, tert-butyl, n-pentyl, n-hexyl, n-heptyl, n-octyl, n-nonyl and n-decyl, and cyclic saturated hydrocarbyl groups such as cyclopropyl, cyclobutyl, cyclopentyl, cyclohexyl, adamantyl and norbornyl. Inter alia, C₁-C₆ groups are preferred.

The hydrocarbylene group R^{s2} is preferably saturated while it may be straight, branched or cyclic. Examples thereof include methylene, ethylene, propylene, butylene, and pentylene.

The hydrocarbyl group R^{s3} or R^{s6} may be saturated or unsaturated and straight, branched or cyclic. Examples thereof include saturated hydrocarbyl groups and aliphatic unsaturated hydrocarbyl groups such as alkenyl and alkynyl groups, with the saturated hydrocarbyl groups being preferred. Suitable saturated hydrocarbyl groups include those exemplified for the hydrocarbyl group represented by R^{s1} as well as n-undecyl, n-dodecyl, tridecyl, tetradecyl, and pentadecyl. Examples of the fluorinated hydrocarbyl group represented by R^{s3} or R^{s6} include the foregoing hydrocarbyl groups in which some or all carbon-bonded hydrogen atoms are substituted by fluorine atoms. In these groups, an ether bond or carbonyl moiety may intervene in a carbon-carbon bond as mentioned above.

Examples of the acid labile group represented by R^{s3} include groups of the above formulae (L1) to (L4), trialkylsilyl groups in which each alkyl moiety has 1 to 6 carbon atoms, and C₄-C₂₀ oxoalkyl groups.

The (u+1)-valent hydrocarbon or fluorinated hydrocarbon group represented by R^{s4} may be straight, branched or cyclic, and examples thereof include the foregoing hydrocarbyl or fluorinated hydrocarbyl groups from which “u” number of hydrogen atoms are eliminated.

The fluorinated hydrocarbyl group represented by R^{s3} is preferably saturated while it may be straight, branched or cyclic. Examples thereof include the foregoing hydrocarbyl groups in which some or all hydrogen atoms are substituted by fluorine atoms. Illustrative examples include trifluoromethyl, 2,2,2-trifluoroethyl, 3,3,3-trifluoro-1-propyl, 3,3,3-trifluoro-2-propyl, 2,2,3,3-tetrafluoropropyl, 1,1,1,3,3,3-hexafluoroisopropyl, 2,2,3,3,4,4,4-heptafluorobutyl, 2,2,3,3,4,4,5,5-octafluoropentyl, 2,2,3,3,4,4,5,5,6,6,7,7-dodecafluoroheptyl, 2-(perfluorobutyl)ethyl, 2-(perfluorohexyl)ethyl, 2-(perfluorooctyl)ethyl, and 2-(perfluorodecyl)ethyl.

Examples of the repeat units having formulae (4A) to (4E) are shown below, but not limited thereto. Herein R^{B} is as defined above.

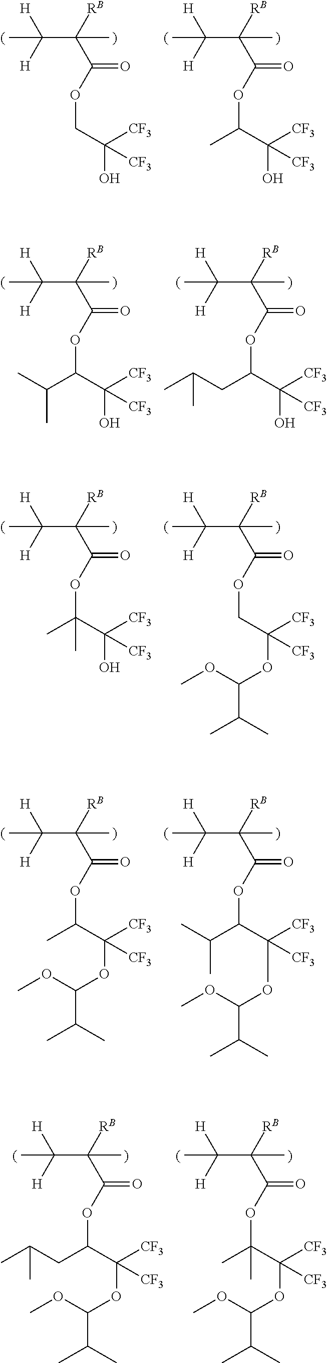

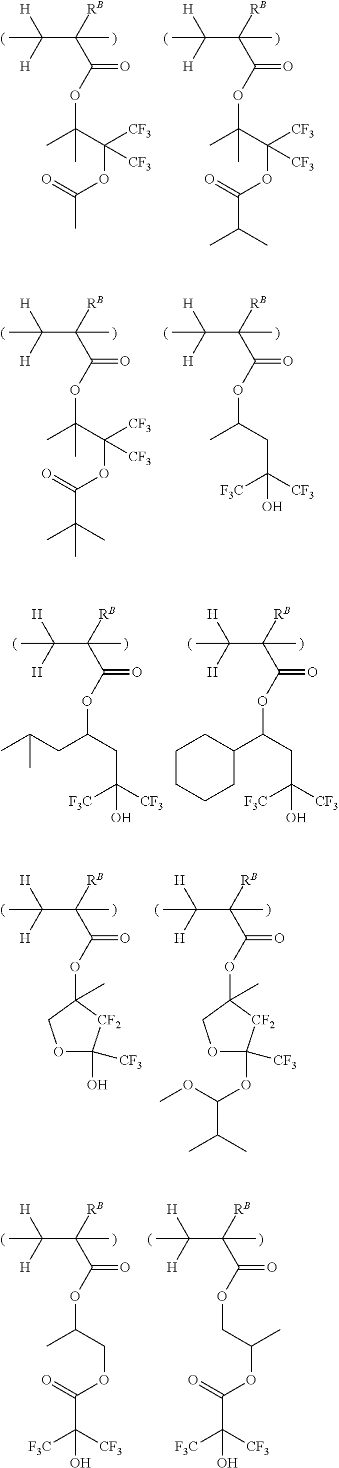

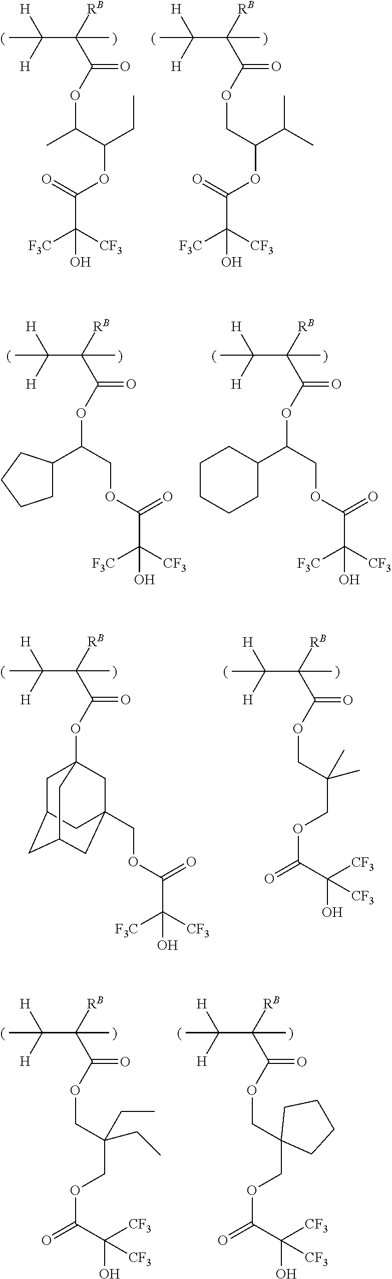

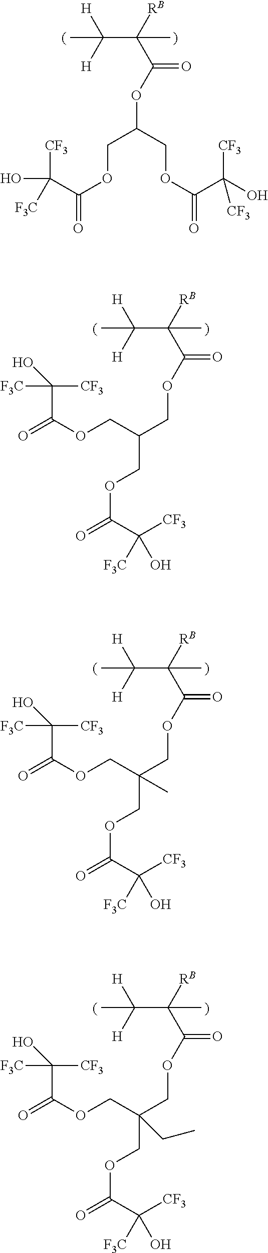

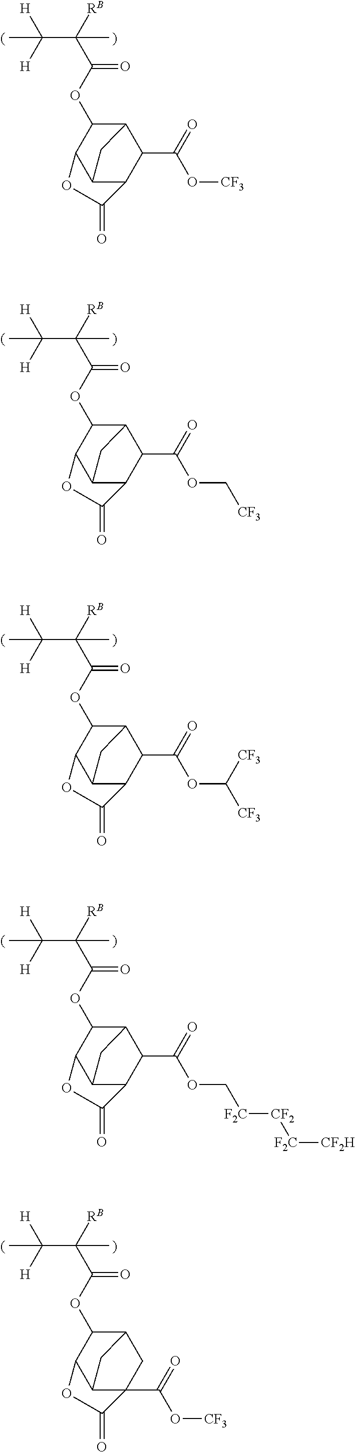

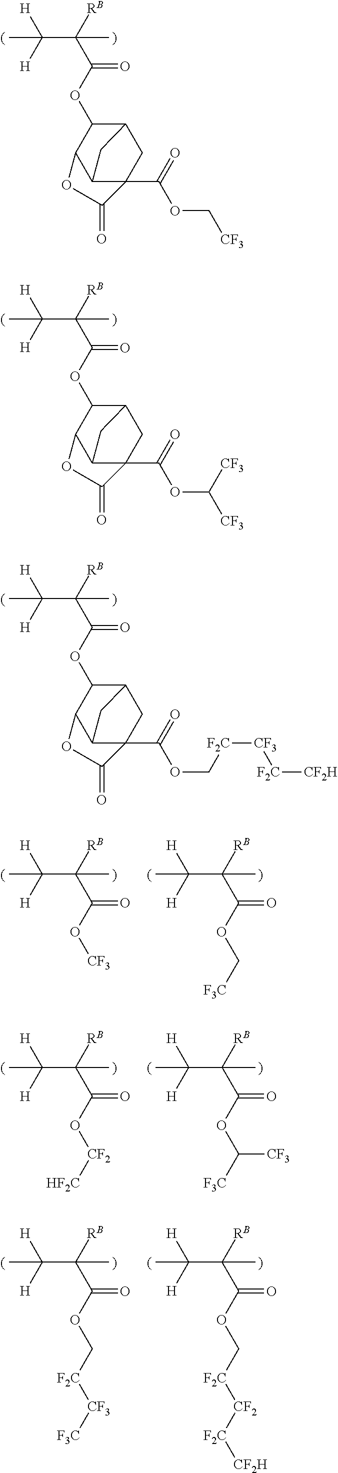

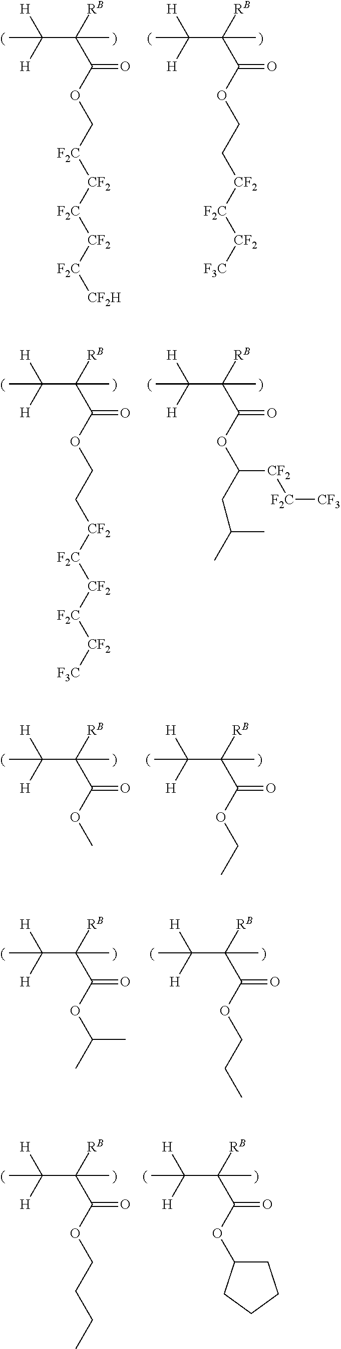

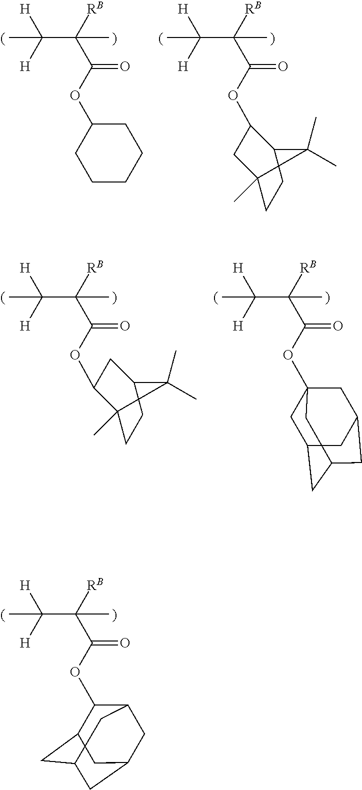

The polymeric surfactant may further contain repeat units other than the repeat units having formulae (4A) to (4E). Typical other repeat units are those derived from methacrylic acid and α-trifluoromethylacrylic acid derivatives. In the polymeric surfactant, the content of the repeat units having formulae (4A) to (4E) is preferably at least 20 mol %, more preferably at least 60 mol %, most preferably 100 mol % of the overall repeat units.

Preferably the polymeric surfactant has a Mw of 1,000 to 500,000, more preferably 3,000 to 100,000 and a Mw/Mn of 1.0 to 2.0, more preferably 1.0 to 1.6.

The polymeric surfactant may be synthesized, for example, by dissolving an unsaturated bond-containing monomer or monomers, from which repeat units having formulae (4A) to (4E) and optional other repeat units are derived, in an organic solvent, adding a radical initiator, and heating for polymerization. Suitable organic solvents used herein include toluene, benzene. THF, diethyl ether, and dioxane. Examples of the polymerization initiator used herein include AIBN, 2,2′-azobis(2,4-dimethylvaleronitrile), dimethyl 2,2-azobis(2-methylpropionate), benzoyl peroxide, and lauroyl peroxide. Preferably the reaction temperature is 50 to 100° C. and the reaction time is 4 to 24 hours. The acid labile group that has been incorporated in the monomer may be kept as such, or the polymer may be protected or partially protected therewith at the end of polymerization.

During the synthesis of the polymeric surfactant, any of well-known chain transfer agents such as dodecylmercaptan and 2-mercaptoethanol may be used for the purpose of adjusting molecular weight. An appropriate amount of the chain transfer agent is 0.01 to 10 mol % based on the total moles of monomers to be polymerized.

When the resist composition contains the surfactant (F), it is preferably used in an amount of 0.1 to 50 parts by weight, more preferably 0.5 to 10 parts by weight per 80 parts by weight of the base polymer (A). As long as the amount of the surfactant is at least 0.1 part by weight, the receding contact angle of resist film surface with water is fully improved. As long as the amount of the surfactant is up to 50 parts by weight, the dissolution rate of resist film surface in developer is so low that the resulting small-size pattern may maintain a sufficient height. The surfactant (F) may be used alone or in admixture.

### (G) Other Components

The resist composition may further comprise other components, for example, a compound which is decomposed with an acid to generate another acid (i.e., acid amplifier compound), organic acid derivative, fluorinated alcohol, and a compound with Mw≤3,000 adapted to change its solubility in developer under the action of acid (i.e., dissolution inhibitor). Each of the other components may be used alone or in admixture. The acid amplifier compound is described in JP-A 2009-269953 and JP-A 2010-215608. The acid amplifier compound is preferably used in an amount of 0 to 5 parts, more preferably 0 to 3 parts by weight per 80 parts by weight of the base polymer. An extra amount of the acid amplifier compound can make the acid diffusion control difficult and cause degradations to resolution and pattern profile. With respect to the organic acid derivative, fluorinated alcohol and dissolution inhibitor, reference should be made to JP-A 2009-269953 and JP-A 2010-215608.

### Process

Another embodiment of the invention is a pattern forming process comprising the steps of applying the resist composition defined above onto a substrate to form a resist film thereon, exposing the resist film to high-energy radiation, and developing the exposed resist film in a developer.

The substrate used herein may be selected from, for example, substrates for IC fabrication. e.g., Si, SiO₂, SiN, SiON, TiN, WSi, BPSG, SOG, and organic antireflective coating, and substrates for mask circuit fabrication, e.g., Cr, CrO, CrON, MoSi₂, and SiO₂.

The resist composition is first applied onto a substrate by a suitable coating technique such as spin coating. The coating is prebaked on a hotplate preferably at a temperature of 60 to 150° C. for 1 to 10 minutes, more preferably at 80 to 140° C. for 1 to 5 minutes to form a resist film of 0.05 to 2 μm thick.

Then the resist film is exposed patternwise to high-energy radiation, for example, KrF excimer laser, ArF excimer laser, EB or EUV. On use of KrF or ArF excimer laser or EUV, the resist film is exposed through a mask having the desired pattern, preferably in a dose of 1 to 200 m/cm², more preferably 10 to 100 mJ/cm². On use of EB, a pattern may be written directly or through a mask having the desired pattern, preferably in a dose of 1 to 300 μC/cm², more preferably 10 to 200 μC/cm².

The exposure may be performed by conventional lithography whereas the immersion lithography of holding a liquid having a refractive index of at least 1.0, typically water between the resist film and the projection lens may be employed if desired. In the case of immersion lithography, a protective film which is insoluble in water may be formed on the resist film.

While the water-insoluble protective film serves to prevent any components from being leached out of the resist film and to improve water slippage at the film surface, it is generally divided into two types. The first type is an organic solvent-strippable protective film which must be stripped, prior to alkaline development, with an organic solvent in which the resist film is not dissolvable. The second type is an alkali-soluble protective film which is soluble in an alkaline developer so that it can be removed simultaneously with the removal of solubilized regions of the resist film. The protective film of the second type is preferably of a material comprising a polymer having a 1,1,1,3,3,3-hexafluoro-2-propanol residue (which is insoluble in water and soluble in an alkaline developer) as a base in an alcohol solvent of at least 4 carbon atoms, an ether solvent of 8 to 12 carbon atoms or a mixture thereof. Alternatively, the aforementioned surfactant which is insoluble in water and soluble in an alkaline developer may be dissolved in an alcohol solvent of at least 4 carbon atoms, an ether solvent of 8 to 12 carbon atoms or a mixture thereof to form a material from which the protective film of the second type is formed.

After the exposure, the resist film may be baked (PEB), for example, on a hotplate preferably at 60 to 150° C. for 1 to 5 minutes, and more preferably at 80 to 140° C. for 1 to 3 minutes.

Finally, development is carried out using as the developer an aqueous alkaline solution, such as a 0.1 to 5 wt %, preferably 2 to 3 wt %, aqueous solution of tetramethylammonium hydroxide (TMAH), this being done by a conventional method such as dip, puddle, or spray development for a period of 0.1 to 3 minutes, and preferably 0.5 to 2 minutes. In this way the exposed region of resist film is dissolved away, forming the desired pattern on the substrate.

After formation of the resist film, deionized water rinsing may be carried out for extracting the acid generator and the like from the film surface or washing away particles, or after exposure, rinsing may be carried out for removing water droplets left on the resist film.

A pattern may also be formed by a double patterning process. The double patterning process includes a trench process of processing an underlay to a 1:3 trench pattern by a first step of exposure and etching, shifting the position, and forming a 1:3 trench pattern by a second step of exposure for forming a 1:1 pattern; and a line process of processing a first underlay to a 1:3 isolated left pattern by a first step of exposure and etching, shifting the position, processing a second underlay formed below the first underlay by a second step of exposure through the 1:3 isolated left pattern, for forming a half-pitch 1:1 pattern.

In the pattern forming process, an alkaline aqueous solution is often used as the developer. Instead, the negative tone development technique wherein the unexposed region of resist film is dissolved in an organic solvent developer is also applicable. In the organic solvent development, the organic solvent used as the developer is preferably selected from 2-octanone, 2-nonanone, 2-heptanone, 3-heptanone, 4-heptanone, 2-hexanone, 3-hexanone, diisobutyl ketone, methylcyclohexanone, acetophenone, methylacetoplienone, propyl acetate, butyl acetate, isobutyl acetate, pentyl acetate, isopentyl acetate, butenyl acetate, propyl foriate, butyl foriate, isobutyl formate, pentyl fornate, isopentyl foriate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, and 2-phenylethyl acetate. These organic solvents may be used alone or in admixture of two or more.

### EXAMPLES

Examples of the invention are given below by way of illustration and not by way of limitation. The abbreviation “pbw” is parts by weight. Analysis is made by IR spectroscopy, NMR spectroscopy, and time-of-flight mass spectrometry (TOF-MS) using analytic instruments as shown below.
IR: NICOLET 6700 by Thermo Fisher Scientific Inc.
¹H-NMR: ECA-500 by JEOL Ltd.
MALDI TOF-MS: S3000 by JEOL Ltd.

### [1] Synthesis of Base Polymer

Monomers of the structure shown below were used in the synthesis of base polymers.

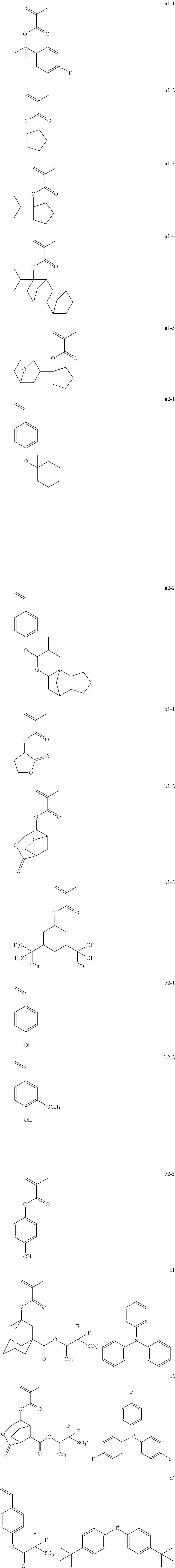

### Synthesis Example 1-1 Synthesis of Base Polymer P-1

A flask under nitrogen atmosphere was charged with 50.1 g of Monomer a1-1, 24.8 g of Monomer b2-1, 38.0 g of Monomer c1, 3.96 g of V-601 (dimethyl 2,2′-azobis(2-methylpropionate) by Fujifilm Wako Pure Chemical Corp.), and 127 g of MEK to form a monomer/initiator solution. Another flask under nitrogen atmosphere was charged with 46 g of MEK, which was heated at 80° C. with stirring. The monomer/initiator solution was added dropwise to the MEK over 4 hours. At the end of addition, the polymerization solution was continuously stirred for 2 hours while maintaining the temperature at 80° C. The polymerization solution was cooled to room temperature, after which it was added dropwise to 2,000 g of hexane with vigorous stirring. The precipitate was collected by filtration. The precipitate was washed twice with 600 g of hexane and vacuum dried at 50° C. for 20 hours, obtaining Base Polymer P-1 as white powder. Amount 98.1 g, yield 98%. Base Polymer P-1 had a Mw of 10,900 and a Mw/Mn of 1.82. It is noted that Mw is measured by GPC versus polystyrene standards using DMF solvent.

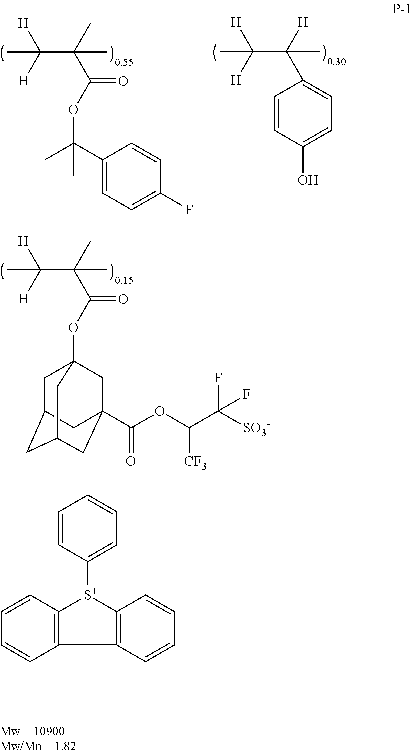

### Synthesis Examples 1-2 to 1-18 Synthesis of Base Polymers P-2 to P-18

Base Polymers P-2 to P-18, shown in Table 1, were synthesized by the same procedure as in Synthesis Example 1-1 except that the type and amount (blending ratio) of monomers were changed.

TABLE 1

| | | Incorpo- | | Incorpo- | | Incorpo- | | Incorpo- | | Incorpo- | | |
|---|---|---|---|---|---|---|---|---|---|---|---|---|
| | | ration | | ration | | ration | | ration | | ration | | |
| Base | Unit | ratio | Unit | ratio | Unit | ratio | Unit | ratio | Unit | ratio | | |
| Polymer | a1 | (mol %) | a2 | (mol %) | b1 | (mol %) | b2 | (mol %) | c | (mol %) | Mw | Mw/Mn |
| P-1 | a1-1 | 55 | — | — | — | — | b2-1 | 30 | c1 | 15 | 10,900 | 1.82 |
| P-2 | a1-2 | 55 | — | — | — | — | b2-1 | 30 | c1 | 15 | 10,700 | 1.81 |
| P-3 | a1-1 | 25 | — | — | — | — | b2-1 | 35 | c2 | 15 | 10,100 | 1.79 |
| | a1-3 | 25 | | | | | | | | | | |
| P-4 | a1-3 | 35 | — | — | — | — | b2-3 | 35 | c3 | 15 | 9,800 | 1.77 |
| | a1-5 | 15 | | | | | | | | | | |
| P-5 | a1-4 | 10 | a2-1 | 30 | b1-2 | 30 | b2-3 | 20 | c2 | 10 | 10,700 | 1.81 |
| P-6 | a1-1 | 50 | — | — | — | — | b2-1 | 25 | c2 | 10 | 10,700 | 1.81 |
| | | | | | | | b2-2 | 15 | | | | |
| P-7 | a1-3 | 50 | — | — | — | — | b2-1 | 35 | c2 | 15 | 9,900 | 1.77 |
| P-8 | a1-1 | 25 | — | — | — | — | b2-1 | 35 | c3 | 15 | 9,700 | 1.84 |
| | a1-3 | 25 | | | | | | | | | | |
| P-9 | a1-3 | 35 | a2-2 | 15 | — | — | b2-1 | 35 | c1 | 15 | 10,200 | 1.78 |
| P-10 | a1-1 | 30 | a2-1 | 20 | b1-3 | 10 | b2-1 | 20 | c2 | 20 | 10,000 | 1.82 |
| P-11 | a1-1 | 20 | a2-1 | 30 | — | — | b2-2 | 30 | c3 | 20 | 9,800 | 1.81 |
| P-12 | a1-1 | 35 | — | — | — | — | b2-1 | 35 | c2 | 15 | 9,600 | 1.79 |
| | a1-5 | 15 | | | | | | | | | | |
| P-13 | a1-1 | 35 | — | — | b1-3 | 10 | b2-3 | 30 | c1 | 10 | 9,900 | 1.81 |
| | a1-4 | 15 | | | | | | | | | | |
| P-14 | a1-2 | 60 | — | — | — | — | b2-1 | 40 | — | — | 7,300 | 1.76 |
| P-15 | a1-1 | 50 | — | — | b1-1 | 20 | b2-1 | 20 | — | — | 7,400 | 1.74 |
| | | | | | b1-3 | 10 | | | | | | |
| P-16 | a1-1 | 50 | — | — | — | — | b2-1 | 50 | — | — | 7,700 | 1.78 |
| P-17 | a1-1 | 25 | a2-2 | 25 | b1-1 | 20 | b2-3 | 30 | — | — | 7,500 | 1.73 |
| P-18 | a1-3 | 35 | a2-2 | 15 | b1-3 | 10 | b2-2 | 25 | — | — | 8,100 | 1.74 |
| | | | | | | | b2-3 | 15 | | | | |

### [2] Synthesis of Onium Salts

### Synthesis Example 2—Synthesis of Onium Salt SQ-1

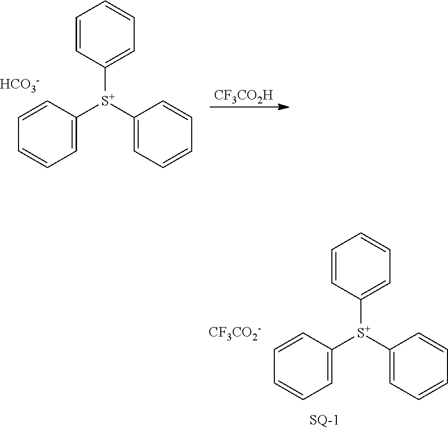 [SMILES: "HCO3-" ; c1ccc([S+](c2ccccc2)c2ccccc2)cc1 ; "CF3CO2H" ; "CF3CO2-" ; c1ccc([S+](c2ccccc2)c2ccccc2)cc1]

After triphenylsulfonium hydrogen carbonate was prepared with reference to Synthesis Example described in JP 6465026, 32 g of 20 wt % aqueous solution of the triphenylsulfonium hydrogen carbonate was mixed with 2.5 g of trifluoroacetic acid and stirred at room temperature for 30 minutes. The reaction solution was concentrated under reduced pressure. Methyl isobutyl ketone was added to the concentrate, which was concentrated under reduced pressure again and azeotropically dewatered. Diisopropyl ether was added to the residue, which was stirred for 30 minutes and filtered. The thus collected powder was dried in vacuum, obtaining 7.2 g (yield 86%) of the target compound designated Onium salt SQ-1 (triphenylsulfonium trifluoroacetate).

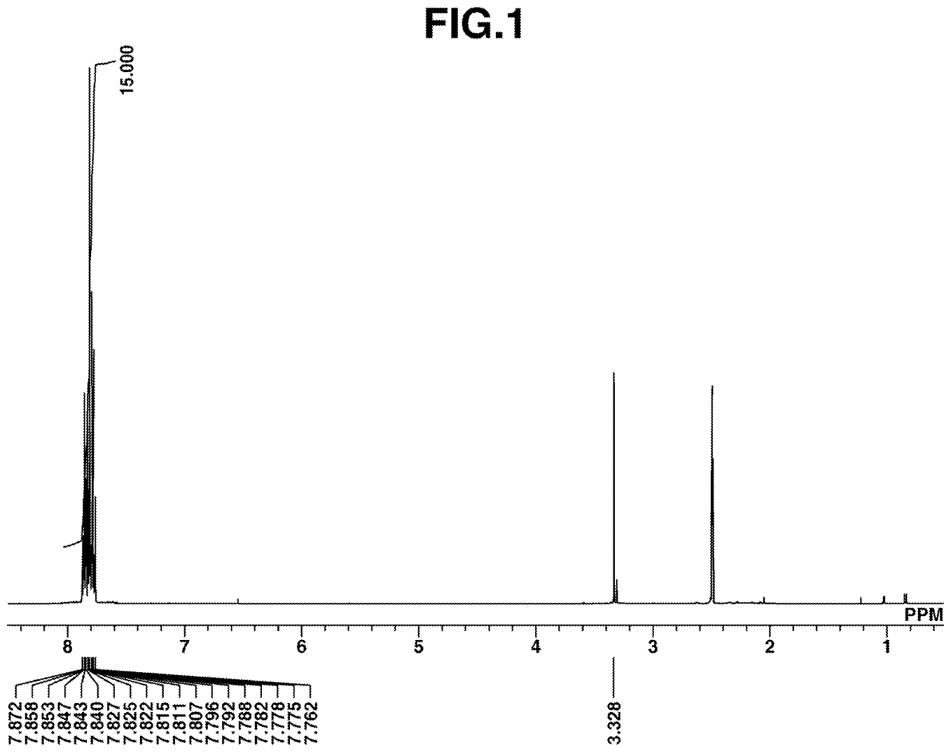

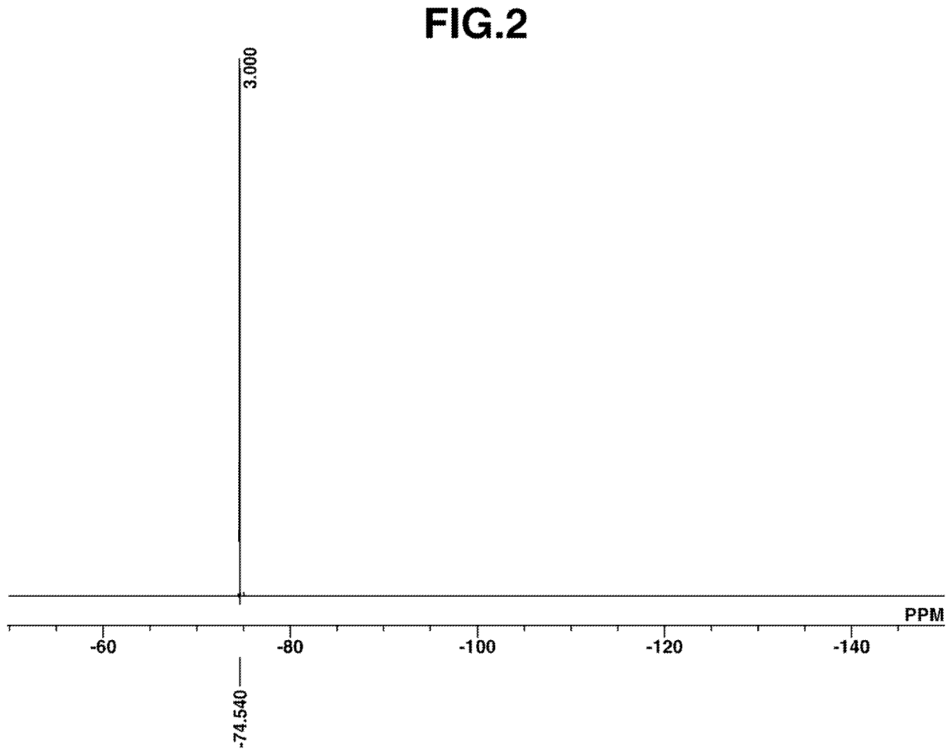

Onium salt SQ-1 was analyzed by spectroscopy. FIGS. 1 and 2 show the NMR spectra (¹H-NMR/DMSO-d₆ and ¹⁹F-NMR/DMSO-d₆) of Onium salt SQ-1. In the ¹H-NMR analysis, traces of residual solvents (diisopropyl ether and methyl isobutyl ketone) and water were observed.

IR (D-ATR): 3055, 1682, 1473, 1445, 1399, 1315, 1198, 1175, 1151, 1122, 1074, 1065, 995, 818, 798, 757, 745, 715, 684, 501 cm⁻¹

MALDI TOF-MS:

positive M⁺ 263 (corresponding to C₁₈H₁₅S⁺)

negative M⁻ 113 (corresponding to C₂F₃O₂⁻)

### Synthesis Examples 2-2 to 2-14 Synthesis of Onium Salts SQ-2 to SQ-10 and Comparative Quenchers SQ-A to SQ-D

Onium salts SQ-2 to SQ-10 and Comparative Quenchers SQ-A to SQ-D, shown below, were synthesized as in Synthesis Example 2-1 using the corresponding reactants.

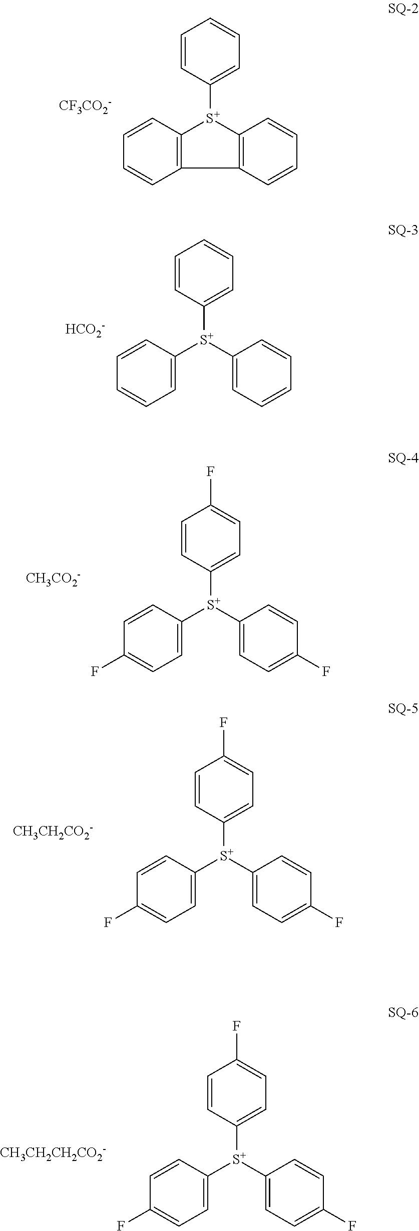

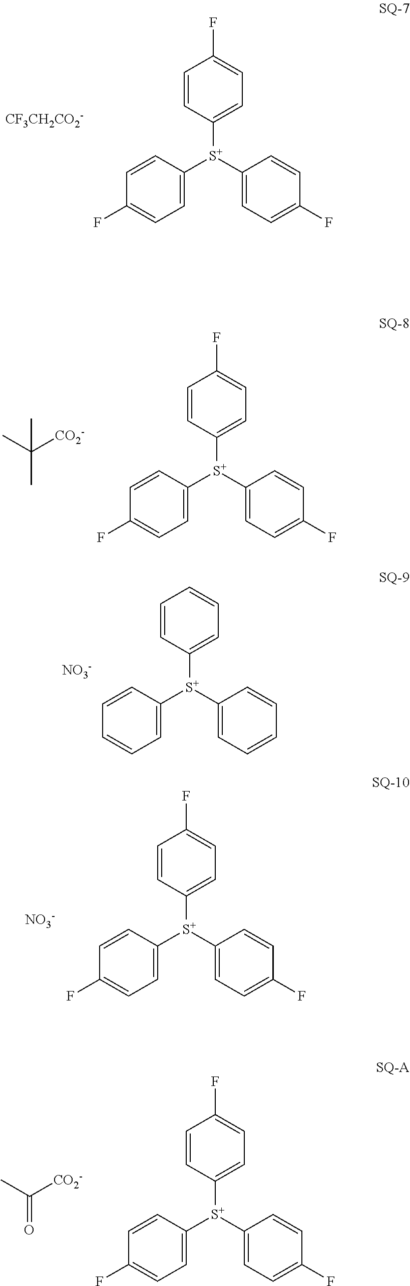

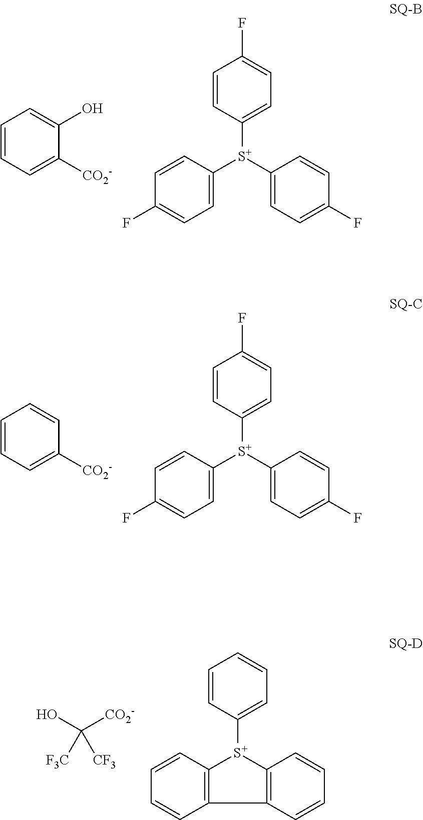

### [3] Preparation of Resist Composition

### Examples 1-1 to 1-30 and Comparative Examples 1-1 to 1-24

A resist composition was prepared by dissolving an inventive onium salt (SQ-1 to SQ-10) or comparative quencher (SQ-A to SQ-D), base polymer (P-1 to P-18), and photoacid generator (PAG-X, PAG-Y) in a solvent containing 100 ppm of surfactant FC-4430 (3M) in accordance with the formulation shown in Tables 2 to 4, and filtering the solution through a Teflon® filter with a pore size of 0.2 μm.

The components in Tables 2 to 4 are identified below.

### Organic Solvent

PGMEA: propylene glycol monomethyl ether acetate
DAA: diacetone alcohol

### Photoacid Generators PAG-X and PAG-Y

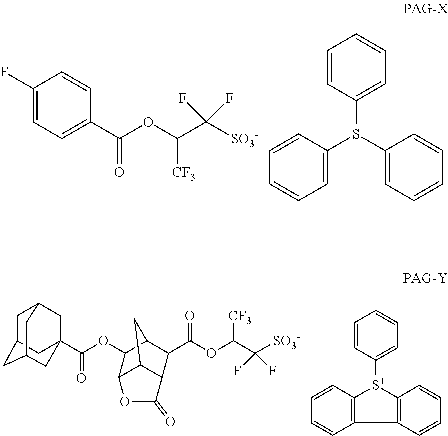

TABLE 2

| | | Resist | Base | Photoacid | Quen- | Sol- | Sol- |
|---|---|---|---|---|---|---|---|
| | | com- | polymer | generator | cher | vent 1 | vent 2 |
| | | position | (pbw) | (pbw) | (pbw) | (pbw) | (pbw) |
| Ex- | 1-1 | R-01 | P-1 | — | SQ-1 | PGMEA | DAA |
| am- | | | (80) | | (7.3) | (2200) | (900) |
| ple | 1-2 | R-02 | P-1 | — | SQ-2 | PGMEA | DAA |
| | | | (80) | | (7.2) | (2200) | (900) |
| | 1-3 | R-03 | P-1 | — | SQ-3 | PGMEA | DAA |
| | | | (80) | | (6.0) | (2200) | (900) |
| | 1-4 | R-04 | P-1 | — | SQ-4 | PGMEA | DAA |
| | | | (80) | | (7.3) | (2200) | (900) |
| | 1-5 | R-05 | P-1 | — | SQ-5 | PGMEA | DAA |
| | | | (80) | | (7.6) | (2200) | (900) |
| | 1-6 | R-06 | P-1 | — | SQ-6 | PGMEA | DAA |
| | | | (80) | | (7.8) | (2200) | (900) |
| | 1-7 | R-07 | P-1 | — | SQ-7 | PGMEA | DAA |
| | | | (80) | | (8.6) | (2200) | (900) |
| | 1-8 | R-08 | P-1 | — | SQ-8 | PGMEA | DAA |
| | | | (80) | | (8.1) | (2200) | (900) |
| | 1-9 | R-09 | P-1 | — | SQ-9 | PGMEA | DAA |
| | | | (80) | | (6.3) | (2200) | (900) |
| | 1-10 | R-10 | P-1 | — | SQ-10 | PGMEA | DAA |
| | | | (80) | | (7.3) | (2200) | (900) |
| | 1-11 | R-11 | P-2 | — | SQ-1 | PGMEA | DAA |
| | | | (80) | | (7.3) | (2200) | (900) |
| | 1-12 | R-12 | P-3 | — | SQ-2 | PGMEA | DAA |
| | | | (80) | | (7.2) | (2200) | (900) |
| | 1-13 | R-13 | P-4 | — | SQ-3 | PGMEA | DAA |
| | | | (80) | | (6.0) | (2200) | (900) |
| | 1-14 | R-14 | P-5 | — | SQ-4 | PGMEA | DAA |
| | | | (80) | | (7.3) | (2200) | (900) |
| | 1-15 | R-15 | P-6 | — | SQ-5 | PGMEA | DAA |
| | | | (80) | | (7.6) | (2200) | (900) |

TABLE 3

| | | Resist | Base | Photoacid | Quen- | Sol- | Sol- |
|---|---|---|---|---|---|---|---|
| | | com- | polymer | generator | cher | vent 1 | vent 2 |
| | | position | (pbw) | (pbw) | (pbw) | (pbw) | (pbw) |
| Ex- | 1-16 | R-16 | P-7 | — | SQ-6 | PGMEA | DAA |
| am- | | | (80) | | (7.8) | (2200) | (900) |
| ple | 1-17 | R-17 | P-8 | — | SQ-7 | PGMEA | DAA |
| | | | (80) | | (8.6) | (2200) | (900) |
| | 1-18 | R-18 | P-9 | — | SQ-8 | PGMEA | DAA |
| | | | (80) | | (8.1) | (2200) | (900) |
| | 1-19 | R-19 | P-10 | — | SQ-9 | PGMEA | DAA |
| | | | (80) | | (6.3) | (2200) | (900) |
| | 1-20 | R-20 | P-11 | — | SQ-10 | PGMEA | DAA |
| | | | (80) | | (7.3) | (2200) | (900) |
| | 1-21 | R-21 | P-12 | — | SQ-9 | PGMEA | DAA |
| | | | (80) | | (6.3) | (2200) | (900) |
| | 1-22 | R-22 | P-13 | — | SQ-10 | PGMEA | DAA |
| | | | (80) | | (7.3) | (2200) | (900) |
| | 1-23 | R-23 | P-14 | PAG-X | SQ-1 | PGMEA | DAA |
| | | | (80) | (28.0) | (7.3) | (2200) | (900) |
| | 1-24 | R-24 | P-15 | PAG-Y | SQ-3 | PGMEA | DAA |
| | | | (80) | (29.6) | (6.0) | (2200) | (900) |
| | 1-25 | R-25 | P-16 | PAG-X | SQ-5 | PGMEA | DAA |
| | | | (80) | (28.0) | (7.6) | (2200) | (900) |
| | 1-26 | R-26 | P-17 | PAG-Y | SQ-7 | PGMEA | DAA |
| | | | (80) | (29.6) | (8.6) | (2200) | (900) |
| | 1-27 | R-27 | P-18 | PAG-X | SQ-9 | PGMEA | DAA |
| | | | (80) | (28.0) | (6.3) | (2200) | (900) |
| | 1-28 | R-28 | P-1 | PAG-X | SQ-1 | PGMEA | DAA |
| | | | (80) | (8.0) | (7.3) | (2200) | (900) |
| | 1-29 | R-29 | P-3 | — | SQ-1 (3.6) | PGMEA | DAA |
| | | | (80) | | SQ-3 (3.0) | (2200) | (900) |
| | 1-30 | R-30 | P-11 | — | SQ-2 | PGMEA | DAA |
| | | | (80) | | (7.2) | (2200) | (900) |

TABLE 4

| | | Resist | Base | Photo- | | | |
|---|---|---|---|---|---|---|---|
| | | com- | poly- | acid | Quen- | Sol- | Sol- |
| | | po- | mer | generator | cher | vent 1 | vent 2 |
| | | sition | (pbw) | (pbw) | (pbw) | (pbw) | (pbw) |
| Com- | 1-1 | CR-01 | P-1 | — | SQ-A | PGMEA | DAA |
| par- | | | (80) | | (7.8) | (2200) | (900) |
| ative | 1-2 | CR-02 | P-1 | — | SQ-B | PGMEA | DAA |
| Ex- | | | (80) | | (8.8) | (2200) | (900) |
| am- | 1-3 | CR-03 | P-1 | — | SQ-C | PGMEA | DAA |
| ple | | | (80) | | (8.5) | (2200) | (900) |
| | 1-4 | CR-04 | P-1 | — | SQ-D | PGMEA | DAA |
| | | | (80) | | (9.1) | (2200) | (900) |
| | 1-5 | CR-05 | P-2 | — | SQ-A | PGMEA | DAA |
| | | | (80) | | (7.8) | (2200) | (900) |
| | 1-6 | CR-06 | P-3 | — | SQ-B | PGMEA | DAA |
| | | | (80) | | (8.8) | (2200) | (900) |
| | 1-7 | CR-07 | P-4 | — | SQ-C | PGMEA | DAA |
| | | | (80) | | (8.5) | (2200) | (900) |
| | 1-8 | CR-08 | P-5 | — | SQ-D | PGMEA | DAA |
| | | | (80) | | (9.1) | (2200) | (900) |
| | 1-9 | CR-09 | P-6 | — | SQ-A | PGMEA | DAA |
| | | | (80) | | (7.8) | (2200) | (900) |
| | 1-10 | CR-10 | P-7 | — | SQ-B | PGMEA | DAA |
| | | | (80) | | (8.8) | (2200) | (900) |
| | 1-11 | CR-11 | P-8 | — | SQ-C | PGMEA | DAA |
| | | | (80) | | (8.5) | (2200) | (900) |
| | 1-12 | CR-12 | P-9 | — | SQ-D | PGMEA | DAA |
| | | | (80) | | (9.1) | (2200) | (900) |
| | 1-13 | CR-13 | P-10 | — | SQ-A | PGMEA | DAA |
| | | | (80) | | (7.8) | (2200) | (900) |
| | 1-14 | CR-14 | P-11 | — | SQ-B | PGMEA | DAA |
| | | | (80 | | (8.8) | (2200) | (900) |
| | 1-15 | CR-15 | P-12 | — | SQ-C | PGMEA | DAA |
| | | | (80) | | (8.5) | (2200) | (900) |
| | 1-16 | CR-16 | P-13 | — | SQ-D | PGMEA | DAA |
| | | | (80) | | (9.1) | (2200) | (900) |
| | 1-17 | CR-17 | P-14 | PAG-X | SQ-A | PGMEA | DAA |
| | | | (80) | (28.0) | (7.8) | (2200) | (900) |
| | 1-18 | CR-18 | P-15 | PAG-Y | SQ-B | PGMEA | DAA |
| | | | (80) | (29.6) | (8.8) | (2200) | (900) |
| | 1-19 | CR-19 | P-16 | PAG-X | SQ-C | PGMEA | DAA |
| | | | (80) | (28.0) | (8.5) | (2200) | (900) |
| | 1-20 | CR-20 | P-17 | PAG-Y | SQ-D | PGMEA | DAA |
| | | | (80 | (29.6) | (9.1) | (2200) | (900) |
| | 1-21 | CR-21 | P-18 | PAG-X | SQ-A | PGMEA | DAA |
| | | | (80) | (28.0) | (7.8) | (2200) | (900) |
| | 1-22 | CR-22 | P-1 | PAG-X | SQ-B | PGMEA | DAA |
| | | | (80) | (8.0) | (8.8) | (2200) | (900) |
| | 1-23 | CR-23 | P-3 | — | SQ-C (4.2) | PGMEA | DAA |
| | | | (80) | | SQ-D (4.5) | (2200) | (900) |
| | 1-24 | CR-24 | P-11 | — | SQ-A | PGMEA | DAA |
| | | | (80) | | (7.8) | (2200) | (900) |

### [4] EUV Lithography Test

### Examples 2-1 to 2-30 and Comparative Examples 2-1 to 2-24

Each of the resist compositions (R-01 to R-30, CR-01 to CR-24) was spin coated on a silicon substrate having a 20-nm coating of silicon-containing spin-on hard mask SHB-A940 (Shin-Etsu Chemical Co., Ltd., silicon content 43 wt %) and prebaked on a hotplate at 100° C. for 60 seconds to form a resist film of 50 nm thick. Using an EUV scanner NXE3300 (ASML, NA 0.33, σ 0.9/0.6, dipole illumination), the resist film was exposed to EUV through a mask bearing a line-and-space (LS) pattern having a width of 18 nm and a pitch of 36 nm (on-wafer size) while changing the dose at a pitch of 1 mJ/cm² and the focus at a pitch of 0.020 μm. The resist film was baked (PEB) at the temperature shown in Tables 5 and 6 for 60 seconds. This was followed by puddle development in a 2.38 wt % TMAH aqueous solution for 30 seconds, rinsing with a surfactant-containing rinse fluid, and spin drying. A positive LS pattern was obtained.

The LS pattern was observed under CD-SEM (CG6300, Hitachi High-Technologies Corp.) and evaluated for sensitivity, exposure latitude (EL), LWR, depth of focus (DOF), and collapse limit by the following methods. The results are shown in Tables 5 and 6.

### Evaluation of Sensitivity

The optimum dose Eop (mJ/cm²) which provided an LS pattern with a line width of 18 nm and a pitch of 36 nm was determined and reported as sensitivity.

### Evaluation of EL

The exposure dose which provided a LS pattern with a space width of 18 nm+10% (i.e., 16.2 to 19.8 nm) was determined. EL (%) is calculated from the exposure doses according to the following equation:

EL (%)=(|E1−E2|/Eop)×100

wherein E1 is an optimum exposure dose which provides a LS pattern with a line width of 16.2 nm and a pitch of 36 m, E2 is an optimum exposure dose which provides a LS pattern with a line width of 19.8 nm and a pitch of 36 nm, and Eop is an optimum exposure dose which provides a LS pattern with a line width of 18 nm and a pitch of 36 nm. A larger value indicates better performance.

### Evaluation of LWR

For the LS pattern formed by exposure at the optimum dose Eop, the line width was measured at 10 longitudinally spaced apart points, from which a 3-fold value (3a) of the standard deviation (a) was determined and reported as LWR. A smaller value of 3a indicates a pattern having small roughness and uniform line width.

### Evaluation of DOF

As an index of DOF, a range of focus which provided a LS pattern with a size of 18 nm±10% (i.e., 16.2 to 19.8 nm) was determined. A greater value indicates a wider DOF.

### Evaluation of Collapse Limit of Line Pattern

For the LS pattern formed by exposure at the dose corresponding to the optimum focus, the line width was measured at 10 longitudinally spaced apart points. The minimum line size above which lines could be resolved without collapse was determined and reported as collapse limit. A smaller value indicates better collapse limit.

TABLE 5

| | | Resist | PEB | Eop | | | | Collapse |
|---|---|---|---|---|---|---|---|---|
| | | com- | temp. | (mJ)/ | EL | LWR | DOF | limit |
| | | position | (° C.) | cm²) | (%) | (nm) | (nm) | (nm) |
| Ex- | 2-1 | R-01 | 105 | 38 | 18 | 2.7 | 110 | 10.6 |
| am- | 2-2 | R-02 | 100 | 39 | 17 | 2.6 | 120 | 10.4 |
| ple | 2-3 | R-03 | 110 | 41 | 19 | 2.8 | 130 | 11.2 |
| | 2-4 | R-04 | 105 | 40 | 19 | 2.9 | 120 | 11.0 |
| | 2-5 | R-05 | 105 | 38 | 18 | 2.9 | 120 | 10.8 |
| | 2-6 | R-06 | 110 | 39 | 18 | 3.0 | 110 | 10.6 |
| | 2-7 | R-07 | 105 | 41 | 17 | 2.9 | 110 | 10.2 |
| | 2-8 | R-08 | 110 | 40 | 19 | 3.0 | 120 | 10.7 |
| | 2-9 | R-09 | 110 | 38 | 19 | 3.0 | 130 | 11.1 |
| | 2-10 | R-10 | 105 | 39 | 19 | 2.9 | 130 | 11.0 |
| | 2-11 | R-11 | 105 | 41 | 17 | 2.7 | 120 | 10.6 |
| | 2-12 | R-12 | 100 | 40 | 18 | 2.6 | 110 | 10.7 |
| | 2-13 | R-13 | 110 | 38 | 19 | 2.8 | 130 | 11.1 |
| | 2-14 | R-14 | 110 | 39 | 19 | 2.9 | 130 | 11.2 |
| | 2-15 | R-15 | 105 | 41 | 18 | 2.9 | 120 | 10.8 |
| | 2-16 | R-16 | 105 | 40 | 18 | 3.0 | 110 | 10.7 |
| | 2-17 | R-17 | 100 | 38 | 18 | 2.8 | 100 | 10.1 |
| | 2-18 | R-18 | 110 | 39 | 19 | 2.9 | 120 | 10.7 |
| | 2-19 | R-19 | 105 | 41 | 19 | 3.0 | 130 | 11.0 |
| | 2-20 | R-20 | 105 | 40 | 18 | 2.9 | 120 | 10.9 |
| | 2-21 | R-21 | 105 | 38 | 19 | 2.9 | 120 | 10.9 |
| | 2-22 | R-22 | 100 | 39 | 18 | 2.9 | 120 | 10.8 |
| | 2-23 | R-23 | 105 | 41 | 17 | 2.6 | 110 | 10.2 |
| | 2-24 | R-24 | 110 | 40 | 19 | 2.8 | 120 | 10.8 |
| | 2-25 | R-25 | 110 | 38 | 18 | 2.9 | 120 | 10.7 |
| | 2-26 | R-26 | 105 | 39 | 18 | 3.0 | 110 | 10.1 |
| | 2-27 | R-27 | 110 | 41 | 19 | 3.0 | 120 | 11.1 |
| | 2-28 | R-28 | 105 | 40 | 17 | 2.7 | 100 | 10.4 |
| | 2-29 | R-29 | 110 | 38 | 18 | 2.8 | 110 | 10.5 |
| | 2-30 | R-30 | 105 | 36 | 17 | 2.7 | 110 | 10.3 |

TABLE 6

| | | Resist | PEB | Eop | | | | Collapse |
|---|---|---|---|---|---|---|---|---|
| | | com- | temp. | (mJ)/ | EL | LWR | DOF | limit |
| | | position | (° C.) | cm²) | (%) | (nm) | (nm) | (nm) |
| Com- | 2-1 | CR-01 | 105 | 37 | 17 | 3.4 | 90 | 14.8 |
| parative | 2-2 | CR-02 | 100 | 36 | 16 | 3.2 | 100 | 15.5 |
| Example | 2-3 | CR-03 | 110 | 39 | 17 | 3.6 | 100 | 15.3 |
| | 2-4 | CR-04 | 105 | 40 | 15 | 3.1 | 90 | 14.8 |
| | 2-5 | CR-05 | 105 | 38 | 16 | 3.5 | 80 | 14.5 |
| | 2-6 | CR-06 | 100 | 38 | 16 | 3.3 | 100 | 15.4 |
| | 2-7 | CR-07 | 110 | 40 | 17 | 3.8 | 90 | 15.4 |
| | 2-8 | CR-08 | 110 | 39 | 16 | 3.2 | 90 | 14.6 |
| | 2-9 | CR-09 | 105 | 37 | 17 | 3.5 | 80 | 15.0 |
| | 2-10 | CR-10 | 105 | 37 | 17 | 3.2 | 90 | 15.1 |
| | 2-11 | CR-11 | 100 | 38 | 18 | 3.6 | 90 | 15.2 |
| | 2-12 | CR-12 | 110 | 39 | 16 | 3.2 | 90 | 14.9 |
| | 2-13 | CR-13 | 105 | 38 | 18 | 3.4 | 90 | 14.8 |
| | 2-14 | CR-14 | 105 | 37 | 17 | 3.3 | 100 | 15.2 |
| | 2-15 | CR-15 | 105 | 40 | 17 | 3.5 | 100 | 15.0 |
| | 2-16 | CR-16 | 100 | 40 | 16 | 3.2 | 90 | 15.0 |
| | 2-17 | CR-17 | 105 | 37 | 17 | 3.3 | 80 | 15.1 |
| | 2-18 | CR-18 | 110 | 38 | 17 | 3.1 | 100 | 15.5 |
| | 2-19 | CR-19 | 110 | 39 | 18 | 3.5 | 90 | 15.3 |
| | 2-20 | CR-20 | 105 | 40 | 17 | 3.1 | 90 | 15.0 |
| | 2-21 | CR-21 | 110 | 37 | 16 | 3.3 | 80 | 14.8 |
| | 2-22 | CR-22 | 105 | 38 | 15 | 3.2 | 90 | 15.1 |
| | 2-23 | CR-23 | 110 | 40 | 15 | 3.5 | 90 | 15.2 |
| | 2-24 | CR-24 | 105 | 38 | 17 | 3.4 | 80 | 14.8 |

It is demonstrated in Tables 5 and 6 that resist compositions within the scope of the invention exhibit a high sensitivity, improved lithography properties, and resistance to pattern collapse.

Japanese Patent Application No. 2022-189708 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A resist composition comprising (A) a base polymer containing a polymer comprising repeat units having an acid labile group, (B) an organic solvent, and (C) an onium salt having the formula (1):
Zq⁺Xq⁻ (1)
wherein Zq⁺ is a sulfonium, iodonium or ammonium cation, and Xq⁻ is an anion, with the proviso that an acid having Xq⁻ as conjugate base, i.e., XqH has a boiling point of lower than 165° C. and a molecular weight of up to 150.

2. The resist composition of claim 1 wherein the repeat unit having an acid labile group is represented by the formula (a1) or (a2): 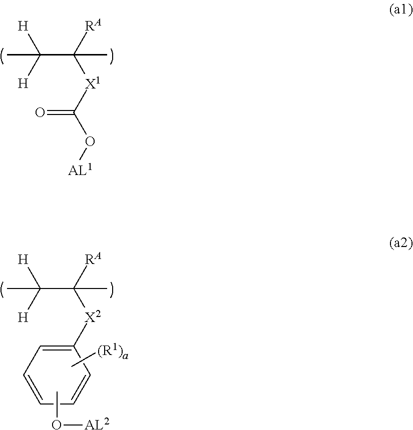
wherein R^{A} is each independently hydrogen, fluorine, methyl or trifluoromethyl,
X¹ is a single bond, phenylene group, naphthylene group or *—C(═O)—O—X¹¹—, X¹¹ is a C₁-C₁₀ saturated hydrocarbylene group which may contain a hydroxy moiety, ether bond, ester bond or lactone ring, a phenylene group or naphthylene group,
X² is a single bond or *—C(═O)—O—,
* designates a point of attachment to the carbon atom in the backbone, and
AL¹ and AL² are each independently an acid labile group,
R¹ is halogen or a C₁-C₂₀ hydrocarbyl group which may contain a heteroatom, and
a is an integer of 0 to 4.

3. The resist composition of claim 1 wherein the polymer further comprises repeat units having the formula (b1) or (b2): 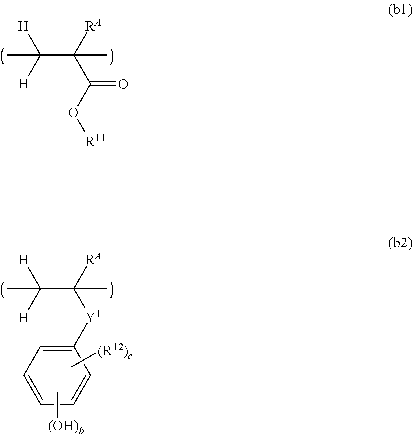
wherein R^{A} is each independently hydrogen, fluorine, methyl or trifluoromethyl,
Y¹ is a single bond or *—C(═O)—O—, * designates a point of attachment to the carbon atom in the backbone,
R¹¹ is hydrogen, or a C₁-C₂₀ group containing at least one moiety selected from hydroxy moiety, cyano moiety, carbonyl moiety, carboxy moiety, ether bond, ester bond, sulfonic ester bond, carbonate bond, lactone ring, sultone ring, and carboxylic anhydride (—C(═O)—O—C(═O)—),
R¹² is halogen or a C₁-C₂₀ hydrocarbyl group which may contain a heteroatom,
b is 1 or 2, c is an integer of 0 to 4, and b+c is from 1 to 5.

4. The resist composition of claim 1 wherein the polymer further comprises repeat units having a photoacid generating group.

5. The resist composition of claim 4 wherein the repeat unit having a photoacid generating group is represented by any one of the formulae (c1) to (c4): 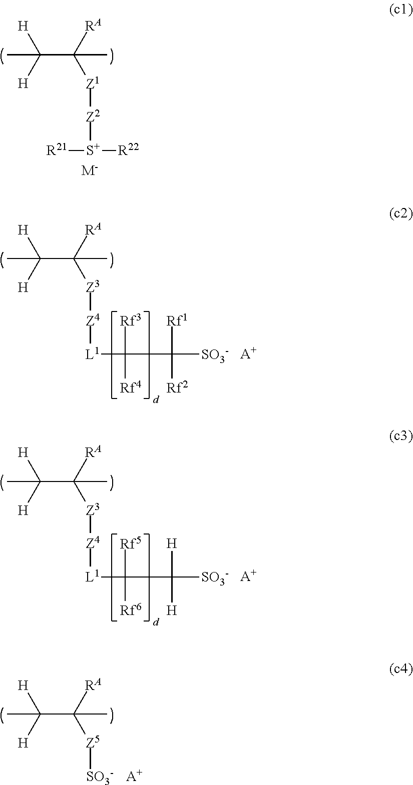
wherein R^{A} is each independently hydrogen, fluorine, methyl or trifluoromethyl,
Z¹ is a single bond or phenylene group,
Z² is *—C(═O)—O—Z²¹—, *—C(═O)—NH—Z²¹—, or *—O—Z²¹—, wherein Z²¹ is a C₁-C₆ aliphatic hydrocarbylene group, phenylene, or divalent group obtained by combining the foregoing, which may contain a carbonyl moiety, ester bond, ether bond or hydroxy moiety,
Z³ is a single bond, phenylene group, naphthylene group or *—C(═O)—O—Z³¹—, wherein Z³¹ is a C₁-C₁₀ aliphatic hydrocarbylene group which may contain a hydroxy moiety, ether bond, ester bond or lactone ring, or a phenylene group or naphthylene group,
Z⁴ is a single bond or **—Z⁴¹—C(═O)—O—, wherein Z⁴¹ is a C₁-C₂₀ hydrocarbylene group which may contain a heteroatom,
Z⁵ is a single bond, methylene, ethylene, phenylene, fluorinated phenylene, trifluoromethyl-substituted phenylene, *—C(═O)—O—Z⁵¹—, *—C(═O)—N(H)—Z⁵¹— or *—O—Z⁵¹—, wherein Z⁵¹ is a C₁-C₆ aliphatic hydrocarbylene group, phenylene, fluorinated phenylene or trifluoromethyl-substituted phenylene group, which may contain a carbonyl moiety, ester bond, ether bond or hydroxy moiety,
* designates a point of attachment to the carbon atom in the backbone, ** designates a point of attachment to Z³,
R²¹ and R²² are each independently a C₁-C₂₀ hydrocarbyl group which may contain a heteroatom, R²¹ and R² may bond together to form a ring with the sulfur atom to which they are attached,
L¹ is a single bond, ether bond, ester bond, carbonyl group, sulfonic ester bond, carbonate bond or carbamate bond,
Rf¹ and Rf² are each independently fluorine or a C₁-C₆ fluorinated saturated hydrocarbyl group,
Rf³ and Rf⁴ are each independently hydrogen, fluorine or a C₁-C₆ fluorinated saturated hydrocarbyl group,
Rf⁵ and Rf⁶ are each independently hydrogen, fluorine or a C₁-C₆ fluorinated saturated hydrocarbyl group, excluding that all Rf and Rf are hydrogen at the same time,
M⁻ is a non-nucleophilic counter anion,
A⁻ is an onium cation, and
d is an integer of 0 to 3.

6. The resist composition of claim 1, further comprising (D) a photoacid generator.

7. The resist composition of claim 6 wherein the photoacid generator (D) has the formula (2) or (3): 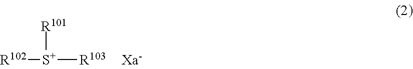
wherein R¹⁰¹, R¹⁰² and R¹⁰³ are each independently a C₁-C₂₀ hydrocarbyl group which may contain a heteroatom, R¹⁰¹ and R¹⁰² may bond together to form a ring with the sulfur atom to which the are attached, Xa⁻ is a non-nucleophilic counter anion, 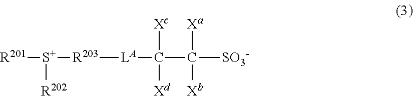
wherein R²⁰¹ and R²⁰² are each independently a C₁-C₃₀ hydrocarbyl group which may contain a heteroatom, R²⁰³ is a C₁-C₃₀ hydrocarbylene group which may contain a heteroatom, any two of R²⁰¹, R²⁰² and R²⁰³ may bond together to form a ring with the sulfur atom to which they are attached,
L^{A} is a single bond, ether bond or a C₁-C₂₀ hydrocarbylene group which may contain a heteroatom,
X^{a}, X^{b}, X^{c} and X^{d} are each independently hydrogen, fluorine or trifluoromethyl, with the proviso that at least one of X^{a}, X^{b}, X^{c} and X^{d} is fluorine or trifluoromethyl.

8. The resist composition of claim 1, further comprising (E) a nitrogen-containing compound.

9. The resist composition of claim 1, further comprising (F) a surfactant.

10. A process for forming a pattern comprising the steps of applying the resist composition of claim 1 to a substrate to form a resist film thereon, exposing the resist film to KrF excimer laser, ArF excimer laser, EB or EUV and developing the exposed resist film in a developer.
